(19) United States
(12) Patent Application Publication
(10) Pub. No.: US 2023/0422608 A1
(43) Pub. Date: Dec. 28, 2023

(54) ORGANIC ELECTROLUMINESCENT ELEMENT AND ELECTRONIC DEVICE

(71) Applicant: IDEMITSU KOSAN CO.,LTD., Tokyo (JP)

(72) Inventors: Hisato MATSUMOTO, Tokyo (JP); Yukitoshi JINDE, Tokyo (JP); Takushi SHIOMI, Tokyo (JP)

(73) Assignee: IDEMITSU KOSAN CO.,LTD., Tokyo (JP)

(21) Appl. No.: 18/128,379

(22) Filed: Mar. 30, 2023

(30) Foreign Application Priority Data
Mar. 30, 2022 (JP) 2022-055805

(51) Int. Cl. H10K 85/60; H10K 50/17; H10K 50/16; H10K 50/81; H10K 50/82

(52) U.S. Cl. CPC H10K 85/636; H10K 85/6572; H10K 50/82; H10K 50/166; H10K 50/81; H10K 50/171

(57) ABSTRACT

An organic electroluminescence device includes an emitting layer between an anode and a cathode, and a first layer between the anode and the emitting layer, in which the emitting layer contains a delayed fluorescent compound M1 represented by a formula (1), the first layer contains a compound M4 represented by a formula (4), and the compound M4 satisfies formulae (a) and (b),

μ_{H}(M4)≤1.0×10⁻³ cm²/Vs Formula (a):

S₁(M4)≥3.15 eV Formula (b):

where: μ_{H}(M4) represents hole mobility of the compound M4; and S₁(M4) represents a lowest singlet energy of the compound M4.

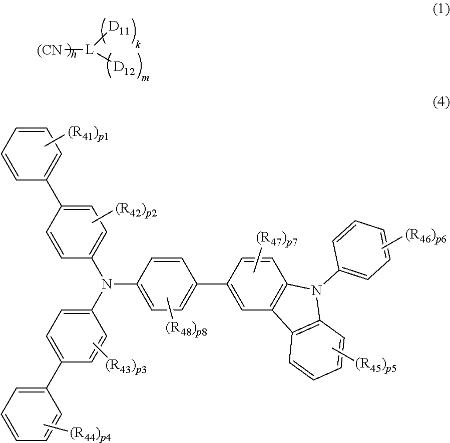

### TECHNICAL FIELD

The present invention relates to an organic electroluminescence device and an electronic device.

### BACKGROUND ART

When a voltage is applied to an organic electroluminescence device (hereinafter, occasionally referred to as “organic EL device”), holes are injected from an anode and electrons are injected from a cathode into an emitting layer. The injected electrons and holes are recombined in the emitting layer to form excitons. Specifically, according to the electron spin statistics theory, singlet excitons and triplet excitons are generated at a ratio of 25%:75%.

A fluorescent organic EL device using light emission from singlet excitons has been applied to a full-color display such as a mobile phone and a television set, but an internal quantum efficiency is said to be at a limit of 25%. Studies have thus been made to improve performance of the organic EL device.

For instance, the organic EL device is expected to emit light more efficiently using triplet excitons in addition to singlet excitons. In view of the above, a highly-efficient fluorescent organic EL device using thermally activated delayed fluorescence (hereinafter simply referred to as “delayed fluorescence” in some cases) has been proposed and studied.

A thermally activated delayed fluorescence (TADF) mechanism uses such a phenomenon in which inverse intersystem crossing from triplet excitons to singlet excitons thermally occurs when a material having a small energy difference (ΔST) between singlet energy level and triplet energy level is used. Thermally activated delayed fluorescence is explained in “Yuki Hando-tai no Debaisu Bussei (Device Physics of Organic Semiconductors)” (edited by ADACHI Chihaya, published by Kodansha, issued on Apr. 1, 2012, on pages 261-268).

As a compound exhibiting TADF properties (hereinafter also referred to as a TADF compound), for instance, a compound in which a donor moiety and an acceptor moiety are bonded in a molecule is known.

Patent Literature 1 (US Patent Application Publication No. 2020/0203621) discloses an organic EL Device including an emitting layer including a delayed fluorescent compound.

A further improvement in performance of the organic EL device has been demanded for an improvement in performance of an electronic device such as a display. The performance of the organic EL device is evaluable in terms of, for instance, luminance, emission wavelength, chromaticity, luminous efficiency, drive voltage, and lifetime.

### SUMMARY OF THE INVENTION

An object of the invention is to provide an organic electroluminescence device capable of exhibiting an improved luminous efficiency and an electronic device including the organic electroluminescence device.

According to an aspect of the invention, an organic electroluminescence device includes an anode, a cathode, an emitting layer between the anode and the cathode, and a first layer provided between the anode and the emitting layer, in which the emitting layer contains a compound M1 represented by a formula (1) below, the compound M1 is a delayed fluorescent compound, the first layer contains a compound M4 represented by a formula (4) below, and the compound M4 satisfies formulae (a) and (b) below.

μ_{H}(M4)≤1.0×10⁻³ cm²/Vs Formula (a):

S₁(M4)≥3.15 eV Formula (b):

μ_{H}(M4) represents hole mobility of the compound M4. S₁(M4) represents a lowest singlet energy of the compound M4.

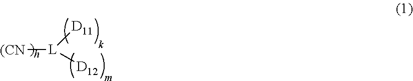

In the formula (1):
CN is a cyano group;
L is a substituted or unsubstituted aromatic hydrocarbon ring having 6 to 30 ring carbon atoms;
D₁₁ and D₁₂ are each independently a group represented by a formula (11), (12) or (13) below;
h is an integer of 2 or more;
k is an integer of 1 or more;
m is an integer of 0 or more;
D₁₁ and D₁₂ are mutually the same or different;
a plurality of D₁₁ are mutually the same or different; and
a plurality of D₁₂ are mutually the same or different.

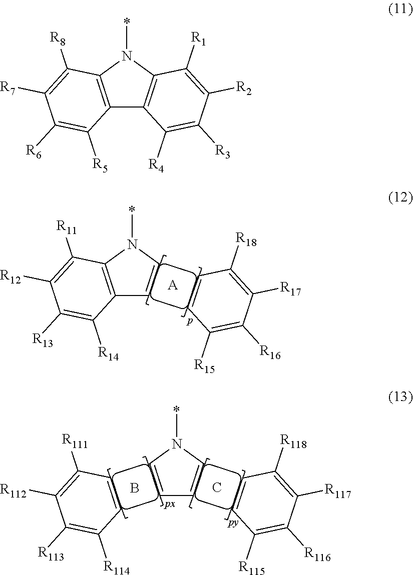

In the formula (11), at least one combination of adjacent two or more of R₁ to R₈ are mutually bonded to form a substituted or unsubstituted monocyclic ring, mutually bonded to form a substituted or unsubstituted fused ring, or not mutually bonded.

In the formula (12), at least one combination of adjacent two or more of R₁₁ to R₁₈ are mutually bonded to form a substituted or unsubstituted monocyclic ring, mutually bonded to form a substituted or unsubstituted fused ring, or not mutually bonded.

In the formula (13), at least one combination of adjacent two or more of R₁₁₁ to R₁₁₈ are mutually bonded to form a substituted or unsubstituted monocyclic ring, mutually bonded to form a substituted or unsubstituted fused ring, or not mutually bonded;
at least one D₁₁ is: a group represented by the formula (11) in which at least one combination of adjacent two or more of R₁ to R₈ are mutually bonded to form the substituted or unsubstituted monocyclic ring or the substituted or unsubstituted fused ring; a group represented by the formula (12); or a group represented by the formula (13);
R₁ to R₈ forming neither the substituted or unsubstituted monocyclic ring nor the substituted or unsubstituted fused ring in the formula (11), R₁₁ to R₁₈ forming neither the substituted or unsubstituted monocyclic ring nor the substituted or unsubstituted fused ring in the formula (12), and R₁₁₁ to R₁₁₈ forming neither the substituted or unsubstituted monocyclic ring nor the substituted or unsubstituted fused ring in the formula (13) are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COPR₉₀₉, a halogen atom, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms.

In the formulae (12) and (13):
a ring A, a ring B, and a ring C are each independently any cyclic structure selected from the group consisting of cyclic structures represented by formulae (14) and (15) below;
the ring A, the ring B, and the ring C are fused with adjacent rings at any positions;
p, px and py are each independently 1, 2, 3, or 4;
when p is 2, 3, or 4, a plurality of rings A are mutually the same or different;
when px is 2, 3, or 4, a plurality of rings B are mutually the same or different;
when py is 2, 3, or 4, a plurality of rings C are mutually the same or different; and
* in the formulae (11) to (13) represents a bonding position to L in the formula (1).

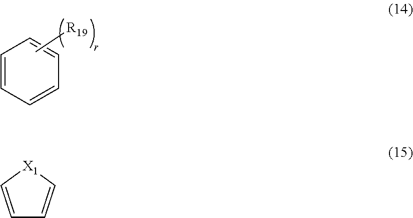

In the formula (14):
r is 0, 2, or 4;
a combination of a plurality of R₁₉ are mutually bonded to form a substituted or unsubstituted monocyclic ring, mutually bonded to form a substituted or unsubstituted fused ring, or not mutually bonded.

In the formula (15): X₁ is a sulfur atom, an oxygen atom, C(R₁₅₁)(R₁₅₂), or N(R₁₅₃);
a combination of R₁₅₁ and R₁₅₂ are mutually bonded to form a substituted or unsubstituted monocyclic ring, mutually bonded to form a substituted or unsubstituted fused ring, or not mutually bonded;
R₁₅₃, R₁₅₁ and R₁₅₂ forming neither the substituted or unsubstituted monocyclic ring nor the substituted or unsubstituted fused ring, and R₁₉ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₉₂)(R₉₉₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₆, a group represented by —COOR₉₀₉, a halogen atom, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms;
a plurality of R₁₉ are mutually the same or different; and a plurality of X₁ are mutually the same or different.

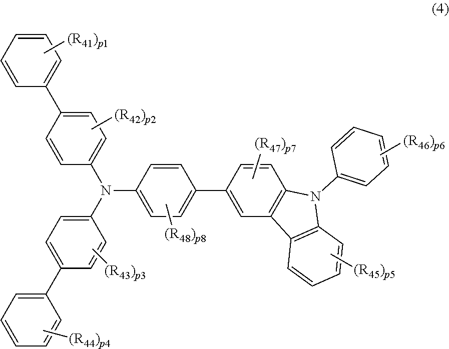

In the formula (4):
p1 is 5, p2 is 4, p3 is 4, p4 is 5, p5 is 4, p6 is 5, p7 is 3, and p8 is 4;
a plurality of R₄₁ are mutually the same or different;
at least one combination of adjacent two or more of the plurality of R₄₁ are mutually bonded to form a substituted or unsubstituted monocyclic ring, mutually bonded to form a substituted or unsubstituted fused ring, or not mutually bonded;
a plurality of R₄₂ are mutually the same or different;
at least one combination of adjacent two or more of the plurality of R₄₂ are mutually bonded to form a substituted or unsubstituted monocyclic ring, mutually bonded to form a substituted or unsubstituted fused ring, or not mutually bonded;
a plurality of R₄₃ are mutually the same or different;
at least one combination of adjacent two or more of the plurality of R₄₃ are mutually bonded to form a substituted or unsubstituted monocyclic ring, mutually bonded to form a substituted or unsubstituted fused ring, or not mutually bonded;
a plurality of R₄₄ are mutually the same or different;
at least one combination of adjacent two or more of the plurality of R₄₄ are mutually bonded to form a substituted or unsubstituted monocyclic ring, mutually bonded to form a substituted or unsubstituted fused ring, or not mutually bonded;
a plurality of R₄₅ are mutually the same or different;
at least one combination of adjacent two or more of the plurality of R₄₅ are mutually bonded to form a substituted or unsubstituted monocyclic ring, mutually bonded to form a substituted or unsubstituted fused ring, or not mutually bonded;
a plurality of R₄₆ are mutually the same or different;
at least one combination of adjacent two or more of the plurality of R₄₆ are mutually bonded to form a substituted or unsubstituted monocyclic ring, mutually bonded to form a substituted or unsubstituted fused ring, or not mutually bonded; a combination of R₄₁ and R₄₂ are mutually bonded to form a substituted or unsubstituted monocyclic ring, mutually bonded to form a substituted or unsubstituted fused ring, or not mutually bonded;
a combination of R₄₃ and R₄₄ are mutually bonded to form a substituted or unsubstituted monocyclic ring, mutually bonded to form a substituted or unsubstituted fused ring, or not mutually bonded;
a plurality of R₄₇ are mutually the same or different;
a plurality of R₄₈ are mutually the same or different;
R₄₁ to R₄₆ forming neither the substituted or unsubstituted monocyclic ring nor the substituted or unsubstituted fused ring and R₄₇ to R₄₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms; the compound M4 satisfies at least one of conditions (i), (ii), (iii), (iv), and (v) below:
the condition (i): at least one R₄₁ is not a hydrogen atom;
the condition (ii): a combination of R₄₁ and R₄₂ are mutually bonded to form a substituted or unsubstituted monocyclic ring or a substituted or unsubstituted fused ring;
the condition (iii): at least one combination of adjacent two or more of a plurality of R₄₁ are mutually bonded to form a substituted or unsubstituted monocyclic ring or a substituted or unsubstituted fused ring;
the condition (iv): at least one combination of adjacent two or more of a plurality of R₄₆ are mutually bonded to form a substituted or unsubstituted monocyclic ring or a substituted or unsubstituted fused ring; and the condition (v): at least one R₄₆ is not a hydrogen atom.

In the formulae, R₉₀₁, R₉₀₂, R₉₀₃, R₉₀₄, R₉₀₅, R₉₀₆, R₉₀₇, R₉₀₈, R₉₀₉, R₉₃₁, R₉₃₂, R₉₃₃, R₉₃₄, R₉₃₅, R₉₃₆, and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₀₈ are present, the plurality of R₉₀₈ are mutually the same or different;
when a plurality of R₉₀₉ are present, the plurality of R₉₀₉ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

According to another aspect of the invention, an electronic device including the organic electroluminescence device according to the aspect of the invention is provided.

According to still another aspect of the invention, an organic electroluminescence device excellent in luminous efficiency can be provided. According to a further aspect of the invention, an electronic device including the organic electroluminescence device can be provided.

### BRIEF DESCRIPTION OF DRAWINGS

FIG. 1 schematically illustrates an exemplary arrangement of an organic electroluminescence device according to a first exemplary embodiment of the invention.

FIG. 2 schematically illustrates an apparatus for measuring transient PL.

FIG. 3 shows an example of decay curves of the transient PL.

FIG. 4 schematically illustrates a relationship in energy level and energy transfer between a compound M1 and a compound M2 in an emitting layer of an exemplary organic electroluminescence device according to the first exemplary embodiment of the invention.

FIG. 5 schematically illustrates a relationship in energy level and energy transfer between the compound M1, the compound M2 and a compound M3 in an emitting layer of an exemplary organic electroluminescence device according to a second exemplary embodiment of the invention.

FIG. 6 schematically illustrates a relationship in energy level and energy transfer between the compound M1 and the compound M3 in an emitting layer of an exemplary organic electroluminescence device according to a third exemplary embodiment of the invention.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, cross-linking compound, carbon ring compound, and heterocyclic compound) in which the atoms are bonded to each other to form the ring. When the ring is substituted by a substituent(s), carbon atom(s) included in the substituent(s) is not counted in the ring carbon atoms. Unless otherwise specified, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring has 4 ring carbon atoms. Further, for instance, 9,9-diphenylfluorenyl group has 13 ring carbon atoms and 9,9′-spirobifluorenyl group has 25 ring carbon atoms.

When a benzene ring is substituted by a substituent in a form of, for instance, an alkyl group, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted as the pyridine ring atoms. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituent Mentioned Herein

Substituent mentioned herein will be described below.

An “unsubstituted aryl group” mentioned herein has, unless otherwise specified herein, 6 to 50, preferably 6 to 30, more preferably 6 to 18 ring carbon atoms.

An “unsubstituted heterocyclic group” mentioned herein has, unless otherwise specified herein, 5 to 50, preferably 5 to 30, more preferably 5 to 18 ring atoms.

An “unsubstituted alkyl group” mentioned herein has, unless otherwise specified herein, 1 to 50, preferably 1 to 20, more preferably 1 to 6 carbon atoms.

An “unsubstituted alkenyl group” mentioned herein has, unless otherwise specified herein, 2 to 50, preferably 2 to 20, more preferably 2 to 6 carbon atoms. An “unsubstituted alkynyl group” mentioned herein has, unless otherwise specified herein, 2 to 50, preferably 2 to 20, more preferably 2 to 6 carbon atoms.

An “unsubstituted cycloalkyl group” mentioned herein has, unless otherwise specified herein, 3 to 50, preferably 3 to 20, more preferably 3 to 6 ring carbon atoms.

An “unsubstituted arylene group” mentioned herein has, unless otherwise specified herein, 6 to 50, preferably 6 to 30, more preferably 6 to 18 ring carbon atoms.

An “unsubstituted divalent heterocyclic group” mentioned herein has, unless otherwise specified herein, 5 to 50, preferably 5 to 30, more preferably 5 to 18 ring atoms.

An “unsubstituted alkylene group” mentioned herein has, unless otherwise specified herein, 1 to 50, preferably 1 to 20, more preferably 1 to 6 carbon atoms.

Substituted or unsubstituted Aryl Group

Specific examples (specific example group G1) of the “substituted or unsubstituted aryl group” mentioned herein include unsubstituted aryl groups (specific example group G1A) below and substituted aryl groups (specific example group G1B). Herein, an unsubstituted aryl group refers to an “unsubstituted aryl group” in a “substituted or unsubstituted aryl group”, and a substituted aryl group refers to a “substituted aryl group” in a “substituted or unsubstituted aryl group. A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below, and a group derived by further substituting a hydrogen atom of a substituent of the “substituted aryl group” in the specific example group G1B below.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

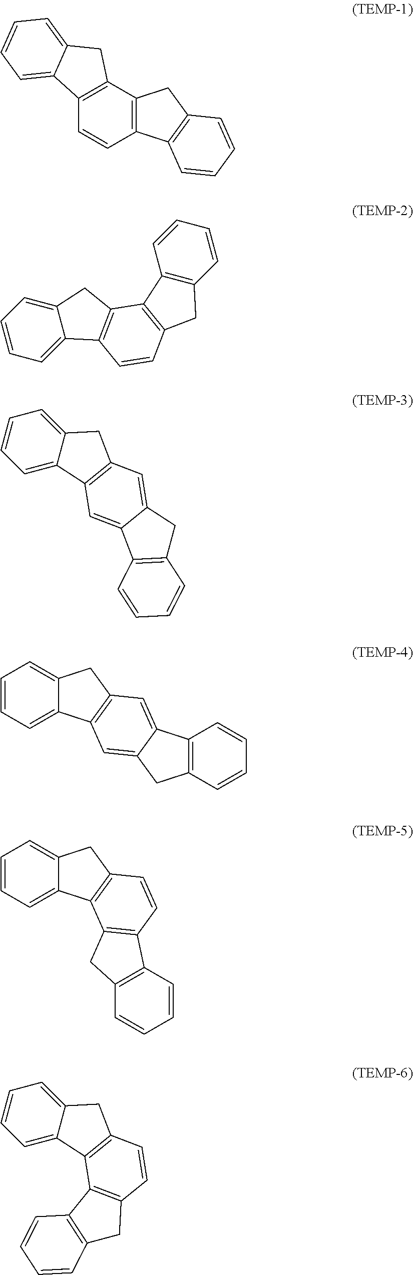

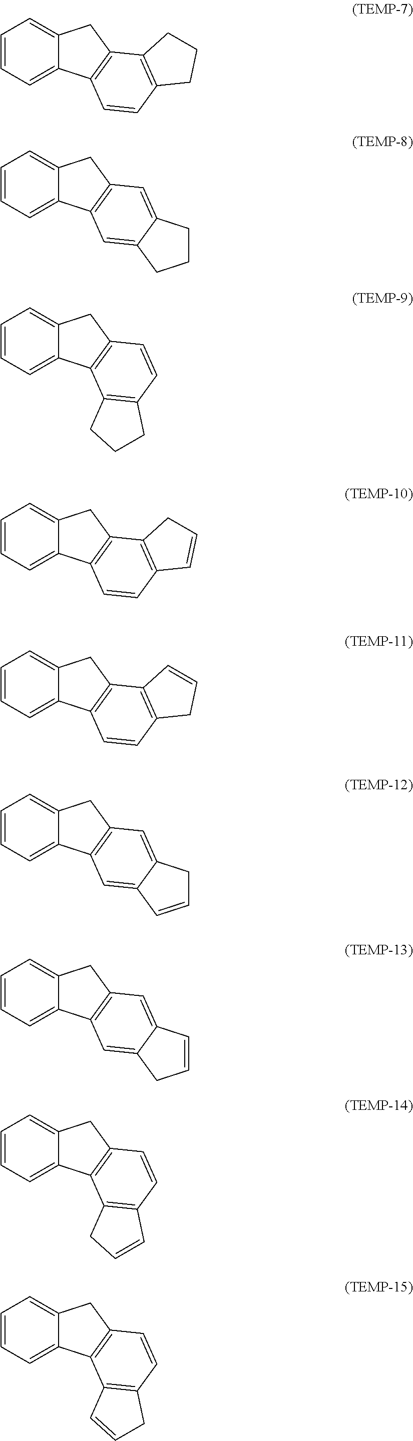

### Substituted Aryl Group (Specific Example Group GIB):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group. A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below, and a group derived by further substituting a hydrogen atom of a substituent of the “substituted heterocyclic group” in the specific example group G2B below.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by formulae (TEMP-16) to (TEMP-33) below.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).
   Monovalent Heterocyclic Groups Derived by Removing One Hydrogen Atom from Cyclic Structures Represented by Formulae (TEMP-16) to (TEMP-33) (Specific Example Group G2A4):

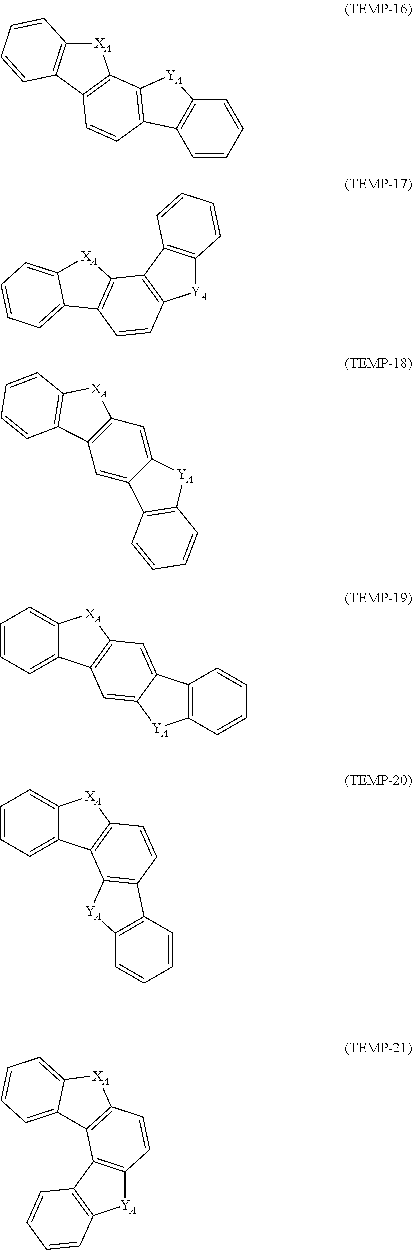

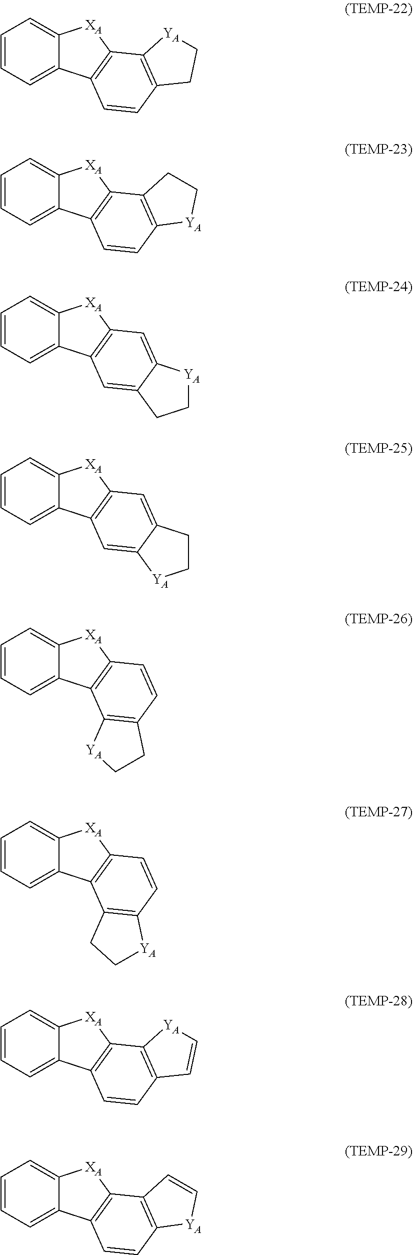

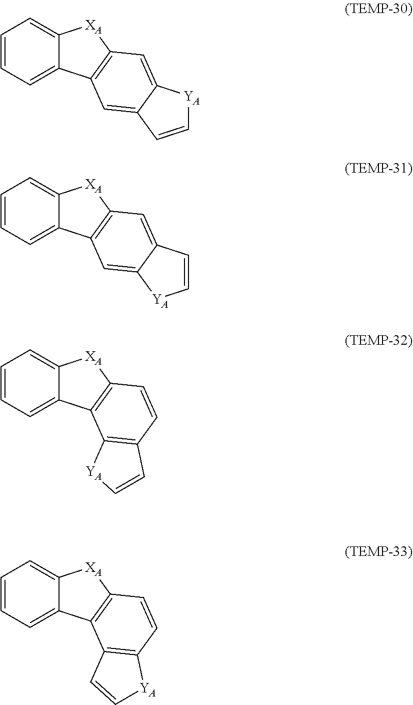

In the formulae (TEMP-16) to (TEMP-33), X_{A} and Y_{A} are each independently an oxygen atom, a sulfur atom, NH or CH2, with a proviso that at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

(9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyldibenzothiophenyl group, and monovalent residue of spiro[9H-thioxanthene-9,9′-[9H]fluorene].
   Groups Obtained by Substituting at Least One Hydrogen Atom of Monovalent Heterocyclic Group Derived from Cyclic Structures Represented by Formulae

(TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group. A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B, and a group derived by further substituting a hydrogen atom of a substituent of the “substituted alkyl group” in the specific example group G3B.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group. A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. Herein, an unsubstituted alkynyl group refers to an “unsubstituted alkynyl group” in a “substituted or unsubstituted alkynyl group.” A simply termed “alkynyl group” herein includes both of an “unsubstituted alkynyl group” and a “substituted alkynyl group.”

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

Unsubstituted Alkynyl Group (Specific Example Group G5A): an ethynyl group.

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group. A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.
   Substituted Cycloalkyl Group (Specific Example Group G6B): a 4-methylcyclohexyl group.
   Group Represented by —Si(R₉₀₁)(R₉₀₂)(R₉₀₃)

Specific examples (specific example group G7) of the group represented herein by —Si(R₉₀₁)(R₉₀₂)(R₉₀₃) include:
Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);
   where: G1 represents a “substituted or unsubstituted aryl group” in the specific example group G1;
G2 represents a “subsitued or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different;
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different.

### Group Represented by —O—(R₉₀₄)

Specific examples (specific example group G8) of a group represented by —O—(R₉₀₄) herein include: —O(G1); —O(G2); —O(G3); and —O(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include; —S(G1); —S(G2); —S(G3); and —S(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6),
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is sometimes referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1); G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-p-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

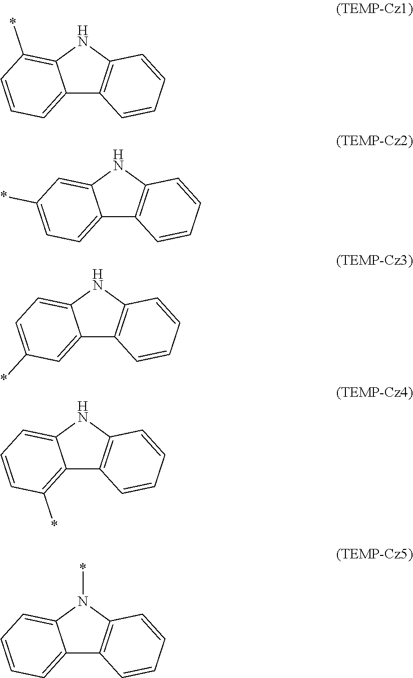 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

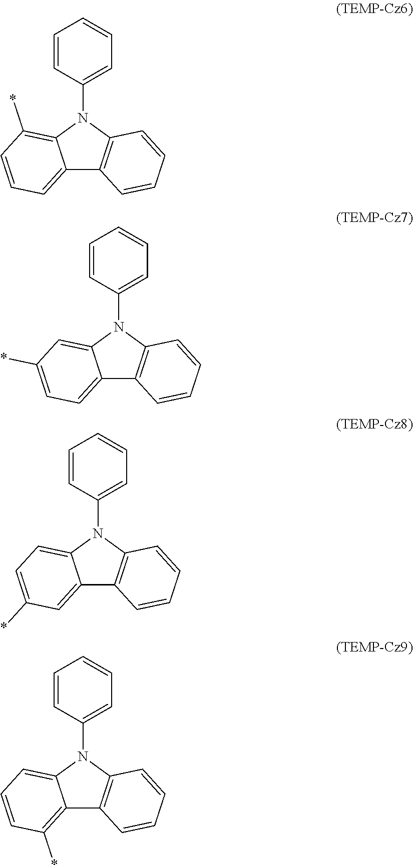

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

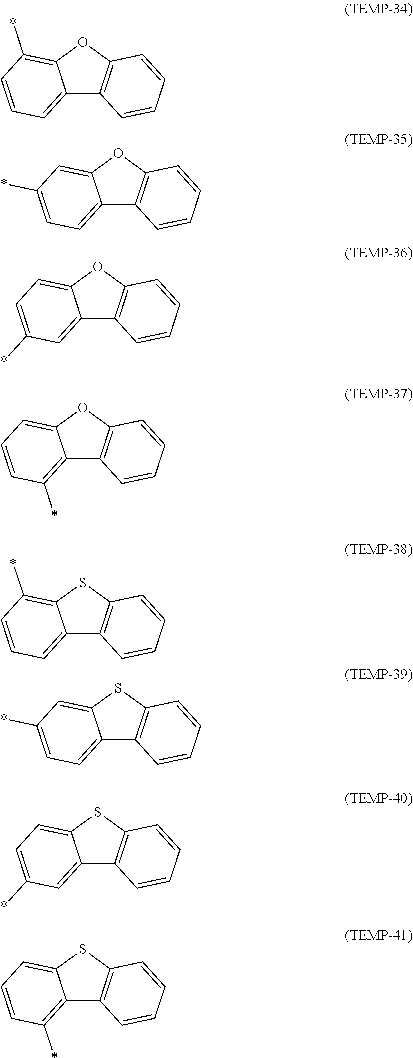

In the formulae (TEMP-34) to (TEMP-41), * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocycle of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

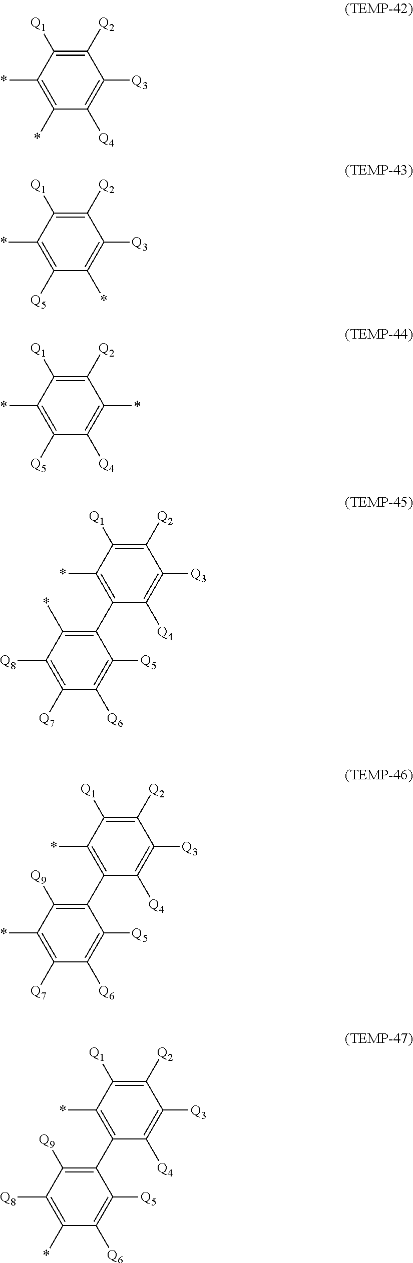

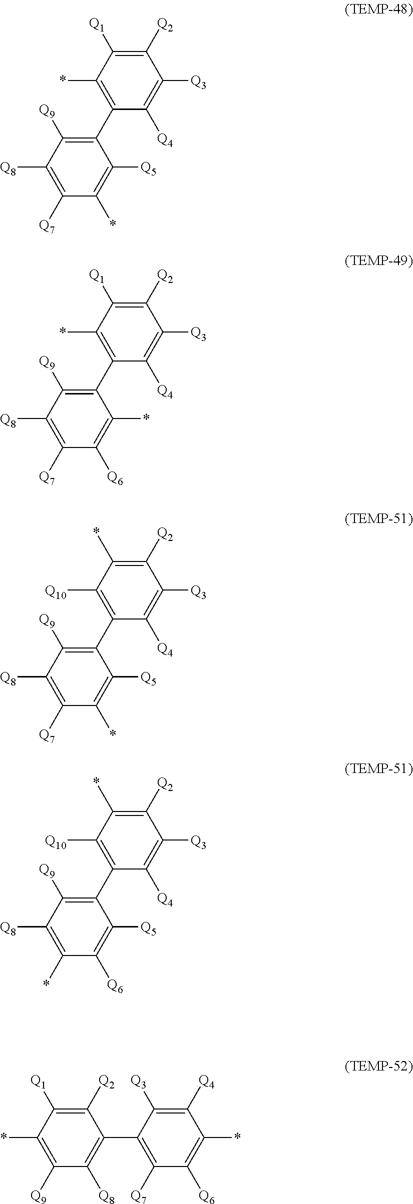

In the formulae (TEMP-42) to (TEMP-52), Q₁ to Q₁₀ are each independently a hydrogen atom or a substituent.

In the formulae (TEMP-42) to (TEMP-52), * represents a bonding position.

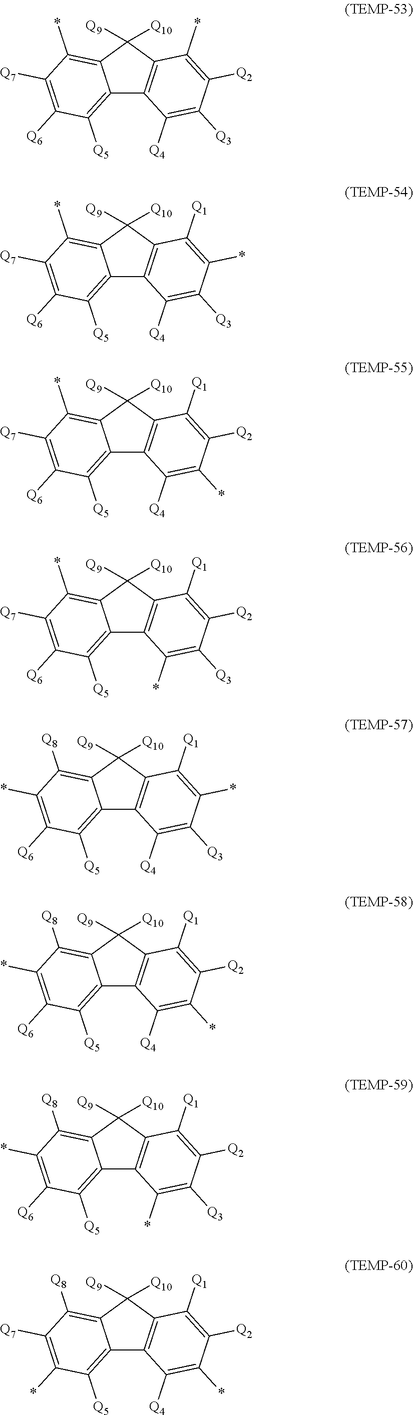

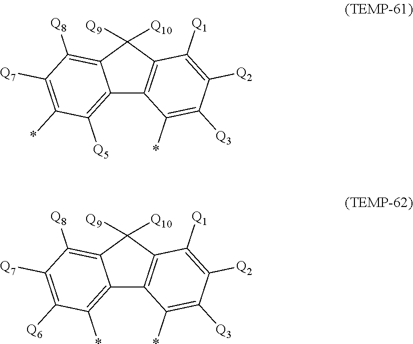

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), * represents a bonding position.

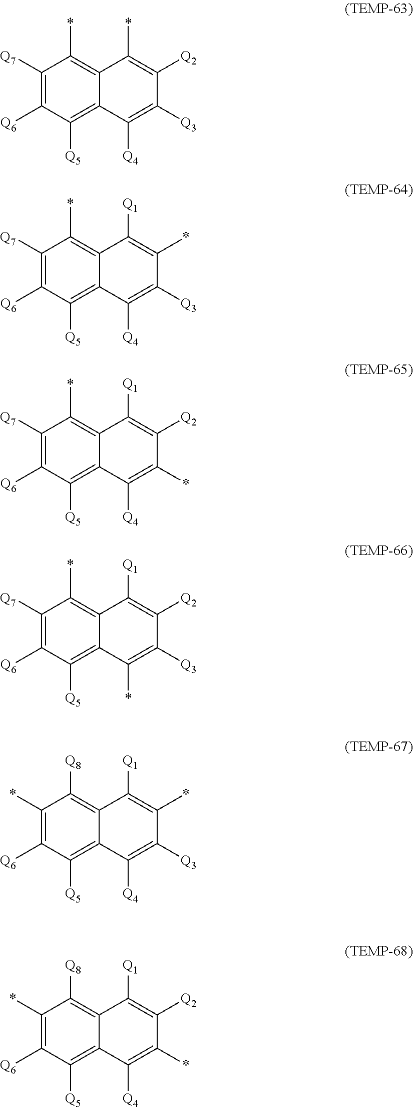

In the formulae (TEMP-63) to (TEMP-68), Q₁ to Q₈ are each independently a hydrogen atom or a substituent.

In the formulae (TEMP-63) to (TEMP-68), * represents a bonding position.

The substituted or unsubstituted divalent heterocyclic group mentioned herein is, unless otherwise specified herein, preferably a group represented by any one of formulae (TEMP-69) to (TEMP-102) below.

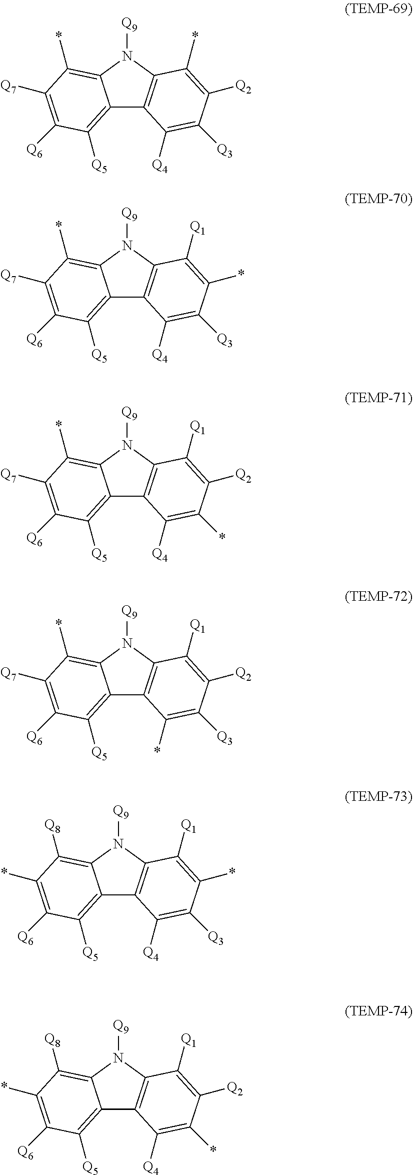

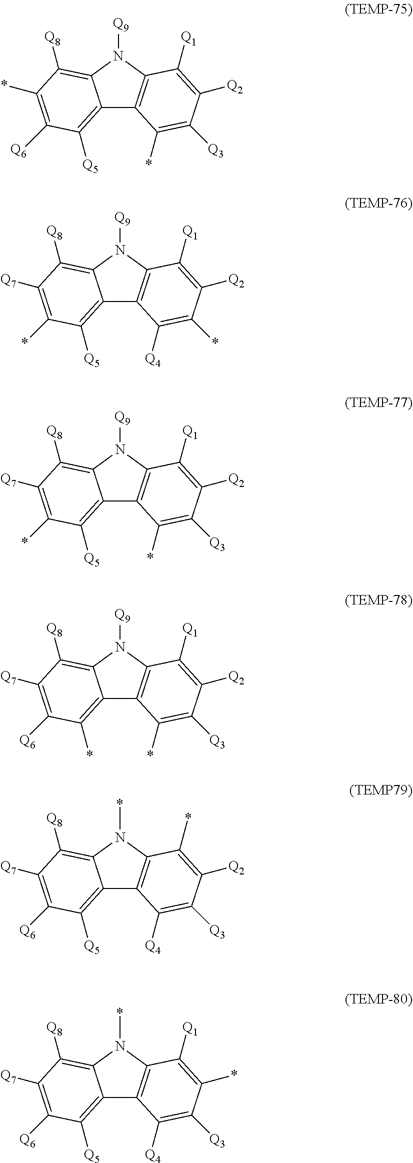

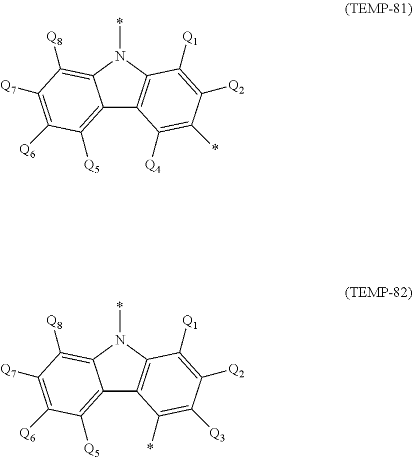

In the formulae (TEMP-69) to (TEMP-82), Q₁ to Q₉ are each independently a hydrogen atom or a substituent.

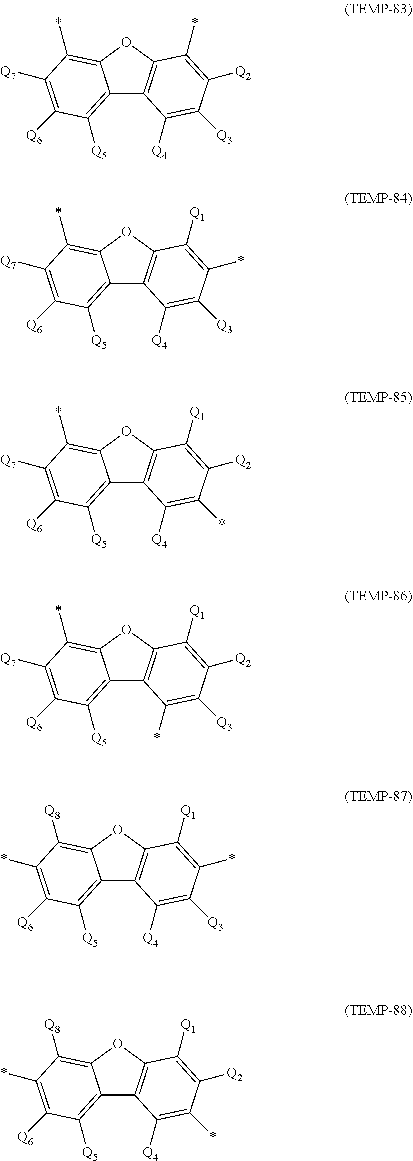

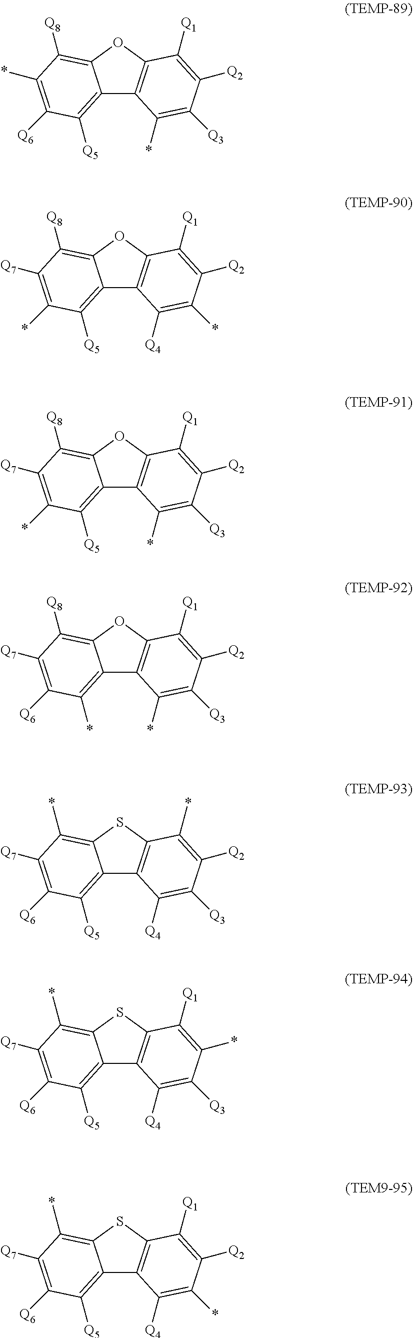

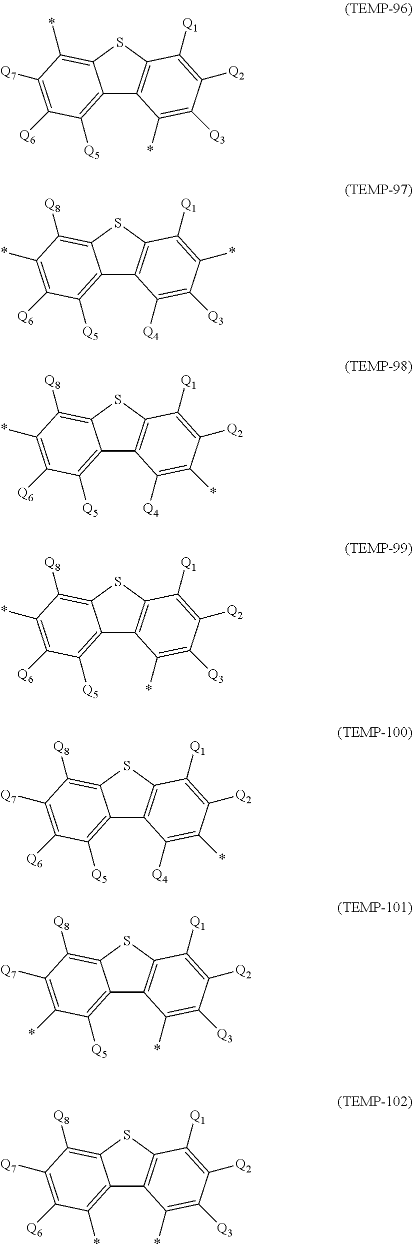

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

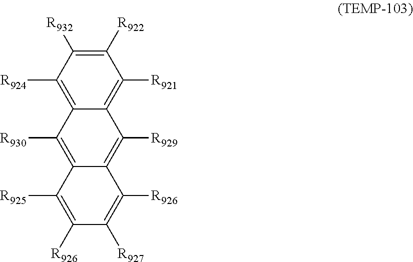

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring QA and R₉₂₅ and R₉₂₆ are simultaneously mutually bonded to form a ring QB, the anthracene compound represented by the formula (TEMP-103) is represented by a formula (TEMP-104) below.

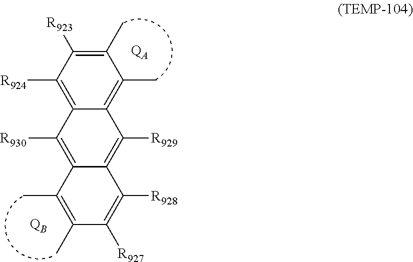

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring QA and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring QA and the ring Q_{C} share R₉₂₂.

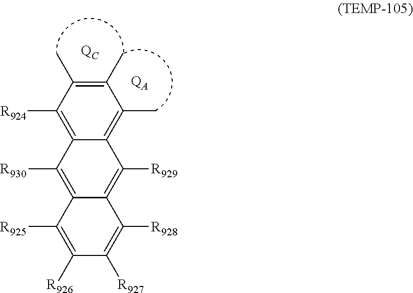

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{C} formed in the formula (TEMP-105) are each a “fused ring.” The ring Q_{A} and the ring Q_{C} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific example of the specific example group G1 with a hydrogen atom.

Specific examples of the aromatic heterocycle include a ring formed by terminating a bond of an aromatic heterocyclic group in the specific example of the specific example group G2 with a hydrogen atom.

Specific examples of the aliphatic hydrocarbon ring include a ring formed by terminating a bond of a group in the specific example of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes an optional element other than carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein,”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle

### “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent” hereinafter), is for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₆ are present, the two or more R₉₀₆ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

Herein, a numerical formula represented by “A≥B” means that the value A is equal to the value B, or the value A is larger than the value B.

Herein, a numerical formula represented by “A≤B” means that the value A is equal to the value B, or the value A is smaller than the value B.

### First Exemplary Embodiment

### Organic Electroluminescence Device

An organic EL device according to a first exemplary embodiment of the invention will be described.

The organic EL device according to the exemplary embodiment includes an anode, a cathode, and an organic layer between the anode and the cathode. The organic layer includes at least one layer formed from an organic compound(s). Alternatively, the organic layer includes a plurality of layers formed from an organic compound(s). The organic layer may further contain an inorganic compound(s).

The organic electroluminescence device according to the exemplary embodiment includes the anode, the cathode, and an emitting layer between the anode and the cathode, a first layer between the anode and the emitting layer, in which the emitting layer contains a compound M1 represented by a formula (1) below, the compound M1 is a delayed fluorescent compound, the first layer contains a compound M4 represented by a formula (4) below, and the compound M4 satisfies formulae (a) and (b) below.

μ_{H}(M4)≤1.0×10⁻³ cm²/Vs Formula (a):

S₁(M4)≥3.15 eV Formula (b):

μ_{H}(M4) represents hole mobility of the compound M4. S₁(M4) represents a lowest singlet energy of the compound M4.

In a green emitting organic EL device including the emitting layer containing a delayed fluorescent compound (occasionally abbreviated as G-TADF device), a decrease in luminous efficiency is caused by absorption of a green light of a hole transporting layer having a large film thickness (occasionally abbreviated as a thick HT layer). A film thickness of the thick HT layer is, for instance, 70 nm or more.

Since the thick HT layer has a long light path length, the green light emitted from the emitting layer may be absorbed, when passing through the thick HT layer, by a material contained in the thick HT layer (occasionally abbreviated as a thick HT layer material). The thick HT layer thus contributes to lowering the luminous efficiency.

Since the thick HT layer material is required to have a high hole mobility, the thick HT layer material often has a highly planar substituent that is advantageous for hole hopping conduction. Having a highly planar substituent expands the conjugated system to lower the lowest singlet energy of the material of the thick HT layer, increasing the influence of the above-mentioned absorption of green light.

In the invention, the delayed fluorescent compound M1 suitable for the G-TADF device is used in the emitting layer and the compound M4 satisfying the formulae (a) and (b) and having a specific chemical structure represented by the formula (4) is used in the first layer (thick HT layer), whereby the absorption of green light can be inhibited and a decrease in efficiency affected by the thick HT layer can be reduced to improve the luminous efficiency.

In the organic EL device according to the exemplary embodiment, the organic layers may include, in addition to the emitting layer and the first layer, any layer usable in the organic EL device. Examples of the layer usable in the organic EL device, which are not particularly limited, include at least one selected from the group consisting of a hole injecting layer, a hole transporting layer, an electron blocking layer, a hole blocking layer, an electron transporting layer, and an electron injecting layer.

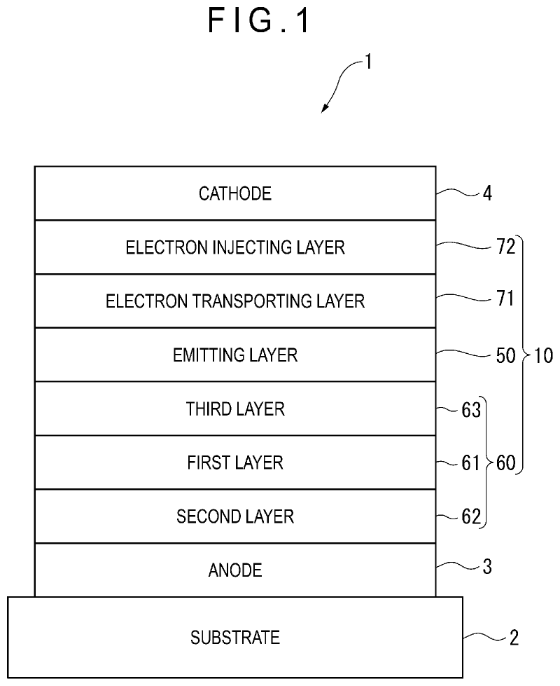

FIG. 1 schematically illustrates an exemplary arrangement of an organic EL device according to the exemplary embodiment.

An organic EL device 1 includes a light-transmissive substrate 2, an anode 3, a cathode 4, and organic layers 10 provided between the anode 3 and the cathode 4. The organic layers 10 include a second layer 62, a first layer 61, a third layer 63, an emitting layer 50, an electron transporting layer 71, and an electron injecting layer 72 that are layered on the anode 3 in this order. The organic EL device 1 includes a hole transporting zone 60 including the first layer 61, the second layer 62, and the third layer 63. The organic EL device of the invention may have any arrangement without being limited to the arrangement of the organic EL device illustrated in FIG. 1.

### Hole Transporting Zone

A zone including one or more layers provided between the anode and the emitting layer may herein be referred to as a hole transporting zone. The first layer in the exemplary embodiment is a layer contained in the hole transporting zone. In the organic EL device according to the exemplary embodiment, the hole transporting zone may include at least one of the second layer or the third layer described later in addition to the first layer.

### First Layer

In an exemplary arrangement of the organic EL device of the exemplary embodiment, a film thickness of the first layer is 70 nm or more.

In an exemplary arrangement of the organic EL device of the exemplary embodiment, a film thickness of the first layer is 80 nm or more.

In an exemplary arrangement of the organic EL device of the exemplary embodiment, a film thickness of the first layer is 140 nm or less.

In the organic EL device according to the exemplary embodiment, the first layer is preferably not in direct contact with the emitting layer.

In the organic EL device of the exemplary embodiment, of at least one layer provided between the anode and emitting layer, the first layer has a largest film thickness.

In the organic EL device according to the exemplary embodiment in which the first layer, the second layer, and the third layer are provided between the anode and the emitting layer, the first layer preferably has the largest film thickness.

### Compound M4

The first layer contains the compound M4 represented by a formula (4) below.

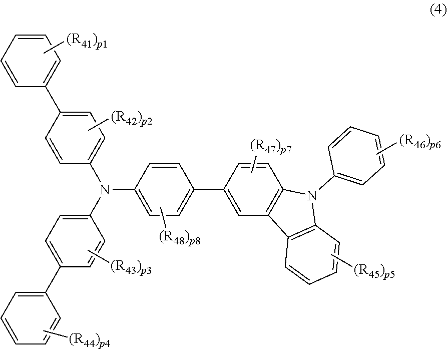

In the formula (4):
p1 is 5, p2 is 4, p3 is 4, p4 is 5, p5 is 4, p6 is 5, p7 is 3, and p8 is 4;
a plurality of R₄₁ are mutually the same or different;
at least one combination of adjacent two or more of the plurality of R₄₁ are mutually bonded to form a substituted or unsubstituted monocyclic ring, mutually bonded to form a substituted or unsubstituted fused ring, or not mutually bonded;
a plurality of R₄₂ are mutually the same or different;
at least one combination of adjacent two or more of the plurality of R₄₂ are mutually bonded to form a substituted or unsubstituted monocyclic ring, mutually bonded to form a substituted or unsubstituted fused ring, or not mutually bonded;
a plurality of R₄₃ are mutually the same or different;
at least one combination of adjacent two or more of the plurality of R₄₃ are mutually bonded to form a substituted or unsubstituted monocyclic ring, mutually bonded to form a substituted or unsubstituted fused ring, or not mutually bonded;
a plurality of R₄₄ are mutually the same or different;
at least one combination of adjacent two or more of the plurality of R₄₄ are mutually bonded to form a substituted or unsubstituted monocyclic ring, mutually bonded to form a substituted or unsubstituted fused ring, or not mutually bonded;
a plurality of R₄₅ are mutually the same or different;
at least one combination of adjacent two or more of the plurality of R₄₅ are mutually bonded to form a substituted or unsubstituted monocyclic ring, mutually bonded to form a substituted or unsubstituted fused ring, or not mutually bonded;
a plurality of R₄₆ are mutually the same or different;
at least one combination of adjacent two or more of the plurality of R₄₆ are mutually bonded to form a substituted or unsubstituted monocyclic ring, mutually bonded to form a substituted or unsubstituted fused ring, or not mutually bonded;
a combination of R₄₁ and R₄₂ are mutually bonded to form a substituted or unsubstituted monocyclic ring, mutually bonded to form a substituted or unsubstituted fused ring, or not mutually bonded;
a combination of R₄₃ and R₄₄ are mutually bonded to form a substituted or unsubstituted monocyclic ring, mutually bonded to form a substituted or unsubstituted fused ring, or not mutually bonded;
a plurality of R₄₇ are mutually the same or different;
a plurality of R₄₈ are mutually the same or different;
R₄₁ to R₄₆ forming neither the substituted or unsubstituted monocyclic ring nor the substituted or unsubstituted fused ring and R₄₇ to R₄₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms;
the compound M4 satisfies at least one of conditions (i), (ii), (iii), (iv), and (v) below:
the condition (i): at least one R₄₁ is not a hydrogen atom;
the condition (ii): a combination of R₄₁ and R₄₂ are mutually bonded to form a substituted or unsubstituted monocyclic ring or a substituted or unsubstituted fused ring;
the condition (iii): at least one combination of adjacent two or more of a plurality of R₄₁ are mutually bonded to form a substituted or unsubstituted monocyclic ring or a substituted or unsubstituted fused ring;
the condition (iv): at least one combination of adjacent two or more of a plurality of R₄₆ are mutually bonded to form a substituted or unsubstituted monocyclic ring or a substituted or unsubstituted fused ring; and the condition (v): at least one R₄₆ is not a hydrogen atom.

In the organic EL device according to the exemplary embodiment, the compound M4 also preferably satisfies the above condition (ii).

In the organic EL device according to the exemplary embodiment, the compound M4 (compound represented by the formula (4)) is also preferably a compound represented by a formula (41) below.

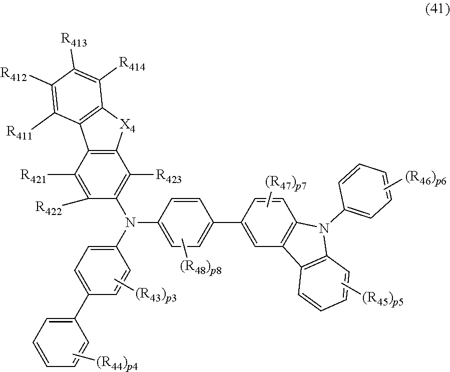

In the formula (41):
X₄ is C(Ra₄)(Rb₄), an oxygen atom, or a sulfur atom;
a combination of Ra₄ and Rb₄ are mutually bonded to form a substituted or unsubstituted monocyclic ring, mutually bonded to form a substituted or unsubstituted fused ring, or not mutually bonded;
Ra₄ and Rb₄ forming neither the substituted or unsubstituted monocyclic ring nor the substituted or unsubstituted fused ring each independently represent the same as R₄₁ to R₄₆ forming neither the substituted or unsubstituted monocyclic ring nor the substituted or unsubstituted fused ring;
p3 to p8 respectively represent the same as p3 to p8 in the formula (4);
R₄₁₁ to R₄₁₄ each independently represent the same as R₄₁ in the formula (4);
R₄₂₁ to R₄₂₃ each independently represent the same as R₄₂ in the formula (4); and
R₄₃ to R₄₈ respectively represent the same as R₄₃ to R₄₈ in the formula (4).

In the organic EL device according to the exemplary embodiment, the compound M4 (compound represented by the formula (4)) is also preferably a compound represented by a formula (42) below.

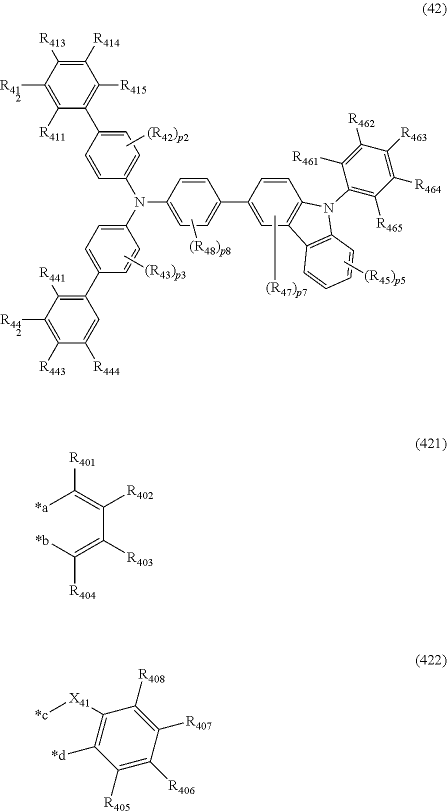

In the formula (42):
p2, p3, p5, p7, and p8 respectively represent the same as p2, p3, p5; p7, and p8 in the formula (4);
R₄₂, R₄₃, R₄₅, R₄₇, and R₄₈ respectively represent the same as R₄₂, R₄₃, R₄₅, R₄₇, and R₄₈ in the formula (4);
at least one combination selected from the group consisting of combinations of adjacent two or more of R₄₁₁ to R₄₁₅, combinations of adjacent two or more of R₄₄₁ to R₄₄₅, and combinations of adjacent two or more of R₄₆₁ to R₄₆₅ are mutually bonded to form a ring represented by the formula (421) or (422);
R₄₁₁ to R₄₁₅ not forming a ring represented by the formula (421) or (422) each independently represent the same as R₄₁ forming neither the substituted or unsubstituted monocyclic ring nor the substituted or unsubstituted fused ring;
R₄₄₁ to R₄₄₅ not forming a ring represented by the formula (421) or (422) each independently represent the same as R₄₄ forming neither the substituted or unsubstituted monocyclic ring nor the substituted or unsubstituted fused ring; and
R₄₆₁ to R₄₆₅ not forming a ring represented by the formula (421) or (422) each independently represent the same as R₄₆ forming neither the substituted or unsubstituted monocyclic ring nor the substituted or unsubstituted fused ring.

In the formula (421):
at least one combination of adjacent two or more of R₄₀₁ to R₄₀₄ are mutually bonded to form a substituted or unsubstituted monocyclic ring, mutually bonded to form a substituted or unsubstituted fused ring, or not mutually bonded;
R₄₀₁ to R₄₀₄ forming neither the substituted or unsubstituted monocyclic ring nor the substituted or unsubstituted fused ring each independently represent the same as R₄₁ forming neither the substituted or unsubstituted monocyclic ring nor the substituted or unsubstituted fused ring; and
a and *b each represent a bonding position.

In the formula (422):
X₄₁ is C(Rc₄)(Rd4), an oxygen atom, a sulfur atom, or N(Rf4);
a combination of Rc₄ and Rd4 are mutually bonded to form a substituted or unsubstituted monocyclic ring, mutually bonded to form a substituted or unsubstituted fused ring, or not mutually bonded;
at least one combination of adjacent two or more of R₄₀₅ to R₄₀₈ are mutually bonded to form a substituted or unsubstituted monocyclic ring, mutually bonded to form a substituted or unsubstituted fused ring, or not mutually bonded;
Rf₄, R₄₀₅ to R₄₀₈ forming neither the substituted or unsubstituted monocyclic ring nor the substituted or unsubstituted fused ring, and Rc₄ and Rd₄ forming neither the substituted or unsubstituted monocyclic ring nor the substituted or unsubstituted fused ring each independently represent the same as R₄₆ forming neither the substituted or unsubstituted monocyclic ring nor the substituted or unsubstituted fused ring; and
*c and *d each represent a bonding position.

In the organic EL device according to the exemplary embodiment, at least one combination selected from the group consisting of combinations of adjacent two or more of R₄₁₁ to R₄₁₅, combinations of adjacent two or more of R₄₄₁ to R₄₄₅, and combinations of adjacent two or more of R₄₆₁ to R₄₆₅ may be mutually bonded to form a ring represented by a formula (425).

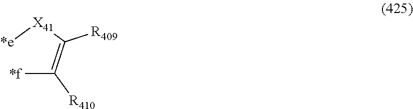

In the formula (425): X₄₁ represents the same as X₄₁ in the formula (422); R₄₀₉ and R₄₁₀ each independently represent the same as R₄₁ forming neither the substituted or unsubstituted monocyclic ring nor the substituted or unsubstituted fused ring; and *e and fd each represent a bonding position.

In the organic EL device according to the exemplary embodiment, it is also preferable that none of combinations of adjacent two or more of R₄₄₁ to R₄₄₅ are bonded to each other. In the organic EL device according to the exemplary embodiment, it is also preferable that none of combinations of adjacent two or more of R₄₄₁ to R₄₄₅ forms a ring represented by the formula (421) or (422).

It is also preferable that at least one combination selected from the group consisting of combinations of adjacent two or more of R₄₁₁ to R₄₁₅ are mutually bonded to form a ring represented by the formula (421) or (422) and none of combinations of adjacent two or more of R₄₄₁ to R₄₄₅ are mutually bonded.

In the organic EL device according to the exemplary embodiment, it is also preferable that a combination of R₄₁₄ and R₄₁₅ satisfy the condition (iii) and are mutually bonded to form a ring represented by the formula (422).

In the organic EL device according to the exemplary embodiment, it is also preferable that a combination of R₄₁₄ and R₄₁₅ are mutually bonded to form a ring represented by the formula (422), *d is a bonding position to R₄₁₄, and *c is a bonding position to R₄₁₅. In this case, a compound represented by the formula (4) is a compound represented by a formula (423) below.

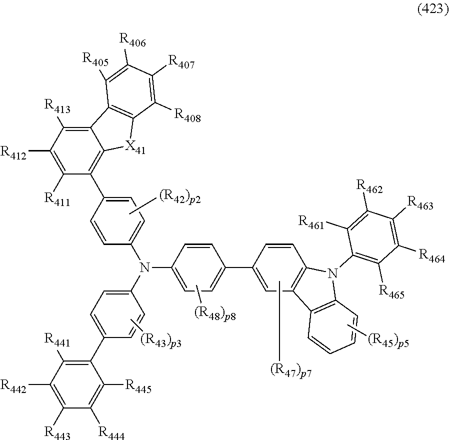

In the formula (423), R₄₀₅ to R₄₀₈, R₄₁₁ to R₄₁₃, R₄₂, R₄₃, R₄₄₁ to R₄₄₅, R₄₅, R₄₆₁ to R₄₆₅, R₄₇, R₄₈, X₄₁, p2, p3, p5, p7 and p8 are each defined as in the formula (42) or (422).

In the organic EL device according to the exemplary embodiment, it is also preferable that the compound M4 satisfies the condition (iv) and a combination of R₄₆₃ and R₄₆₄ are mutually bonded to form a ring represented by the formula (421).

In the organic EL device according to the exemplary embodiment, it is also preferable that a combination of R₄₆₃ and R₄₆₄ are mutually bonded to form a ring represented by the formula (421), *a is a bonding position to R₄₆₃, and *b is a bonding position to R₄₆₄. In this case, a compound represented by the formula (4) is a compound represented by a formula (424) below,

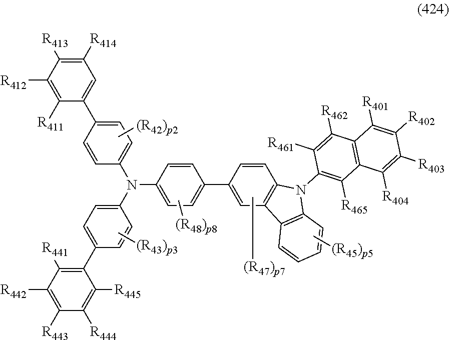

In the formula (424), R₄₀₁ to R₄₀₄, R₄₁₁ to R₄₁₅, R₄₂, R₄₃, R₄₄₁ to R₄₄₅, R₄₅, R₄₆₁, R₄₆₂, R₄₆₅, R₄₇, R₄₈, p2, p3, p5, p7 and p8 are each defined as in the formula (42) or (421).

In the organic EL device according to the exemplary embodiment, it is also preferable that the compound M4 satisfies the condition (i) and at least one R₄₁ is a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the organic EL device according to the exemplary embodiment, it is more preferable that the compound M4 satisfies the condition (i) and at least one R₄₁ is a substituted or unsubstituted aryl group having 6 to 50 ring carbon atoms, still more preferably a substituted or unsubstituted aryl group having 6 to 30 ring carbon atoms.

In the organic EL device according to the exemplary embodiment, it is also preferable that the compound M4 satisfies the condition (i) but does not satisfy the conditions (ii) to (v).

In the organic EL device according to the exemplary embodiment, it is also preferable that the compound M4 satisfies the condition (v) and at least one R₄₆ is a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the organic EL device according to the exemplary embodiment, it is preferable that the compound M4 satisfies the condition (v) and at least one R₄₆ is a substituted or unsubstituted aryl group having 6 to 50 ring carbon atoms, more preferably a substituted or unsubstituted aryl group having 6 to 30 ring carbon atoms.

In the organic EL device according to the exemplary embodiment, it is also preferable that the compound M4 satisfies the condition (v) but does not satisfy the conditions (ii) to (v).

In the organic EL device according to the exemplary embodiment, the compound M4 is preferably a monoamine compound having one substituted or unsubstituted amino group in a molecule.

In the monoamine compound, a nitrogen atom of an amino group is not an atom forming a ring (i.e., a ring atom). When a nitrogen atom is a ring atom in a carbazole ring, an azine ring and the like, the nitrogen atom is not a nitrogen atom as an amino group.

For instance, a compound HT-X below has two nitrogen atoms in a molecule: one nitrogen atom in the compound HT-X is a ring atom of a carbazole ring and the other nitrogen atom is not a ring atom but a nitrogen atom as an amino group. The compound HT-X is a compound having a structure in which 9-phenyl-3-carbazolyl group is bonded to a nitrogen atom of an amino group via a linking group, that is, a monoamine compound.

A compound HT-Y below is also a compound having a structure in which 9-carbazolyl group is bonded to a nitrogen atom of an amino group via a linking group, that is, a monoamine compound.

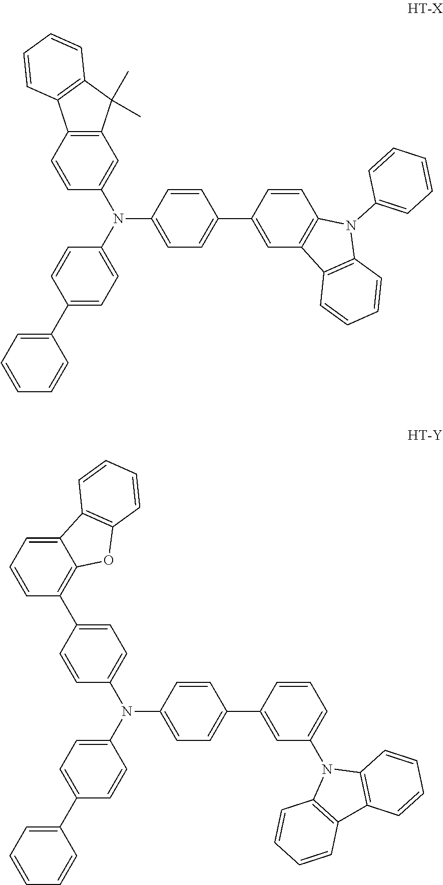 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

In the organic EL device according to the exemplary embodiment; it is preferable that R₄₂, R₄₃, R₄₅, R₄₇, and R₄₈ are each a hydrogen atom.

In the organic EL device according to the exemplary embodiment, it is also preferable that the groups specified to be “substituted or unsubstituted” in a compound represented by the formula (4) are each an “unsubstituted” group.

In the organic EL device according to the exemplary embodiment, in the formula regarding the compound, R₉₀₁, R₉₀₂, R₉₀₃, R₉₀₄, R₉₀₅, R₉₀₆, R₉₀₇, R₉₀₈, R₉₀₉, R₉₃₁, R₉₃₂, R₉₃₃, R₉₃₄, R₉₃₅, R₉₃₆, and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₀₈ are present, the plurality of R₉₀₈ are mutually the same or different;
when a plurality of R₉₀₉ are present, the plurality of R₉₀₉ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

### Hole Mobility of Compound M4

The compound M4 preferably satisfies a formula (a1) below, more preferably a formula (a2) below.

μ_{H}(M4)≤7.0×10⁻⁴ cm²/Vs Formula (a1):

μ_{H}(M4)≤6.5×10⁻⁴ cm²/Vs Formula (a2):

The compound M4 preferably satisfies a formula (a3) below. With the hole mobility of the compound M4 satisfying the formula (a3), the drive voltage of the organic EL device even with a large film thickness of the first layer is unlikely to increase.

5×10⁻⁵ cm²/Vs≤μ_{H}(M4) Formula (a3):

### Measurement Method of Hole Mobility

Hole mobility can be measured by measuring impedance using a device for mobility evaluation produced according to the following steps. The device for mobility evaluation is produced, for instance, according to the following steps.

A compound HA-2 below is vapor-deposited on a glass substrate having an ITO transparent electrode (anode) so as to cover the transparent electrode, thereby forming a hole injecting layer. A compound HT-A was vapor-deposited on the hole injecting layer to form a hole transporting layer. Subsequently, a compound Target, which is to be measured for the hole mobility, is vapor-deposited to form a measurement target layer. Metal aluminum (Al) is vapor-deposited on the measurement target layer to form a metal cathode,

An arrangement of the above device for mobility evaluation is roughly shown as follows.

ITO(130) HA-2(5)/HT-A(10) Target(200)/Al(80)

Numerals in parentheses represent a film thickness (nm).

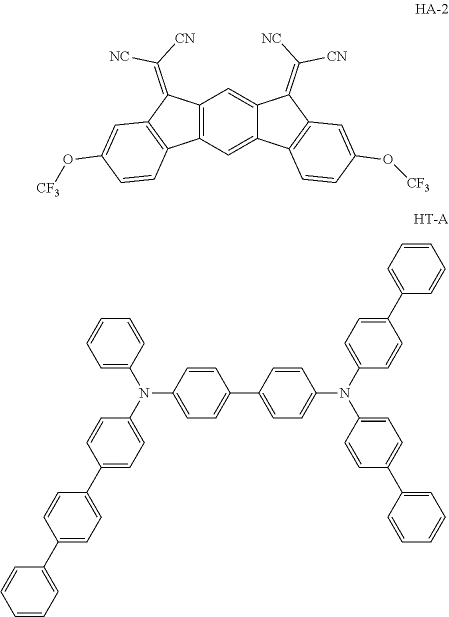 [SMILES: N#CC(C#N)=C1c2cc(OC(F)(F)F)ccc2-c2cc3c(cc21)C(=C(C#N)C#N)c1cc(OC(F)(F)F)ccc1-3 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

The device for evaluating hole mobility is set in an impedance measurement apparatus and an impedance measurement is performed. In the impedance measurement, a measurement frequency is swept from 1 Hz to 1 MHz. At this time, an alternating current amplitude of 0.1 V and a direct current voltage V are applied to the device. A modulus M is calculated from a measured impedance Z using a relationship of a calculation formula (C1) below.

M=jωZ Calculation Formula (C1):

In the calculation formula (C1), j is an imaginary unit whose square is −1 and ω is an angular frequency [rad/s].

In a bode plot in which an imaginary part of the modulus M is represented by an ordinate axis and the frequency [Hz] is represented by an abscissa axis, an electrical time constant τ of the device for mobility evaluation is obtained from a frequency fmax showing a peak using a calculation formula (C2) below.

τ=1/(2πfmax) Calculation Formula (C2):
π in the calculation formula (C2) is a symbol representing a circumference ratio.

A hole mobility μ_{H} is calculated from a relationship of a calculation formula (C3) below using τ obtained according to the calculation formula (C2).

μ_{H}=d²/(Vτ) Calculation Formula (C3):
d in the calculation formula (C3) is a total film thickness of organic thin film(s) forming the device. In a case of the device arrangement for hole mobility evaluation, d=215 [nm] is satisfied.

The hole mobility herein is a value obtained in a case where a square root of an electric field intensity meets E^{1/2}=500 [V^{1/2}/cm^{1/2}]. The square root of the electric field intensity, E^{1/2}, can be calculated from a relationship of a calculation formula (C4) below.

E^{1/2}=V^{1/2}/d^{1/2} Calculation Formula (C4):

For the impedance measurement, a 1260 type by Solartron Analytical is used as the impedance measurement apparatus, and for a higher accuracy, a 1296 type dielectric constant measurement interface by Solartron Analytical can be used together therewith.

### Lowest Singlet Energy of Compound M4

The compound M4 preferably satisfies a formula (b1) below.

3.17 eV≤S₁(M4) Formula (b1):

The compound M4 preferably satisfies a formula (b2) below.

S₁(M4)≤3.30 eV Formula (b2):

The lowest singlet energy of the compound M4 can be measured in the same manner as a measurement method of the lowest singlet energy S1 using a solution described later (solution method).

### Producing Method of Compound M4

The compound M4 can be produced by a known method. The compound M4 can also be produced based on a known method through a known alternative reaction using a known material(s) tailored for the target compound.

### Specific Examples of Compound M4

Specific examples of the compound M4 in the exemplary embodiment include compounds below. However, the invention is by no means limited to the specific examples.

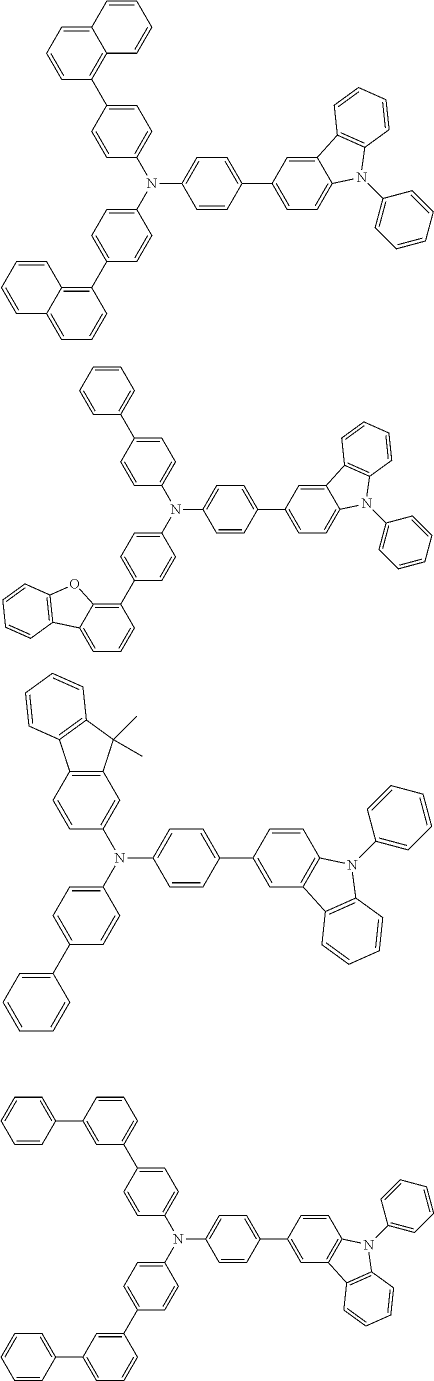

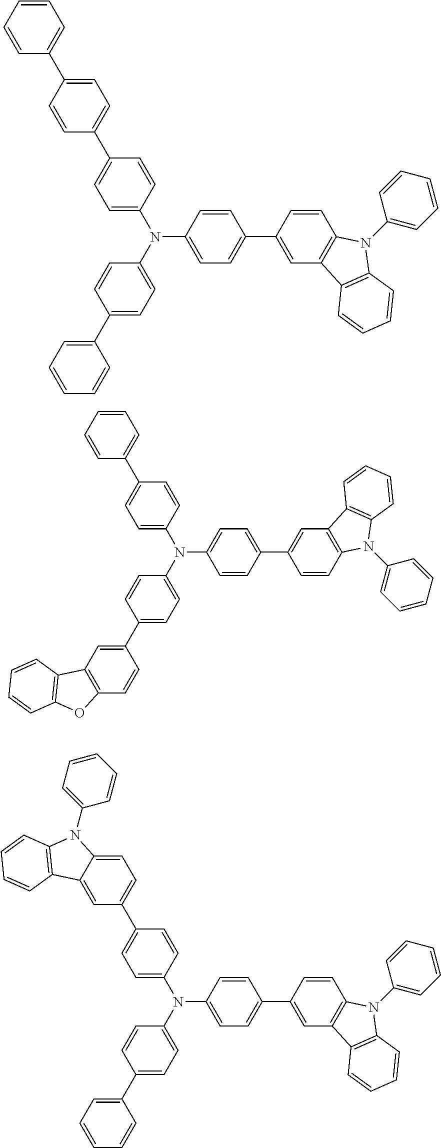

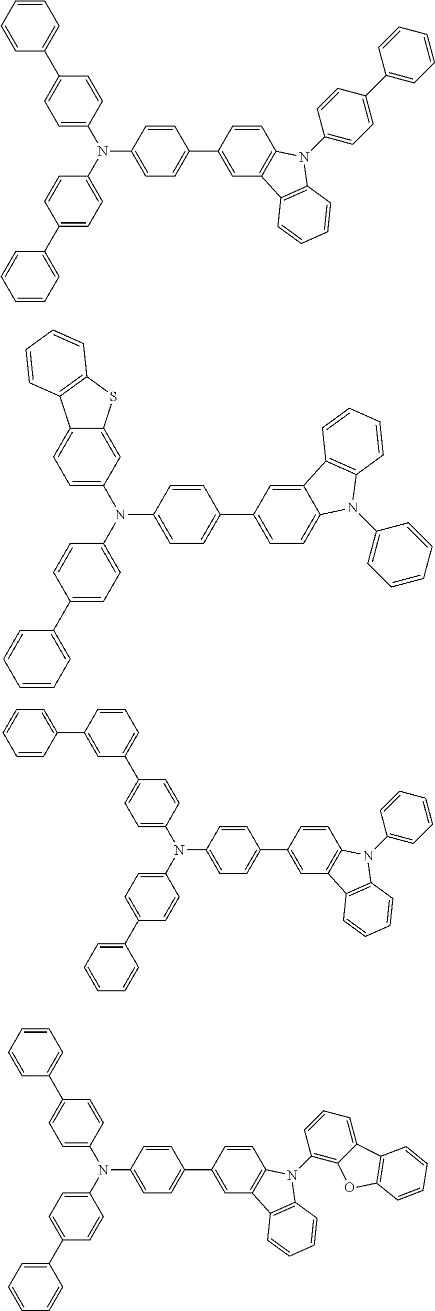

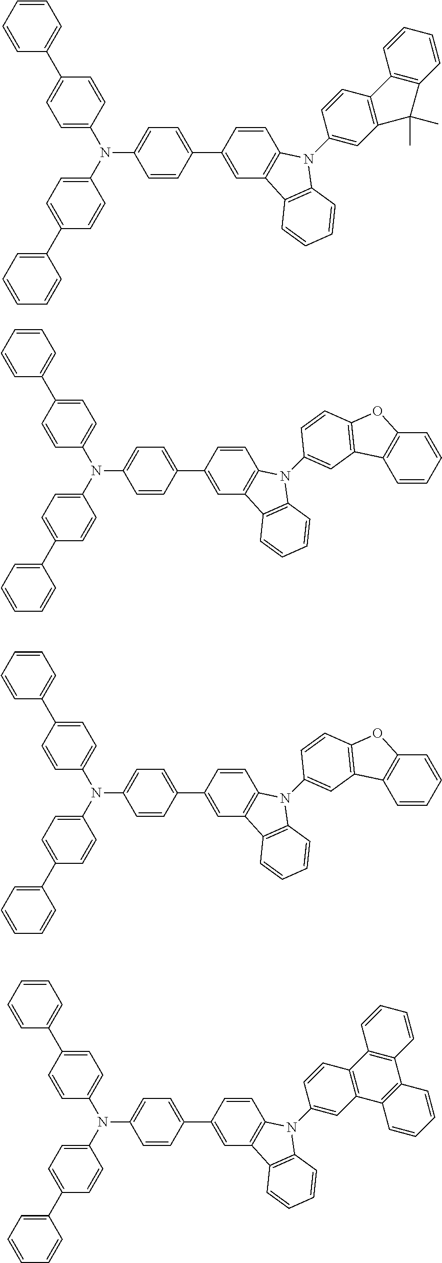

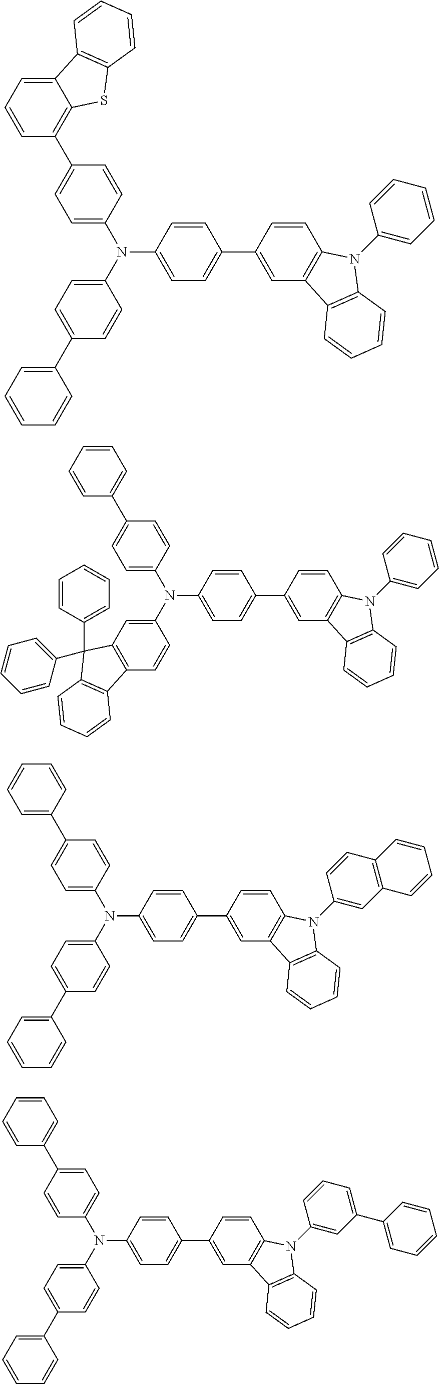

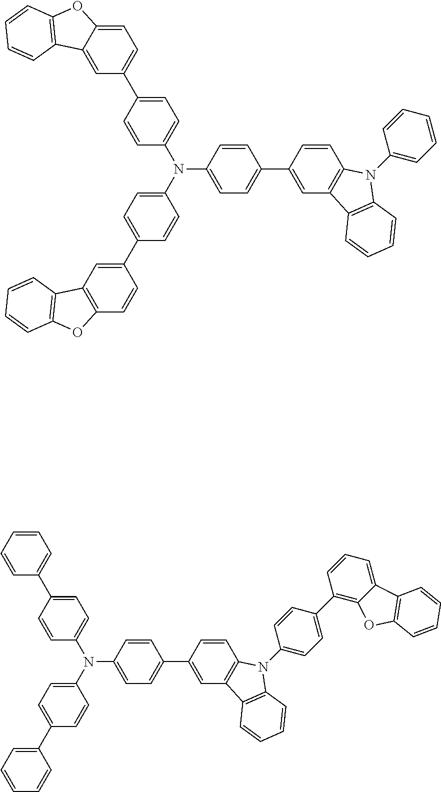 [SMILES: c1ccc(-n2c3ccccc3c3cc(-c4ccc(N(c5ccc(-c6ccc7oc8ccccc8c7c6)cc5)c5ccc(-c6ccc7oc8ccccc8c7c6)cc5)cc4)ccc32)cc1 ; c1ccc(-c2ccc(N(c3ccc(-c4ccccc4)cc3)c3ccc(-c4ccc5c(c4)c4ccccc4n5-c4ccc(-c5cccc6c5oc5ccccc56)cc4)cc3)cc2)cc1]

In the organic EL device according to the exemplary embodiment, the first layer is also preferably the hole transporting layer.

In the organic EL device according to the exemplary embodiment, the hole transporting zone may include the first layer and another hole transporting layer.

### Hole Transporting Layer

The hole transporting layer is a layer containing a highly hole-transporting substance. An aromatic amine compound, carbazole derivative, anthracene derivative and the like are usable for the hole transporting layer. Specific examples of a material for the hole transporting layer include 4,4′-bis[N-(1-naphthyl)-N-phenylamino]biphenyl (abbreviation: NPB), N′-bis(3-methylphenyl)-N, N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4-bis[N-(9,9-dimethylfluorene-2-yl)-N-phenylamino]biphenyl (abbreviation: DFLDPBi), 4,4′,4″-tris(N, N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/Vs or more.

For the hole transporting layer, a carbazole derivative such as CBP, CzPA, and PCzPA and an anthracene derivative such as t-BuDNA, DNA, and DPAnth may be used. A high polymer compound such as poly(N-vinylcarbazole) (abbreviation: PVK) and poly(4-vinyltriphenylamine) (abbreviation: PVTPA) is also usable.

However, in addition to the above substances, any substance exhibiting a higher hole transportability than an electron transportability may be used. It should be noted that the layer containing the substance exhibiting a high hole transportability may be not only a single layer but also a laminate of two or more layers formed of the above substance(s).

### Second Layer

In the organic EL device according to the exemplary embodiment, the second layer is preferably disposed between the first layer and the anode.

In the organic EL device according to the exemplary embodiment, the first layer is also preferably in direct contact with the second layer.

In the organic EL device according to the exemplary embodiment, the second layer is also preferably in direct contact with the anode.

In the organic EL device according to the exemplary embodiment in which the second layer is not provided, the first layer may be in direct contact with the anode.

In the organic EL device according to the exemplary embodiment, the second layer is also preferably the hole injecting layer.

In the organic EL device according to the exemplary embodiment, the second layer is preferably smaller in film thickness than the first layer.

In the organic EL device according to the exemplary embodiment, the second layer preferably contains a compound M5 and a compound M6. The compound M5 and the compound M4 are mutually the same or different. Accordingly, the compound M5 contained in the second layer may be a compound represented by the formula (4). The compound M5 and the compound M6 are mutually different.

In the organic EL device according to the exemplary embodiment, the compound M6 is preferably an accepting compound.

### Accepting Compound

An accepting compound has at least one of a first cyclic structure represented by a formula (P11) below or a second cyclic structure represented by a formula (P12) below.

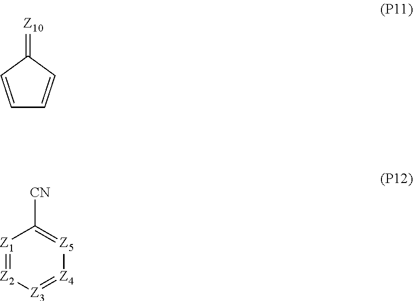

The first cyclic structure represented by the formula (P11) is fused with at least one cyclic structure of a substituted or unsubstituted aromatic hydrocarbon ring having 6 to 50 ring carbon atoms or a substituted or unsubstituted heterocyclic ring having 5 to 50 ring atoms in a molecule of the accepting compound.

A structure represented by ═Z₁₀ is represented by a formula (11a), (11b), (11c), (11d), (11e), (11f), (11g), (11h), (11i), (11j), (11k), or (11m),

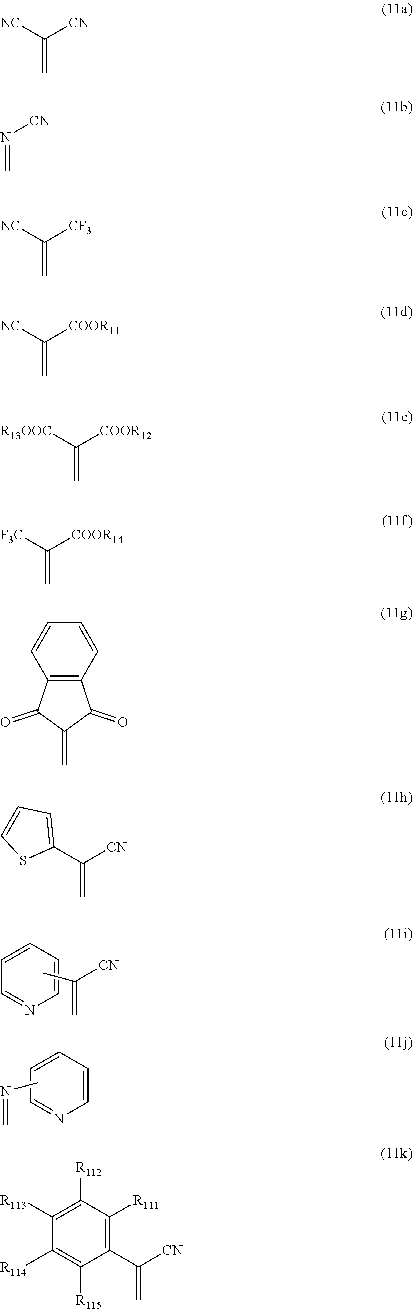

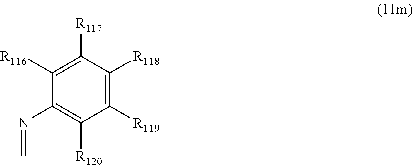

In the formulae (11a), (11b), (11c), (11d), (11e), (11f), (11g), (11h), (11i), (11j), (ilk), or (11m), R₁₁ to R₁₄ and R₁₁₁ to R₁₂₀ are each independently a hydrogen atom, a halogen atom, a hydroxy group, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to ring carbon atoms, or a substituted or unsubstituted heterocyclic group having 5 to 50 ring atoms.

In the formula (P12):
Z₁ to Z₅ are each independently a nitrogen atom, a carbon atom bonded to R₁₅, or a carbon atom bonded to another atom in a molecule of the accepting compound;
at least one of Z₁ to Z₅ is a carbon atom bonded to another atom in a molecule of the accepting compound;
R₁₅ is selected from the group consisting of a hydrogen atom, a halogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted alkenyl group having 2 to 50 carbon atoms, a substituted or unsubstituted aralkyl group having 7 to 50 carbon atoms, a carboxy group, a substituted or unsubstituted ester group, a substituted or unsubstituted carbamoyl group, a nitro group, and a substituted or unsubstituted siloxanyl group; and
when a plurality of R₁₅ are present, the plurality of R₁₅ are mutually the same or different.

In the accepting compound, R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In the organic EL device according to the exemplary embodiment, the accepting compound preferably has at least one cyano group.

In an exemplary arrangement of the organic EL device according to the exemplary embodiment, the second layer contains the compound M5 represented by the formula (4) and the compound M6 (accepting compound), the compound M5 and the compound M6 are mutually different, and a content of the accepting compound in the second layer is less than 50 mass %,

In an exemplary arrangement of the organic EL device according to the exemplary embodiment, the content of the accepting compound in the second layer is 10 mass % or less or 5 mass % or less.

In an exemplary arrangement of the organic EL device according to the exemplary embodiment, the content of the accepting compound in the second layer is in a range from 1 mass % to 3 mass %.

Specific examples of the accepting compound include the following compounds. However, the invention is by no means limited to the specifically listed accepting compounds.

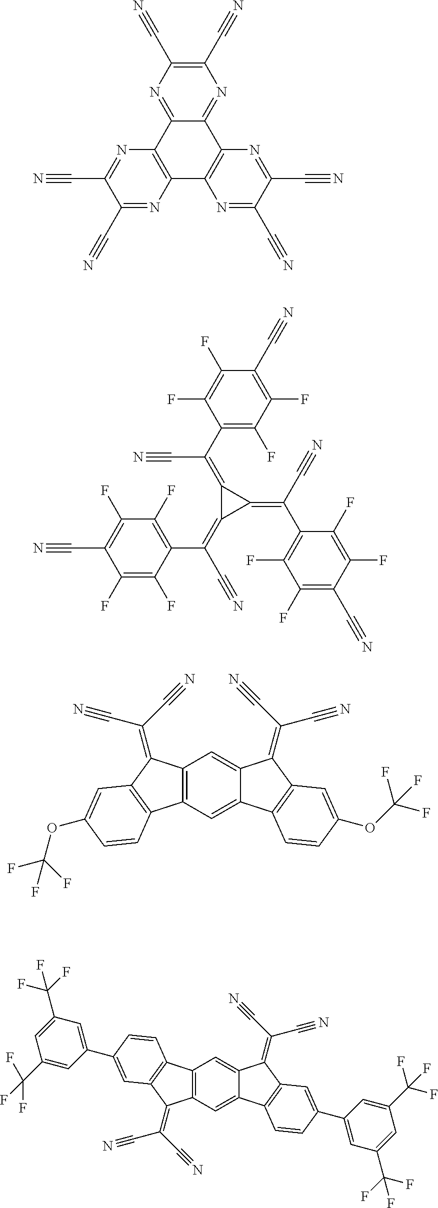 [SMILES: N#Cc1nc2c3nc(C#N)c(C#N)nc3c3nc(C#N)c(C#N)nc3c2nc1C#N ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=C1c2cc(OC(F)(F)F)ccc2-c2cc3c(cc21)C(=C(C#N)C#N)c1cc(OC(F)(F)F)ccc1-3 ; N#CC(C#N)=C1c2cc(-c3cc(C(F)(F)F)cc(C(F)(F)F)c3)ccc2-c2cc3c(cc21)-c1ccc(-c2cc(C(F)(F)F)cc(C(F)(F)F)c2)cc1C3=C(C#N)C#N]

### Hole Injecting Layer

The hole injecting layer is a layer containing a substance exhibiting a high hole injectability. Examples of the substance exhibiting a high hole injectability include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the highly hole-injectable substance include: an aromatic amine compound, which is a low-molecule organic compound, such that 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazole-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1).

In addition, a high polymer compound (e.g., oligomer, dendrimer and polymer) is usable as the substance exhibiting a high hole injectability. Examples of the high-molecule compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), and poly[N, N′-bis(4-butylphenyl)-N, N′-bis(phenyl)benzidine] (abbreviation: Poly-TPD). Moreover, an acid-added high polymer compound such as poly(3,4-ethylenedioxythiophene)/poly(styrene sulfonic acid) (PEDOT/PSS) and polyaniline/poly(styrene sulfonic acid) (PAni/PSS) is also usable.

### Third Layer

In the organic EL device according to the exemplary embodiment, a third layer is preferably disposed between the first layer and the emitting layer.

In the organic EL device according to the exemplary embodiment, the third layer is also preferably in direct contact with the emitting layer.

In the organic EL device according to the exemplary embodiment, the third layer is also preferably in direct contact with the first layer.

In the organic EL device according to the exemplary embodiment, the second layer, the first layer, and the third layer are preferably disposed in this order.

In the organic EL device according to the exemplary embodiment, the third layer is preferably smaller in film thickness than the first layer.

In the organic EL device according to the exemplary embodiment, the film thickness of the third layer is preferably 5 nm or more.

In the organic EL device according to the exemplary embodiment, the film thickness of the third layer is preferably 50 nm or less.

In the organic EL device according to the exemplary embodiment, the third layer preferably contains a compound M7. The compound M7 and the compound M4 are mutually different.

In the organic EL device according to the exemplary embodiment, the third compound also preferably does not contain a compound represented by the formula (4).

In the organic EL device according to the exemplary embodiment, the third layer is preferably an electron blocking layer.

### Electron Blocking Layer

The electron blocking layer is preferably a layer for transporting holes and blocking electrons from reaching a layer close to the anode (e.g., the hole transporting layer) beyond the electron blocking layer. A compound contained in the electron blocking layer is exemplified by a compound used in a known electron blocking layer and is preferably at least one compound selected from the group consisting of an aromatic amine compound and a carbazole derivative. The compound contained in the electron blocking layer may be a monoamine compound having only one substituted or unsubstituted amino group in a molecule. The compound contained in the electron blocking layer may be a compound having a substituted or unsubstituted carbazole group and one substituted or unsubstituted amino group in a molecule.

The electron blocking layer may block excitons generated in the emitting layer from being transferred to a layer(s) (e.g., the hole transporting layer and the hole injecting layer) close to the anode beyond the electron blocking layer in order that excited energy does not leak to the neighboring layers.

### Emitting Layer

In the organic EL device according to the exemplary embodiment, the emitting layer preferably contains the compound M1 and the compound M2. In this arrangement, the compound M1 is preferably a host material (also referred to as a matrix material) and the compound M2 is also preferably a dopant material (also referred to as a guest material, emitter or luminescent material).

In a case where the emitting layer contains the compound M1 in the exemplary embodiment, the emitting layer preferably does not contain a phosphorescent metal complex and also preferably does not contain a metal complex other than the phosphorescent metal complex.

In an exemplary arrangement, the emitting layer may contain a metal complex.

In an exemplary arrangement, the emitting layer also preferably does not contain a metal complex.

In an exemplary arrangement, the emitting layer preferably does not contain a phosphorescent material (dopant material).

In an exemplary arrangement, the emitting layer preferably does not contain a heavy-metal complex and a phosphorescent rare earth metal complex. Examples of the heavy-metal complex include iridium complex, osmium complex, and platinum complex.

### Compound M1

In the organic EL device according to the exemplary embodiment, the compound M1 is a delayed fluorescent compound represented by a formula (1) below.

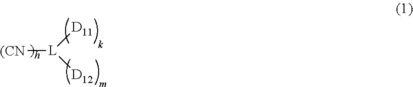

In the formula (1):
CN is a cyano group;
L is a substituted or unsubstituted aromatic hydrocarbon ring having 6 to 30 ring carbon atoms;
D₁₁ and D₁₂ are each independently a group represented by a formula (11), (12) or (13) below;
h is an integer of 2 or more;
k is an integer of 1 or more;
m is an integer of 0 or more;
D₁₁ and D₁₂ are mutually the same or different;
a plurality of D₁₁ are mutually the same or different; and
a plurality of D₁₂ are mutually the same or different.

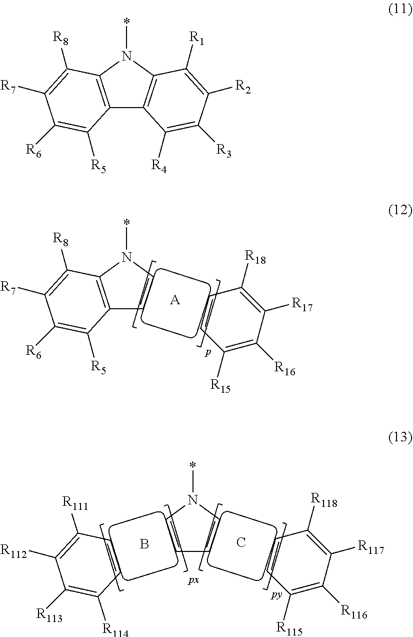

In the formula (11), at least one combination of adjacent two or more of R₁ to R₈ are mutually bonded to form a substituted or unsubstituted monocyclic ring, mutually bonded to form a substituted or unsubstituted fused ring, or not mutually bonded.

In the formula (12), at least one combination of adjacent two or more of R₁₁ to R₁₈ are mutually bonded to form a substituted or unsubstituted monocyclic ring, mutually bonded to form a substituted or unsubstituted fused ring, or not mutually bonded.

In the formula (13), at least one combination of adjacent two or more of R₁₁₁ to R₁₁₈ are mutually bonded to form a substituted or unsubstituted monocyclic ring, mutually bonded to form a substituted or unsubstituted fused ring, or not mutually bonded;
R₁ to R₈ forming neither the substituted or unsubstituted monocyclic ring nor the substituted or unsubstituted fused ring in the formula (11), R₁₁ to R₁₃ forming neither the substituted or unsubstituted monocyclic ring nor the substituted or unsubstituted fused ring in the formula (12), and R₁₁₁ to R₁₁₈ forming neither the substituted or unsubstituted monocyclic ring nor the substituted or unsubstituted fused ring in the formula (13) are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —(═O)(R₉₃₁)(R₉₃₂), a group represented by —Ge(R₉₃₃)(R₉₃₄)(R₉₃₆), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms.

In the formulae (12) and (13):
a ring A, a ring B, and a ring C are each independently any cyclic structure selected from the group consisting of cyclic structures represented by formulae (14) and (15) below;
the ring A, the ring B, and the ring C are fused with adjacent rings at any positions;
p, px and py are each independently 1, 2, 3, or 4;
when p is 2, 3, or 4, a plurality of rings A are mutually the same or different;
when px is 2, 3, or 4, a plurality of rings B are mutually the same or different;
when py is 2, 3, or 4, a plurality of rings C are mutually the same or different; and
* in the formulae (11) to (13) represents a bonding position to L in the formula (1).

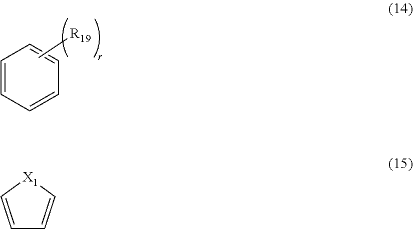

In the formula (14):
r is 0, 2, or 4;
a combination of a plurality of R₁₉ are mutually bonded to form a substituted or unsubstituted monocyclic ring, mutually bonded to form a substituted or unsubstituted fused ring, or not mutually bonded.

In the formula (15): X₁ is a sulfur atom, an oxygen atom, C(R₁₆₁)(R₁₅₂), or N(R₁₆₃);
a combination of R₁₅₁ and R₁₅₂ are mutually bonded to form a substituted or unsubstituted monocyclic ring, mutually bonded to form a substituted or unsubstituted fused ring, or not mutually bonded;
R₁₅₃, R₁₅₁ and R₁₅₂ forming neither the substituted or unsubstituted monocyclic ring nor the substituted or unsubstituted fused ring, and R₁₉ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR909, a halogen atom, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms;
a plurality of R₁₉ are mutually the same or different; and
a plurality of X₁ are mutually the same or different.

In an example of the organic EL device according to the exemplary embodiment, at least one D₁₁ is: a group represented by the formula (11) in which at least one combination of adjacent two or more of R₁ to R₈ are mutually bonded to form the substituted or unsubstituted monocyclic ring or the substituted or unsubstituted fused ring; a group represented by the formula (12); or a group represented by the formula (13).

The compound M1 is also preferably a compound represented by a formula (100) below,

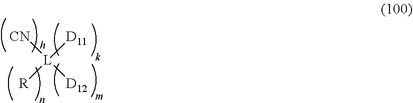

In the formula (100): L, D₁₁, D₁₂, h, k, and m respectively represent the same as L, D₁₁, D₁₂, h, k, and m in the formula (1).

R is each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms;
at least one R, which is a substituent, is bonded to L in a compound represented by the formula (100) via carbon-carbon bonding;
n is an integer of 1 or more; and
a plurality of R are mutually the same or different.

In a compound represented by the formula (1) or (100), L is preferably a substituted or unsubstituted aromatic hydrocarbon ring having 6 to 14 ring carbon atoms, more preferably a substituted or unsubstituted aromatic hydrocarbon ring having 6 to 10 ring carbon atoms.

In a compound represented by the formula (1) or (100), the aromatic hydrocarbon ring having 6 to 14 ring carbon atoms for L is preferably a benzene ring, naphthalene ring, fluorene ring, or phenanthrene ring.

In a compound represented by the formula (1) or (100), L is preferably a benzene ring. In a case where L is a benzene ring, a compound represented by the formula (100) is represented by a formula (101) below.

In the organic EL device according to the exemplary embodiment, a compound represented by the formula (1) (compound Kill) is preferably represented by the formula (101) below.

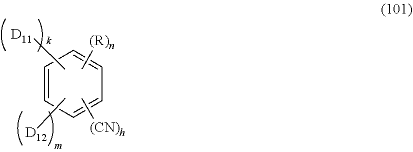

In the formula (101), D₁₁ and D₁₂ respectively represent the same as D₁₁ and D₁₂ in the formula (1);
h is 2, 3, 4, or 5;
k is 1, 2, 3, or 4;
m is 0, 1, 2, or 3;
n is 0, 1, 2, or 3;
h+k+m+n=6 is satisfied;
R is each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₉₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms; and
a plurality of R are mutually the same or different.

In the compound M1, a benzene ring in the formula (101) to which groups represented by the formulae (11) to (13) and the like are bonded is a benzene ring per se explicitly depicted in the formula (101), not a benzene ring included in R, D₁₁, and D₁₂.

In the compound M1, preferably, h is 2, 3, or 4, k is 1, 2, or 3, m is 0, 1, or 2, n is 1, 2, or 3, and at least one R, which is a substituent, is bonded to a benzene ring in the formula (101) via carbon-carbon bonding.

In the compound M1, h is more preferably 2 or 3, still more preferably 2.

In the organic EL device according to the exemplary embodiment, a compound represented by the formula (1) is preferably a compound represented by a formula (110), (120), or (130) below.

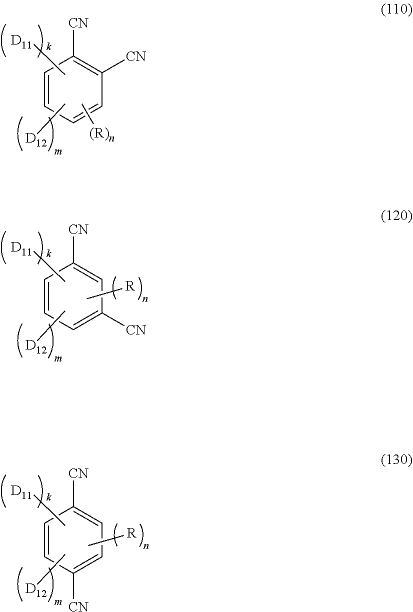

In the formulae (110), (120), and (130), D₁₁, D₁₂, R, k, m, and n respectively represent the same as D₁₁, D₁₂, R, k, m, and n in the formula (1) or (101).

In the compound N/11, preferably, k is 1, m is 1, and n is 2.

In the compound M1, at least one D₁₁ is preferably a group represented by the formula (12) or (13).

In the compound M1, at least one ail is preferably a group represented by a formula (121), (122), or (131) below.

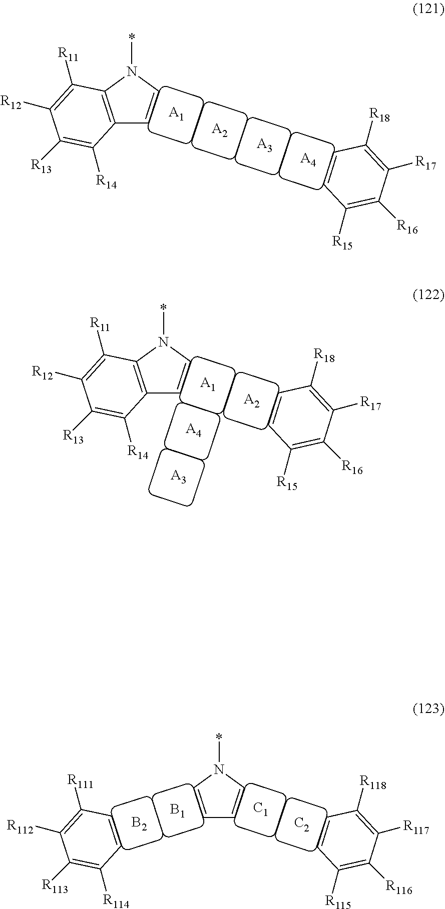

In the formulae (121) and (122):
R₁₁ to R₁₈ respectively represent the same as R₁₁ to R₁₈ in the formula (12); and
of a ring A₁, a ring A₂, a ring A₃, and a ring A₄, two of the rings A₁, A₂, A₃, and A₄ are each a cyclic structure represented by the formula (14) and the remaining two of the rings A₁, A₂, A₃, and A₄ are each a cyclic structure represented by the formula (15).

In the formula (131): R₁₁₁ to R₁₁₈ respectively represent the same as R₁₁₁ to R₁₁₈ in the formula (13);
one of a ring B₁ and a ring B₂ is a cyclic structure represented by the formula (14) and the other of the ring B₁ and the ring B₂ is a cyclic structure represented by the formula (15);
one of a ring C₁ and a ring C₂ is a cyclic structure represented by the formula (14) and the other of the ring C₁ and the ring C₂ is a cyclic structure represented by the formula (15); and
* in the formulae (121), (122), and (131) represents a bonding position to L in the formula (1) or a benzene ring in the formula (101).

In the compound M1, preferably, the ring A₁ and the ring A3 are each a cyclic structure represented by the formula (14) and the ring A2 and the ring A4 are each a cyclic structure represented by the formula (15).

In the compound M1, preferably, the ring B₁ is a cyclic structure represented by the formula (14) and the ring B₂ is a cyclic structure represented by the formula (15).

In the compound M1, preferably, the ring C₁ is a cyclic structure represented by the formula (14) and the ring C₂ is a cyclic structure represented by the formula (15).

In the compound M1, at least one D₁₁ is preferably a group represented by the formula (131).

In the compound M1, at least one D₁₁ is preferably a group represented by a formula (123), (124), (125), or (132) below.

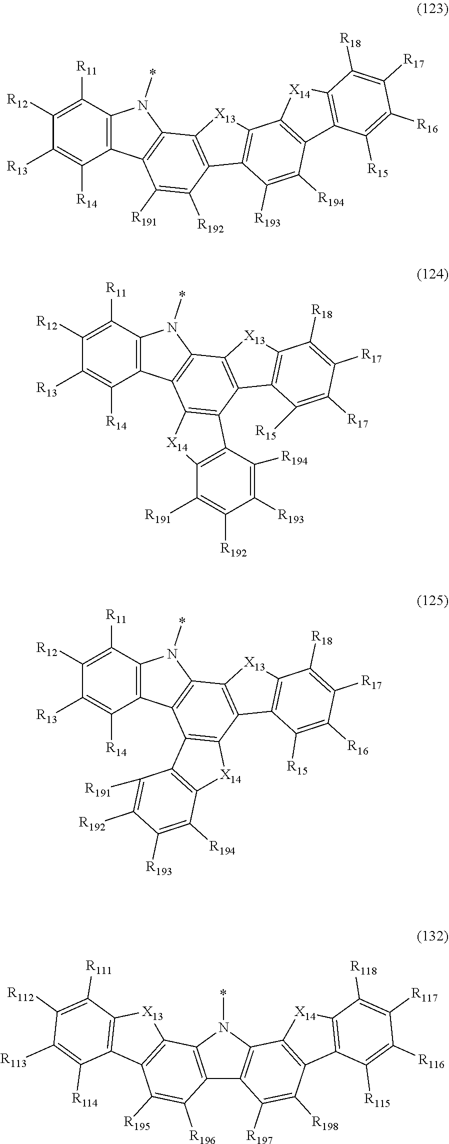

In the formulae (123), (124), and (125): R₁₁ to R₁₈ respectively represent the same as R₁₁ to R₁₈ in the formula (12); and R₁₉₁ to R₁₉₄ each independently represent the same as R₁₉ in the formula (14).

In the formula (132): R₁₁₁ to R₁₁₈ respectively represent the same as R₁₁₁ to R₁₁₈ in the formula (13); and R₁₉₅ to R₁₉₈ each independently represent the same as R₁₉ in the formula (14).

In the formulae (123), (124), (125), and (132), X₁₃ and X₁₄ each independently represent the same as X₁ in the formula (15); and * represents a bonding position to L in the formula (1) or a benzene ring in the formula (101).

In the compound M1, X₁₃ is preferably a sulfur atom.

In the compound M1, at least one D₁₁ is preferably a group represented by the formula (132).

In the compound M1, preferably, D₁₂ is a group represented by the formula (11) or (12) and m is an integer of 1 or more.

In the compound M1, D₁₂ is preferably a group represented by the formula (12).

In the compound M1, a group represented by the formula (12) is preferably a group selected from the group consisting of groups represented by formulae (12A), (12B), (12C), (12D), (12E), and (12F) below.

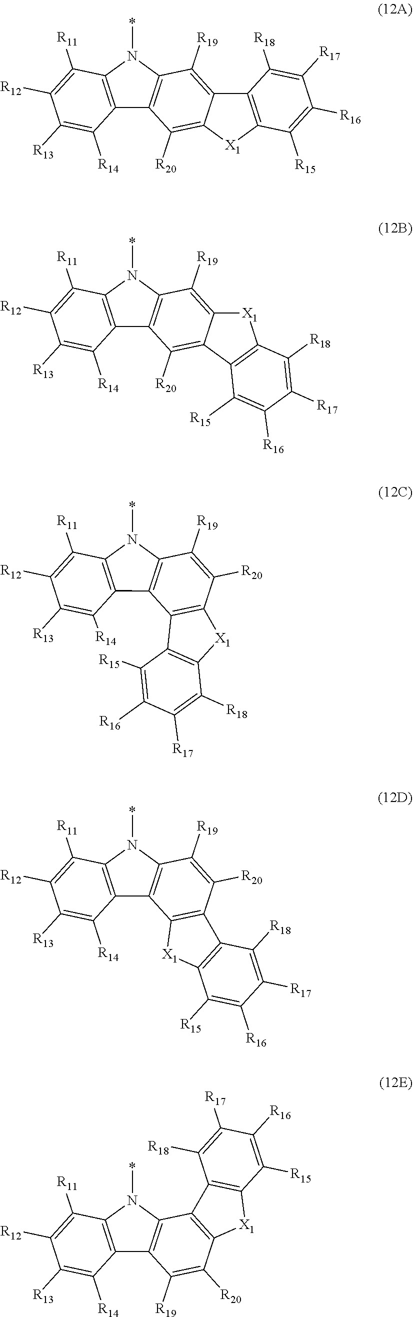

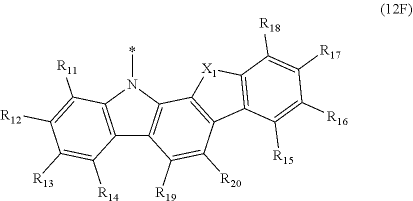

In the formulae (12A), (12B), (12C), (12D), (12E), and (12F):
R₁₁ to R₁₈ each independently represent the same as R₁₁ to R₁₈ in the formula (12);
R₁₉ and R₂₀ each independently represent the same as R₁₉ in the formula (14); and

X₁ represents the same as X₁ in the formula (15).
* in the formulae (12A), (12B), (12C), (12D), (12E), and (12F) represents a bonding position to L in the formula (1) or a benzene ring in the formula (101).

In the compound M1, X₁ is preferably an oxygen atom or a sulfur atom.

In the compound M1, it is also preferable that none of combinations of adjacent two or more of R₁ to R₈ are bonded to each other.

In the compound M1, it is also preferable that none of combinations of adjacent two or more of R₁₁ to R₁₈ are bonded to each other.

In the compound M1, it is also preferable that none of combinations of adjacent two or more of R₁₁₁ to R₁₁₈ are bonded to each other.

In the compound M1, R in the formula (100) or (101) is preferably each independently a substituted or unsubstituted alkyl group having 1 to 20 carbon atoms, a substituted or unsubstituted aryl group having 6 to 30 ring carbon atoms, or a substituted or unsubstituted heterocyclic group having 5 to 30 ring atoms.

In the compound M1, R in the formula (100) or (101) is preferably each independently a substituted or unsubstituted alkyl group having 1 to 6 carbon atoms, a substituted or unsubstituted aryl group having 6 to 18 ring carbon atoms, or a substituted or unsubstituted heterocyclic group having 5 to 18 ring atoms.

In the compound M1, R₁ to R₈ in the formula (11), R₁₁ to R₁₈ in the formula (12), R₁₁₁ to R₁₁₈ in the formula (13), and R₁₉ in the formula (14) are preferably each independently a hydrogen atom, a substituted or unsubstituted alkyl group having 1 to 20 carbon atoms, a substituted or unsubstituted aryl group having 6 to 30 ring carbon atoms, or a substituted or unsubstituted heterocyclic group having 5 to 30 ring atoms.

In the compound M1, R₁₁ to R₁₈ in the formula (11), R₁₁ to R₁₈ in the formula (12), R₁₁₁ to R₁₁₈ in the formula (13), and R₁₉ in the formula (14) are preferably each independently a hydrogen atom, a substituted or unsubstituted alkyl group having 1 to 6 carbon atoms, a substituted or unsubstituted aryl group having 6 to 18 ring carbon atoms, or a substituted or unsubstituted heterocyclic group having 5 to 18 ring atoms.

In the compound M1: preferably, R in the formula (100) or (101) is each independently a substituted or unsubstituted alkyl group having 1 to 20 carbon atoms, a substituted or unsubstituted aryl group having 6 to 30 ring carbon atoms, or a substituted or unsubstituted heterocyclic group having 5 to 30 ring atoms; and R₁ to R₈ in the formula (11), R₁₁ to R₁₈ in the formula (12), R₁₁₁ to R₁₁₈ in the formula (13), and R₁₉ in the formula (14) are each independently a hydrogen atom, a substituted or unsubstituted alkyl group having 1 to 20 carbon atoms, a substituted or unsubstituted aryl group having 6 to 30 ring carbon atoms, or a substituted or unsubstituted heterocyclic group having 5 to 30 ring atoms.

In the compound M1 preferably, R in the formula (100) or (101) is each independently a substituted or unsubstituted alkyl group having 1 to 6 carbon atoms, a substituted or unsubstituted aryl group having 6 to 18 ring carbon atoms, or a substituted or unsubstituted heterocyclic group having 5 to 18 ring atoms; and R₁ to R₈ in the formula (11), R₁₁ to R₁₈ in the formula (12), R₁₁₁ to R₁₁₈ in the formula (13), and R₁₉ in the formula (14) are each independently a hydrogen atom, a substituted or unsubstituted alkyl group having 1 to 6 carbon atoms, a substituted or unsubstituted aryl group having 6 to 18 ring carbon atoms, or a substituted or unsubstituted heterocyclic group having 5 to 18 ring atoms.

In the compound M1, the substituent for “the substituted or unsubstituted” group is an unsubstituted alkyl group having 1 to 25 carbon atoms, an unsubstituted alkenyl group having 2 to 25 carbon atoms, an unsubstituted alkynyl group having 2 to 25 carbon atoms, an unsubstituted cycloalkyl group having 3 to 25 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₈)(R₉₀₇), an unsubstituted aralkyl group having 7 to 50 carbon atoms, a group represented by —C(═O)R₉₀₈, a group represented by —COOR₉₀₉, a group represented by —(═O)(R₉₃₁)(R₉₃₂), a group represented by —Ge(R₉₃₃)(R₉₃₄)(R₉₃₅), a group represented by —B(R₉₃₈)(R₉₃₇), a group represented by —S(═O)₂R₉₃₈, a halogen atom, a cyano group, a nitro group, an unsubstituted aryl group having 6 to 25 ring carbon atoms, or an unsubstituted heterocyclic group having 5 to 25 ring atoms.

R₉₀₁ to R₉₀₉ and R₉₃₁ to R₉₃₈ are preferably each independently a hydrogen atom, an unsubstituted alkyl group having 1 to 25 carbon atoms, an unsubstituted aryl group having 6 to 25 ring carbon atoms, or an unsubstituted heterocyclic group having 5 to 25 ring atoms.

In the compound M1, the substituent for “the substituted or unsubstituted” group is preferably a halogen atom, an unsubstituted alkyl group having 1 to 25 carbon atoms, an unsubstituted aryl group having 6 to 25 ring carbon atoms, or an unsubstituted heterocyclic group having 5 to 25 ring atoms.

In the compound M1, the substituent for “the substituted or unsubstituted” group is preferably an unsubstituted alkyl group having 1 to 10 carbon atoms, an unsubstituted aryl group having 6 to 12 ring carbon atoms, or an unsubstituted heterocyclic group having 5 to 12 ring atoms.

In the organic EL device according to the exemplary embodiment, it is also preferable that the groups specified to be “substituted or unsubstituted” in the compound M1 are each an “unsubstituted” group.

A group represented by —O—(R₉₀₄) herein in which R₉₀₄ is a hydrogen atom is a hydroxy group.

A group represented by —O—(R₉₀₅) herein in which R₉₀₅ is a hydrogen atom is a thiol group.

A group represented by —P(═O)(R₉₃₁)(R₉₃₂) herein is a substituted phosphine oxide group when R₉₃₁ and R₉₃₂ are each a substituent, and an aryl phosphoryl group when R₉₃₁ and R₉₃₂ are each an aryl group.

A group represented by —Ge(R₉₃₃)(R₉₃₄)(R₉₃₅) herein in which R₉₃₃, R₉₃₄, and R₉₃₅ are each a substituent is a substituted germanium group.

A group represented by —B(R₉₃₆)(R₉₃₇) herein in which R₉₃₆ and R₉₃₇ are each a substituent is a substituted boryl group.

### Delayed Fluorescence

Delayed fluorescence is explained in “Yuki Hando-tai no Debaisu Bussei (Device Physics of Organic Semiconductors)” (edited by ADACHI, Chihaya, published by Kodansha, on pages 261-268). This document describes that, if an energy difference ΔE₁₃ of a fluorescent material between a singlet state and a triplet state is reducible, a reverse energy transfer from the triplet state to the singlet state, which usually occurs at a low transition probability, would occur at a high efficiency to express thermally activated delayed fluorescence (TADF). Further, a generation mechanism of delayed fluorescence is explained in FIG. 10.38 in the document. The compound M1 of the exemplary embodiment is preferably a compound exhibiting thermally activated delayed fluorescence generated by such a mechanism.

In general, emission of delayed fluorescence can be confirmed by measuring the transient PL (Photo Luminescence).

The behavior of delayed fluorescence can also be analyzed based on the decay curve obtained from the transient PL measurement. The transient PL measurement is a method of irradiating a sample with a pulse laser to excite the sample, and measuring the decay behavior (transient characteristics) of PL emission after the irradiation is stopped. PL emission in TADF materials is classified into a light emission component from a singlet exciton generated by the first PL excitation and a light emission component from a singlet exciton generated via a triplet exciton. The lifetime of the singlet exciton generated by the first PL excitation is on the order of nanoseconds and is very short. Therefore, light emission from the singlet exciton rapidly attenuates after irradiation with the pulse laser.

On the other hand, the delayed fluorescence is gradually attenuated due to light emission from a singlet exciton generated via a triplet exciton having a long lifetime. As described above, there is a large temporal difference between the light emission from the singlet exciton generated by the first PL excitation and the light emission from the singlet exciton generated via the triplet exciton. Therefore, the luminous intensity derived from delayed fluorescence can be determined.

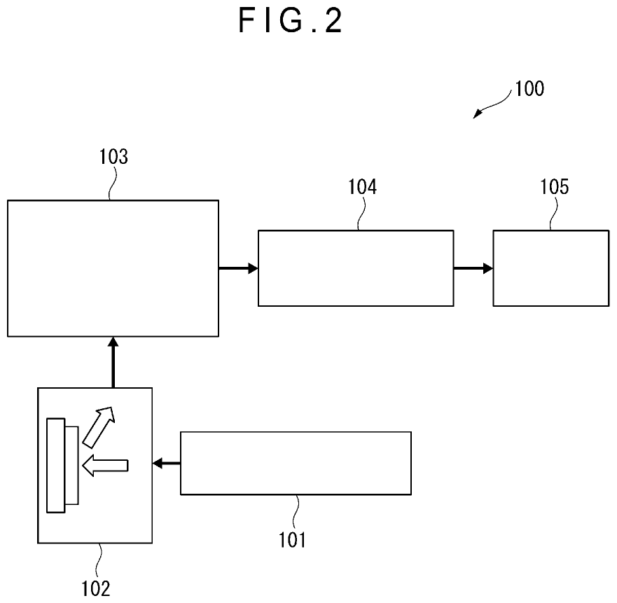

FIG. 2 is a schematic diagram of an exemplary apparatus for measuring the transient PL. An example of a method of measuring a transient PL as illustrated in FIG. 2 and an example of behavior analysis of delayed fluorescence will be described.

A transient PL measuring apparatus 100 in FIG. 2 includes: a pulse laser 101 capable of radiating a light having a predetermined wavelength; a sample chamber 102 configured to house a measurement sample; a spectrometer 103 configured to divide a light radiated from the measurement sample; a streak camera 104 configured to provide a two-dimensional image; and a personal computer 105 configured to import and analyze the two-dimensional image. An apparatus for measuring the transient PL is not limited to the apparatus illustrated in FIG. 2

The sample housed in the sample chamber 102 is obtained by forming a thin film, in which a matrix material is doped with a doping material at a concentration of 12 mass %, on the quartz substrate,

The thin film sample housed in the sample chamber 102 is irradiated with the pulse laser from the pulse laser 101 to excite the doping material. Emission is extracted in a direction of 90 degrees with respect to a radiation direction of the excited light. The extracted emission is divided by the spectrometer 103 to form a two-dimensional image in the streak camera 104. As a result, the two-dimensional image is obtainable in which the ordinate axis represents a time, the abscissa axis represents a wavelength, and a bright spot represents a luminous intensity. When this two-dimensional image is taken out at a predetermined time axis, an emission spectrum in which the ordinate axis represents the luminous intensity and the abscissa axis represents the wavelength is obtainable. Moreover, when this two-dimensional image is taken out at the wavelength axis, a decay curve (transient PL) in which the ordinate axis represents a logarithm of the luminous intensity and the abscissa axis represents the time is obtainable.

For instance, a thin film sample A was prepared as described above from a reference compound H1 as the matrix material and a reference compound D1 as the doping material and was measured in terms of the transient PL.

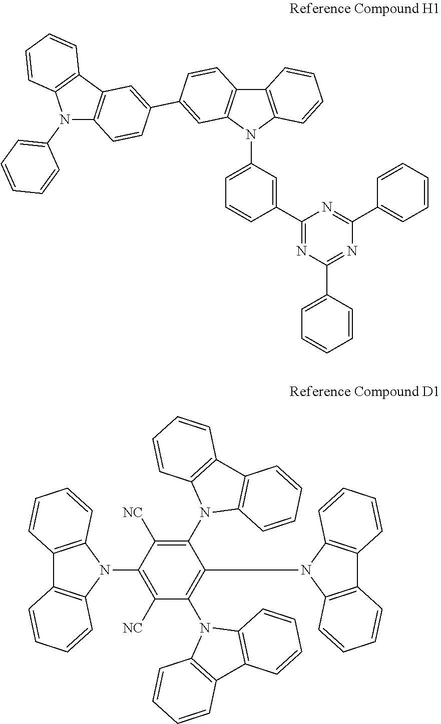 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

The decay curve was analyzed with respect to the above thin film sample A and a thin film sample B. The thin film sample B was produced in the same manner as described above from a reference compound H2 as the matrix material and the reference compound D1 as the doping material.

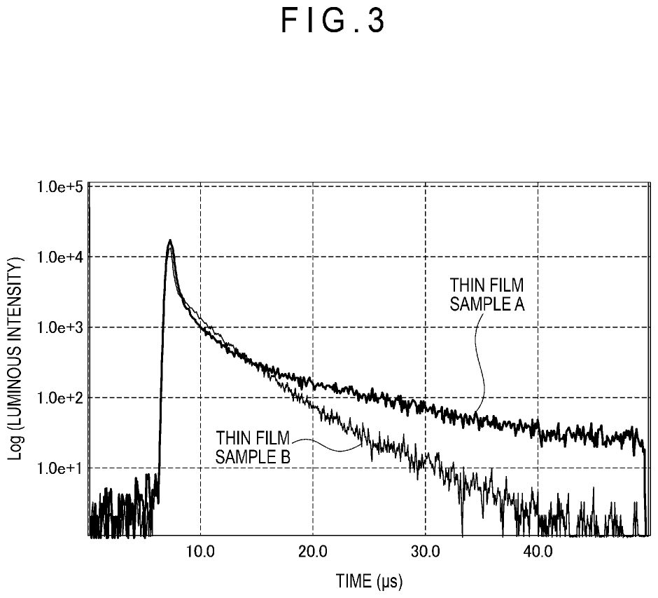

FIG. 3 illustrates decay curves obtained from transient PL obtained by measuring the thin film samples A and B.

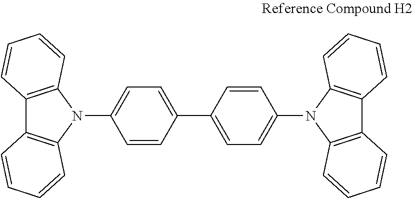 [SMILES: c1ccc2c(c1)c1ccccc1n2-c1ccc(-c2ccc(-n3c4ccccc4c4ccccc43)cc2)cc1]

As described above, an emission decay curve in which the ordinate axis represents the luminous intensity and the abscissa axis represents the time can be obtained by the transient PL measurement. Based on the emission decay curve, a fluorescence intensity ratio between fluorescence emitted from a singlet state generated by photo-excitation and delayed fluorescence emitted from a singlet state generated by reverse energy transfer via a triplet state can be estimated. In a delayed fluorescent material, a ratio of the intensity of the slowly decaying delayed fluorescence to the intensity of the promptly decaying fluorescence is relatively large.

Specifically, Prompt emission and Delay emission are present as emission from the delayed fluorescent material. Prompt emission is observed promptly when the excited state is achieved by exciting the compound of the exemplary embodiment with a pulse beam (i.e., a beam emitted from a pulse laser) having a wavelength absorbable by the delayed fluorescent material. Delay emission is observed not promptly when the excited state is achieved but after the excited state is achieved.

An amount of Prompt emission, an amount of Delay emission and a ratio between the amounts thereof can be obtained according to the method as described in “Nature 492,234-238, 2012” (Reference Document 1). The amount of Prompt emission and the amount of Delay emission may be calculated using an apparatus different from one described in Reference Document 1 or the apparatus illustrated in FIG. 2.

A sample produced by the following method is used for measuring delayed fluorescence of the compound M1 according to the exemplary embodiment. For instance, the compound M1 according to the exemplary embodiment is dissolved in toluene to prepare a dilute solution with an absorbance of 0.05 or less at the excitation wavelength to eliminate the contribution of self-absorption. In order to prevent quenching due to oxygen, the sample solution is frozen and degassed and then sealed in a cell with a lid under an argon atmosphere to obtain an oxygen-free sample solution saturated with argon.

The fluorescence spectrum of the sample solution is measured with a spectrofluorometer FP-8600 (produced by JASCO Corporation), and the fluorescence spectrum of a 9,10-diphenylanthracene ethanol solution is measured under the same conditions. Using the fluorescence area intensities of both spectra, the total fluorescence quantum yield is calculated by an equation (1) in Morris et al. J. Phys. Chem. 80 (1976) 969.

In the exemplary embodiment, provided that an amount of Prompt emission of a measurement target compound is denoted by X_{P} and an amount of Delay emission is denoted by X_{D}, a value of X_{D}/X_{P} is preferably 0.05 or more.

The amounts of Prompt emission and Delay emission and a ratio of the amounts thereof in compounds other than the compound M1 according to the exemplary embodiment herein are measured in the same manner as those of the compound M1 according to the exemplary embodiment.

### ΔST

In the exemplary embodiment, a difference (S₁−T_{77K}) between the lowest singlet energy S₁ and the energy gap T_{77K} at 77K is defined as ΔST.

In the exemplary embodiment, a difference ΔST(M1) between the lowest singlet energy S₁(M1) of the compound M1 and the energy gap T_{77K}(M1) at 77K of the compound M1 is preferably less than 0.3 eV, more preferably less than 0.2 eV, still more preferably less than 0.1 eV, and still further more preferably less than 0.01 eV. In other words, ΔST(M1) preferably satisfies a relationship of a numerical formula (Numerical Formula (10), Numerical Formula (11), Numerical Formula (12), or Numerical Formula (13)) below.

ΔST(M1)=S₁(M1)−T_{77K}(M1)<0.3 eV (Numerical Formula 10)

ΔST(M1)=S₁(M1)−T_{77K}(M1)<0.2 eV (Numerical Formula 11)

ΔST(M1)=S₁(M1)−T_{77K}(M1)<0.1 eV (Numerical Formula 12)

ΔST(M1)=S₁(M1)−T_{77K}(M1)<0.01 eV (Numerical Formula 13)

### Relationship Between Triplet Energy and Energy Gap at 77K

Here, a relationship between a triplet energy and an energy gap at 77K will be described. In the exemplary embodiment, the energy gap at 77K is different from a typical triplet energy in some aspects.

The triplet energy is measured as follows. First, a solution in which a compound (measurement target) is dissolved in an appropriate solvent is encapsulated in a quartz glass tube to prepare a sample. A phosphorescence spectrum (ordinate axis: phosphorescent luminous intensity, abscissa axis: wavelength) of the sample is measured at a low temperature (77K). A tangent is drawn to the rise of the phosphorescence spectrum close to the short-wavelength region. The triplet energy is calculated by a predetermined conversion equation based on a wavelength value at an intersection of the tangent and the abscissa axis.

Herein, the compound M1 according to the exemplary embodiment is a thermally activated delayed fluorescent compound, preferably a compound having a small ΔST. When ΔST is small, intersystem crossing and inverse intersystem crossing are likely to occur even at a low temperature (77K), so that the singlet state and the triplet state coexist. As a result, the spectrum to be measured in the same manner as the above includes emission from both the singlet state and the triplet state. Although it is difficult to distinguish from which state, the singlet state or the triplet state, light is emitted, the value of the triplet energy is basically considered dominant.

Accordingly, in the exemplary embodiment, the triplet energy is measured by the same method as a typical triplet energy T, but a value measured in the following manner is referred to as an energy gap T77K in order to differentiate the measured energy from the typical triplet energy in a strict meaning. The measurement target compound is dissolved in EPA (diethylether isopentane:ethanol=5:5:2 in volume ratio) at a concentration of 10 μmol/L, and the obtained solution is put in a quartz cell to provide a measurement sample. A phosphorescence spectrum (ordinate axis: phosphorescent luminous intensity, abscissa axis: wavelength) of the sample is measured at a low temperature (77K). A tangent is drawn to the rise of the phosphorescence spectrum close to the short-wavelength region. An energy amount is calculated by a conversion equation (F1) below based on a wavelength value λ_{edge} [nm] at an intersection of the tangent and the abscissa axis and is defined as an energy gap T77K at 77K.

T_{77K}[eV]=1239.8/λ_{edge} Conversion Equation (F1):

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (manufactured by Hitachi High-Technologies Corporation) is usable. Any apparatus for phosphorescence measurement is usable. A combination of a cooling unit, a low temperature container, an excitation light source and a light-receiving unit may be used for phosphorescence measurement.

### Lowest Singlet Energy S₁

A method of measuring the lowest singlet energy S₁ with use of a solution (occasionally referred to as a solution method) is exemplified by a method below.

A toluene solution of a measurement target compound at a concentration of 10 μmol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value λedge (nm) at an intersection of the tangent and the abscissa axis is assigned to a conversion equation (F2) below to calculate the lowest singlet energy.

S₁[eV]=1239.85/λ_{edge} Conversion Equation (F2):

Any apparatus for measuring absorption spectrum is usable. For instance, a spectrophotometer (U3310 manufactured by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

### Producing Method of Compound M1 in Exemplary Embodiment

The compound M1 can be produced by a known method. The compound M1 can also be produced based on a known method through a known alternative reaction using a known material(s) tailored for the target compound.

### Specific Examples of Compound M1 in the Exemplary Embodiment

Specific examples of the compound M1 in the exemplary embodiment include compounds below. However, the invention is by no means limited to the specific examples. Herein, a deuterium atom is denoted as D in formulae, and a protium atom is denoted as H or omitted. Herein, occasionally, a methyl group is denoted as Me and a phenyl group is denoted as Ph.

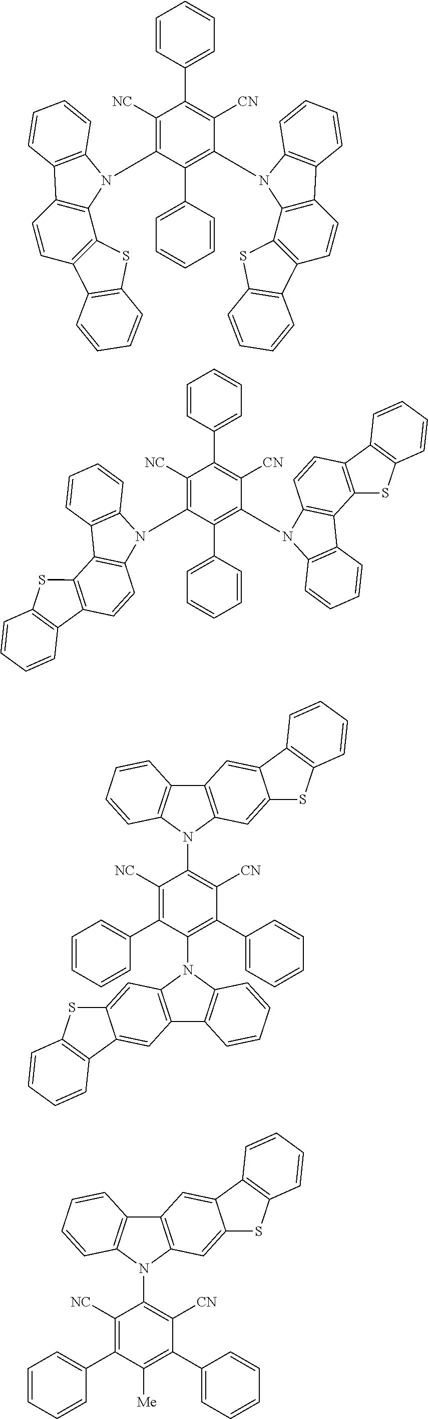

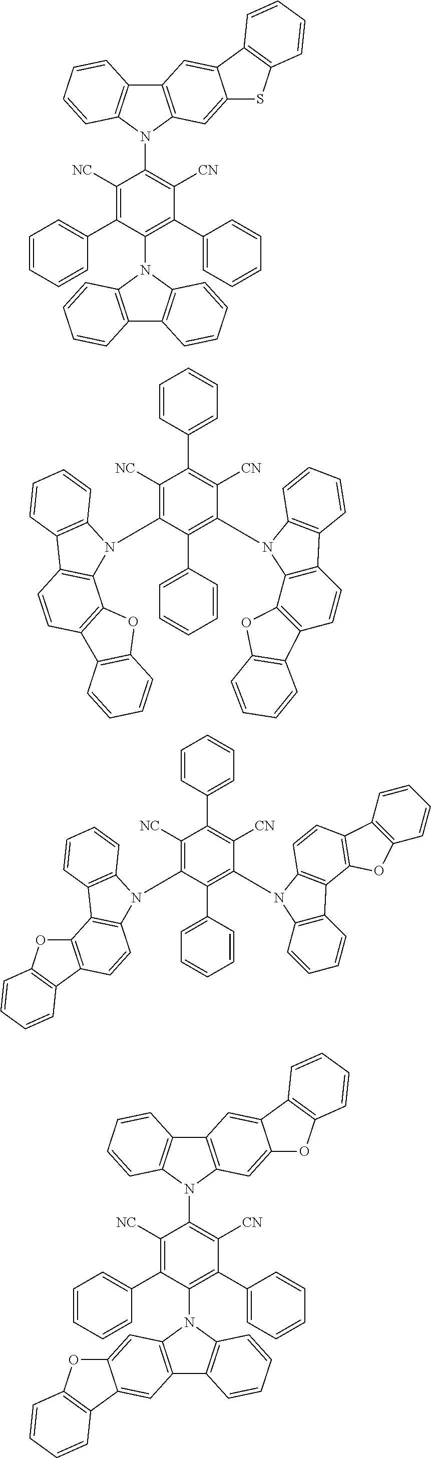

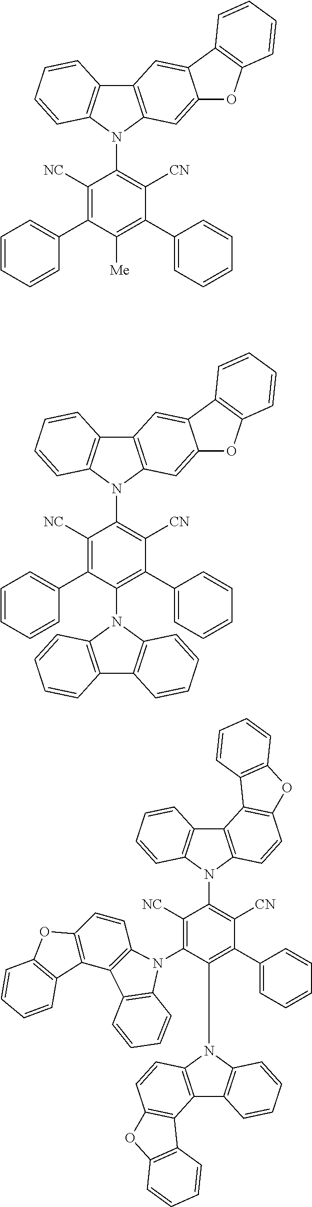

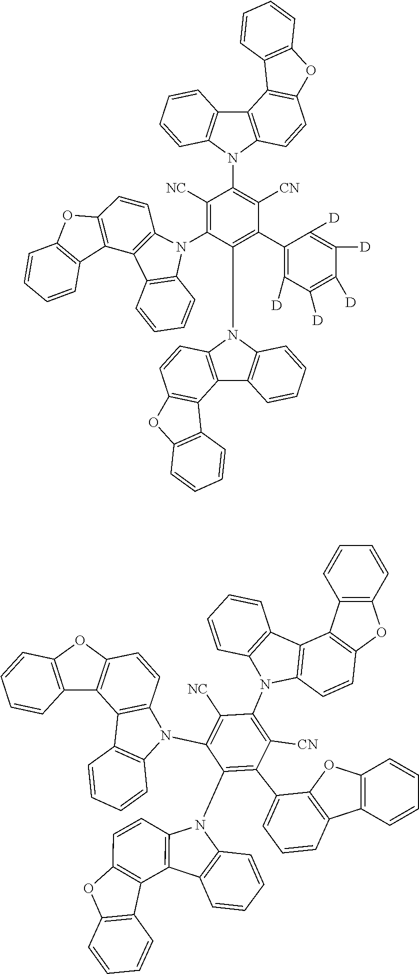

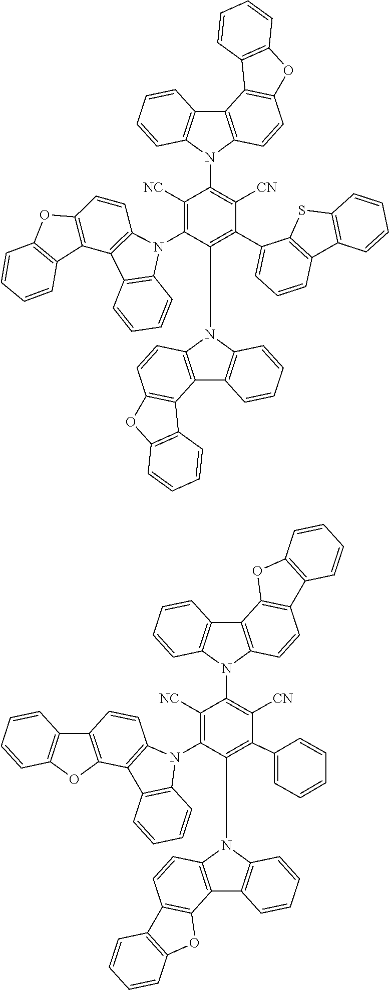

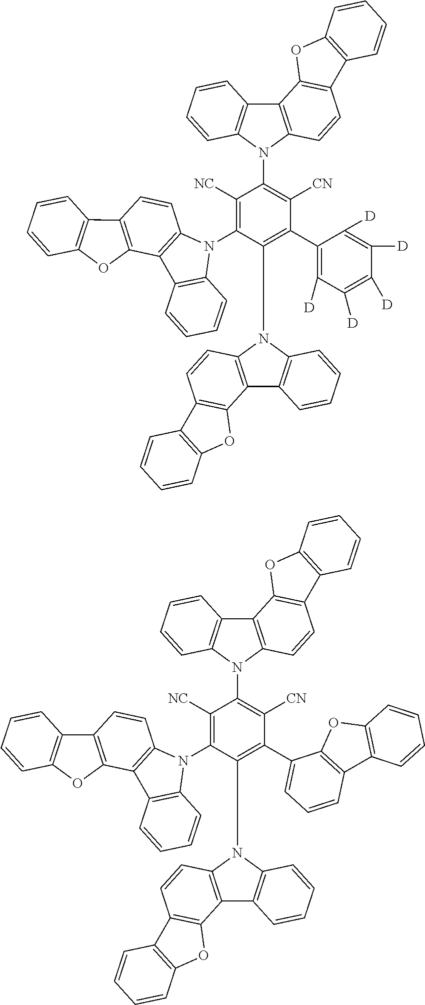

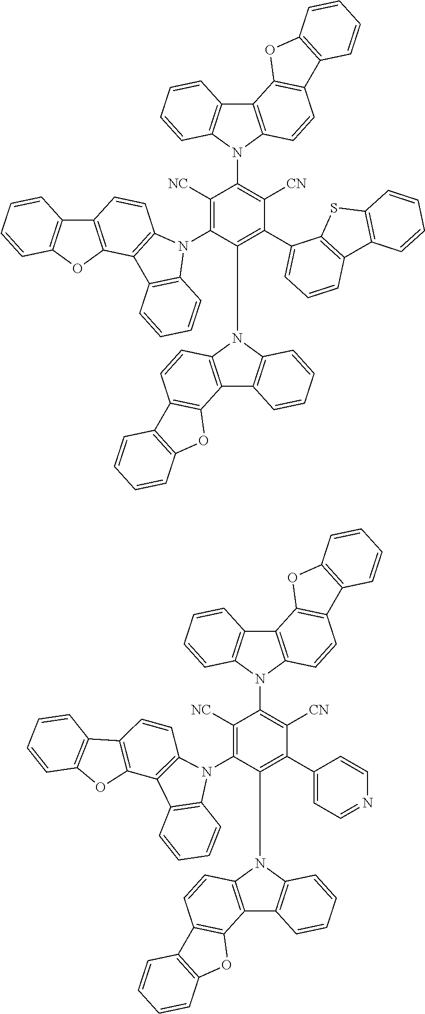

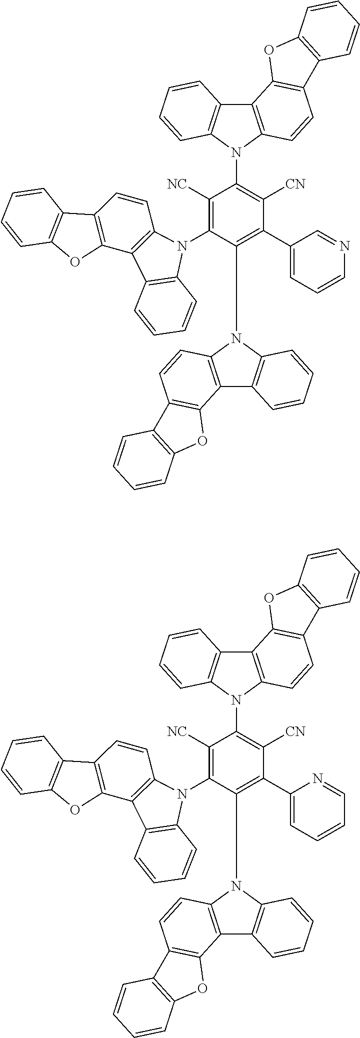 [SMILES: N#Cc1c(-c2cccnc2)c(-n2c3ccccc3c3c4oc5ccccc5c4ccc32)c(-n2c3ccccc3c3c4oc5ccccc5c4ccc32)c(C#N)c1-n1c2ccccc2c2c3oc4ccccc4c3ccc21 ; N#Cc1c(-c2ccccn2)c(-n2c3ccccc3c3c4oc5ccccc5c4ccc32)c(-n2c3ccccc3c3c4oc5ccccc5c4ccc32)c(C#N)c1-n1c2ccccc2c2c3oc4ccccc4c3ccc21]

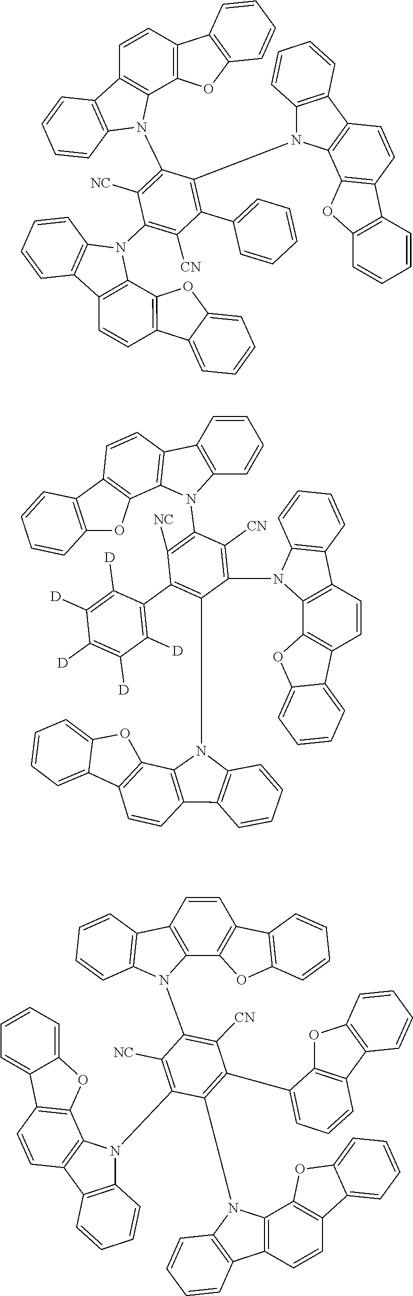

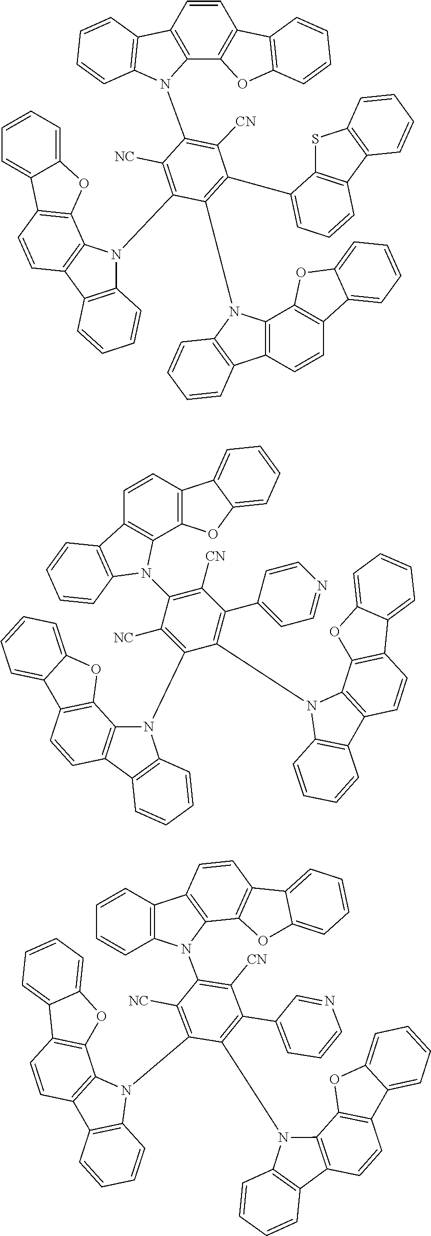 [SMILES: N#Cc1c(-c2cccc3c2sc2ccccc23)c(-n2c3ccccc3c3ccc4c5ccccc5oc4c32)c(-n2c3ccccc3c3ccc4c5ccccc5oc4c32)c(C#N)c1-n1c2ccccc2c2ccc3c4ccccc4oc3c21 ; N#Cc1c(-c2ccncc2)c(-n2c3ccccc3c3ccc4c5ccccc5oc4c32)c(-n2c3ccccc3c3ccc4c5ccccc5oc4c32)c(C#N)c1-n1c2ccccc2c2ccc3c4ccccc4oc3c21 ; N#Cc1c(-c2cccnc2)c(-n2c3ccccc3c3ccc4c5ccccc5oc4c32)c(-n2c3ccccc3c3ccc4c5ccccc5oc4c32)c(C#N)c1-n1c2ccccc2c2ccc3c4ccccc4oc3c21]

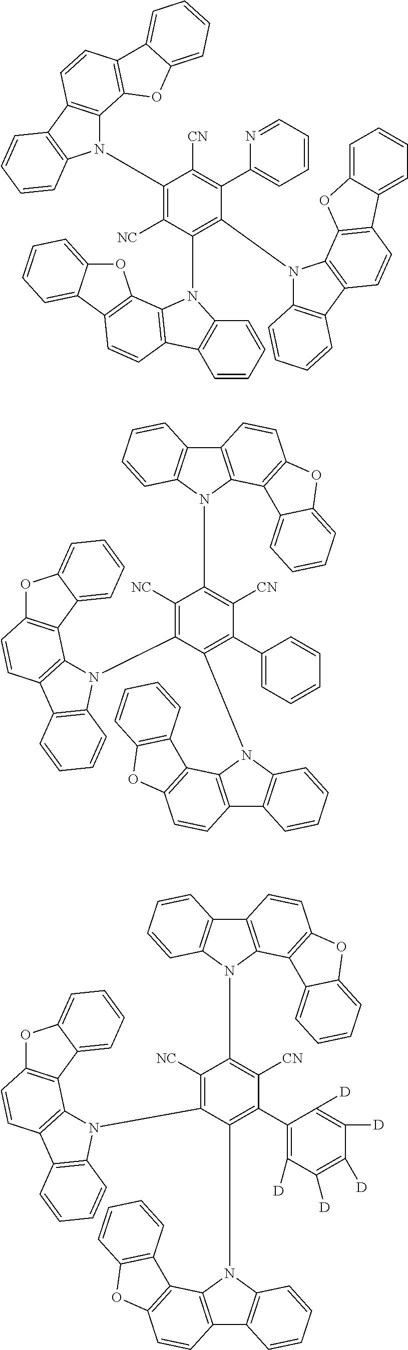

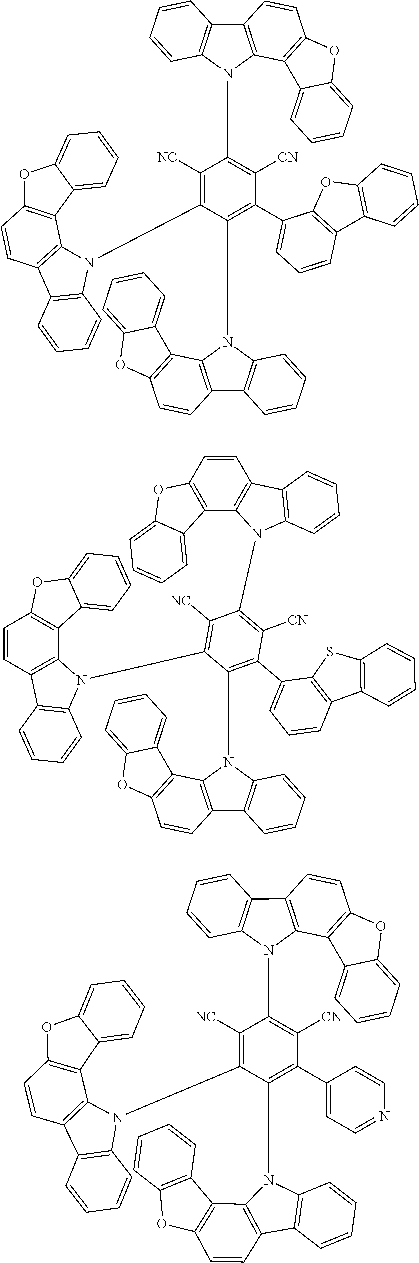

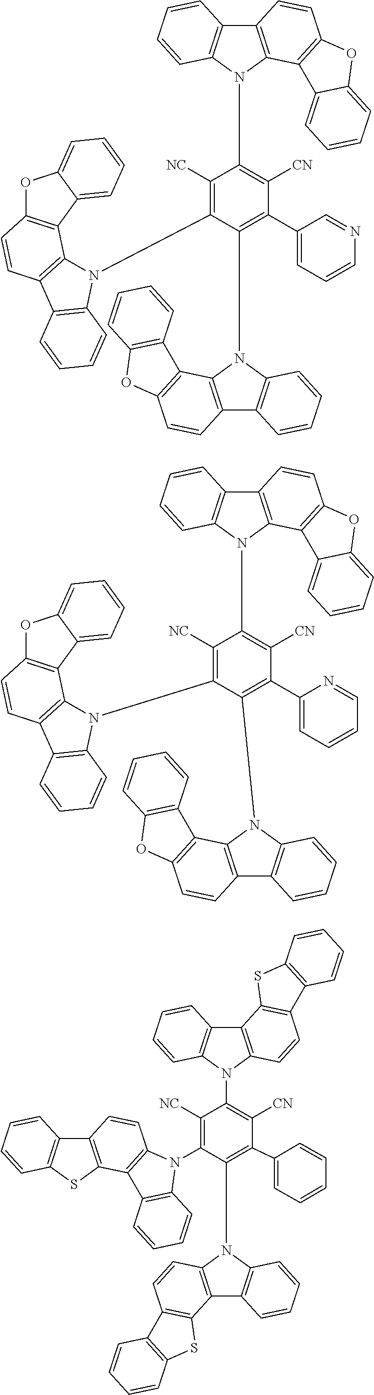

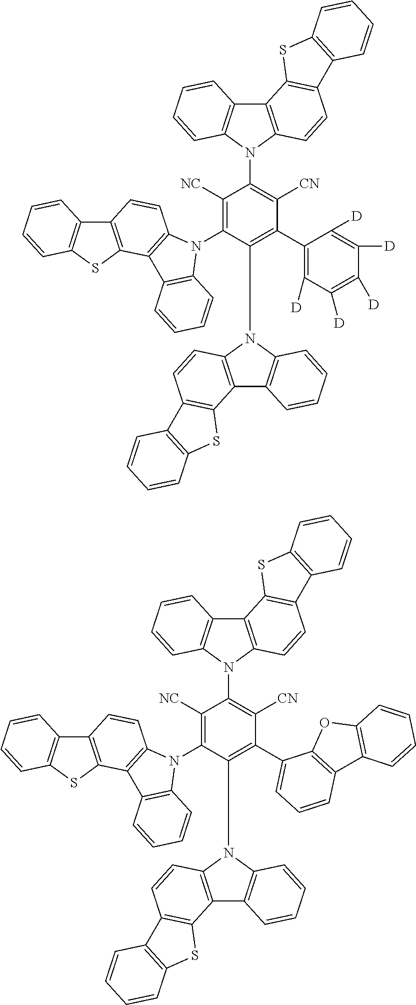

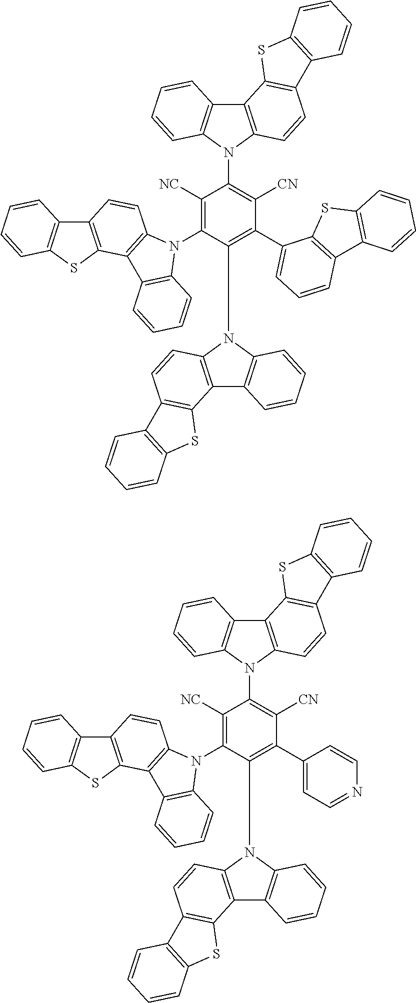 [SMILES: N#Cc1c(-c2cccc3c2sc2ccccc23)c(-n2c3ccccc3c3c4sc5ccccc5c4ccc32)c(-n2c3ccccc3c3c4sc5ccccc5c4ccc32)c(C#N)c1-n1c2ccccc2c2c3sc4ccccc4c3ccc21 ; N#Cc1c(-c2ccncc2)c(-n2c3ccccc3c3c4sc5ccccc5c4ccc32)c(-n2c3ccccc3c3c4sc5ccccc5c4ccc32)c(C#N)c1-n1c2ccccc2c2c3sc4ccccc4c3ccc21]

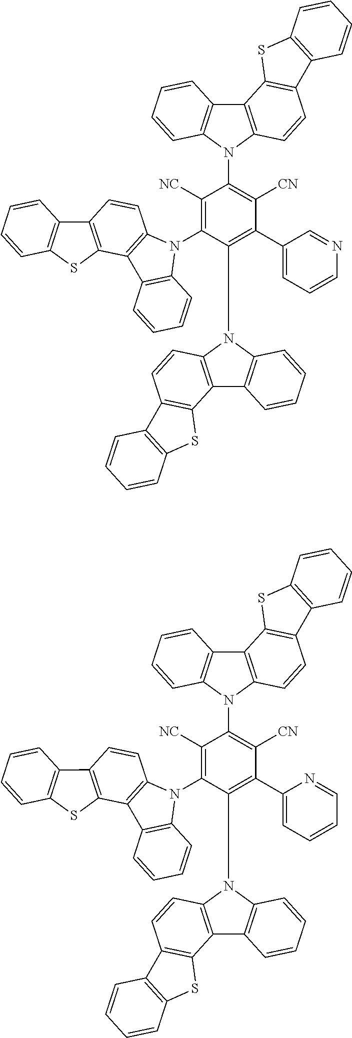 [SMILES: N#Cc1c(-c2cccnc2)c(-n2c3ccccc3c3c4sc5ccccc5c4ccc32)c(-n2c3ccccc3c3c4sc5ccccc5c4ccc32)c(C#N)c1-n1c2ccccc2c2c3sc4ccccc4c3ccc21 ; N#Cc1c(-c2ccccn2)c(-n2c3ccccc3c3c4sc5ccccc5c4ccc32)c(-n2c3ccccc3c3c4sc5ccccc5c4ccc32)c(C#N)c1-n1c2ccccc2c2c3sc4ccccc4c3ccc21]

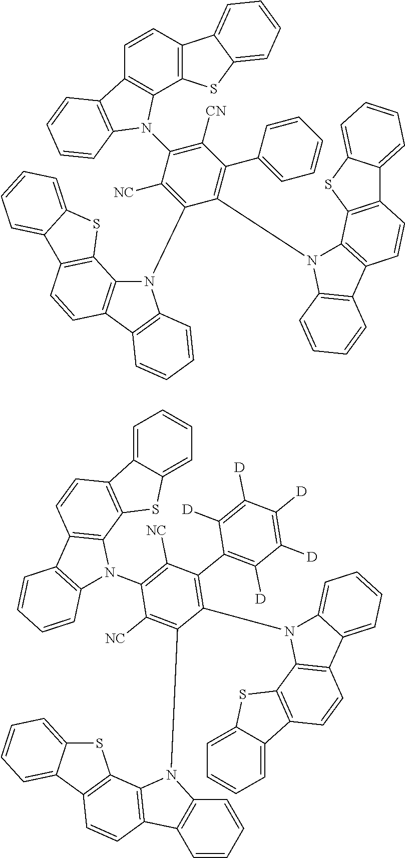

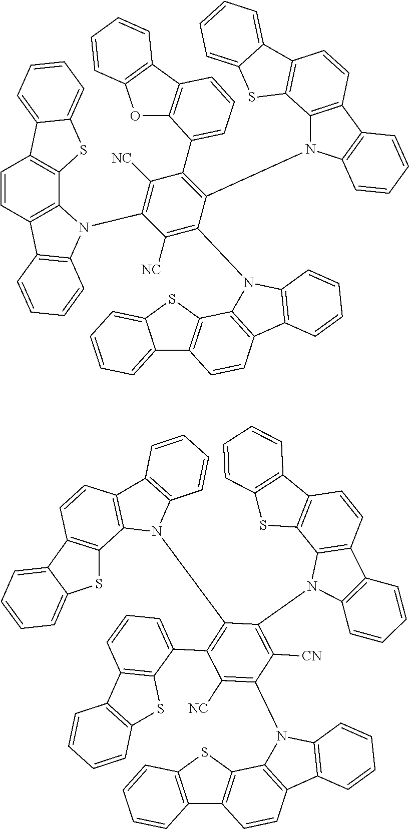 [SMILES: N#Cc1c(-c2cccc3c2oc2ccccc23)c(-n2c3ccccc3c3ccc4c5ccccc5sc4c32)c(-n2c3ccccc3c3ccc4c5ccccc5sc4c32)c(C#N)c1-n1c2ccccc2c2ccc3c4ccccc4sc3c21 ; N#Cc1c(-c2cccc3c2sc2ccccc23)c(-n2c3ccccc3c3ccc4c5ccccc5sc4c32)c(-n2c3ccccc3c3ccc4c5ccccc5sc4c32)c(C#N)c1-n1c2ccccc2c2ccc3c4ccccc4sc3c21]

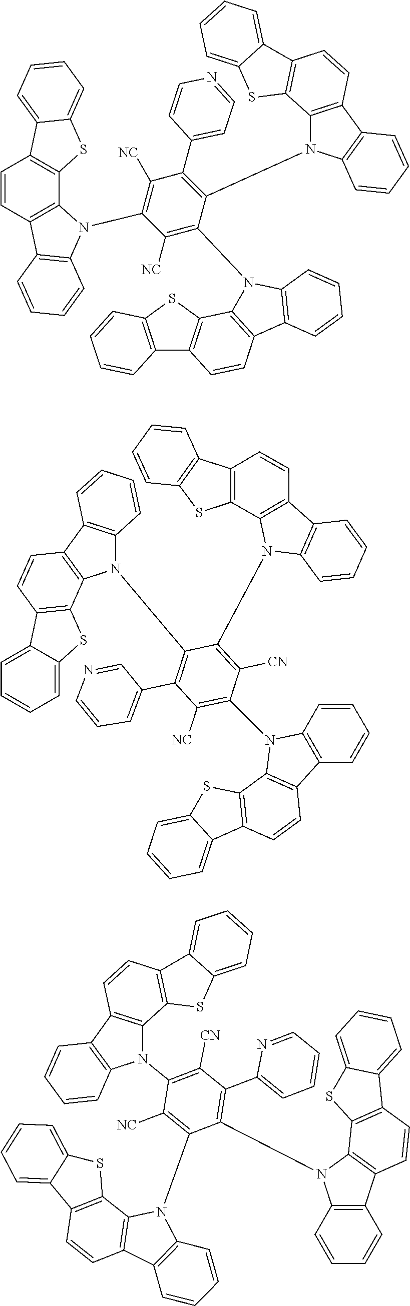

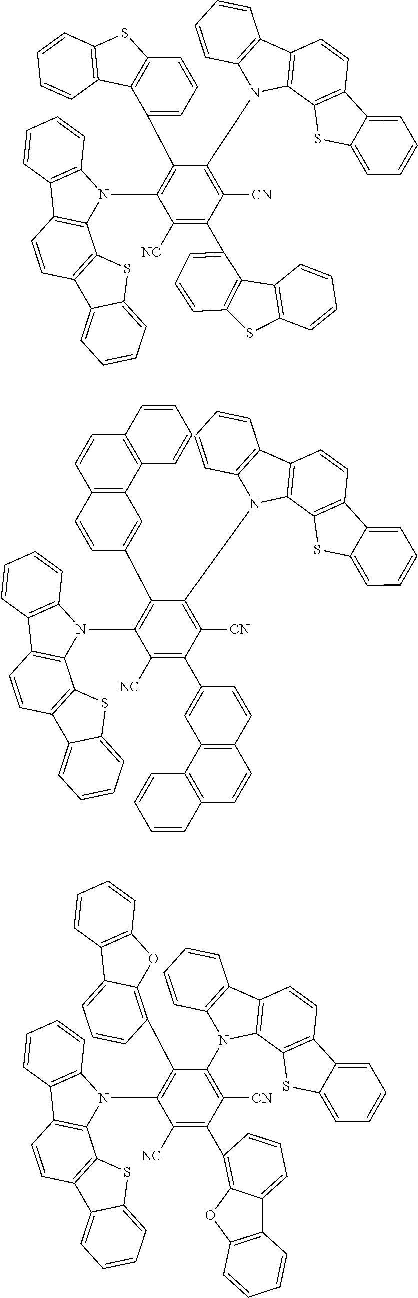 [SMILES: N#Cc1c(-c2cccc3sc4ccccc4c23)c(C#N)c(-n2c3ccccc3c3ccc4c5ccccc5sc4c32)c(-c2cccc3sc4ccccc4c23)c1-n1c2ccccc2c2ccc3c4ccccc4sc3c21 ; N#Cc1c(-c2ccc3ccc4ccccc4c3c2)c(C#N)c(-n2c3ccccc3c3ccc4c5ccccc5sc4c32)c(-c2ccc3ccc4ccccc4c3c2)c1-n1c2ccccc2c2ccc3c4ccccc4sc3c21 ; N#Cc1c(-c2cccc3c2oc2ccccc23)c(C#N)c(-n2c3ccccc3c3ccc4c5ccccc5sc4c32)c(-c2cccc3c2oc2ccccc23)c1-n1c2ccccc2c2ccc3c4ccccc4sc3c21]

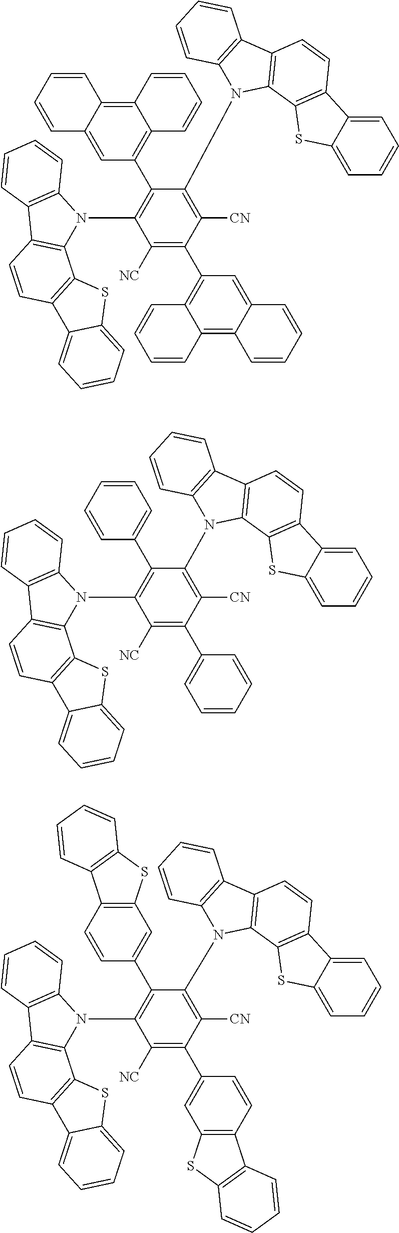

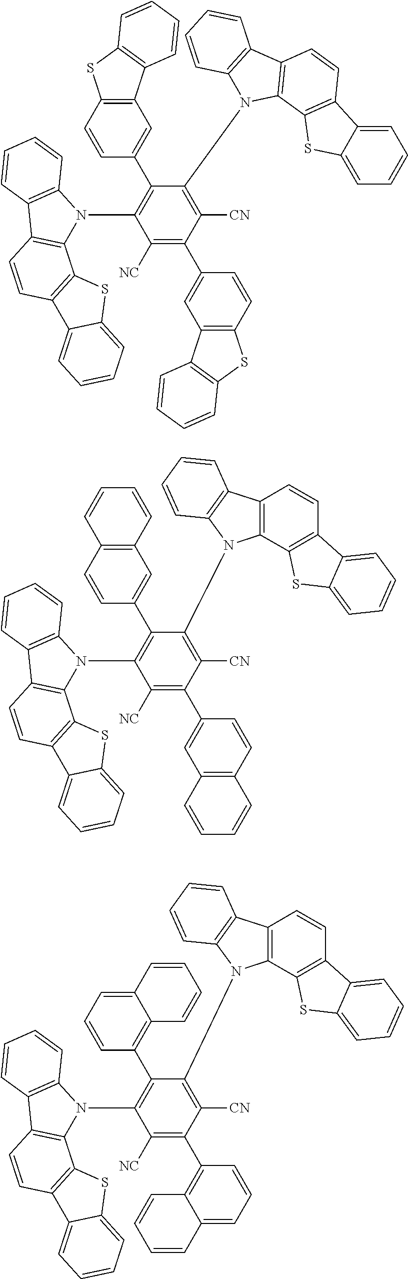

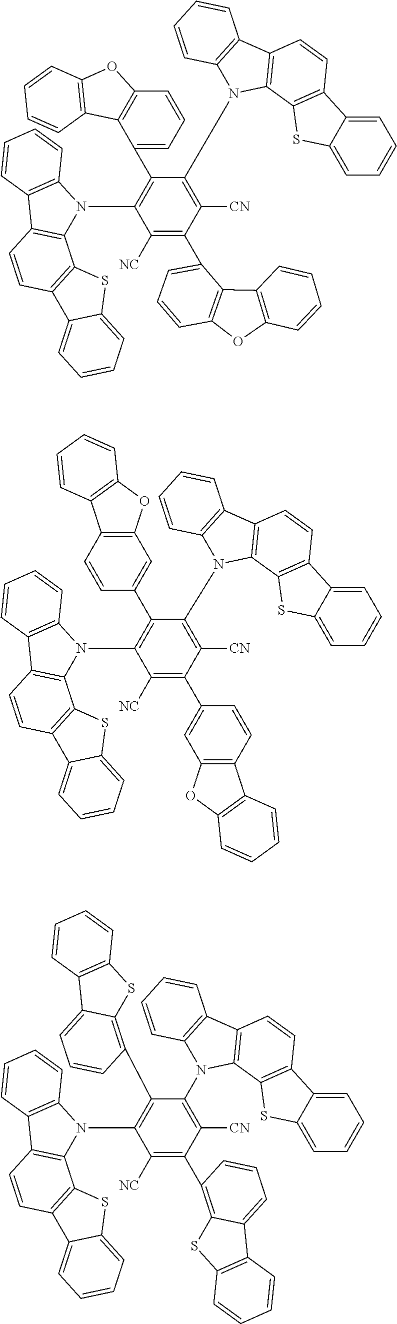 [SMILES: N#Cc1c(-c2cccc3oc4ccccc4c23)c(C#N)c(-n2c3ccccc3c3ccc4c5ccccc5sc4c32)c(-c2cccc3oc4ccccc4c23)c1-n1c2ccccc2c2ccc3c4ccccc4sc3c21 ; N#Cc1c(-c2ccc3c(c2)oc2ccccc23)c(C#N)c(-n2c3ccccc3c3ccc4c5ccccc5sc4c32)c(-c2ccc3c(c2)oc2ccccc23)c1-n1c2ccccc2c2ccc3c4ccccc4sc3c21 ; N#Cc1c(-c2cccc3c2sc2ccccc23)c(C#N)c(-n2c3ccccc3c3ccc4c5ccccc5sc4c32)c(-c2cccc3c2sc2ccccc23)c1-n1c2ccccc2c2ccc3c4ccccc4sc3c21]

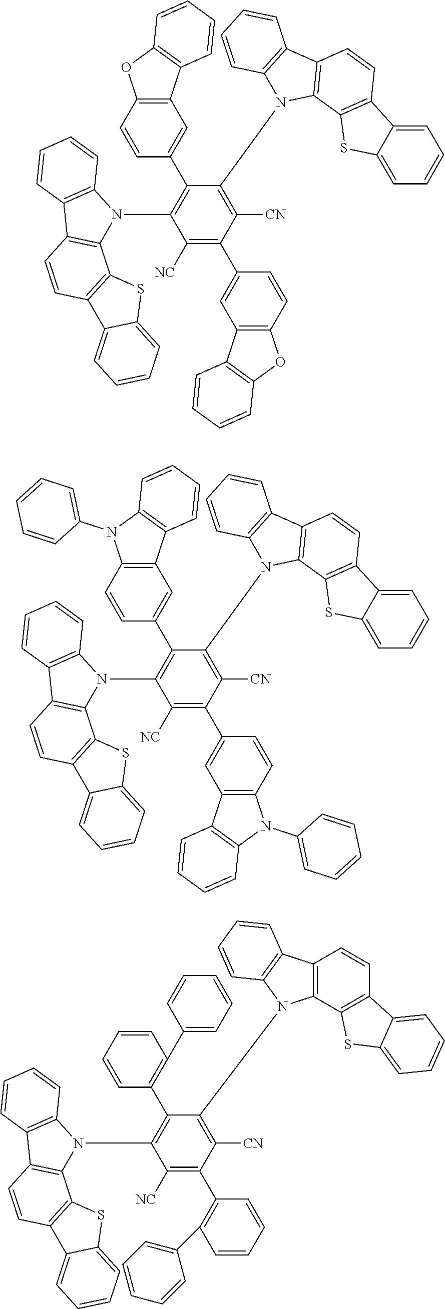

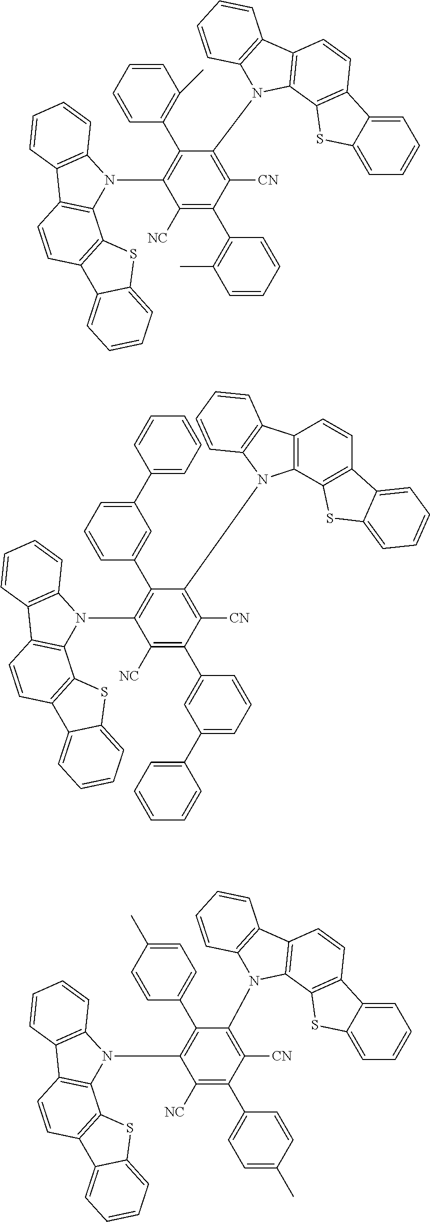 [SMILES: Cc1ccccc1-c1c(C#N)c(-n2c3ccccc3c3ccc4c5ccccc5sc4c32)c(-c2ccccc2C)c(-n2c3ccccc3c3ccc4c5ccccc5sc4c32)c1C#N ; N#Cc1c(-c2cccc(-c3ccccc3)c2)c(C#N)c(-n2c3ccccc3c3ccc4c5ccccc5sc4c32)c(-c2cccc(-c3ccccc3)c2)c1-n1c2ccccc2c2ccc3c4ccccc4sc3c21 ; Cc1ccc(-c2c(C#N)c(-n3c4ccccc4c4ccc5c6ccccc6sc5c43)c(-c3ccc(C)cc3)c(-n3c4ccccc4c4ccc5c6ccccc6sc5c43)c2C#N)cc1]

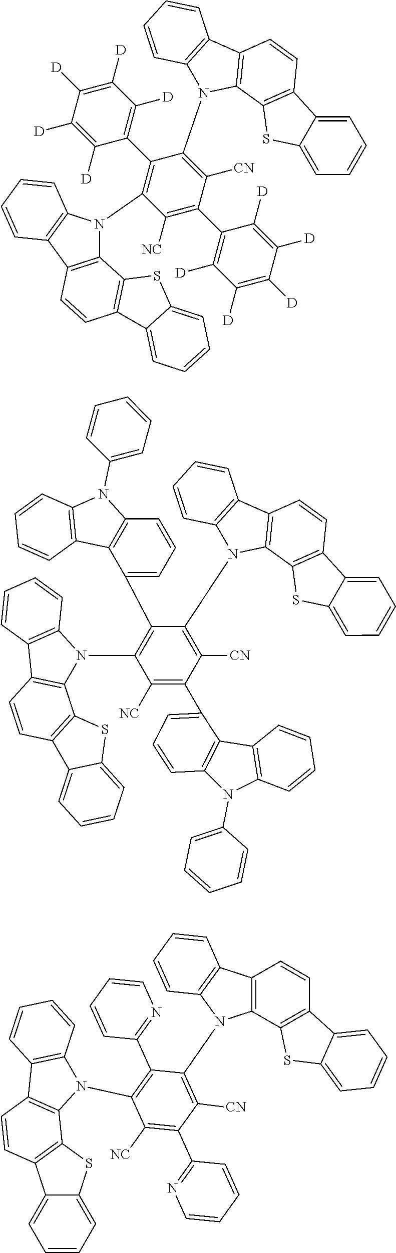

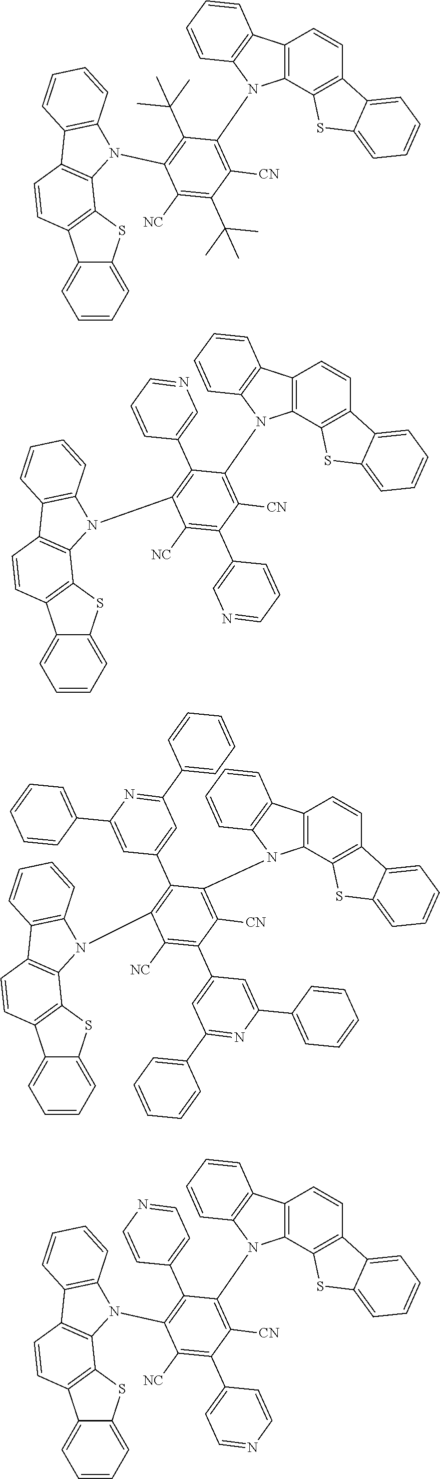 [SMILES: CC(C)(C)c1c(C#N)c(-n2c3ccccc3c3ccc4c5ccccc5sc4c32)c(C(C)(C)C)c(-n2c3ccccc3c3ccc4c5ccccc5sc4c32)c1C#N ; N#Cc1c(-c2cccnc2)c(C#N)c(-n2c3ccccc3c3ccc4c5ccccc5sc4c32)c(-c2cccnc2)c1-n1c2ccccc2c2ccc3c4ccccc4sc3c21 ; N#Cc1c(-c2cc(-c3ccccc3)nc(-c3ccccc3)c2)c(C#N)c(-n2c3ccccc3c3ccc4c5ccccc5sc4c32)c(-c2cc(-c3ccccc3)nc(-c3ccccc3)c2)c1-n1c2ccccc2c2ccc3c4ccccc4sc3c21 ; N#Cc1c(-c2ccncc2)c(C#N)c(-n2c3ccccc3c3ccc4c5ccccc5sc4c32)c(-c2ccncc2)c1-n1c2ccccc2c2ccc3c4ccccc4sc3c21]

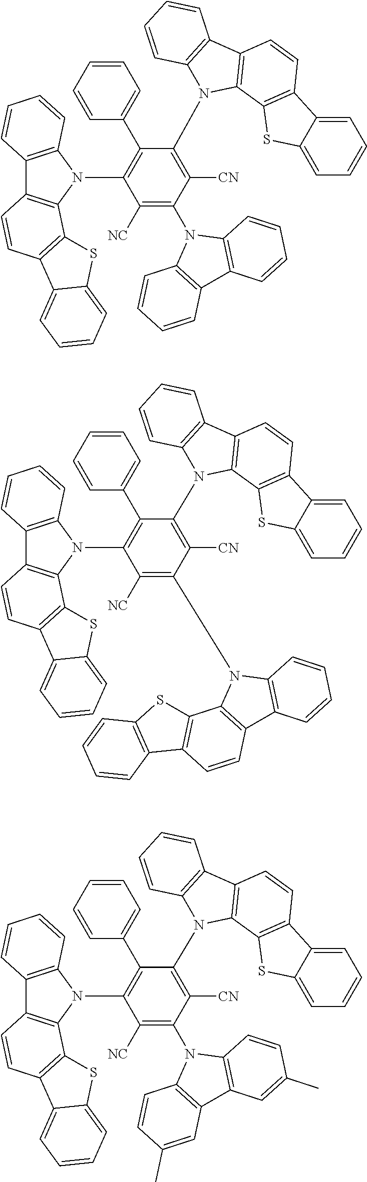 [SMILES: N#Cc1c(-n2c3ccccc3c3ccccc32)c(C#N)c(-n2c3ccccc3c3ccc4c5ccccc5sc4c32)c(-c2ccccc2)c1-n1c2ccccc2c2ccc3c4ccccc4sc3c21 ; N#Cc1c(-n2c3ccccc3c3ccc4c5ccccc5sc4c32)c(C#N)c(-n2c3ccccc3c3ccc4c5ccccc5sc4c32)c(-c2ccccc2)c1-n1c2ccccc2c2ccc3c4ccccc4sc3c21 ; Cc1ccc2c(c1)c1cc(C)ccc1n2-c1c(C#N)c(-n2c3ccccc3c3ccc4c5ccccc5sc4c32)c(-c2ccccc2)c(-n2c3ccccc3c3ccc4c5ccccc5sc4c32)c1C#N]

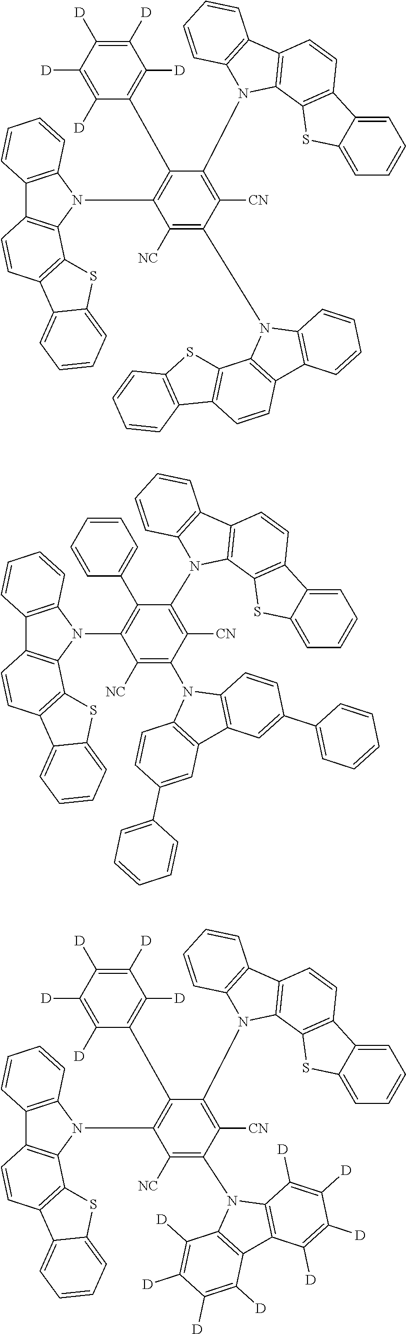

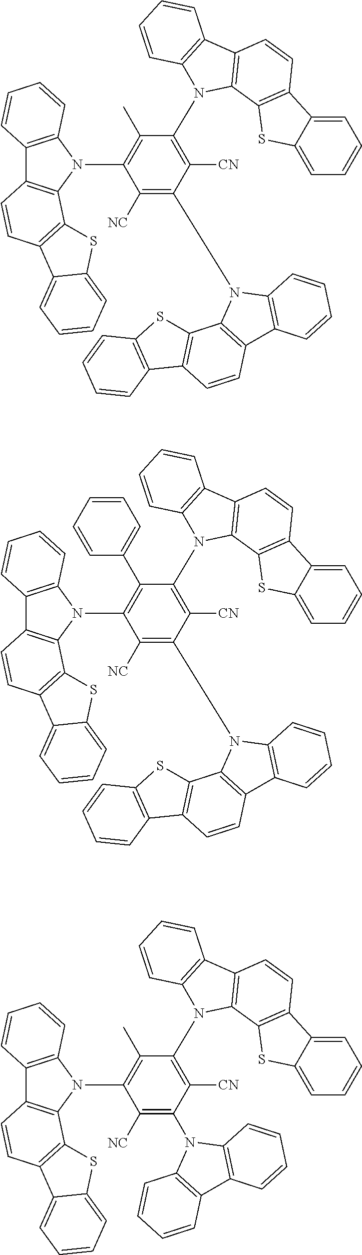 [SMILES: Cc1c(-n2c3ccccc3c3ccc4c5ccccc5sc4c32)c(C#N)c(-n2c3ccccc3c3ccc4c5ccccc5sc4c32)c(C#N)c1-n1c2ccccc2c2ccc3c4ccccc4sc3c21 ; N#Cc1c(-n2c3ccccc3c3ccc4c5ccccc5sc4c32)c(C#N)c(-n2c3ccccc3c3ccc4c5ccccc5sc4c32)c(-c2ccccc2)c1-n1c2ccccc2c2ccc3c4ccccc4sc3c21 ; Cc1c(-n2c3ccccc3c3ccc4c5ccccc5sc4c32)c(C#N)c(-n2c3ccccc3c3ccccc32)c(C#N)c1-n1c2ccccc2c2ccc3c4ccccc4sc3c21]

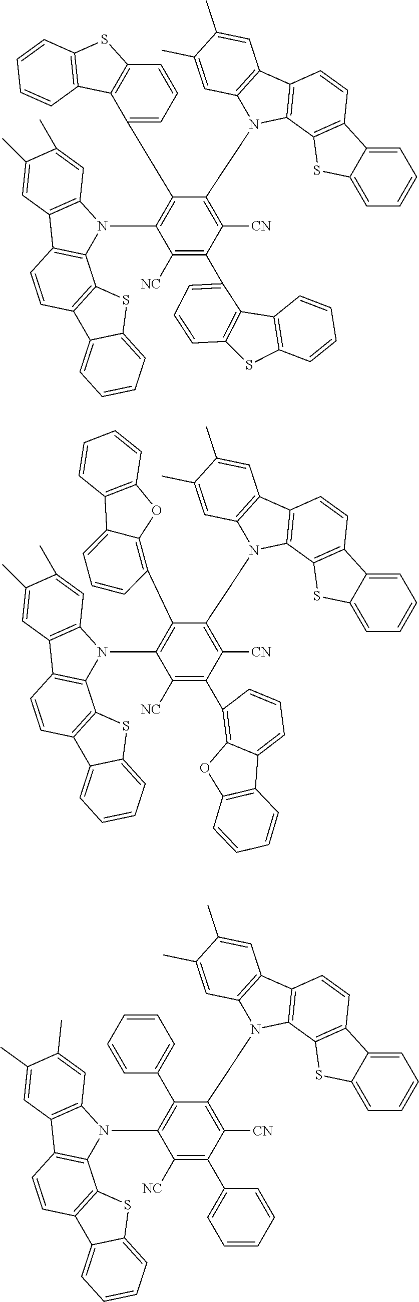

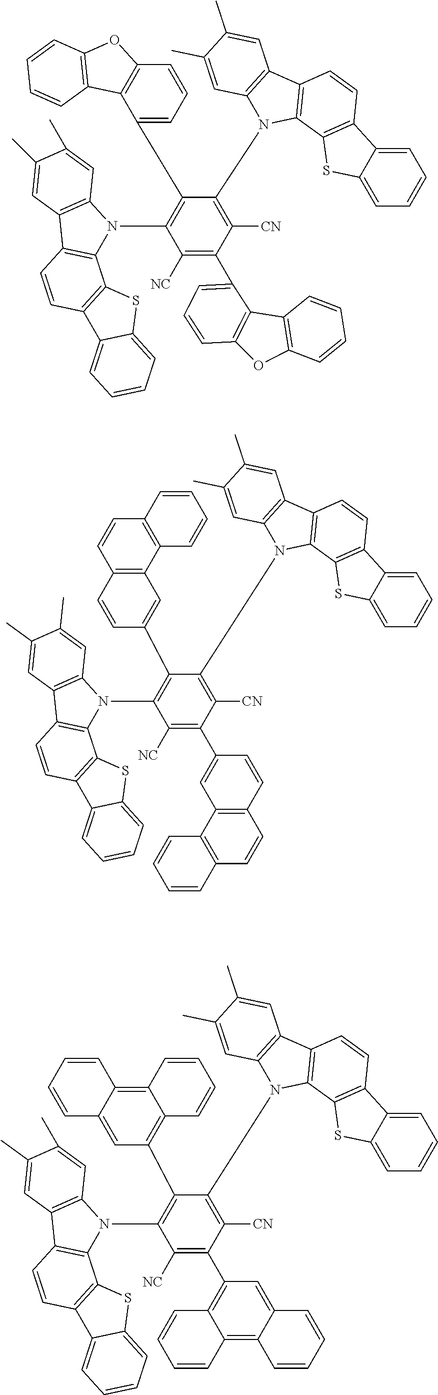 [SMILES: Cc1cc2c3ccc4c5ccccc5sc4c3n(-c3c(C#N)c(-c4cccc5oc6ccccc6c45)c(C#N)c(-n4c5cc(C)c(C)cc5c5ccc6c7ccccc7sc6c54)c3-c3cccc4oc5ccccc5c34)c2cc1C ; Cc1cc2c3ccc4c5ccccc5sc4c3n(-c3c(C#N)c(-c4ccc5ccc6ccccc6c5c4)c(C#N)c(-n4c5cc(C)c(C)cc5c5ccc6c7ccccc7sc6c54)c3-c3ccc4ccc5ccccc5c4c3)c2cc1C ; Cc1cc2c3ccc4c5ccccc5sc4c3n(-c3c(C#N)c(-c4cc5ccccc5c5ccccc45)c(C#N)c(-n4c5cc(C)c(C)cc5c5ccc6c7ccccc7sc6c54)c3-c3cc4ccccc4c4ccccc34)c2cc1C]

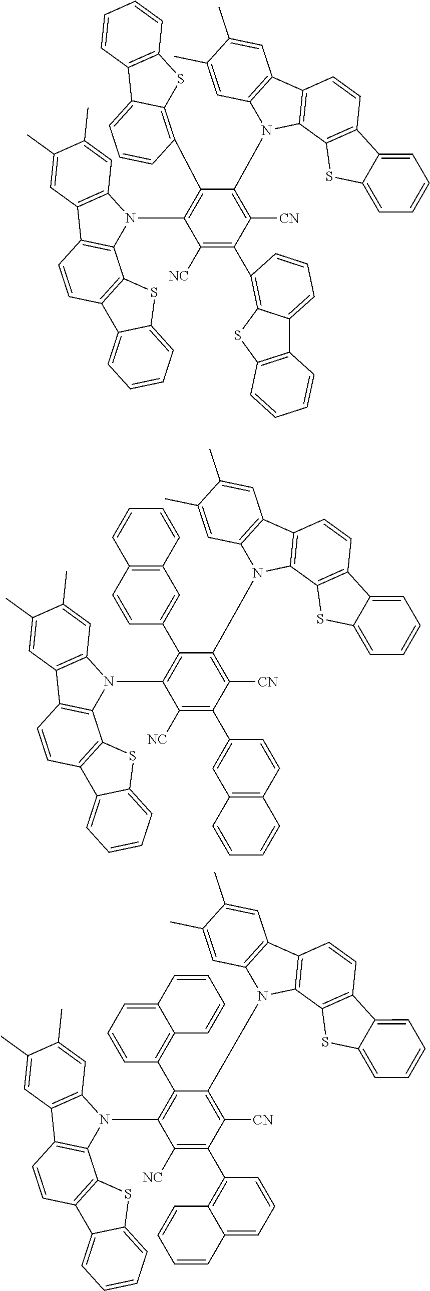

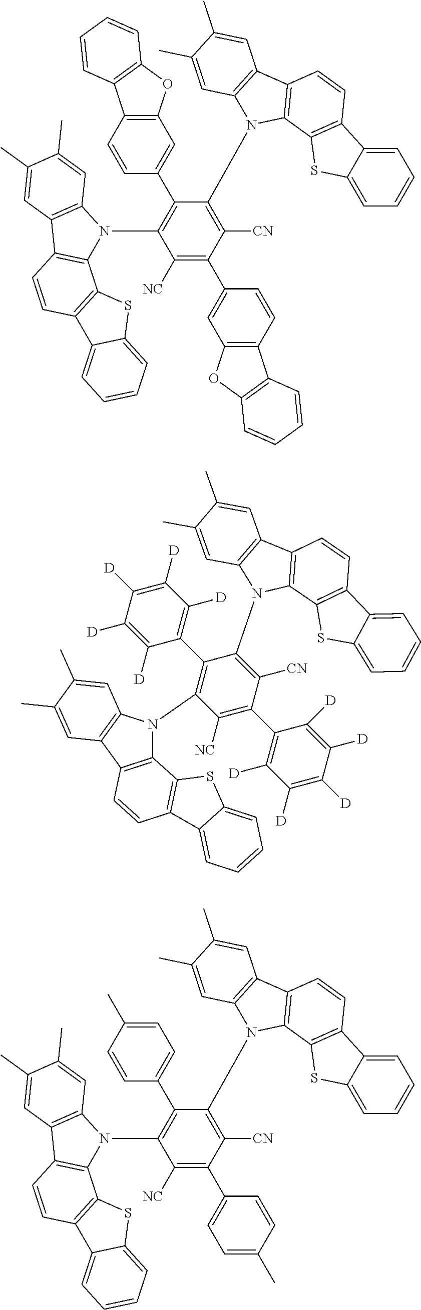

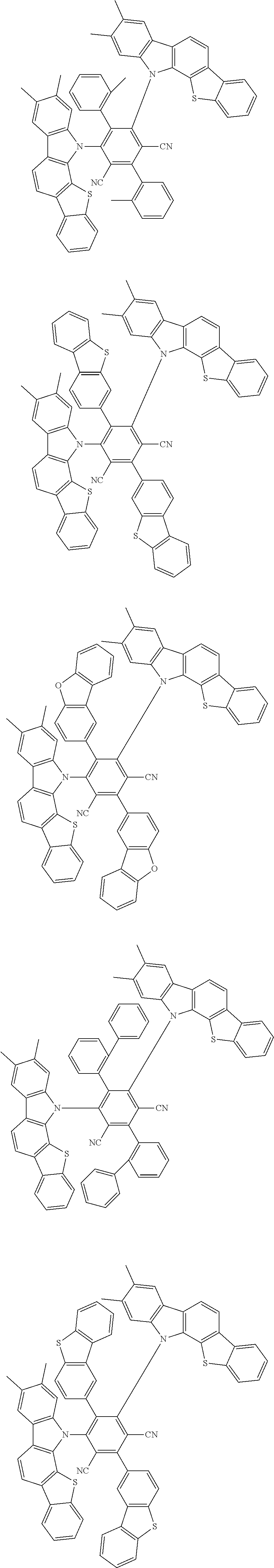

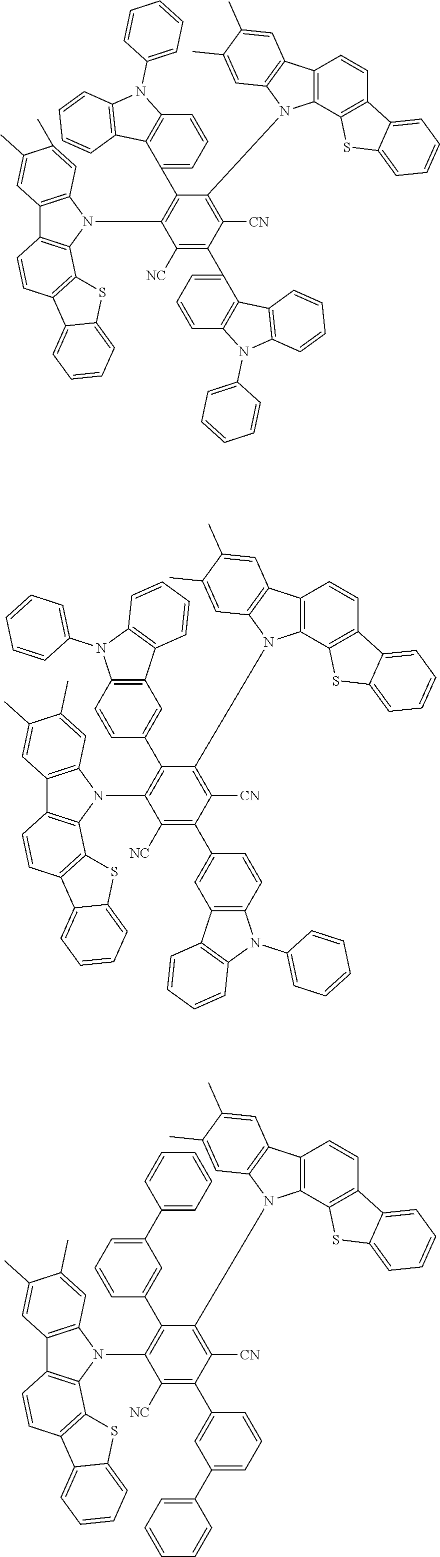 [SMILES: Cc1cc2c3ccc4c5ccccc5sc4c3n(-c3c(C#N)c(-c4cccc5c4c4ccccc4n5-c4ccccc4)c(C#N)c(-n4c5cc(C)c(C)cc5c5ccc6c7ccccc7sc6c54)c3-c3cccc4c3c3ccccc3n4-c3ccccc3)c2cc1C ; Cc1cc2c3ccc4c5ccccc5sc4c3n(-c3c(C#N)c(-c4ccc5c(c4)c4ccccc4n5-c4ccccc4)c(C#N)c(-n4c5cc(C)c(C)cc5c5ccc6c7ccccc7sc6c54)c3-c3ccc4c(c3)c3ccccc3n4-c3ccccc3)c2cc1C ; Cc1cc2c3ccc4c5ccccc5sc4c3n(-c3c(C#N)c(-c4cccc(-c5ccccc5)c4)c(C#N)c(-n4c5cc(C)c(C)cc5c5ccc6c7ccccc7sc6c54)c3-c3cccc(-c4ccccc4)c3)c2cc1C]

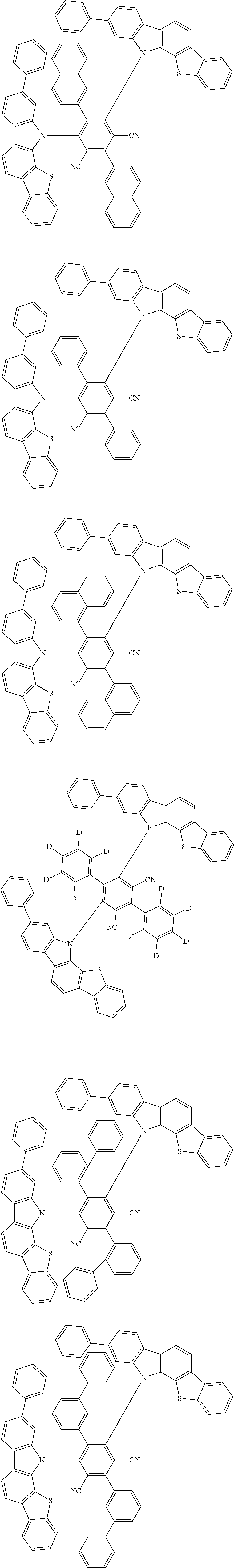

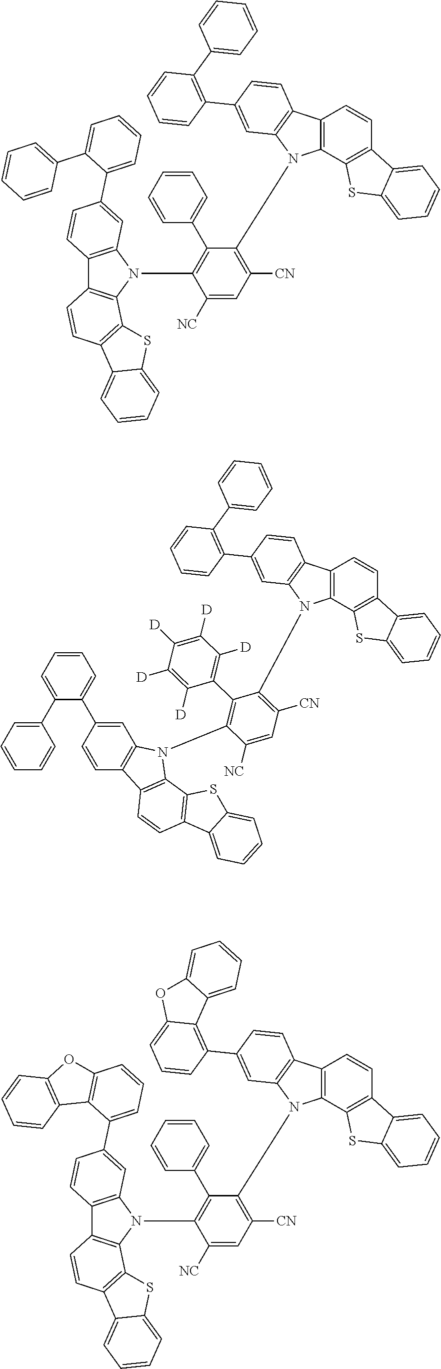 [SMILES: N#Cc1cc(C#N)c(-n2c3cc(-c4ccccc4-c4ccccc4)ccc3c3ccc4c5ccccc5sc4c32)c(-c2ccccc2)c1-n1c2cc(-c3ccccc3-c3ccccc3)ccc2c2ccc3c4ccccc4sc3c21 ; [2H]c1c([2H])c([2H])c(-c2c(-n3c4cc(-c5ccccc5-c5ccccc5)ccc4c4ccc5c6ccccc6sc5c43)c(C#N)cc(C#N)c2-n2c3cc(-c4ccccc4-c4ccccc4)ccc3c3ccc4c5ccccc5sc4c32)c([2H])c1[2H] ; N#Cc1cc(C#N)c(-n2c3cc(-c4cccc5oc6ccccc6c45)ccc3c3ccc4c5ccccc5sc4c32)c(-c2ccccc2)c1-n1c2cc(-c3cccc4oc5ccccc5c34)ccc2c2ccc3c4ccccc4sc3c21]

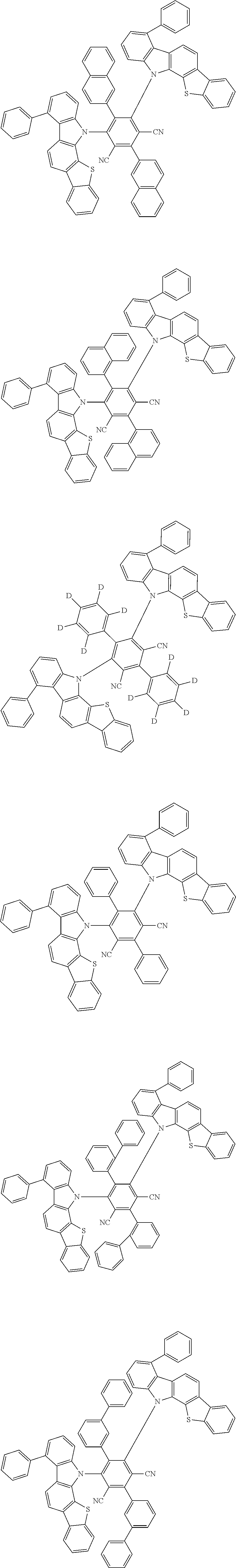

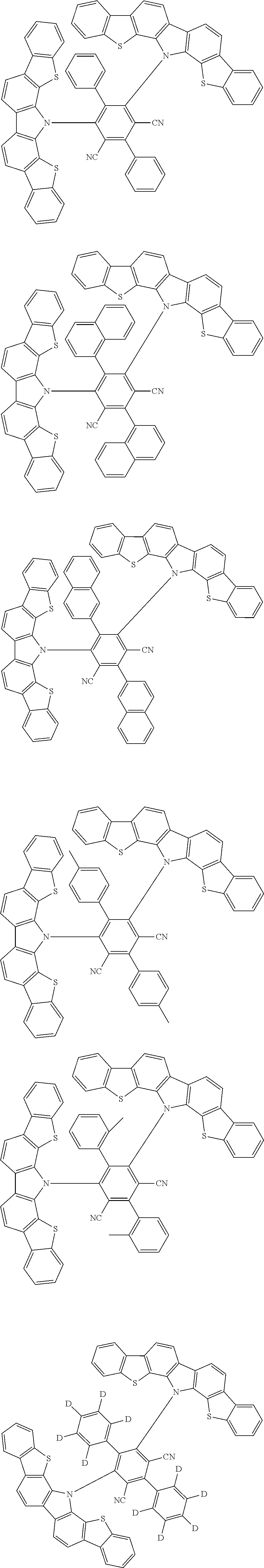

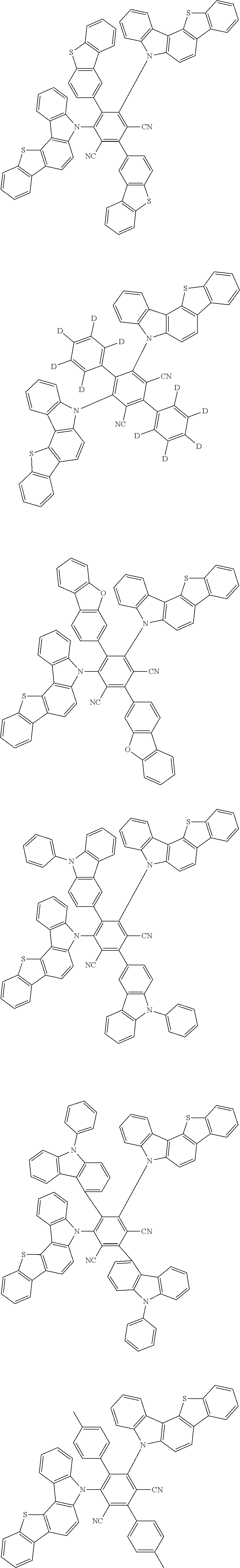

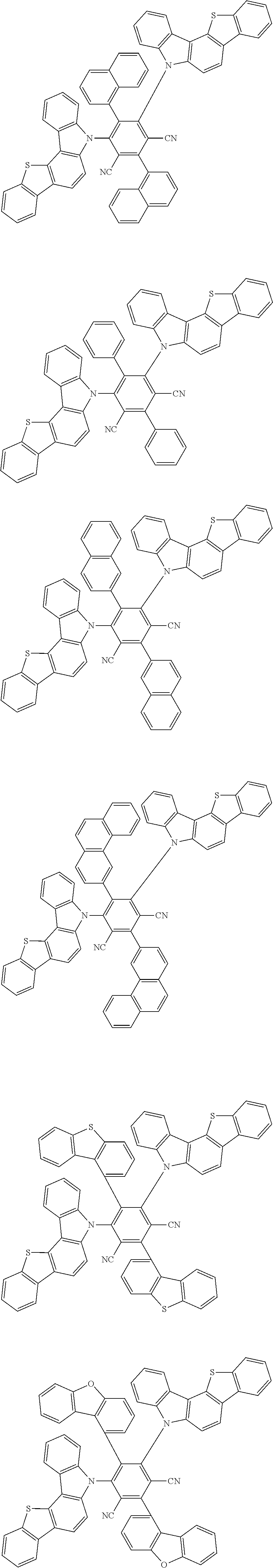

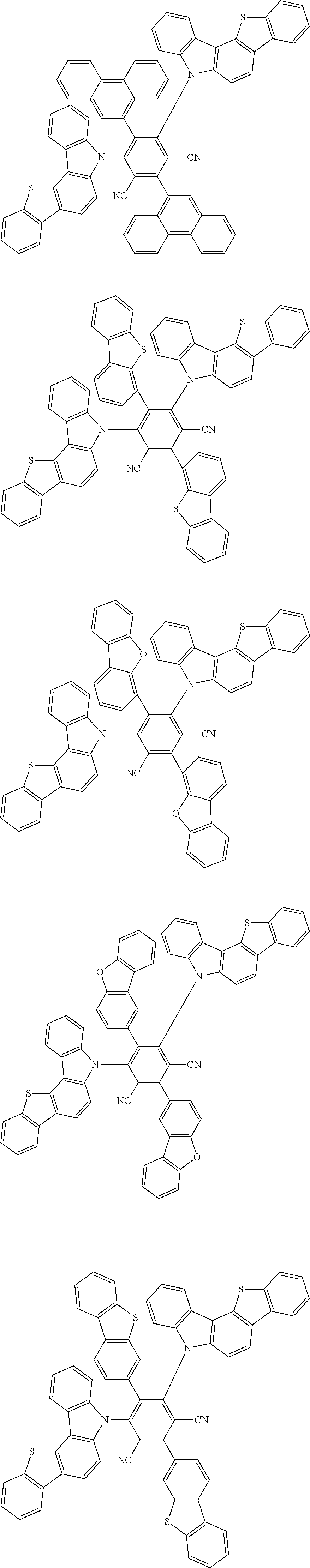

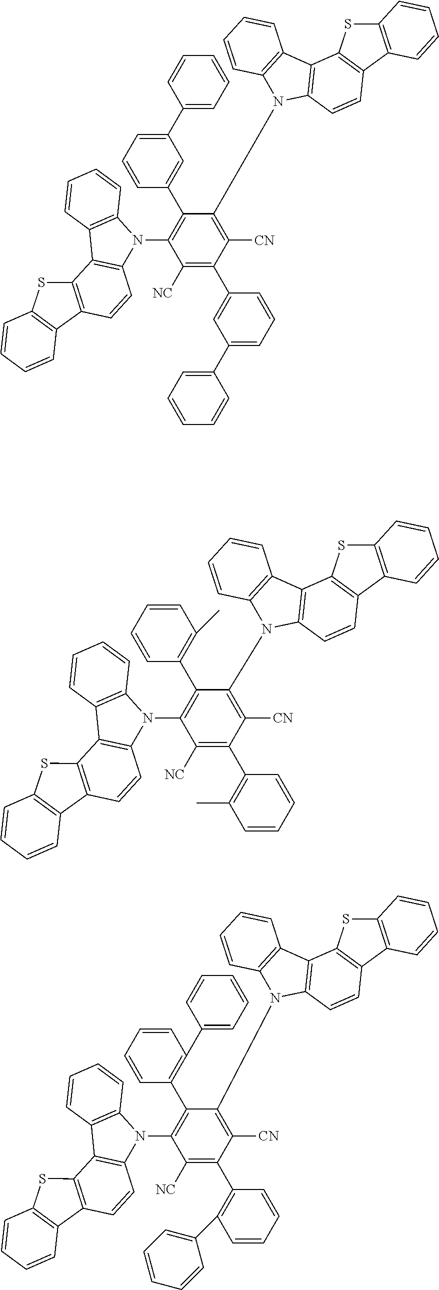 [SMILES: N#Cc1c(-c2cccc(-c3ccccc3)c2)c(C#N)c(-n2c3ccccc3c3c4sc5ccccc5c4ccc32)c(-c2cccc(-c3ccccc3)c2)c1-n1c2ccccc2c2c3sc4ccccc4c3ccc21 ; Cc1ccccc1-c1c(C#N)c(-n2c3ccccc3c3c4sc5ccccc5c4ccc32)c(-c2ccccc2C)c(-n2c3ccccc3c3c4sc5ccccc5c4ccc32)c1C#N ; N#Cc1c(-c2ccccc2-c2ccccc2)c(C#N)c(-n2c3ccccc3c3c4sc5ccccc5c4ccc32)c(-c2ccccc2-c2ccccc2)c1-n1c2ccccc2c2c3sc4ccccc4c3ccc21]

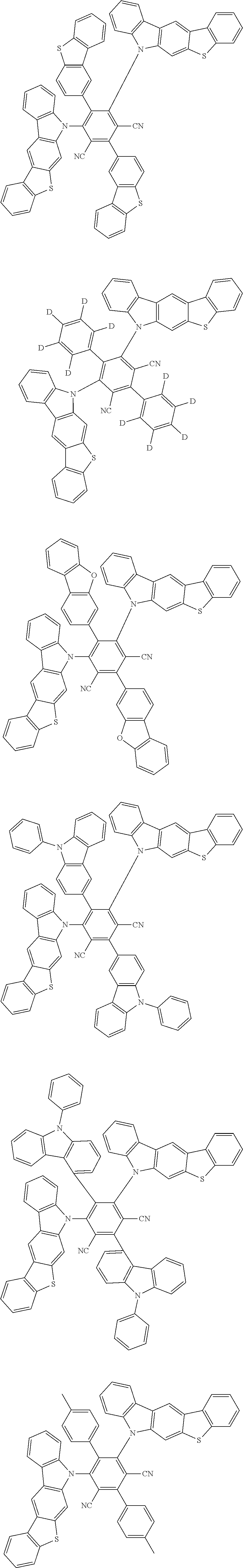

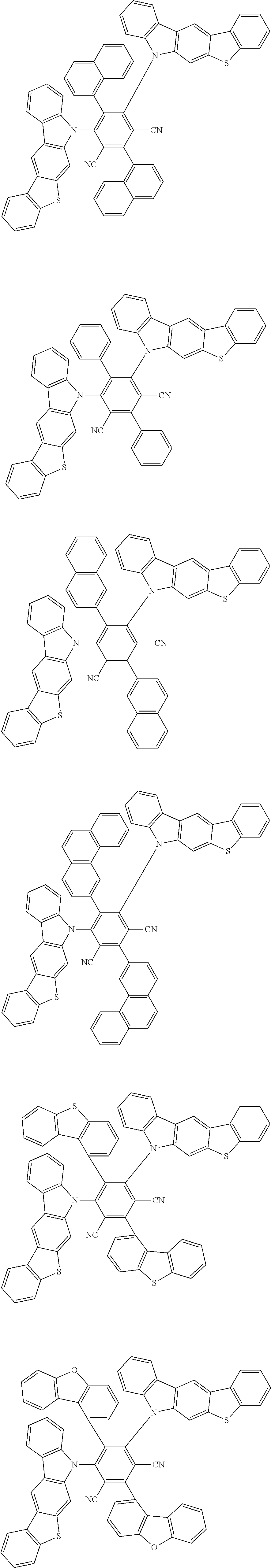

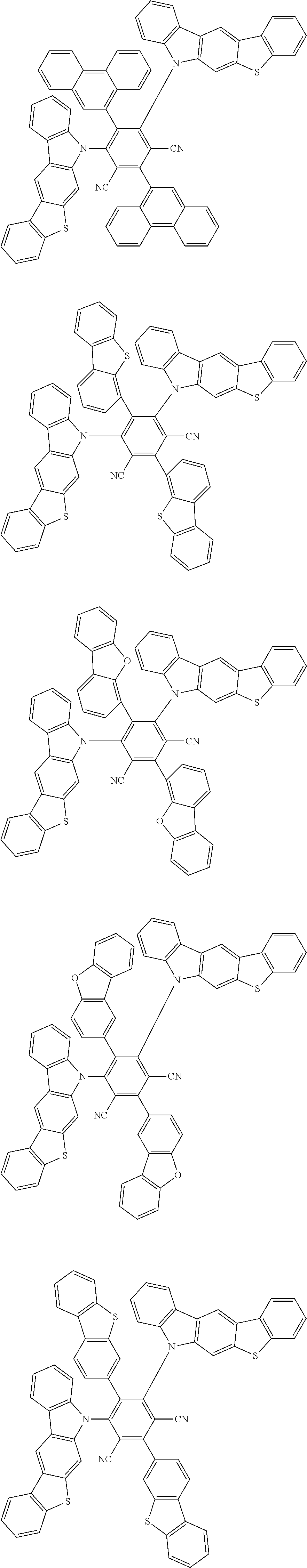

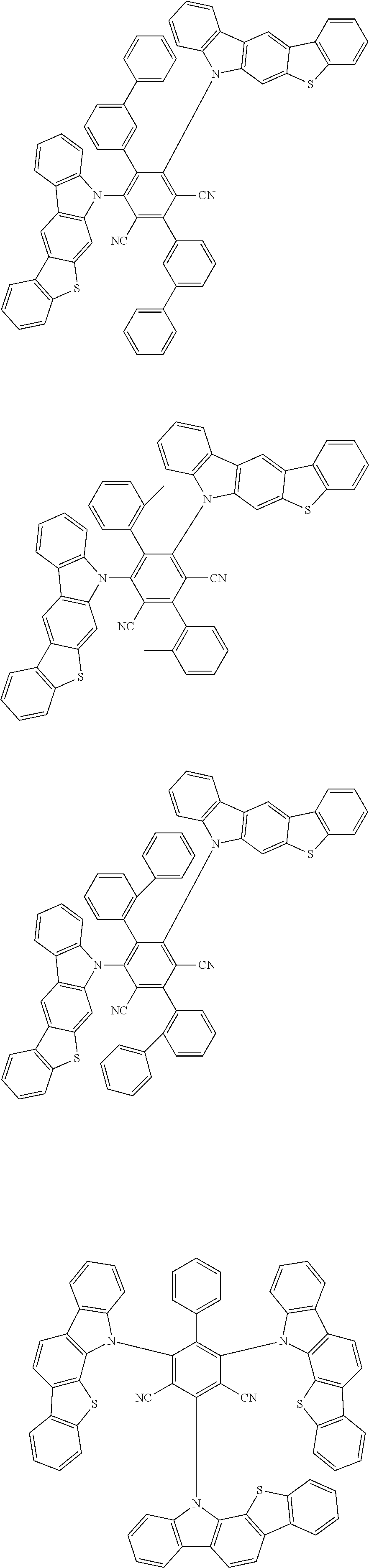 [SMILES: N#Cc1c(-c2cccc(-c3ccccc3)c2)c(C#N)c(-n2c3ccccc3c3cc4c(cc32)sc2ccccc24)c(-c2cccc(-c3ccccc3)c2)c1-n1c2ccccc2c2cc3c(cc21)sc1ccccc13 ; Cc1ccccc1-c1c(C#N)c(-n2c3ccccc3c3cc4c(cc32)sc2ccccc24)c(-c2ccccc2C)c(-n2c3ccccc3c3cc4c(cc32)sc2ccccc24)c1C#N ; N#Cc1c(-c2ccccc2-c2ccccc2)c(C#N)c(-n2c3ccccc3c3cc4c(cc32)sc2ccccc24)c(-c2ccccc2-c2ccccc2)c1-n1c2ccccc2c2cc3c(cc21)sc1ccccc13 ; N#Cc1c(-n2c3ccccc3c3ccc4c5ccccc5sc4c32)c(C#N)c(-n2c3ccccc3c3ccc4c5ccccc5sc4c32)c(-c2ccccc2)c1-n1c2ccccc2c2ccc3c4ccccc4sc3c21]

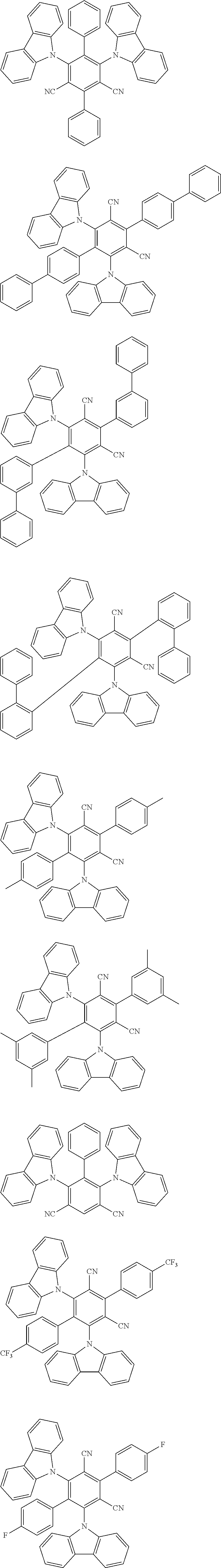

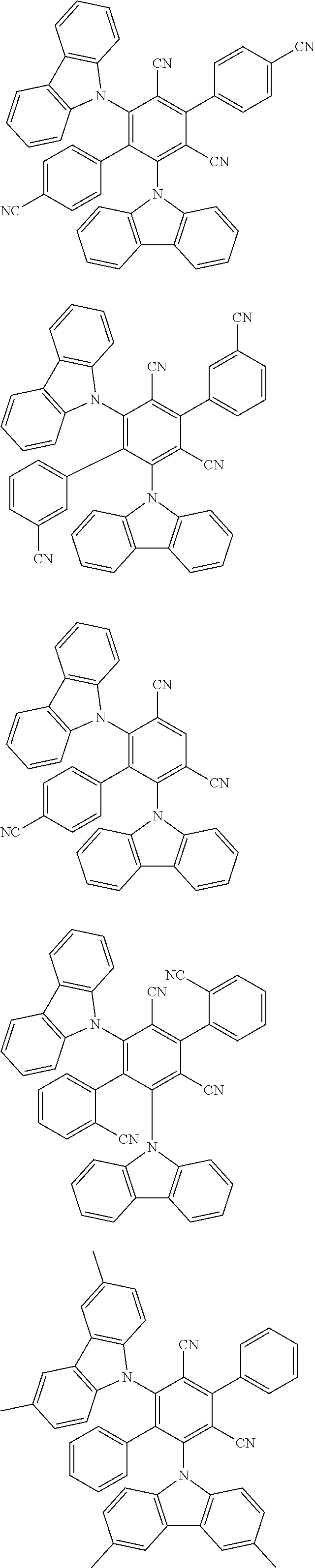

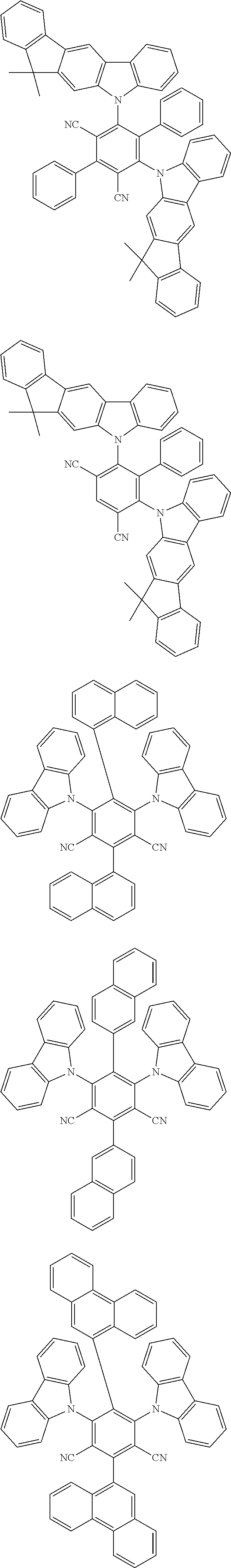

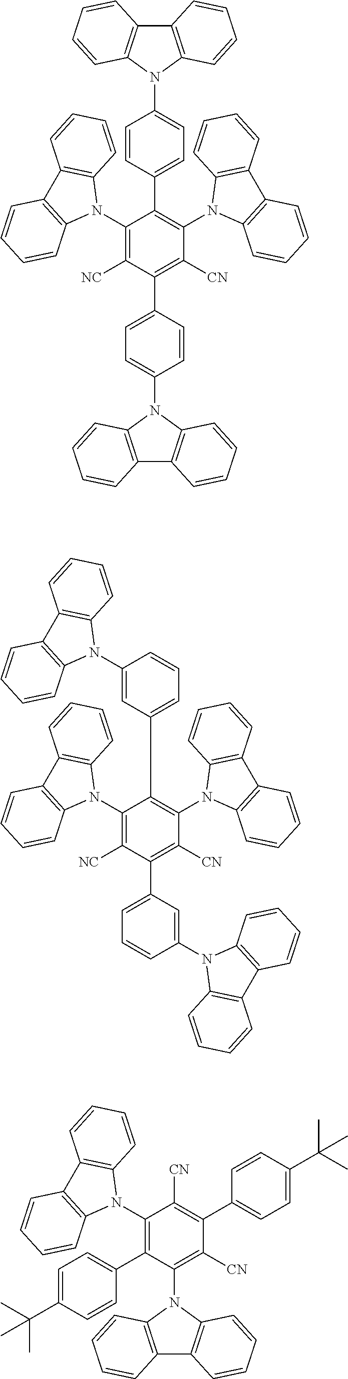 [SMILES: N#Cc1c(-c2ccc(-n3c4ccccc4c4ccccc43)cc2)c(C#N)c(-n2c3ccccc3c3ccccc32)c(-c2ccc(-n3c4ccccc4c4ccccc43)cc2)c1-n1c2ccccc2c2ccccc21 ; N#Cc1c(-c2cccc(-n3c4ccccc4c4ccccc43)c2)c(C#N)c(-n2c3ccccc3c3ccccc32)c(-c2cccc(-n3c4ccccc4c4ccccc43)c2)c1-n1c2ccccc2c2ccccc21 ; CC(C)(C)c1ccc(-c2c(C#N)c(-n3c4ccccc4c4ccccc43)c(-c3ccc(C(C)(C)C)cc3)c(-n3c4ccccc4c4ccccc43)c2C#N)cc1]

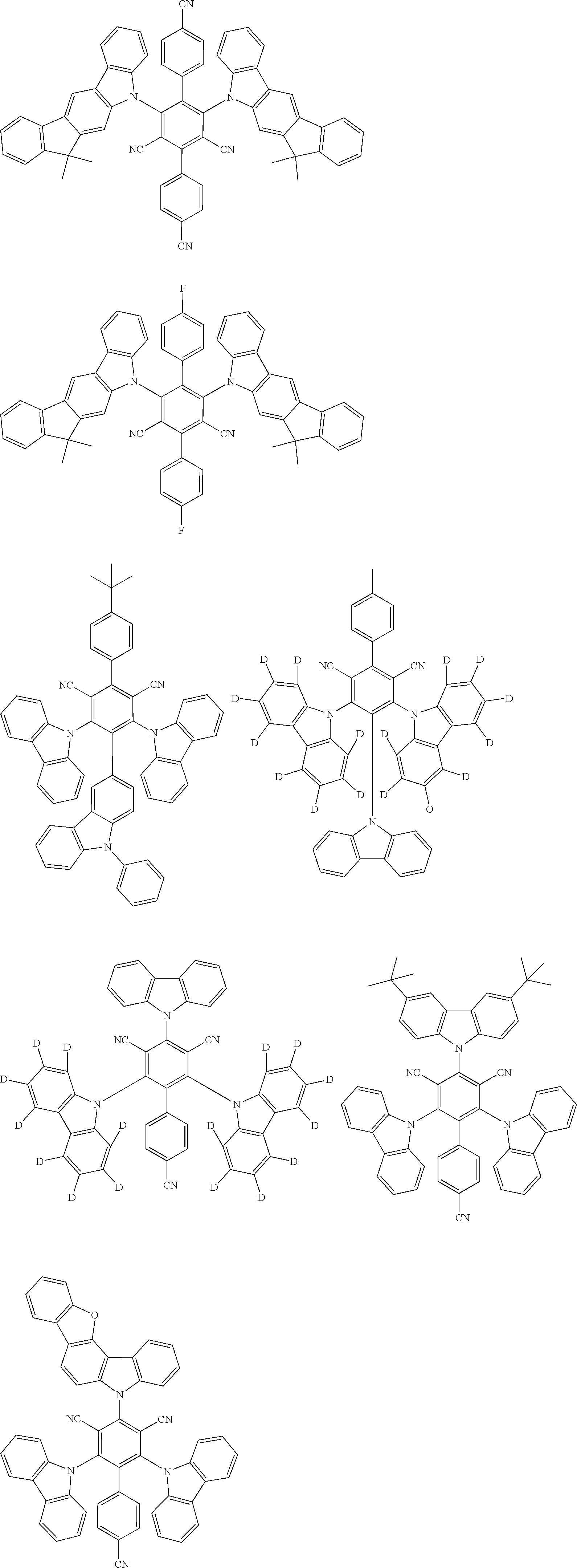

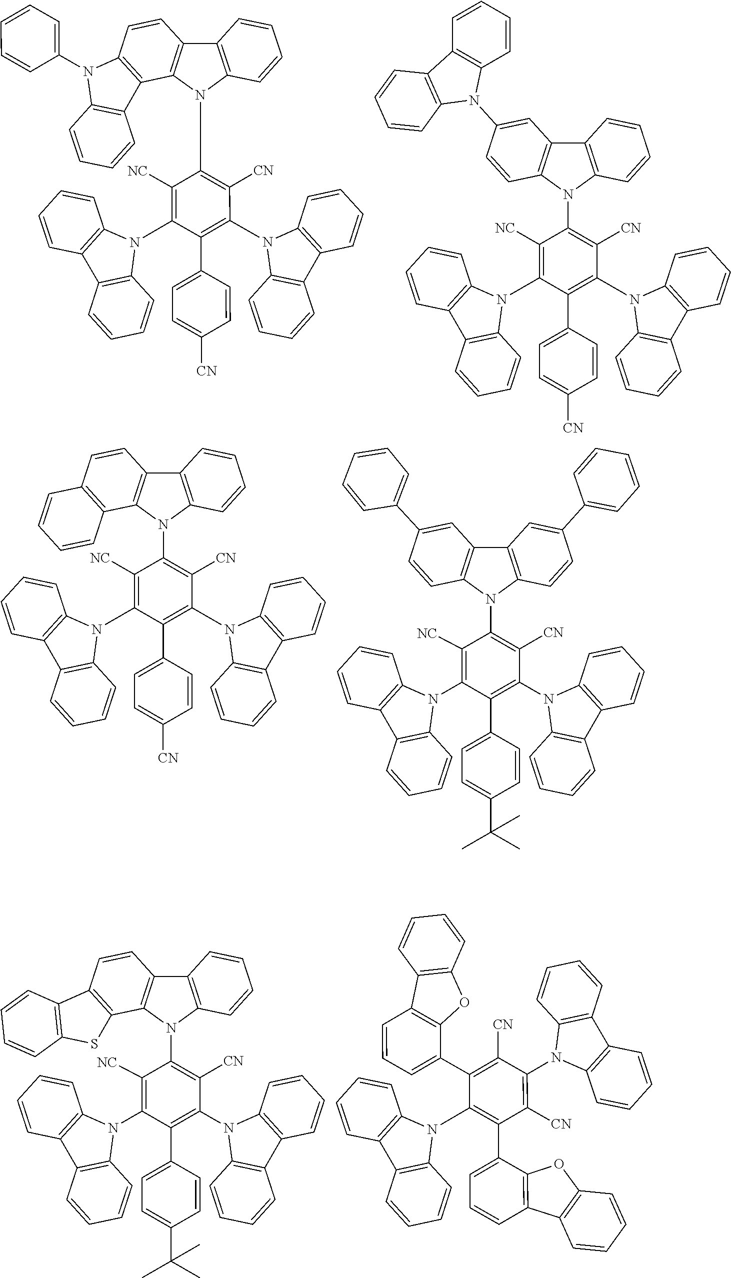

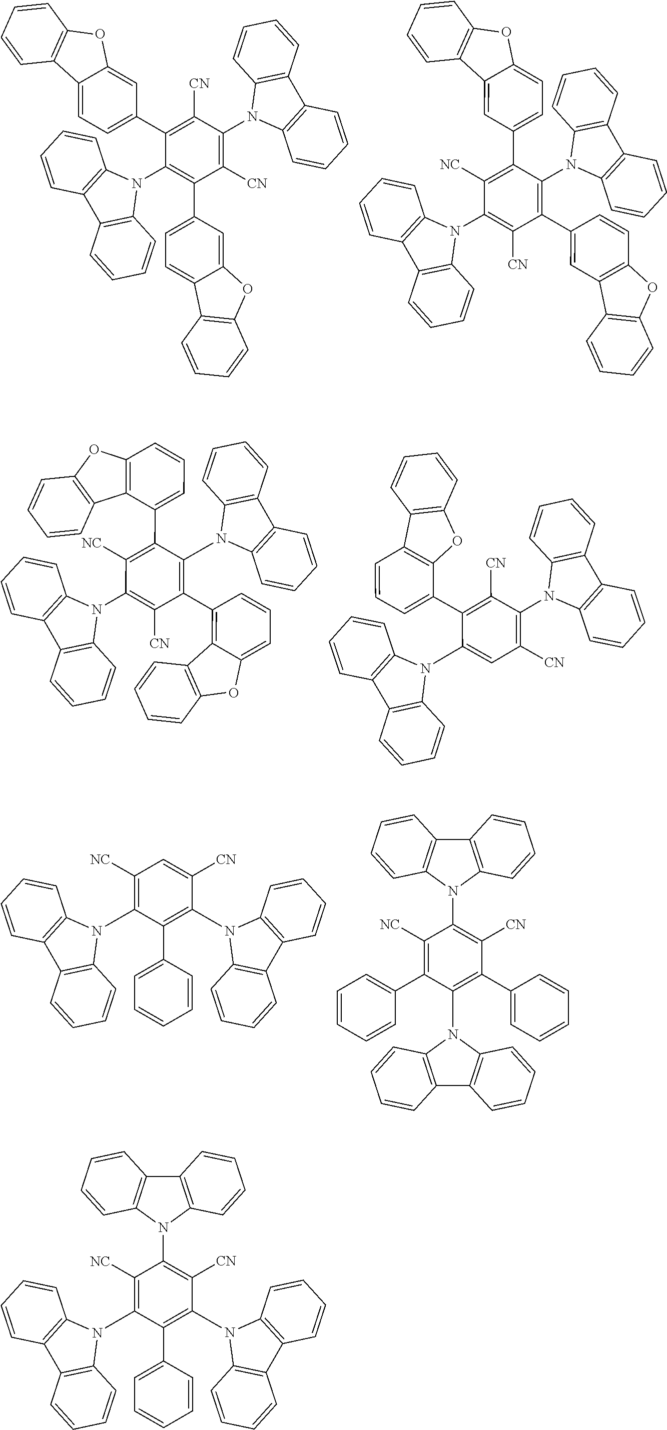

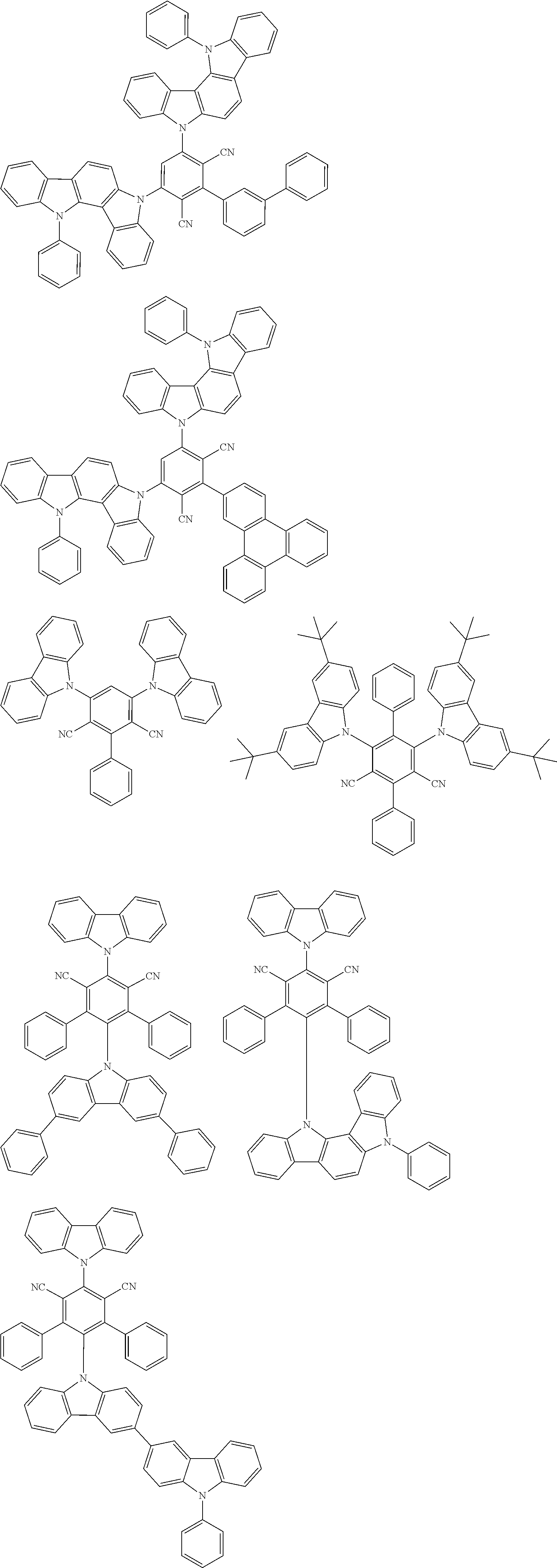

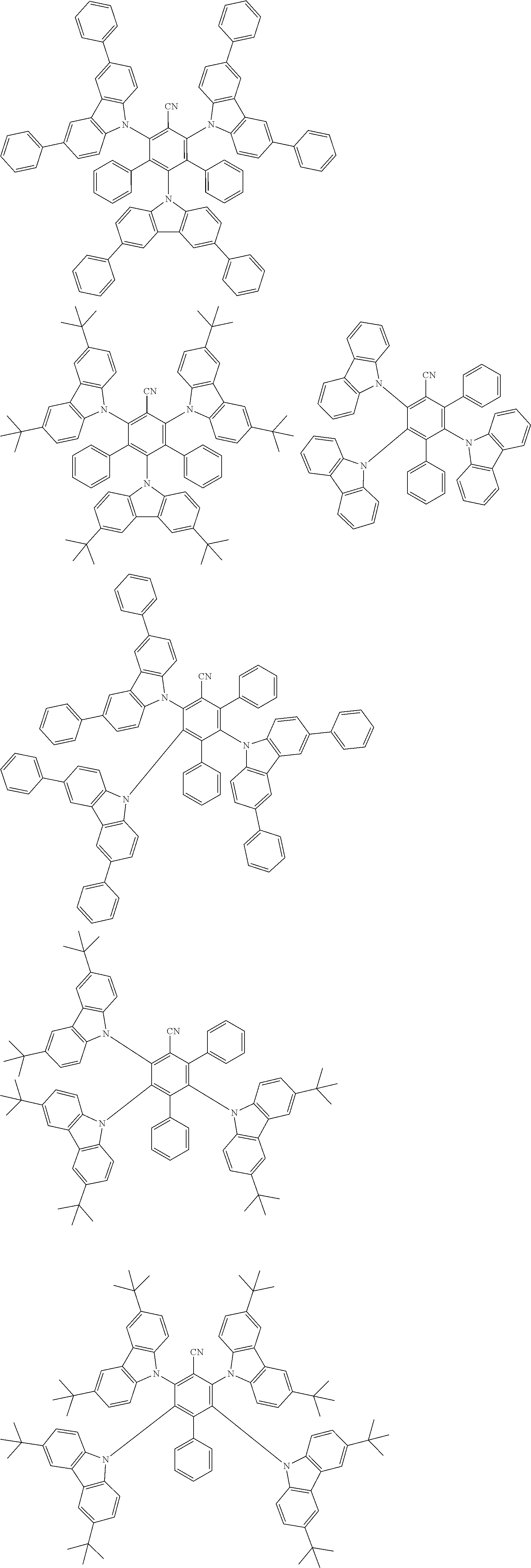

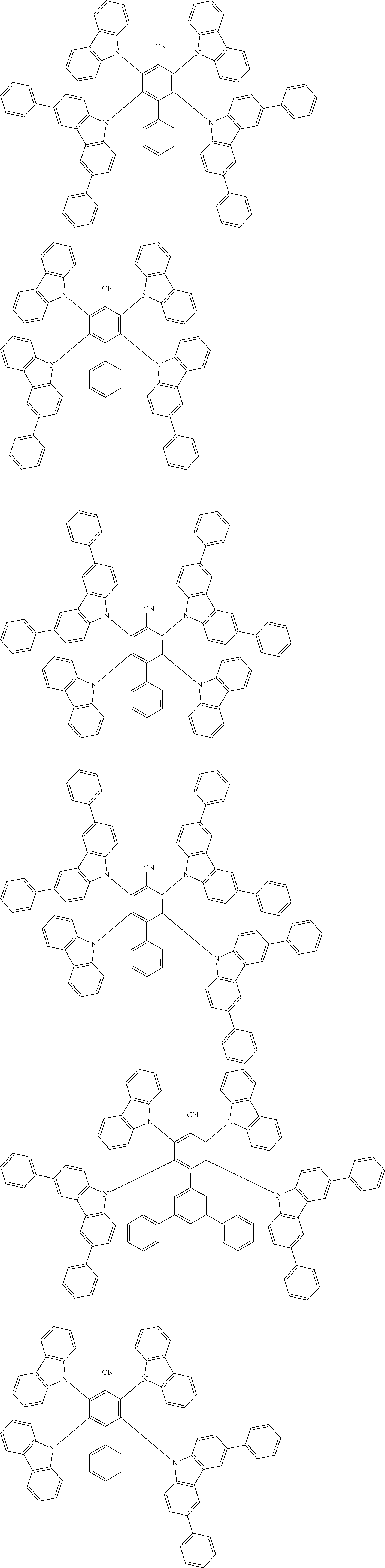

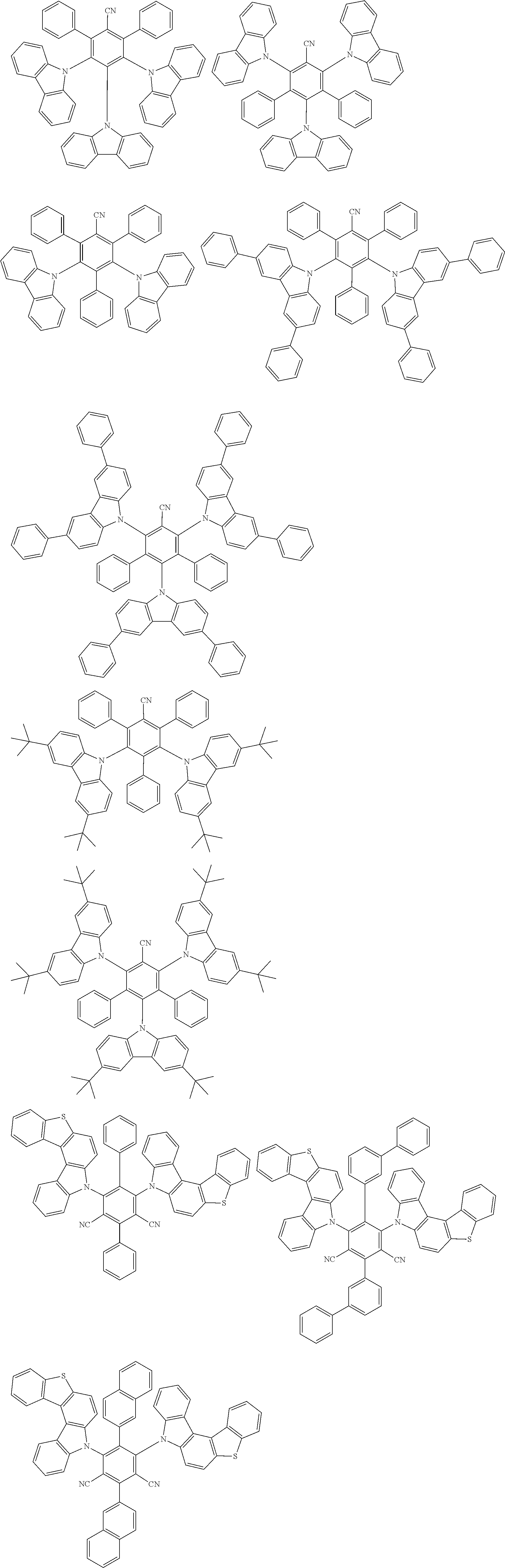

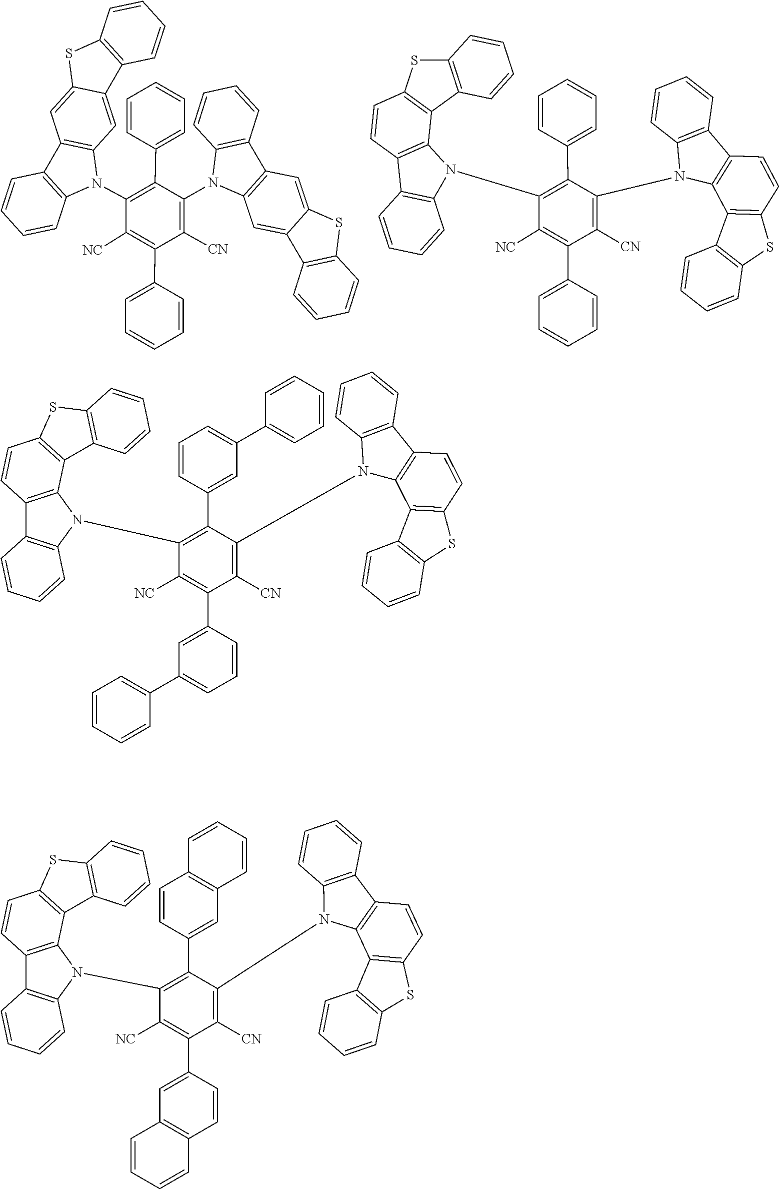

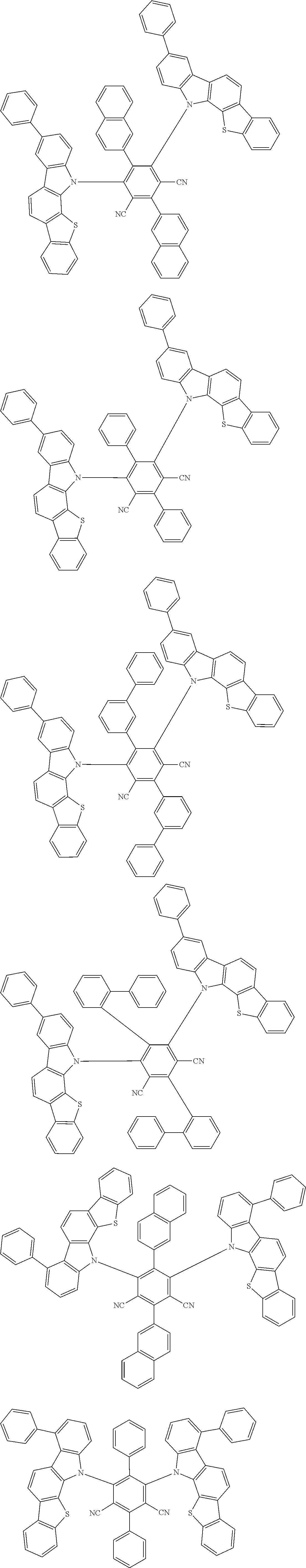

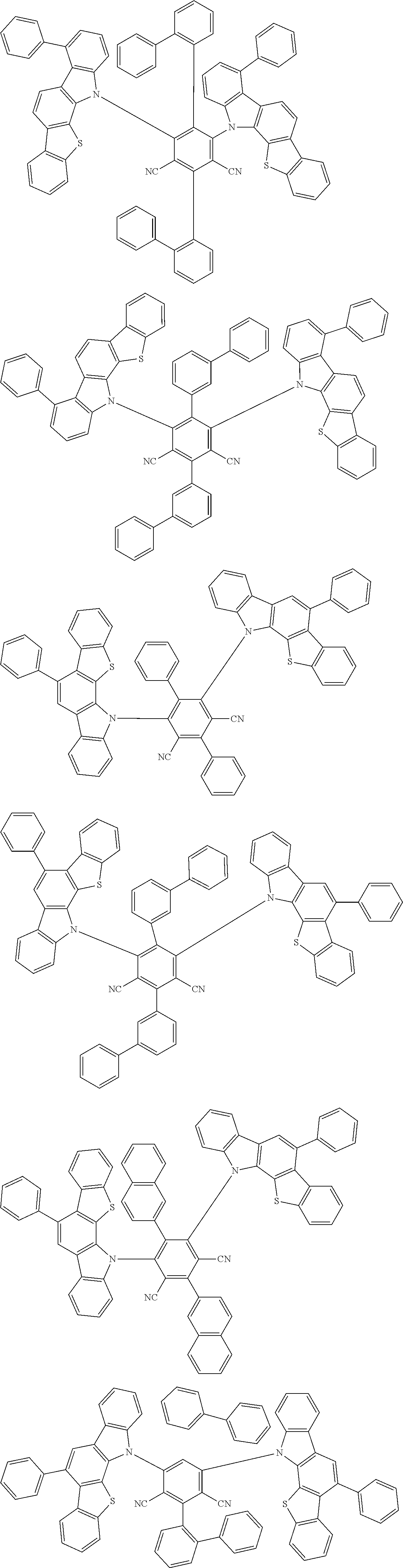

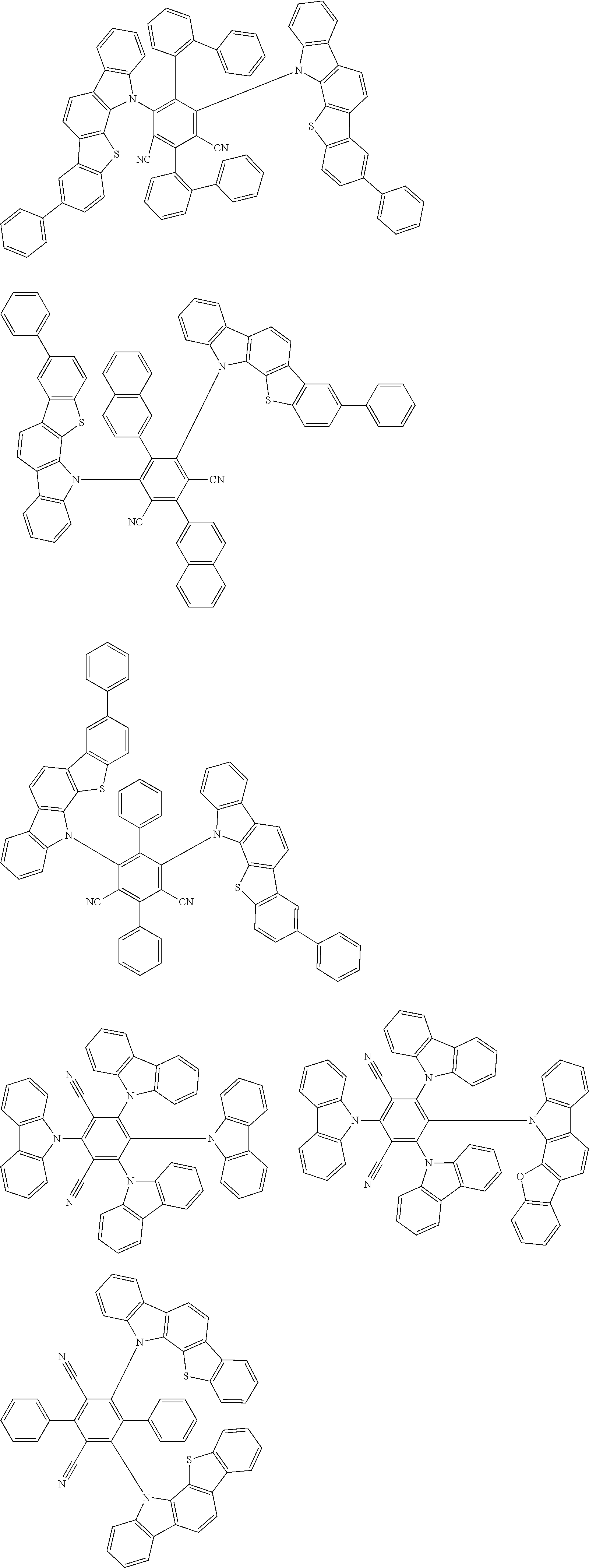

### Compound M2

The compound M2 is preferably a fluorescent compound. The compound M2 is preferably a compound not exhibiting thermally activated delayed fluorescence.

The compound M2 of the exemplary embodiment is not a phosphorescent metal complex. The compound M2 is preferably not a heavy-metal complex. The compound M2 is also preferably not a metal complex.

A fluorescent material is usable as the compound M2 of the exemplary embodiment. Specific examples of the fluorescent material include a bisarylaminonaphthalene derivative, aryl-substituted naphthalene derivative, bisarylaminoanthracene derivative, aryl-substituted anthracene derivative, bisarylaminopyrene derivative, aryl-substituted pyrene derivative, bisarylamino chrysene derivative, aryl-substituted chrysene derivative, bisarylaminofluoranthene derivative, aryl-substituted fluoranthene derivative, indenoperylene derivative, acenaphthofluoranthene derivative, compound including a boron atom, pyromethene boron complex compound, compound having a pyromethene skeleton, metal complex of the compound having a pyrromethene skeleton, diketopyrrolopyrrole derivative, perylene derivative, and naphthacene derivative.

The compound M2 preferably emits light having a maximum peak wavelength in a range from 400 nm to 700 nm.

Herein, the maximum peak wavelength means a peak wavelength of a fluorescence spectrum exhibiting a maximum luminous intensity among fluorescence spectra measured in a toluene solution in which a measurement target compound is dissolved at a concentration ranging from 10⁻⁶ mol/l to 10⁻⁵ mol/l. A spectrophotofluorometer (F-7000 manufactured by Hitachi High-Tech Science Corporation) is used as a measurement apparatus.

The compound M2 preferably exhibits red or green light emission.

Herein, the red light emission refers to light emission whose maximum peak wavelength of fluorescence spectrum is in a range from 600 nm to 660 nm.

When the compound M2 is a red fluorescent compound, the maximum peak wavelength of the compound M2 is preferably in a range from 600 nm to 660 nm, more preferably in a range from 600 nm to 640 nm, and still more preferably in a range from 610 nm to 630 nm.

Herein, the green light emission refers to light emission whose maximum peak wavelength of fluorescence spectrum is in a range from 500 nm to 560 nm.

When the compound M2 is a green fluorescent compound, the maximum peak wavelength of the compound M2 is preferably in a range from 500 nm to 560 nm, more preferably in a range from 500 nm to 540 nm, and still more preferably in a range from 510 nm to 540 nm.

Herein, the blue light emission refers to light emission whose maximum peak wavelength of fluorescence spectrum is in a range from 430 nm to 480 nm.

When the compound M2 is a blue fluorescent compound, the maximum peak wavelength of the compound M2 is preferably in a range from 430 nm to 480 nm, more preferably in a range from 440 nm to 480 nm.

The maximum peak wavelength of the light emitted from the organic EL device is measured as follows.

Voltage is applied on the organic EL device such that a current density becomes 10 mA/cm², where spectral radiance spectrum is measured by a spectroradiometer CS-2000 (manufactured by Konica Minolta, Inc.). A peak wavelength of an emission spectrum, at which the luminous intensity of the resultant spectral radiance spectrum is at the maximum, is measured and defined as the maximum peak wavelength (unit: nm),

### Compound Represented by Formula (D1)

The compound M2 of the exemplary embodiment is preferably a compound represented by a formula (D1) below.

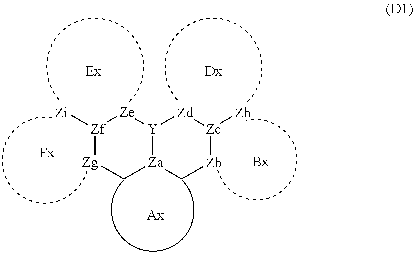

In the formula (D1):
a ring Ax, a ring Bx, a ring Dx, a ring Ex, and a ring Fx are each independently a cyclic structure selected from the group consisting of a substituted or unsubstituted aryl ring having 6 to 30 ring carbon atoms, and a substituted or unsubstituted heterocyclic ring having 5 to 30 ring atoms;
one of the ring Bx and the ring Dx is present or both of the ring Bx and the ring Dx are present;
when both of the ring Bx and the ring Dx are present, the ring Bx and the ring Dx share a bond connecting Zc to Zh;
one of the ring Ex and the ring Fx is present or both of the ring Ex and the ring Fx are present;
when both of the ring Ex and the ring Fx are present, the ring Ex and the ring Fx share a bond connecting Zf to Zi;
Za is a nitrogen atom or a carbon atom; Zb is a nitrogen atom or a carbon atom when the ring Bx is present, and
Zb is an oxygen atom, a sulfur atom, NRb, C(Rb₁)(Rb₂), or Si(Rb₃)(Rb₄) when the ring Bx is not present;
Zc is a nitrogen atom or a carbon atom;
Zd is a nitrogen atom or a carbon atom when the ring Dx is present, and
Zd is an oxygen atom, a sulfur atom, or NRd when the ring Dx is not present;
Ze is a nitrogen atom or a carbon atom when the ring Ex is present, and
Ze is an oxygen atom; a sulfur atom, or NRe when the ring Ex is not present;
Zf is a nitrogen atom or a carbon atom;
Zg is a nitrogen atom or a carbon atom when the ring Fx is present, and
Zg is an oxygen atom, a sulfur atom, NRg, C(Rg₁)(Rg₂), or Si(Rg₃)(Rg₄) when the ring Fx is not present;
Zh is a nitrogen atom or a carbon atom;
Zi is a nitrogen atom or a carbon atom;
Y is a boron atom, a phosphorus atom, SiRh, P═O, or P═S;
Rb, Rb₁, Rb₂, Rb₃, Rb₄, Rd, Re, Rg, Rg₁, Rg₂, Rg₃, Rg₄; and Rh are each independently a hydrogen atom or a substituent;
Rb, Rb₁, Rb₂, Rb₃, Rb₄, Rd, Re, Rg, Rg₁, Rg₂, Rg₃, Rg₄, and Rh as a substituent are each independently a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a group represented by —Si(R₉₁₁)(R₉₁₂)(R₉₁₃), a group represented by —O—(R₉₁₄), a group represented by —S—(R₉₁₅), or a group represented by —N(R₉₁₆)(R₉₁₇); and
a bond between Y and Za, a bond between Y and Zd, and a bond between Y and Ze are each a single bond.

In the compound M2, a bond between Y and Za, a bond between Y and Zd, and a bond between Y and Ze are each a single bond and the single bond is not a coordinate bond but a covalent bond.

Herein, a heterocyclic ring is exemplified by a cyclic structure (heterocyclic ring) obtained by removing a bond from a “heterocyclic group” exemplified by the above “Substituent Mentioned Herein.” The heterocyclic ring may be substituted or unsubstituted.

Herein, an aryl ring is exemplified by a cyclic structure (aryl ring) obtained by removing a bond from an “aryl group” exemplified by the above “Substituent Mentioned Herein.” The aryl ring may be substituted or unsubstituted,

### Compound Represented by Formula (D11)

In the organic EL device according to the exemplary embodiment, the compound M2 is also preferably a compound represented by a formula (D₁₁) below. A compound represented by the formula (D1) is also preferably a compound represented by a formula (D11) below.

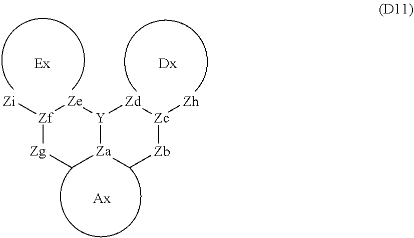

In the formula (D11):
a ring Ax, a ring Dx, and a ring Ex are each independently a cyclic structure selected from the group consisting of a substituted or unsubstituted aryl ring having 6 to 30 ring carbon atoms, and a substituted or unsubstituted heterocyclic ring having 5 to 30 ring atoms;
Za is a nitrogen atom or a carbon atom;
Zb is an oxygen atom, a sulfur atom, NRb, C(Rb₁)(Rb₂), or Si(Rb₃)(Rb₄);
Zc is a nitrogen atom or a carbon atom;

Zd is a nitrogen atom or a carbon atom;
Ze is a nitrogen atom or a carbon atom;
Zf is a nitrogen atom or a carbon atom;
Zg is an oxygen atom, a sulfur atom, NRg, C(Rg₁)(Rg₂), or Si(Rg₃)(Rg₄);
Zh is a nitrogen atom or a carbon atom;
Zi is a nitrogen atom or a carbon atom;
Y is a boron atom, a phosphorus atom, SiRh, P═O, or P═S;
Rb, Rb₁, Rb₂, Rb₃, Rb₄, Rg, Rg₁, Rg₂, Rg₃, Rg₄, and Rh each independently represent the same as Rb, Rb₁, Rb₂, Rb₃, Rb₄, Rg, Rg₂, Rg₃, Rg₄, and Rh in the formula (D1).

### Compound Represented by Formula (D10)

In the organic EL device according to the exemplary embodiment, the compound M2 is also preferably a compound represented by a formula (D10) below. A compound represented by the formula (D1) is also preferably a compound represented by a formula (D10) below.

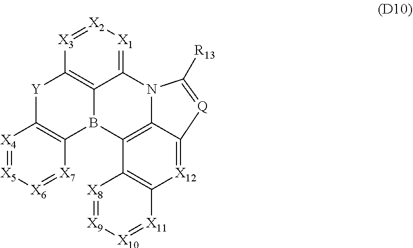

In the formula (D10):
X₁ is CR₁ or a nitrogen atom;
X₂ is CR₂ or a nitrogen atom;
X₃ is CR₃ or a nitrogen atom;
X₄ is CR₄ or a nitrogen atom;
X₅ is CR₅ or a nitrogen atom;
X₆ is CR₆ or a nitrogen atom;
X₇ is CR₇, a nitrogen atom, or a carbon atom bonded to X₈ with a single bond;
X₈ is CR₈, a nitrogen atom, or a carbon atom bonded to X₇ with a single bond;
X₉ is CR9 or a nitrogen atom;
X₁₀ is CR₁₀ or a nitrogen atom;
X₁₁ is CR₁₁ or a nitrogen atom;
X₁₂ is CR12 or a nitrogen atom;
Q is CR_{Q} or a nitrogen atom;
Y is NR_{Y1}, an oxygen atom, a sulfur atom, C(R_{Y2})(R_{Y3}), or Si(R_{Y4})(R_{Y5});
at least one combination of adjacent two or more of R₁ to R₆ and R₉ to R₁₁ are mutually bonded to form a substituted or unsubstituted monocyclic ring, mutually bonded to form a substituted or unsubstituted fused ring, or not mutually bonded;
at least one combination of adjacent two or more of R₃, R₄, and R_{Y1} are mutually bonded to form a substituted or unsubstituted monocyclic ring, mutually bonded to form a substituted or unsubstituted fused ring, or not mutually bonded;
at least one hydrogen atom in a monocyclic ring or a fused ring formed by mutually bonding at least one combination of adjacent two or more of R₃, R₄, and R_{Y1} is substituted or not substituted by at least one substituent selected from the group consisting of an alkyl group having 1 to 50 carbon atoms, an aryl group having 6 to 50 ring carbon atoms; a heterocyclic group having 5 to 50 ring atoms, a group represented by —O—(R₉₂₀), and a group represented by —N(R₉₂₁)(R₉₂₂);
at least one hydrogen atom of the substituent is substituted or not substituted by an aryl group having 6 to 50 ring carbon atoms or an alkyl group having 1 to 50 carbon atoms;
R₁ to R₁₁ forming neither the substituted or unsubstituted monocyclic ring nor the substituted or unsubstituted fused ring and R₁₂ to R₁₃ and R_{Q} are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms; a group represented by —Si(R₉₁₁)(R₉₁₂)(R₉₁₃); a group represented by —O—(R₉₁₄), a group represented by —S—(R₉₁₅), a group represented by —N(R₉₁₆)(R₉₁₇), a substituted or unsubstituted aralkyl group having 7 to 50 carbon atoms, a group represented by —C(═O)R₉₁₈, a group represented by —COOR₉₁₉, a halogen atom, a cyano group, a nitro group, a substituted or unsubstituted aryl group having 6 to 50 ring carbon atoms, or a substituted or unsubstituted heterocyclic group having 5 to 50 ring atoms;
R_{Y1} forming neither the substituted or unsubstituted monocyclic ring nor the substituted or unsubstituted fused ring is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
a combination of R_{Y2} and R_{Y3} are mutually bonded to form a substituted or unsubstituted monocyclic ring, mutually bonded to form a substituted or unsubstituted fused ring, or not mutually bonded;
R_{Y2} and R_{Y3} forming neither the substituted or unsubstituted monocyclic ring nor the substituted or unsubstituted fused ring and R_{Y4} and R_{Y5} are each independently a hydrogen atom, a halogen atom, a substituted or unsubstituted alkyl group having 1 to 50 carbon atoms, a substituted or unsubstituted aryl group having 6 to 50 ring carbon atoms, or a substituted or unsubstituted heterocyclic group having to 50 ring atoms;
R₉₁₁ to R₉₂₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₁₁ are present, the plurality of R₉₁₁ are mutually the same or different;
when a plurality of R₉₁₂ are present, the plurality of R₉₁₂ are mutually the same or different;
when a plurality of R₉₁₃ are present, the plurality of R₉₁₃ are mutually the same or different;
when a plurality of R₉₁₄ are present, the plurality of R₉₁₄ are mutually the same or different;
when a plurality of R₉₁₅ are present, the plurality of R₉₁₅ are mutually the same or different;
when a plurality of R₉₁₆ are present, the plurality of R₉₁₆ are mutually the same or different;
when a plurality of R₉₁₇ are present, the plurality of R₉₁₇ are mutually the same or different;
when a plurality of R₉₁₈ are present, the plurality of R₉₁₈ are mutually the same or different;
when a plurality of R₉₁₉ are present, the plurality of R₉₁₉ are mutually the same or different;
when a plurality of R₉₂₀ are present, the plurality of R₉₂₀ are mutually the same or different;
when a plurality of R₉₂₁ are present, the plurality of R₉₂₁ are mutually the same or different; and
when a plurality of R₉₂₂ are present, the plurality of R₉₂₂ are mutually the same or different.

In a compound represented by the formula (D10), when X₇ is a carbon atom bonded to X₈ with a single bond and X₈ is a carbon atom bonded to X₇ with a single bond, the formula (D10) is represented by a formula (D10A) below.

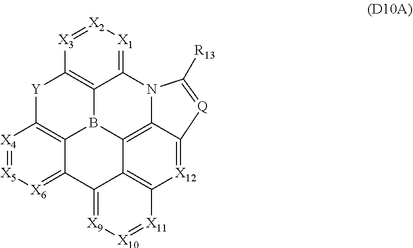

In the formula (D10A) ; X₁ to X₆, X₉ to X₁₂, Y, Q, and R₁₃ are each independently defined as in the formula (D10).

A compound represented by the formula (D10) is also preferably represented by a formula (D12) below.

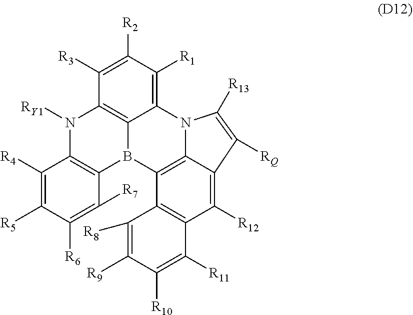

In the formula (D12), R₁ to R₁₃, R_{Y1}, and R_{Q} are each independently defined the same as in the formula (D10).

A compound represented by the formula (D10) is also preferably represented by a formula (D12A) below.

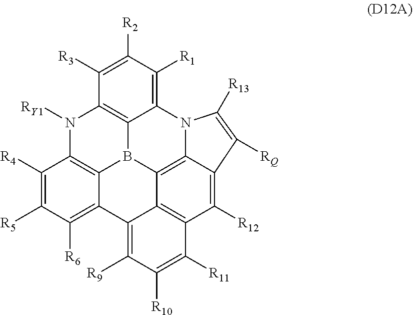

In the formula (D12A), R₁ to R₆, R₉ to R₁₃, R_{Y1}, and R_{Q} are each independently defined as in the formula (D10).

A compound represented by the formula (D10) is also preferably represented by a formula (D13) below

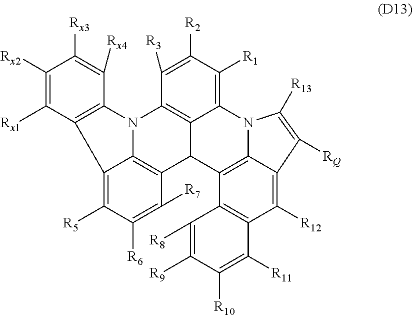

In the formula (D13):
R₁ to R₃, R₅ to R₁₃, and Ra are each independently defined as in the formula (D10);
at least one combination of adjacent two or more of Rₓ₁ to Rₓ₄ are mutually bonded to form a substituted or unsubstituted monocyclic ring, mutually bonded to form a substituted or unsubstituted fused ring, or not mutually bonded;
Rₓ₁ to Rₓ₄ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aralkyl group having 7 to 50 carbon atoms, a group represented by —Si(R₉₃₁)(R₉₃₂)(R₉₃₃), a group represented by —O—(R₉₃₄), a group represented by —S—(R₉₃₅), a group represented by —N(R₉₃₆)(R₉₃₇), a substituted or unsubstituted aralkyl group having 7 to 50 carbon atoms, a group represented by —C(═O)R₉₃₈, a group represented by —COOR₉₃₉, a halogen atom, a cyano group, a nitro group, a substituted or unsubstituted aryl group having 6 to 50 ring carbon atoms, or a substituted or unsubstituted heterocyclic group having 5 to 50 ring atoms;
R₉₃₁ to R₉₃₉ are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different;
when a plurality of R₉₃₇ are present, the plurality of R₉₃₇ are mutually the same or different;
when a plurality of R₉₃₈ are present, the plurality of R₉₃₈ are mutually the same or different; and
when a plurality of R₉₃₉ are present, the plurality of R₉₃₉ are mutually the same or different.

In the formula (D13), a combination of R₅ and R₆ are mutually bonded to form a substituted or unsubstituted monocyclic ring, mutually bonded to form a substituted or unsubstituted fused ring, or not bonded.

A compound represented by the formula (D10) is also preferably represented by a formula (D13A) below.

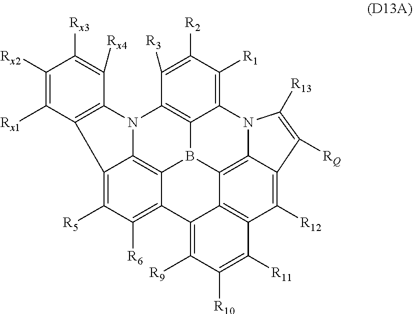

In the formula (D13A): R₁ to R₃, R₅ to R₆, R₉ to R₁₃, and R_{Q} are each independently defined as in the formula (D10); and Rₓ₁ to Rₓ₄ are each independently defined as in the formula (D13).

It is also preferable that R₁ to R₁₃ and R_{Q} in the compound represented by the formula (D10) are each independently a hydrogen atom, a substituted or unsubstituted alkyl group having 1 to 50 carbon atoms, a substituted or unsubstituted aryl group having 6 to 50 ring carbon atoms, or a substituted or unsubstituted heteroaryl group having 5 to 50 ring atoms.

It is also preferable that R₁ to R₁₃ and R_{Q} in the compound represented by the formula (D10) are each independently a hydrogen atom, a substituted or unsubstituted alkyl group having 1 to 25 carbon atoms, a substituted or unsubstituted aryl group having 6 to 25 ring carbon atoms, or a substituted or unsubstituted heteroaryl group having 5 to 25 ring atoms.

It is also preferable that R₁ to R₃, R₅ to R₁₃, R_{Q}, and Rₓ₁ to Rₓ₄ in a compound represented by the formula (D10) are each independently a hydrogen atom, a substituted or unsubstituted alkyl group having 1 to 50 carbon atoms, a substituted or unsubstituted aryl group having 6 to 50 ring carbon atoms, or a substituted or unsubstituted heteroaryl group having 5 to 50 ring atoms.

It is also preferable that R₁ to R₃, R₅ to R₁₃, R_{Q}, and Rₓ₁ to Rₓ₄ in a compound represented by the formula (D10) are each independently a hydrogen atom, a substituted or unsubstituted alkyl group having 1 to 25 carbon atoms, a substituted or unsubstituted aryl group having 6 to 25 ring carbon atoms, or a substituted or unsubstituted heteroaryl group having 5 to 25 ring atoms.

It is preferable that R₁ to R₁₃, R_{Q}, and Rₓ₁ to Rₓ₄ in a compound represented by the formula (D10) are each independently a hydrogen atom, a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

It is also preferable that R₁ to R₁₃, R_{Q}, and Rₓ₁ to Rₓ₄ in a compound represented by the formula (D10) are each independently a hydrogen atom, a substituted or unsubstituted alkyl group having 1 to 25 carbon atoms, a substituted or unsubstituted aryl group having 6 to 25 ring carbon atoms, or a substituted or unsubstituted heterocyclic group having 5 to 25 ring atoms.

A compound represented by the formula (D10) is also preferably represented by a formula (D14) below.

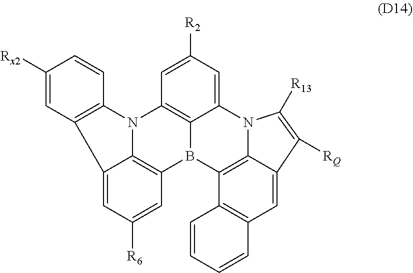

In the formula (D14), R₂, R₆, R₁₃, R_{Q}, and Rₓ₂ are each independently a hydrogen atom, a substituted or unsubstituted alkyl group having 1 to 10 carbon atoms, a substituted or unsubstituted aryl group having 6 to 12 ring carbon atoms, or a substituted or unsubstituted heteroaryl group having 5 to 18 ring atoms.

A compound represented by the formula (D10) is also preferably represented by a formula (D15) below.

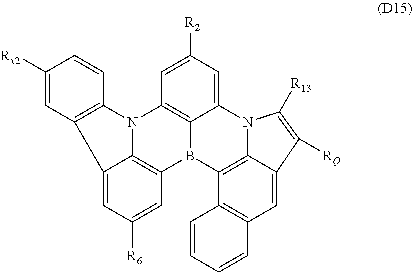

In the formula (D15), R₂, R₆, R₁₃, R_{Q}, and Rₓ₂ are each independently a hydrogen atom, a substituted or unsubstituted alkyl group having 1 to 10 carbon atoms, a substituted or unsubstituted aryl group having 6 to 12 ring carbon atoms, or a substituted or unsubstituted heteroaryl group having 5 to 18 ring atoms.

It is preferable that R₁₃ and Ra in the compound represented by the formula (D10) are each independently a substituted or unsubstituted alkyl group having 1 to carbon atoms, a substituted or unsubstituted phenyl group, a substituted or unsubstituted naphthyl group, or a substituted or unsubstituted dibenzofuranyl group. In a compound represented by the formula (D10), R₆ and Rₓ₂ are preferably each independently a hydrogen atom or a substituted or unsubstituted alkyl group having 1 to 10 atoms.

### Compound Represented by Formula (D20)

In the organic EL device according to the exemplary embodiment, the compound M2 is also preferably a compound represented by a formula (D20) below.

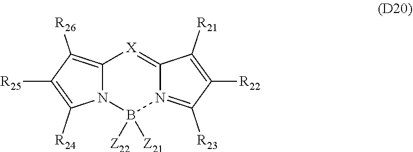

In the formula (D20):
X is a nitrogen atom, or a carbon atom bonded to Y;
Y is a hydrogen atom or a substituent;
R₂₁ to R₂₆ are each independently a hydrogen atom or a substituent, or at least one combination of a combination of R₂₁ and R₂₂, a combination of R₂₂ and R₂₃, a combination of R₂₄ and R₂₅, or a combination of R₂₅ and R₂₆ are mutually bonded to form a ring;
Y and R₂₁ to R₂₆ as a substituent are each independently selected from the group consisting of a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, a substituted or unsubstituted alkylthio group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted alkenyl group having 2 to 30 carbon atoms, a substituted or unsubstituted aralkyl group having 7 to 30 carbon atoms, a substituted or unsubstituted heteroaryl group having 5 to 30 ring atoms, a halogen atom, a carboxy group, a substituted or unsubstituted ester group, a substituted or unsubstituted carbamoyl group, a substituted or unsubstituted amino group, a nitro group, a cyano group, a substituted or unsubstituted silyl group, and a substituted or unsubstituted siloxanyl group;
Z₂₁ and Z₂₂ are each independently a substituent, or Z₂₁ and Z₂₂ are mutually bonded to form a ring; and

Z₂₁ and Z₂₂ as a substituent are each independently selected from the group consisting of a halogen atom, a substituted or unsubstituted alkyl group having 1 to carbon atoms, a substituted or unsubstituted alkyl halide group having 1 to 30 carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, and a substituted or unsubstituted aryloxy group having 6 to 30 ring carbon atoms.

In the compound M2 according to the exemplary embodiment, the substituent for “the substituted or unsubstituted” group is an unsubstituted alkyl group having 1 to 25 carbon atoms, an unsubstituted alkenyl group having 2 to 25 carbon atoms, an unsubstituted alkynyl group having 2 to 25 carbon atoms, an unsubstituted cycloalkyl group having 3 to 25 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), an unsubstituted aralkyl group having 7 to 50 carbon atoms, a group represented by —C(═O)R₉₀₈, a group represented by —COOR₉₀₉, a group represented by —S(═O)₂R₉₄₁, a group represented by —(═O)(R₉₄₂)(R₉₄₃), a group represented by —Ge(R₉₄₄)(R₉₄₅)(R₉₄₆), a halogen atom, a cyano group, a nitro group, an unsubstituted aryl group having 6 to 25 ring carbon atoms, or an unsubstituted heterocyclic group having 5 to 25 ring atoms.

R₉₀₁ to R₉₀₉ and R₉₄₁ to R₉₄₆ are preferably each independently a hydrogen atom, an unsubstituted alkyl group having 1 to 25 carbon atoms, an unsubstituted aryl group having 6 to 25 ring carbon atoms, or an unsubstituted heterocyclic group having 5 to 25 ring atoms.

In the compound M2 according to the exemplary embodiment, the substituent for “the substituted or unsubstituted” group is preferably a halogen atom, an unsubstituted alkyl group having 1 to 25 carbon atoms, an unsubstituted aryl group having 6 to 25 ring carbon atoms, or an unsubstituted heterocyclic group having 5 to ring atoms.

In the compound M2 according to the exemplary embodiment, the substituent for “the substituted or unsubstituted” group is preferably an unsubstituted alkyl group having 1 to 10 carbon atoms, an unsubstituted aryl group having 6 to 12 ring carbon atoms, or an unsubstituted heterocyclic group having 5 to 12 ring atoms.

In the compound M2 according to the exemplary embodiment, it is also preferable that the groups specified to be “substituted or unsubstituted” are each an “unsubstituted” group.

### Specific Examples of Compounds Represented by Formula (D1), (D11), (D10), or (D20)

Specific examples of compounds represented by the formula (D1) (D11), (D10), or (D20) include compounds shown below. However, the invention is by no means limited to the specific examples.

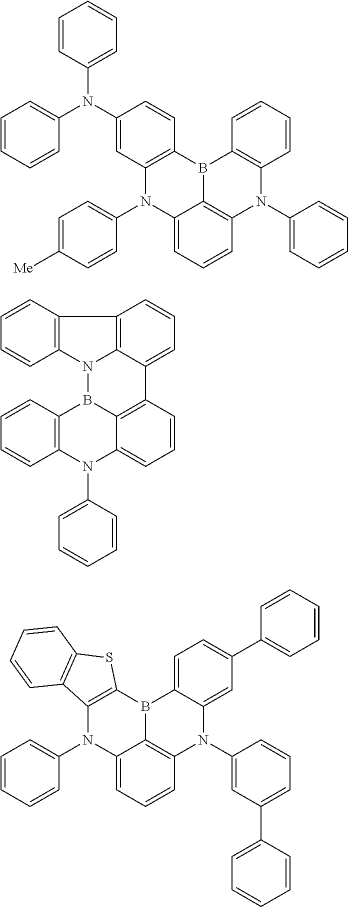

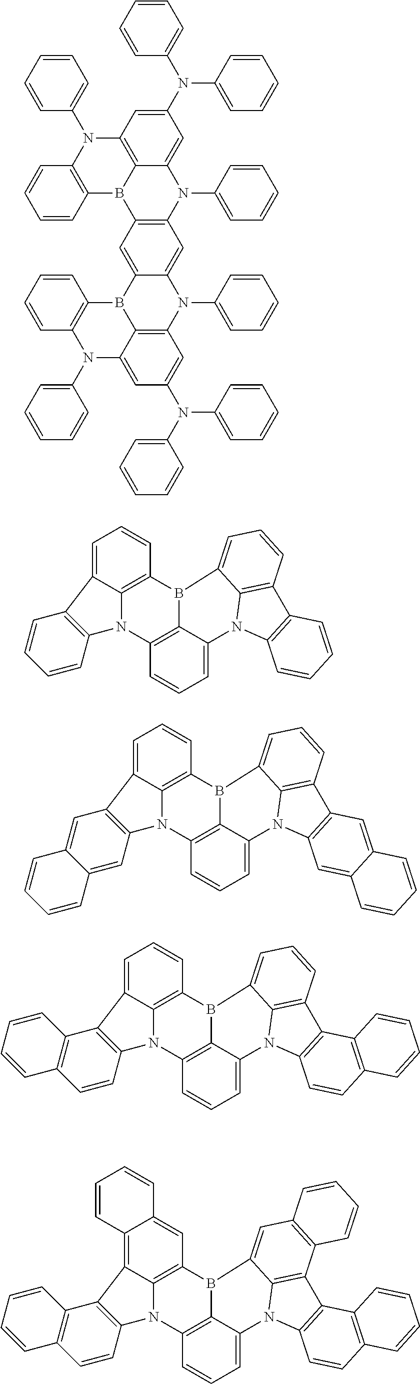

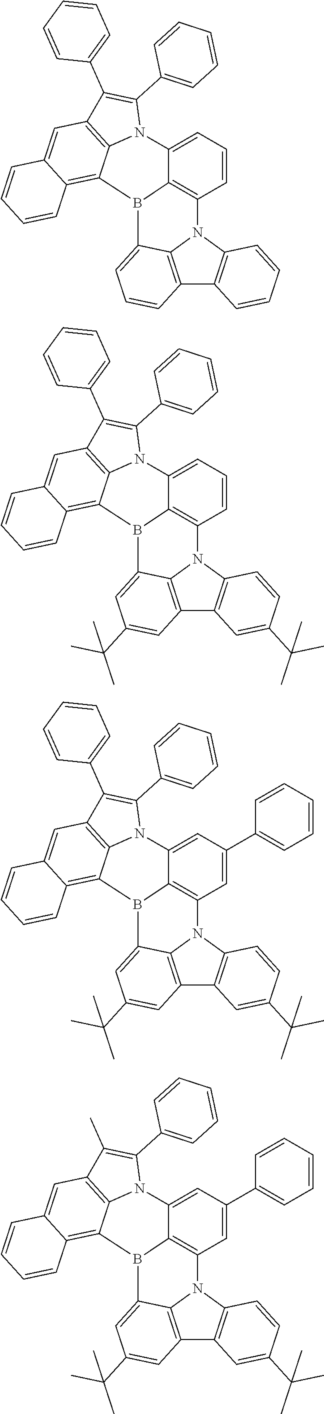

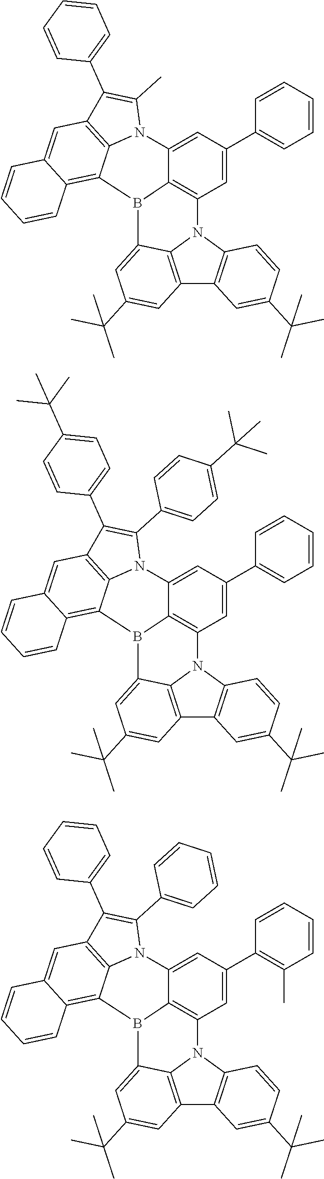

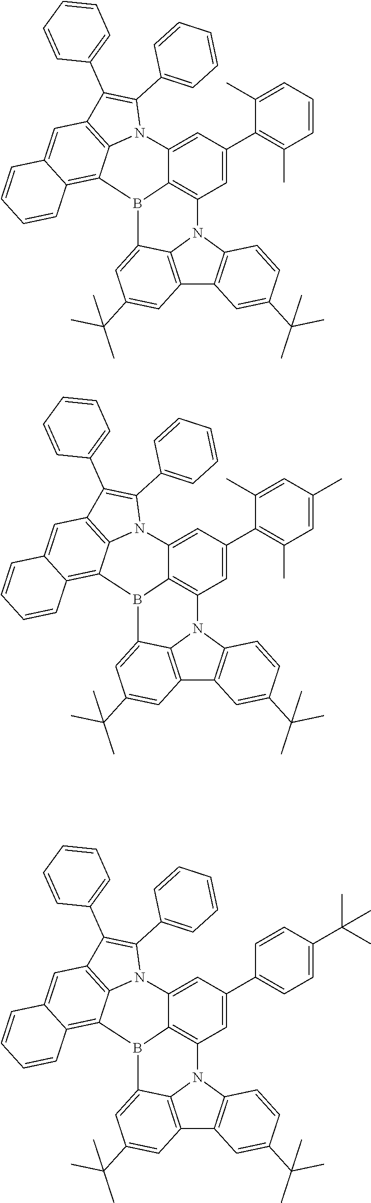

### Relationship Between Compound M1 and Compound M2 in Emitting Layer

In the organic EL device according to the exemplary embodiment, it is preferable that the emitting layer contains the compound M1 and the compound M2, the compound M2 is a fluorescent compound, and the lowest singlet energy S₁(M1) of the compound M1 and the lowest singlet energy S₁(M2) of the compound M2 satisfy a relationship of a numerical formula (Numerical Formula 1) below.

S₁(M1)>S₁(M2) (Numerical Formula 1)

An energy gap T_{77K}(M1) at 77K of the compound M1 is preferably larger than an energy gap T_{77K}(M2) at 77K of the compound M2. In other words, a relationship of a numerical formula (Numerical Formula 5) below is preferably satisfied.

T_{77K}(M1)>T_{77K}(M2) (Numerical Formula 5)

When the organic EL device according to the exemplary embodiment emits light, it is preferable that the compound M2 mainly emits light in the emitting layer.

### TADF Mechanism

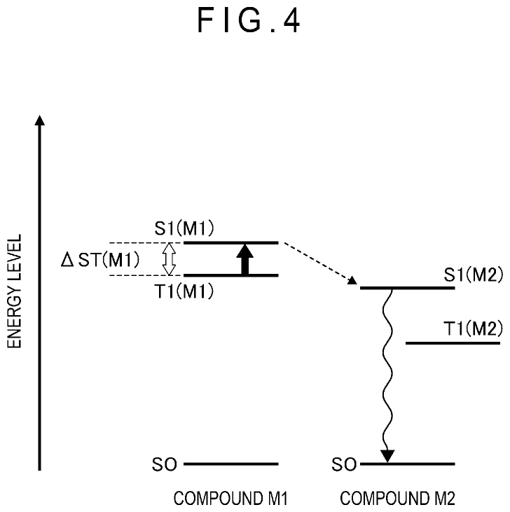

FIG. 4 illustrates an example of a relationship between energy levels of the compound M1 and the compound M2 in the emitting layer. In FIG. 4, S0 represents a ground state. S1(M1) represents a lowest singlet state of the compound M1. T1(M1) represents a lowest triplet state of the compound M1. S1(M2) represents a lowest singlet state of the compound M2. T1(M2) represents a lowest triplet state of the compound M2.

A dashed arrow directed from S1(M1) to S1(M2) in FIG. 4 represents FOrster energy transfer from the lowest singlet state of the compound M1 to the compound M2.

As illustrated in FIG. 4, when a compound having a small ΔST(M1) is used as the compound M1, inverse intersystem crossing from the lowest triplet state T1(M1) to the lowest singlet state S1(M1) can be caused by a heat energy. Subsequently, Förster energy transfer from the lowest singlet state S1(M1) of the compound M1 to the compound M2 occurs to generate the lowest singlet state S1(M2). Consequently, fluorescence from the lowest singlet state S1(M2) of the compound M2 can be observed. It is inferred that the internal quantum efficiency can be theoretically raised up to 100% also by using delayed fluorescence by the TADF mechanism.

The organic EL device according to the exemplary embodiment preferably emits red light or green light.

When the organic EL device according to the exemplary embodiment emits a green light, the maximum peak wavelength of the light emitted from the organic EL device is preferably in a range from 500 nm to 560 nm.

When the organic EL device according to the exemplary embodiment emits a red light, the maximum peak wavelength of the light emitted from the organic EL device is preferably in a range from 600 nm to 660 nm.

When the organic EL device according to the exemplary embodiment emits a blue light, the maximum peak wavelength of the light emitted from the organic EL device is preferably in a range from 430 nm to 480 nm.

The maximum peak wavelength of the light emitted from the organic EL device is measured as follows.

Voltage is applied on the organic EL device such that a current density becomes 10 mA/cm 2, where spectral radiance spectrum is measured by a spectroradiometer CS-2000 (manufactured by Konica Minolta, Inc.). A peak wavelength of an emission spectrum, at which the luminous intensity of the resultant spectral radiance spectrum is at the maximum, is measured and defined as the maximum peak wavelength (unit: nm).

### Film Thickness of Emitting Layer

A film thickness of the emitting layer of the organic EL device according to the exemplary embodiment is preferably in a range from 5 nm to 50 nm, more preferably in a range from 7 nm to 50 nm, most preferably in a range from 10 nm to nm. When the film thickness of the emitting layer is 5 nm or more, the formation of the emitting layer and the adjustment of the chromaticity are likely to be easy. When the film thickness of the emitting layer is 50 nm or less, an increase in the drive voltage is likely to be inhibited.

### Content Ratios of Compounds in Emitting Layer

For instance, content ratios of the compound M1 and the compound M2 in the emitting layer preferably fall within ranges shown below.

The content ratio of the compound M1 is preferably in a range from 10 mass % to 80 mass %, more preferably in a range from 10 mass % to 60 mass %, and still more preferably in a range from 20 mass % to 60 mass %. The content ratio of the compound M1 may be in a range from 90 mass % to 99.9 mass %, may be in a range from 95 mass % to 99.9 mass %, and may be in a range from 99 mass % to 99.9 mass %.

The content ratio of the compound M2 is preferably in a range from 0.01 mass % to 10 mass %, more preferably in a range from 0.01 mass % to 5 mass %, and still more preferably in a range from 0.01 mass % to 1 mass %.

It should be noted that the emitting layer of the exemplary embodiment may contain a material other than the compound M1 and the compound M2.

The emitting layer may contain a single type of the compound M1 or may contain two or more types of the compound M1. The emitting layer may contain a single type of the compound M2 or may contain two or more types of the compound M2.

The arrangement of the organic EL device according to the exemplary embodiment will be further described below.

### Substrate

The substrate is used as a support for the organic EL device. For instance, glass, quartz, plastics and the like are usable for the substrate. A flexible substrate is also usable. The flexible substrate is a bendable substrate. Examples of the flexible substrate include a plastic substrate made using polycarbonate, polyarylate, polyethersulfone, polypropylene, polyester, polyvinyl fluoride, and polyvinyl chloride. Moreover, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include ITO (Indium Tin Oxide), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the organic layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), alloys including the rare earth metal are also usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

### Hole Blocking Layer

The hole blocking layer is preferably a layer for transporting electrons and blocking holes from reaching a layer close to the cathode (e.g., the electron transporting layer) beyond the hole blocking layer. The compound contained in the hole blocking layer is exemplified by a compound used in a known hole blocking layer. The compound contained in the electron hole blocking layer, which is exemplified by similar to a compound used usable in an known electron blocking transporting layer described later; and is preferably at least one compound selected from the group consisting of a metal complex, a heteroaromatic compound, and a high polymer compound. The compound contained in the hole blocking layer may be, for instance, at least one compound selected from the group consisting of an imidazole derivative, benzimidazole derivative, azine derivative, carbazole derivative, and phenanthroline derivative.

In order to prevent excitation energy from leaking out from the emitting layer toward neighboring layer(s), the hole blocking layer is also preferably a layer blocking excitors generated in the emitting layer from being transferred to a layer(s) closer to the cathode (e.g., the electron transporting layer and the electron injecting layer) beyond the hole blocking layer.

### Electron Transporting Layer

The electron transporting layer is a layer containing a highly electron-transporting substance. For the electron transporting layer, 1) a metal complex such as an aluminum complex, beryllium complex, and zinc complex, 2) a hetero aromatic compound such as an imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinato)aluminum (abbreviation: Almq3), bis(10-hydroxybenzo[h]quinolinato)beryllium (abbreviation: BeBq2), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. The above-described substances mostly have an electron mobility of 10⁻⁶ cm²/(V·s) or more. It should be noted that any substance other than the above substance may be used for the electron transporting layer as long as the substance exhibits a higher electron transportability than the hole transportability. It should be noted that the electron transporting layer may be not only a single layer but also a laminate of two or more layers formed of the above substance(s).

Further, a high polymer compound is usable for the electron transporting layer. For instance, poly[(9,9-dihexylfluorene-2,7-diyl)-co-(pyridine-3,5-diyl)] (abbreviation: PF-Py), poly[(9,9-dioctylfluorene-2,7-diyl)-co-(2,2′-bipyridine-6,6′-diyl)] (abbreviation: PF-BPy) and the like are usable.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Layer Formation Method

A method for forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

### Film Thickness

A thickness of each of the organic layers in the organic EL device according to the exemplary embodiment is not limited except for the above particular description. In general, the thickness preferably ranges from several nanometers to 1 μm because excessively small film thickness is likely to cause defects (e.g. pin holes) and excessively large thickness leads to the necessity of applying high voltage and consequent reduction in efficiency.

According to the first exemplary embodiment, a luminous efficiency of the organic EL device is improvable. The organic EL device according to the first exemplary embodiment is usable in an electronic device such as a display device and a light-emitting unit.

### Second Exemplary Embodiment

An arrangement of an organic EL device according to a second exemplary embodiment will be described below. In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable, unless otherwise specified.

The organic EL device according to the second exemplary embodiment is different from the organic EL device according to the first exemplary embodiment in that the emitting layer further includes a compound M3. The second exemplary embodiment is the same as the first exemplary embodiment in other respects.

Specifically, in the second exemplary embodiment, the emitting layer contains the compound M1, the compound M2, and the compound M3. In this arrangement, it is preferable that the compound M1 is a host material and the compound M2 is a dopant material.

### Compound M3

In the emitting layer of the organic EL device of the exemplary embodiment, the compound M3 may be a thermally activated delayed fluorescent compound or a compound exhibiting no thermally activated delayed fluorescence. However, the compound M3 is preferably a compound exhibiting no thermally activated delayed fluorescence.

The compound M3, which is not particularly limited, is preferably a compound other than an amine compound. As the compound M3, for instance, a carbazole derivative, dibenzofuran derivative, and a dibenzothiophen derivative are usable. However, the compound M3 is not limited to these derivatives.

### Compound Represented by Formula (3)

In the emitting layer of the organic EL device according to the exemplary embodiment, the compound M3 is also preferably a compound represented by a formula (3) below

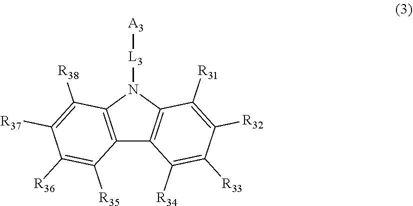

In the formula (3):
A3 is a substituted or unsubstituted aryl group having 6 to 50 ring carbon atoms, or a substituted or unsubstituted heterocyclic group having 5 to 50 ring atoms;
L₃ is a single bond, a substituted or unsubstituted arylene group having 6 to ring carbon atoms, a substituted or unsubstituted divalent heterocyclic group having 5 to 50 ring atoms, a divalent group formed by bonding two groups selected from the group consisting of a substituted or unsubstituted arylene group having 6 to ring carbon atoms and a substituted or unsubstituted divalent heterocyclic group having 5 to 50 ring atoms, or a divalent group formed by bonding three groups selected from the group consisting of a substituted or unsubstituted arylene group having 6 to 30 ring carbon atoms and a substituted or unsubstituted divalent heterocyclic group having 5 to 30 ring atoms;
at least one combination of adjacent two or more of R₃₁ to R₃₈ are mutually bonded to form a substituted or unsubstituted monocyclic ring, mutually bonded to form a substituted or unsubstituted fused ring, or not mutually bonded;
R₃₁ to R₃₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, a substituted or unsubstituted heterocyclic group having 5 to 50 ring atoms, or a group represented by a formula (3A) below.

*-L₃₁ [symbol] L₃₂-R_{B})ₙ₃ (3A)

In the formula (3A):
R_{B} is a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms;
when a plurality of RB are present, the plurality of RB are mutually the same or different;
L₃₁ is a single bond, a substituted or unsubstituted arylene group having 6 to ring carbon atoms, a trivalent group, tetravalent group, pentavlent group, or hexavalent group derived from the arylene group, a substituted or unsubstituted divalent heterocyclic group having 5 to 50 ring atoms, a trivalent group, tetravalent group, pentavlent group, or hexavalent group derived from the heterocyclic group, a divalent group formed by bonding two groups selected from the group consisting of a substituted or unsubstituted arylene group having 6 to 50 ring carbon atoms and a substituted or unsubstituted divalent heterocyclic group having 5 to 50 ring atoms, or a trivalent group, tetravalent group, pentavlent group, or hexavalent group derived from the divalent group;
L₃₂ is a single bond, a substituted or unsubstituted arylene group having 6 to ring carbon atoms, or a substituted or unsubstituted divalent heterocyclic group having 5 to 50 ring atoms;
n₃ is 1; 2, 3, 4, or 5;
when L31 is a single bond, n₃ is 1 and L32 is bonded to a carbon atom in a six-membered ring in the formula (3);
when a plurality of L₃₂ are present, the plurality of L₃₂ are mutually the same or different; and
represents a bonding position to a carbon atom in a six-membered ring in the formula (3).

In a compound represented by the formula (3),
R₉₀₁, R₉₀₂, R₉₀₃, R₉₀₄, R₉₀₅, R₉₀₆, R₉₀₇, R₉₀₈, R₉₀₉, R₉₃₁, R₉₃₂, R₉₃₃, R₉₃₄, R₉₃₅, R₉₃₆, and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₀₈ are present, the plurality of R₉₀₈ are mutually the same or different;
when a plurality of R₉₀₉ are present, the plurality of R₉₀₉ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

A compound represented by the formula (3) is also preferably a compound represented by one of formulae (31) to (36) below.

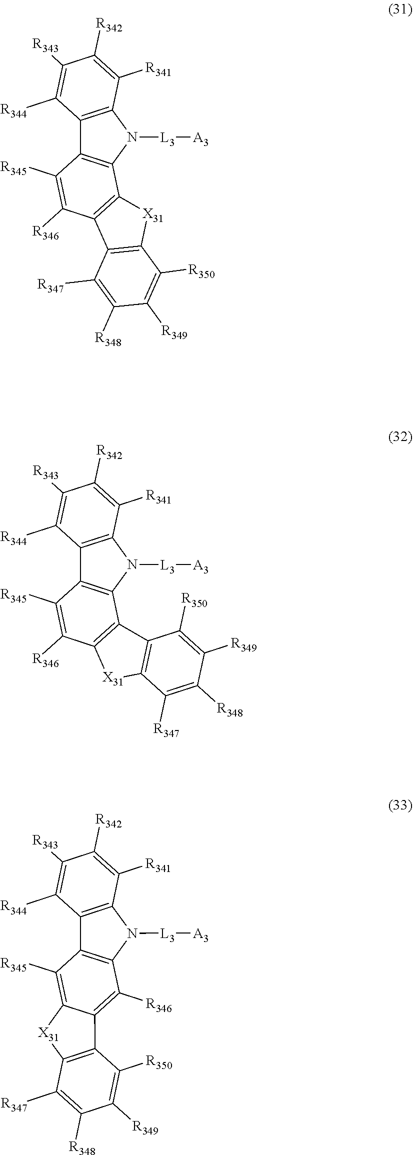

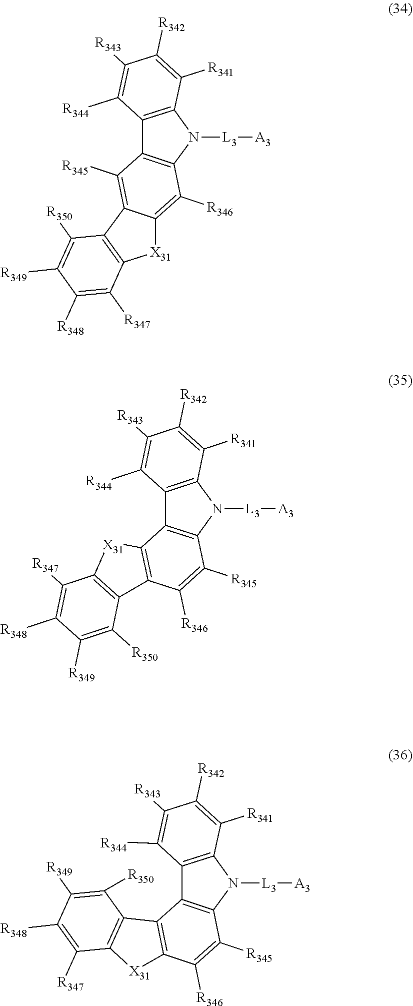

In the formulae (31) to (36):
A₃ and L₃ respectively represent the same as A₃ and L₃ in the formula (3);
at least one combination of adjacent two or more of R₃₄₁ to R₃₅₀ are mutually bonded to form a substituted or unsubstituted monocyclic ring, mutually bonded to form a substituted or unsubstituted fused ring, or not mutually bonded;
X₃₁ is a sulfur atom, an oxygen atom, NR₃₅₂, or CR₃₅₃R₃₅₄;
a combination of R₃₅₃ and R₃₅₄ are mutually bonded to form a substituted or unsubstituted monocyclic ring, mutually bonded to form a substituted or unsubstituted fused ring, or not mutually bonded; and
R₃₄₁ to R₃₅₀ forming neither the substituted or unsubstituted monocyclic ring nor the substituted or unsubstituted fused ring, R₃₅₂, and R₃₅₃ and R₃₅₄ forming neither the substituted or unsubstituted monocyclic ring nor the substituted or unsubstituted fused ring each independently represent the same as R₃₁ to R₃₈ forming neither the substituted or unsubstituted monocyclic ring nor the substituted or unsubstituted fused ring.

In a compound represented by the formula (3), R₃₅₂ is preferably a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In a compound represented by the formula (3), it is preferable that a combination of R₃₅₃ and R₃₅₄ are mutually bonded to form a substituted or unsubstituted monocyclic ring, mutually bonded to form a substituted or unsubstituted fused ring, or not mutually bonded;
R₃₅₃ and R₃₅₄ forming neither the substituted or unsubstituted monocyclic ring nor the substituted or unsubstituted fused ring are each independently a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In a compound represented by the formula (3), X₃₁ is preferably a sulfur atom or an oxygen atom.

In a compound represented by the formula (3), A3 is preferably a group represented by one of formulae (A31) to (A37) below.

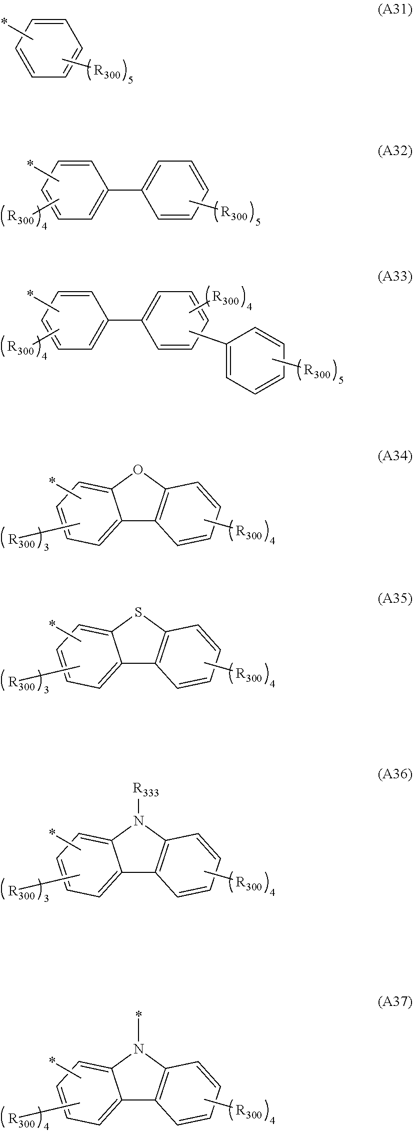

In the formulae (A31) to (A37):
at least one combination of adjacent two or more of a plurality of R₃₀₀ are mutually bonded to form a substituted or unsubstituted monocyclic ring, mutually bonded to form a substituted or unsubstituted fused ring, or not mutually bonded;
R₃₀₀ forming neither the substituted or unsubstituted monocyclic ring nor the substituted or unsubstituted fused ring, and R₃₃₃ each independently represent the same as R₃₁ to R₃₈ forming neither the substituted or unsubstituted monocyclic ring nor the substituted or unsubstituted fused ring; and
* in the formulae (A31) to (A37) each represents a bonding position to L3 in a compound represented by the formula (3).

In a compound represented by the formula (3), A3 is also preferably a group represented by the formula (A34), (A35), or (A37).

In a compound represented by the formula (3), A3 is preferably a group represented by one of formulae (A371) to (A376) below.

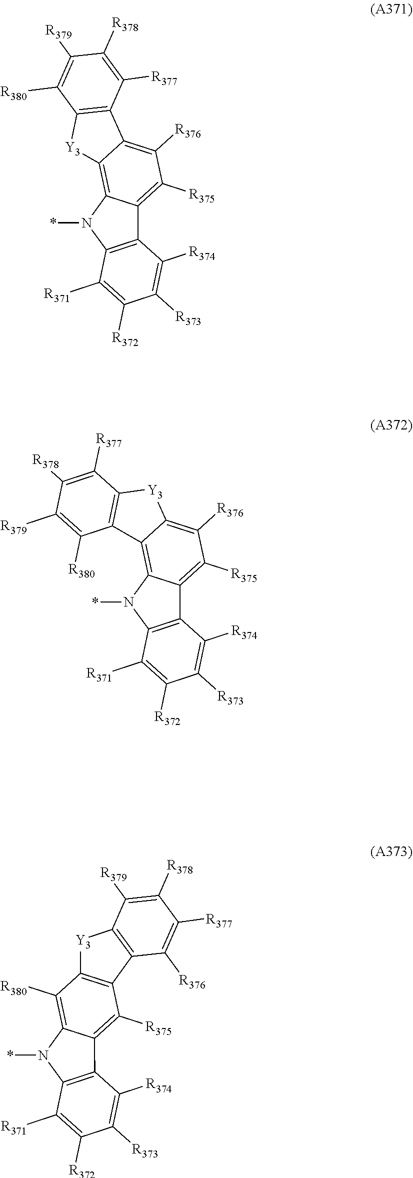

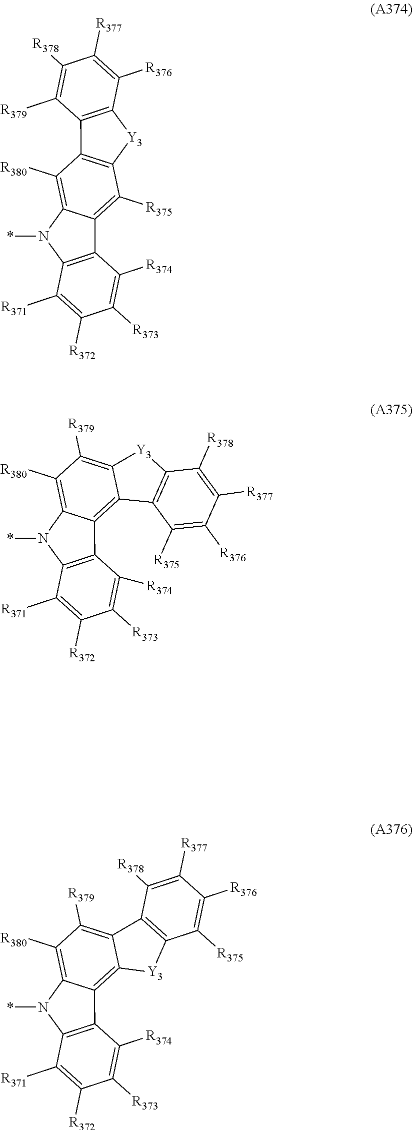

In the formulae (A371) to (A376):
Y₃ is a sulfur atom, an oxygen atom, N(R₃₈₁), or C(R₃₈₂)(R₃₈₃);
a combination of R₃₈₂ and R₃₈₃ are mutually bonded to form a substituted or unsubstituted monocyclic ring, mutually bonded to form a substituted or unsubstituted fused ring, or not mutually bonded;
at least one combination of adjacent two or more of R₃₇₁ to R₃₈₀ are mutually bonded to form a substituted or unsubstituted monocyclic ring, mutually bonded to form a substituted or unsubstituted fused ring, or not mutually bonded;
R₃₇₁ to R₃₈₀ forming neither the substituted or unsubstituted monocyclic ring nor the substituted or unsubstituted fused ring, R₃₈₂ and R₃₈₃ forming neither the substituted or unsubstituted monocyclic ring nor the substituted or unsubstituted fused ring, and R₃₈₁ each independently represent the same as R₃₁ to R₃₈ forming neither the substituted or unsubstituted monocyclic ring nor the substituted or unsubstituted fused ring; and
* in the formulae (A371) to (A376) each represents a bonding position to L3 in a compound represented by the formula (3).

In the formulae (A371) to (A376): R₃₈₁ is preferably a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the formulae (A371) to (A376): it is preferable that a combination of R₃₈₂ and R₃₈₃ are mutually bonded to form a substituted or unsubstituted monocyclic ring, mutually bonded to form a substituted or unsubstituted fused ring, or not mutually bonded;
R₃₈₂ and R₃₈₃ forming neither the substituted or unsubstituted monocyclic ring nor the substituted or unsubstituted fused ring are each independently a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In the formulae (A371) to (A376), Y₃ is preferably a sulfur atom or an oxygen atom.

A compound represented by the formula (3) is also preferably a compound represented by one of formulae (311) to (316) below.

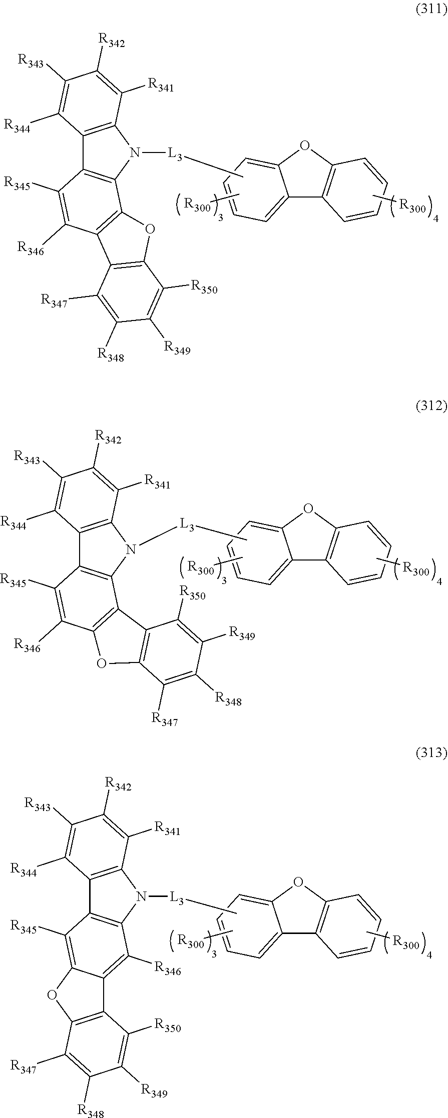

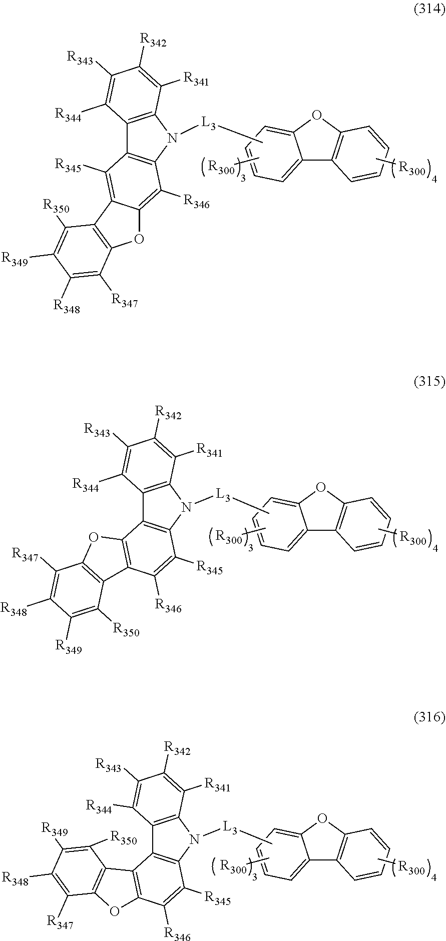

In the formulae (311) to (316):
L₃ represents the same as L3 in the formula (3);
at least one combination of adjacent two or more of a plurality of R₃₀₀ are mutually bonded to form a substituted or unsubstituted monocyclic ring, mutually bonded to form a substituted or unsubstituted fused ring, or not mutually bonded;
at least one combination of adjacent two or more of R₃₄₁ to R₃₅₀ are mutually bonded to form a substituted or unsubstituted monocyclic ring, mutually bonded to form a substituted or unsubstituted fused ring, or not mutually bonded;
R₃₀₀ forming neither the substituted or unsubstituted monocyclic ring nor the substituted or unsubstituted fused ring, and R₃₄₁ to R₃₅₀ forming neither the substituted or unsubstituted monocyclic ring nor the substituted or unsubstituted fused ring each independently represent the same as R₃₁ to R₃₈ forming neither the substituted or unsubstituted monocyclic ring nor the substituted or unsubstituted fused ring.

A compound represented by the formula (3) is also preferably a compound represented by a formula (321) below.

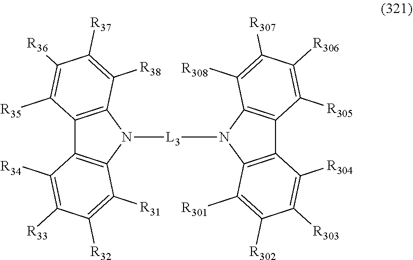

In the formula (321):
L3 represents the same as L3 in the formula (3); and
R₃₁ to R₃₈ and R₃₀₁ to R₃₀₈ each independently represent the same as R₃₁ to R₃₈ forming neither the substituted or unsubstituted monocyclic ring nor the substituted or unsubstituted fused ring.

In a compound represented by the formula (3), L3 is preferably a single bond or a substituted or unsubstituted arylene group having 6 to 50 ring carbon atoms.

In a compound represented by the formula (3), L3 is preferably a single bond, a substituted or unsubstituted phenylene group, a substituted or unsubstituted biphenylene group, or a substituted or unsubstituted terphenylene group. In a compound represented by the formula (3), L3 is preferably a group represented by a formula (317) below.

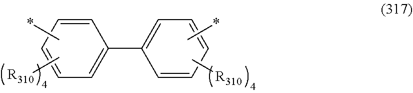

In the formula (317):
R₃₁₀ each independently represents the same as R₃₁ to R₃₈ forming neither the substituted or unsubstituted monocyclic ring nor the substituted or unsubstituted fused ring, and * each independently represents a bonding position.

In a compound represented by the formula (3), L3 also preferably contains a divalent group represented by a formula (318) or (319) below.

In a compound represented by the formula (3), L3 is also preferably a divalent group represented by the formula (318) or (319) below.

A compound represented by the formula (3) is also preferably a compound represented by a formula (323) or (323) below.

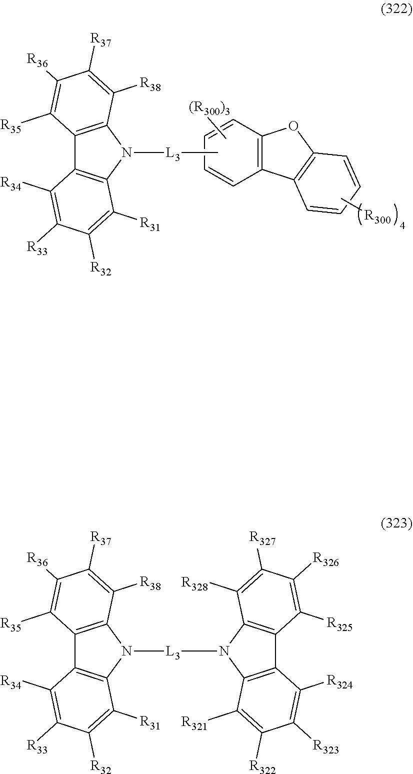

In the formulae (322) and (323):
L31 is a substituted or unsubstituted arylene group having 6 to 50 ring carbon atoms, a substituted or unsubstituted divalent heterocyclic group having 5 to 50 ring atoms, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms;
L31 contains a divalent group represented by the formula (318) or (319); and
R₃₁ to R₃₆, R₃₀₀, and R₃₂₁ to R₃₂₈ each independently represent the same as R₃₁ to R₃₈ forming neither the substituted or unsubstituted monocyclic ring nor the substituted or unsubstituted fused ring.

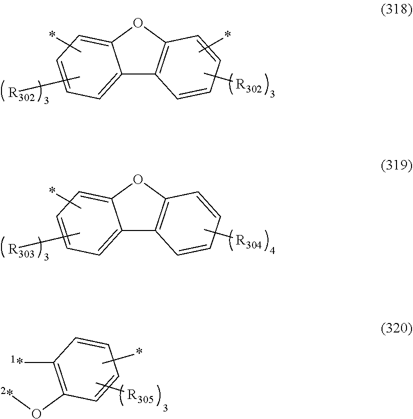

In the formula (319):
a combination of adjacent two of a plurality of R₃₀₄ are mutually bonded to form a ring represented by the formula (320).

In the formulae (320), 1* and 2* each independently represent a bonding position to a ring bonded to R₃₀₄.
R₃₀₂ in the formula (318), R₃₀₃ in the formula (319), R₃₀₄ not forming a ring represented by the formula (320), and R₃₀₅ in the formula (320) each independently represent the same as R₃₁ to R₃₈ forming neither the substituted or unsubstituted monocyclic ring nor the substituted or unsubstituted fused ring.
* in the formulae (318) to (320) each independently represent a bonding position.

In a compound represented by the formula (3), a group represented by the formula (319) for L₃ or L₃₁ is, for instance, a group represented by a formula (319A) below.

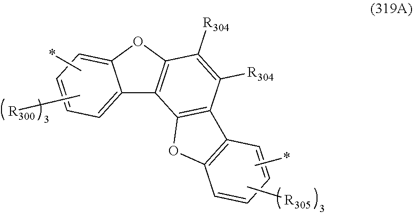

In the formula (319A), R₃₀₃, R₃₀₄, and R₃₀₅ each independently represent the same as R₃₁ to R₃₈ forming neither the substituted or unsubstituted monocyclic ring nor the substituted or unsubstituted fused ring, and * each independently represents a bonding position.

It is also preferable that a compound represented by the formula (3) is a compound represented by the formula (322) and L31 is a group represented by the formula (318).

A compound represented by the formula (3) is also preferably a compound represented by a formula (324) below.

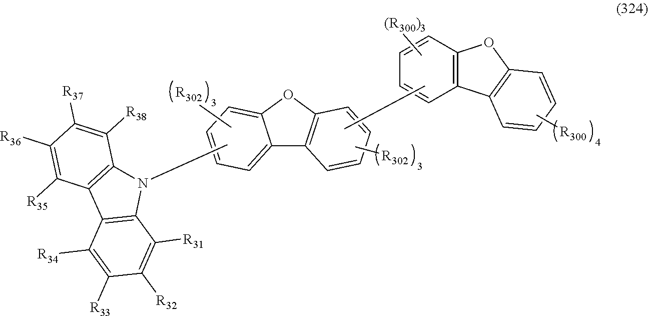

In the formula (324), R₃₁ to R₃₈, R₃₀₀ and R₃₀₂ each independently represent the same as R₃₁ to R₃₈ forming neither the substituted or unsubstituted monocyclic ring nor the substituted or unsubstituted fused ring.

In a compound represented by the formula (3), it is preferable that R₃₁ to R₃₈ forming neither the substituted or unsubstituted monocyclic ring nor the substituted or unsubstituted fused ring each independently represent a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by the formula (3A), in which RB in the formula (3A) is a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In a compound represented by the formula (3), it is preferable that R₃₁ to R₃₈ forming neither the substituted or unsubstituted monocyclic ring nor the substituted or unsubstituted fused ring are each independently a hydrogen atom, a substituted or unsubstituted aryl group having 6 to 50 ring carbon atoms, or a group represented by the formula (3A), in which RB in the formula (3A) is a substituted or unsubstituted aryl group having 6 to 50 ring carbon atoms.

In a compound represented by the formula (3), it is preferable that R₃₁ to R₃₈ forming neither the substituted or unsubstituted monocyclic ring nor the substituted or unsubstituted fused ring are each independently a hydrogen atom, a substituted or unsubstituted phenyl group, or a group represented by the formula (3A), in which R_{B} in the formula (3A) is a substituted or unsubstituted phenyl group.

A compound represented by the formula (3) is also preferably a compound not having a pyridine ring, a pyrimidine ring, and a triazine ring.

### Compound Represented by Formula (3B)

In the emitting layer of the organic EL device according to the exemplary embodiment, the compound M3 is also preferably a compound represented by a formula (3B) below.

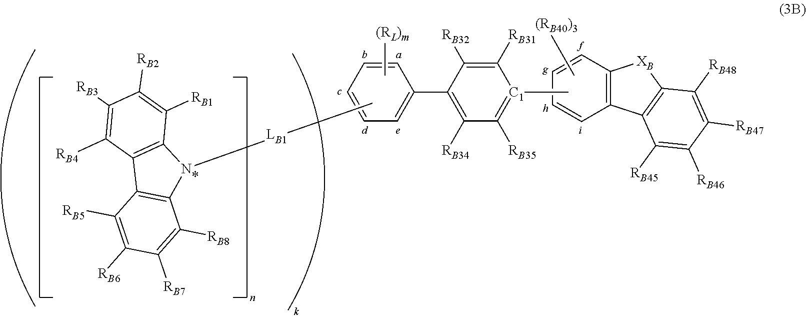

In the formula (3B):
X_{B} is an oxygen atom or a sulfur atom;
C₁ is a carbon atom;
n is 1, 2, or 3; k is 1, 2, or 3;
m is 2, 3, or 4; k+m=5 is satisfied;
when m is 2 or more, a plurality of R_{L} are mutually the same or different;
at least one combination of adjacent two or more of R_{B1} to R_{B8} are mutually bonded to form a substituted or unsubstituted monocyclic ring, mutually bonded to form a substituted or unsubstituted fused ring, or not mutually bonded;
when at least one of n or k is 2 or more, a plurality of R_{B1} are mutually the same or different, a plurality of R_{B2} are mutually the same or different, a plurality of R_{B3} are mutually the same or different, a plurality of R_{B4} are mutually the same or different, a plurality of R_{B5} are mutually the same or different, a plurality of R_{B6} are mutually the same or different, a plurality of R_{B7} are mutually the same or different, and a plurality of R_{B8} are mutually the same or different;
L_{B1} is a single bond, or a linking group; when L_{B1} is a single bond, n is 1,
when k is 2 or more, a plurality of L_{B1} are mutually the same or different;
L_{B1} as a linking group is a group derived from a substituted or unsubstituted aryl group having 6 to 30 ring carbon atoms, a group derived from a substituted or unsubstituted heterocyclic group having 5 to 30 ring atoms, or a group formed by bonding two groups selected from the group consisting of a group derived from a substituted or unsubstituted aryl group having 6 to 30 ring carbon atoms and a group derived from a substituted or unsubstituted heterocyclic group having 5 to 30 ring atoms;
when k is 1 and m is 4, four R_{L} are respectively bonded to carbon atoms at any ones of positions of a, b, c, d and e shown in the formula (3B), and one L_{B1} is bonded to a carbon atom at a position of one of a, b, c, d and e which is not bonded to R_{L};
when k is 2 and m is 3, three R_{L} are respectively bonded to carbon atoms at any ones of positions of a, b, c, d and e shown in the formula (3B), and two L_{B1} are respectively bonded to carbon atoms at any ones of positions of a, b, c, d and e which are not bonded to R_{L};
when k is 3 and m is 2, two R_{L} are respectively bonded to carbon atoms at any ones of positions of a, b, c, d and e shown in the formula (3B), and three L_{B1} are respectively bonded to carbon atoms at any ones of positions of a, b, c, d and e which are not bonded to R_{L};
at least one combination of adjacent two or more of R B₄₀ and R_{B45} to R B₄₈ are mutually bonded to form a substituted or unsubstituted monocyclic ring, mutually bonded to form a substituted or unsubstituted fused ring, or not mutually bonded; three R_{B40} are mutually the same or different, three R_{B40} are respectively bonded to carbon atoms at any ones of positions of f, g, h, and i shown in the formula (3B), and C₁ is bonded to a carbon atom at a position of one of f, g, h, and i which is not bonded to R_{B40};
R_{L}, R_{B31}, R_{B32}, R_{B34}, and R_{B35} as well as R_{B1} to R_{B8} forming neither the substituted or unsubstituted monocyclic ring nor the substituted or unsubstituted fused ring, and R_{B40} and R_{B45} to R_{B48} forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₅, a group represented by —COOR₉₀₉, a halogen atom, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms.

In a compound represented by the formula (3B), R₉₀₁ to R₉₀₉ and R₉₃₁ to R₉₃₇ respectively represent the same as R₉₀₁ to R₉₀₉ and R₉₃₁ to R₉₃₇ in the formula (3).

In compound represented by the formula (3B), when n is 2, or 3, each nitrogen atom N* in a structure in parentheses with subscript n is bonded to L_{B1}.

In a compound represented by the formula (3B), when L_{B1} is a single bond, a nitrogen atom N* in a structure in parentheses with subscript n is bonded to a carbon atom at one of positions a, b, c, d, and e.

In a compound represented by the formula (3B), when k is 2 or 3, each L_{B1} in a structure in parentheses with subscript k is bonded to a carbon atom at one of the positions a, b, c, d, and e.

For instance, in a compound represented by the formula (3B), when n is 2 and k is 1, when L_{B1} is bonded to a carbon atom at the position c, and when a carbon atom C₁ is bonded to a carbon atom at a position h, the compound represented by the formula (3B) is represented by a formula (31B) below.

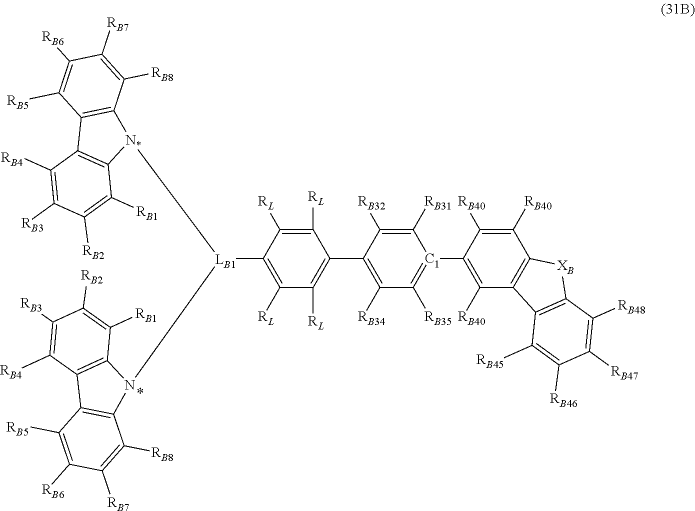

In a compound represented by the formula (31B), RBI to R_{B6}, R_{L}, R_{B31}, R_{B32}, R_{B34}, R_{B35}, R_{B40}, R_{B45} to R_{B48}, L_{B1}, and X₆ are each defined as in the formula (3B).

For instance, in a compound represented by the formula (3B), when L_{B1} is a single bond, when n is 2, when one of two nitrogen atoms N* in a structure in parentheses with subscript n is bonded to a carbon atom at the position b and the other of the two nitrogen atoms N* is bonded to a carbon atom at the position b, and when a carbon atom C₁ is bonded to a carbon atom at the position h, the compound represented by the formula (3B) is represented by a formula (32B) below.

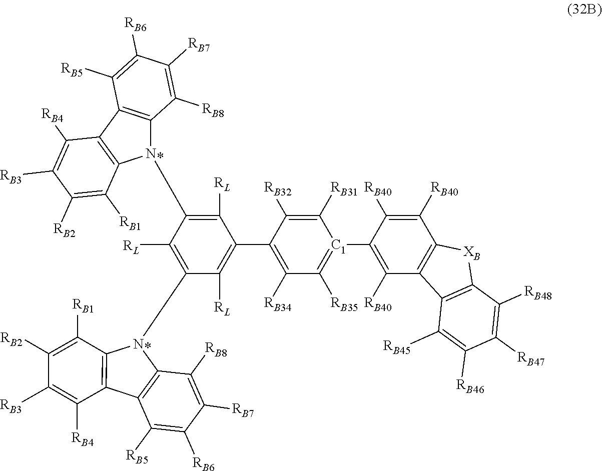

In the formula (32B), R_{B1} to R_{B8}, R_{L}, R_{B31}, R_{B32}, R_{B34}, R_{B35}, R_{B40}, R_{B45} to R_{B48}, and X₆ are each defined as in the formula (3B).

### Compound Represented by Formula (MRX3)

In the emitting layer of the organic EL device according to the exemplary embodiment, the compound M3 is also preferably a compound represented by a formula (MRX3) below.

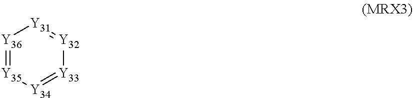

In the formula (MRX3):
Y₃₁ to Y₃₆ are each independently CR₃ or a nitrogen atom;
two or more of Y₃₁ to Y₃₆ are each a nitrogen atom;
when a plurality of R₃ are present, at least one combination of adjacent two or more of the plurality of R₃ are mutually bonded to form a substituted or unsubstituted monocyclic ring, mutually bonded to form a substituted or unsubstituted fused ring, or not mutually bonded;
R₃ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, a substituted or unsubstituted heterocyclic group having 5 to 50 ring atoms, or a group represented by a formula (MRX3A) below.

*-L₃₁ [symbol] L₃₂-R_{B})ₙ₃ (MRX3A)

In the formula (MRX3A):
R_{B} represents the same as R_{B} in the formula (3);
when a plurality of R_{B} are present, the plurality of R_{B} are mutually the same or different;
L₃₁ and L₃₂ respectively represent the same as L31 and L32 in the formula (3);
n₃ is 1, 2, 3, 4, or 5;
when L₃₁ is a single bond, n₃ is 1 and L₃₂ is bonded to a carbon atom in a six-membered ring in the formula (MRX3);
when a plurality of L32 are present, the plurality of L32 are mutually the same or different; and

* represents a bonding position to a carbon atom in a six-membered ring in the formula (MRX3).

In a compound represented by the formula (MRX3), R₉₀₁ to R₉₀₉ and R₉₃₁ to R₉₃₇ respectively represent the same as R₉₀₁ to R₉₀₉ and R₉₃₁ to R₉₃₇ in the formula (3).

A compound represented by the formula (MRX3) preferably does not include a pyridine ring in a molecule.

A compound represented by the formula (MRX3) is also preferably a compound represented by a formula (MRX31) or (MRX32) below.

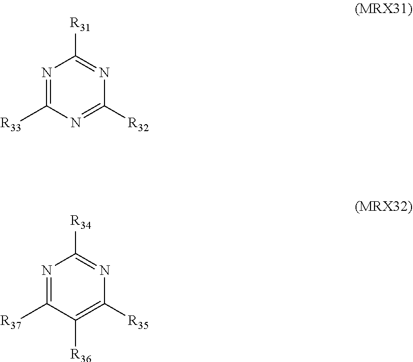

In the formula (MRX32):
at least one combination of adjacent two or more of R₃₅ to R₃₇ are mutually bonded to form a substituted or unsubstituted monocyclic ring, mutually bonded to form a substituted or unsubstituted fused ring, or not mutually bonded; and
R₃₁ to R₃₃ in the formula (MRX31), R₃₄ in the formula (MRX32), and R₃₅ to R₃₇ forming neither the substituted or unsubstituted monocyclic ring nor the substituted or unsubstituted fused ring each independently represent the same as R₃ in the formula (MRX3).

A compound represented by the formula (MRX3) is also preferably a compound represented by the formula (MRX31).

R₃ in the formula (MRX3) is preferably each independently a hydrogen atom, a substituted or unsubstituted alkyl group having 1 to 50 carbon atoms, a substituted or unsubstituted aryl group having 6 to 50 ring carbon atoms, a substituted or unsubstituted heterocyclic group having 5 to 50 ring atoms, or a group represented by the formula (MRX3A).

R₃ in the formula (MRX3) is preferably each independently a hydrogen atom, a substituted or unsubstituted alkyl group having 1 to 50 carbon atoms, a substituted or unsubstituted aryl group having 6 to 50 ring carbon atoms, or a group represented by the formula (MRX3A).

A compound represented by the formula (MRX3) preferably has at least one group selected from the group consisting of groups represented by formulae (MRXA31) to (MRXA44) below in a molecule.

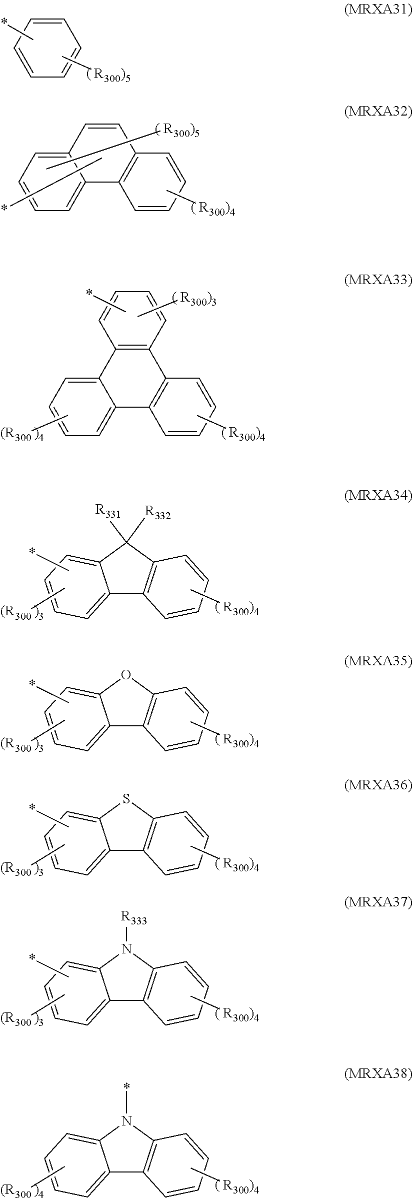

In the formulae (MRXA31) to (MRKA38):
at least one combination of adjacent two or more of a plurality of R₃₀₀ are mutually bonded to form a substituted or unsubstituted monocyclic ring, mutually bonded to form a substituted or unsubstituted fused ring, or not mutually bonded;
a combination of R₃₃₁ and R₃₃₂ are mutually bonded to form a substituted or unsubstituted monocyclic ring, mutually bonded to form a substituted or unsubstituted fused ring, or not mutually bonded;
R₃₀₀, R₃₃₁, and R₃₃₂ forming neither the substituted or unsubstituted monocyclic ring nor the substituted or unsubstituted fused ring, and R₃₃₃ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a substituted or unsubstituted aryl group having 6 to 50 ring carbon atoms, or a substituted or unsubstituted heterocyclic group having 5 to 50 ring atoms; and
* in the formulae (MRXA31) to (MRXA38) each represents a bonding position to another atom in a molecule of a compound represented by the formula (MRX3).

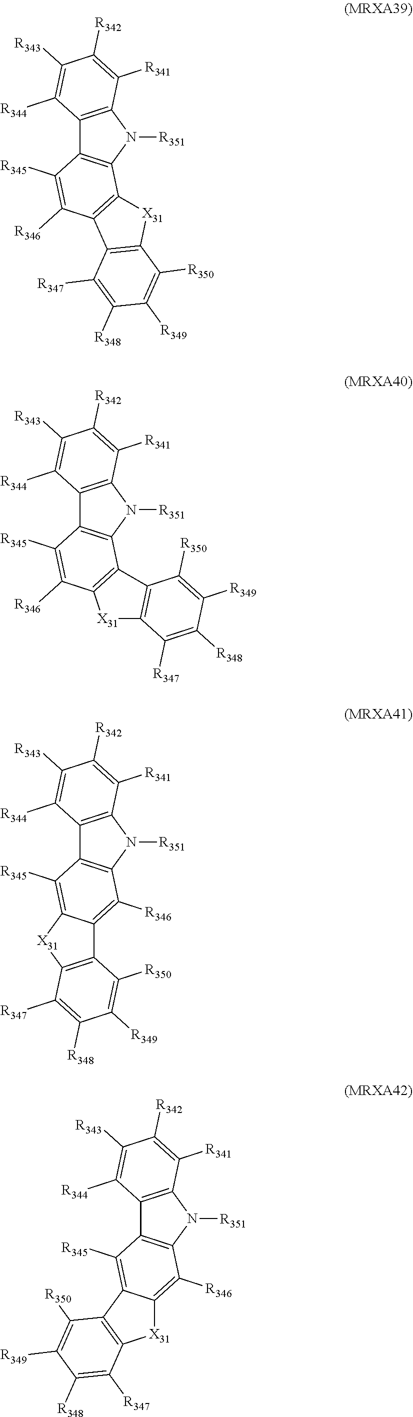

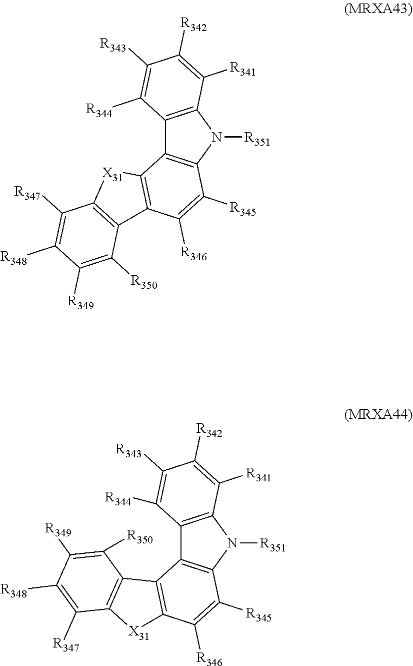

In the formulae (MRXA39) to (MRXA44):
at least one combination of adjacent two or more of R₃₄₁ to R₃₅₀ are mutually bonded to form a substituted or unsubstituted monocyclic ring, mutually bonded to form a substituted or unsubstituted fused ring, or not mutually bonded;
at least one of R₃₄₁ to R₃₅₁ represents a bonding position to another atom in a molecule of a compound represented by the formula (MRX3);
X₃₁ is a sulfur atom, an oxygen atom, NR₃₅₂, or CR₃₅₃R₃₅₄:
a combination of R₃₅₃ and R₃₅₄ are mutually bonded to form a substituted or unsubstituted monocyclic ring, mutually bonded to form a substituted or unsubstituted fused ring, or not mutually bonded;
R₃₄₁ to R₃₅₁ not being a bonding position to another atom in a molecule of a compound represented by the formula (MRX3) and forming neither the substituted or unsubstituted monocyclic ring nor the substituted or unsubstituted fused ring, R₃₅₃ and R₃₅₄ forming neither the substituted or unsubstituted monocyclic ring nor the substituted or unsubstituted fused ring, and R₃₅₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₅)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a substituted or unsubstituted aryl group having 6 to 50 ring carbon atoms, or a substituted or unsubstituted heterocyclic group having 5 to 50 ring atoms.

A group represented by the formula (MRX3) preferably has, in a molecule, at least one group selected from the group consisting of groups represented by the formulae (MRXA38) to (MRXA44).

In a compound represented by the formula (MRX3), it is preferable that at least one of Y₃₁ to Y₃₆ is CR₃, at least one R₃ is a group represented by the formula (MRX3A), and R_{B} is a group represented by one of the formulae (MRXA31) to (MRXA44).

In a compound represented by the formula (MRX3), it is preferable that at least one of Y₃₁ to Y₃₆ is CR₃, at least one R₃ is a group represented by the formula (MRX3A), and R_{B} is a group represented by one of the formulae (MRXA38) to (MRXA44).

In a compound represented by the formula (MRX3), it is preferable that R₃₅₂ is a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In a compound represented by the formula (MRX3), it is preferable that a combination of R₃₅₃ and R₃₅₄ are mutually bonded to form a substituted or unsubstituted monocyclic ring, mutually bonded to form a substituted or unsubstituted fused ring, or not mutually bonded; and
R₃₅₃ and R₃₅₄ forming neither the substituted or unsubstituted monocyclic ring nor the substituted or unsubstituted fused ring are each independently a substituted or unsubstituted alkyl group having 1 to 50 carbon atoms, a substituted or unsubstituted aryl group having 6 to 50 ring carbon atoms, or a substituted or unsubstituted heterocyclic group having 5 to 50 ring atoms.

In a compound represented by the formula (3) and a compound represented by the formula (MRX3), it is preferable that L31 is a single bond, a substituted or unsubstituted arylene group having 6 to 50 ring carbon atoms, a trivalent group, tetravalent group, pentavlent group, or hexavalent group derived from the arylene group, or a divalent group formed by bonding two groups selected from the group consisting of a substituted or unsubstituted arylene group having 6 to 50 ring carbon atoms, or a trivalent group, tetravalent group, pentavlent group, or hexavalent group derived from the divalent group; and
L₃₂ is a single bond or a substituted or unsubstituted arylene group having 6 to 50 ring carbon atoms.

In a compound represented by the formula (3) and a compound represented by the formula (MRX3), it is preferable that L3 is a single bond or a substituted or unsubstituted arylene group having 6 to 50 ring carbon atoms, n3 is 1, and L32 is a single bond or a substituted or unsubstituted arylene group having 6 to 50 ring carbon atoms.

In a compound represented by the formula (3) and a compound represented by the formula (MRX3), it is preferable that L31 is a single bond, a substituted or unsubstituted phenylene group, a substituted or unsubstituted biphenylene group, or a divalent group formed by bonding two groups selected from the group consisting of a substituted or unsubstituted phenylene group and a substituted or unsubstituted biphenylene group, or a trivalent group, tetravalent group, pentavlent group, or hexavalent group derived from the divalent group;
n₃ is 1; and
L₃₂ is a single bond, a substituted or unsubstituted phenylene group, or a substituted or unsubstituted biphenylene group.

In a compound represented by the formula (3), a compound represented by the formula (3B), and a compound represented by the formula (MRX3), it is preferable that the substituent for “the substituted or unsubstituted” group is an unsubstituted alkyl group having 1 to 25 carbon atoms, an unsubstituted alkenyl group having 2 to carbon atoms, an unsubstituted alkynyl group having 2 to 25 carbon atoms, an unsubstituted cycloalkyl group having 3 to 25 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), an unsubstituted aralkyl group having 7 to 50 carbon atoms, a group represented by —C(═O)R₉₀₈, a group represented by —COOR₉₀₉, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a group represented by —S(═O)₂R₉₃₈, a halogen atom, a cyano group, a nitro group, an unsubstituted aryl group having 6 to 25 ring carbon atoms, or an unsubstituted heterocyclic group having 5 to 25 ring atoms;
R₉₀₁ to R₉₀₉ and R₉₃₁ to R₉₃₈ are preferably each independently a hydrogen atom, an unsubstituted alkyl group having 1 to 25 carbon atoms, an unsubstituted aryl group having 6 to 25 ring carbon atoms, or an unsubstituted heterocyclic group having 5 to 25 ring atoms.

In a compound represented by the formula (3), a compound represented by the formula (3B), and a compound represented by the formula (MRX3), it is preferable that the substituent for the substituted or unsubstituted” group is a halogen atom, an unsubstituted alkyl group having 1 to 25 carbon atoms, an unsubstituted aryl group having 6 to 25 ring carbon atoms, or an unsubstituted heterocyclic group having 5 to ring atoms.

In a compound represented by the formula (3), a compound represented by the formula (3B), and a compound represented by the formula (MRX3), it is preferable that the substituent for “the substituted or unsubstituted” group is an unsubstituted alkyl group having 1 to 10 carbon atoms, an unsubstituted aryl group having 6 to 12 ring carbon atoms, or an unsubstituted heterocyclic group having 5 to 12 ring atoms.

In a compound represented by the formula (3), a compound represented by the formula (3B), and a compound represented by the formula (MRX3), it is also preferable that the groups specified to be “the substituted or unsubstituted” are each an “unsubstituted” group.

### Producing Method of Compound M3

The compound M3 of the exemplary embodiment can be produced by a known method.

### Specific Examples of Compound M3

Specific examples of the compound M3 in the exemplary embodiment include compounds below. However, the invention is by no means limited to the specifically listed compounds.

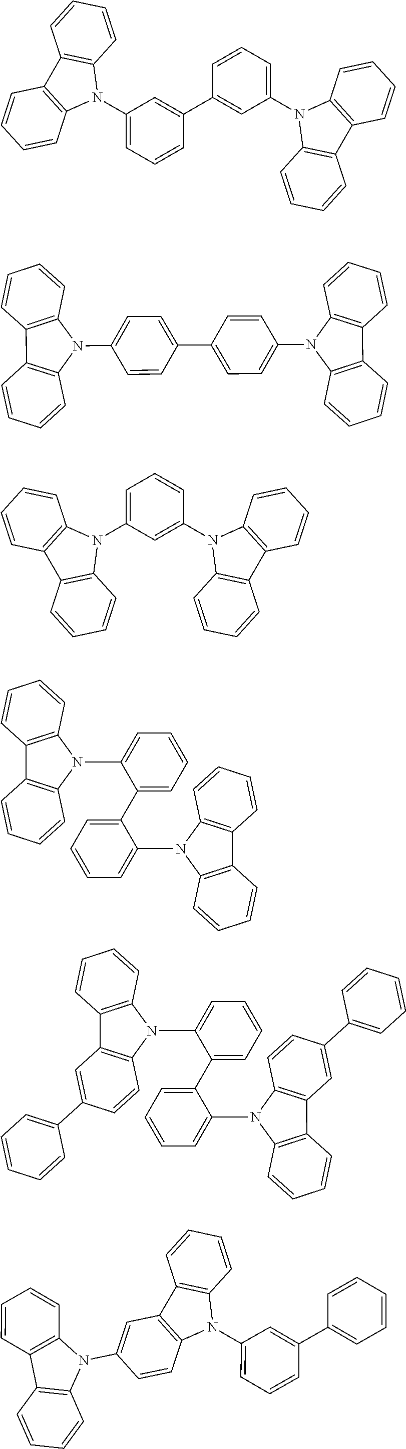 [SMILES: c1cc(-c2cccc(-n3c4ccccc4c4ccccc43)c2)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc(-c2ccc3c(c2)c2ccccc2n3-c2ccccc2-c2ccccc2-n2c3ccccc3c3cc(-c4ccccc4)ccc32)cc1 ; c1ccc(-c2cccc(-n3c4ccccc4c4cc(-n5c6ccccc6c6ccccc65)ccc43)c2)cc1]

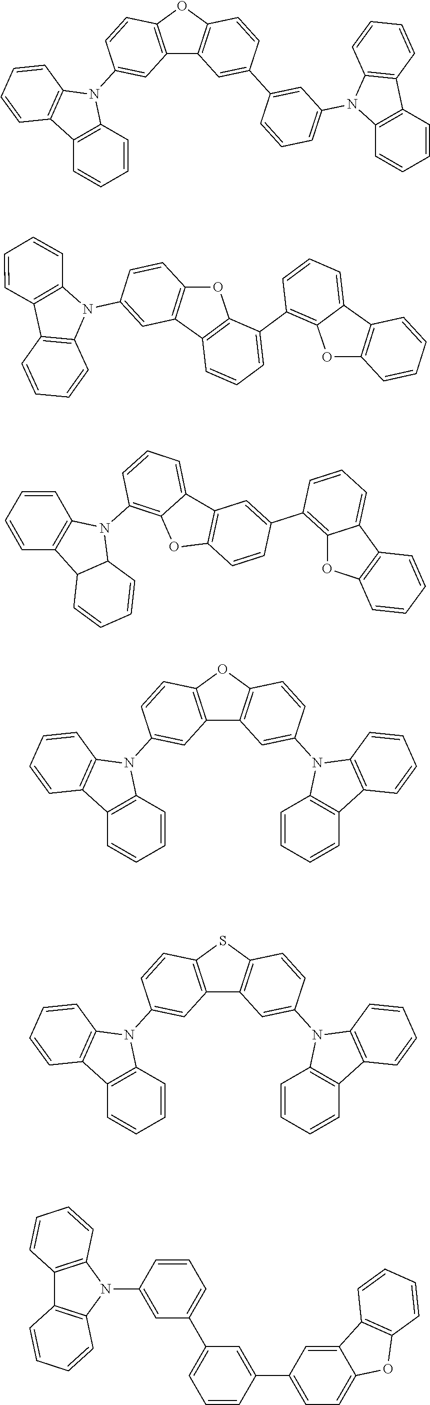 [SMILES: c1cc(-c2ccc3oc4ccc(-n5c6ccccc6c6ccccc65)cc4c3c2)cc(-n2c3ccccc3c3ccccc32)c1 ; c1ccc2c(c1)oc1c(-c3cccc4c3oc3ccc(-n5c6ccccc6c6ccccc65)cc34)cccc12 ; C1=CC2c3ccccc3N(c3cccc4c3oc3ccc(-c5cccc6c5oc5ccccc56)cc34)C2C=C1 ; c1ccc2c(c1)c1ccccc1n2-c1ccc2oc3ccc(-n4c5ccccc5c5ccccc54)cc3c2c1 ; c1ccc2c(c1)c1ccccc1n2-c1ccc2sc3ccc(-n4c5ccccc5c5ccccc54)cc3c2c1 ; c1cc(-c2cccc(-n3c4ccccc4c4ccccc43)c2)cc(-c2ccc3oc4ccccc4c3c2)c1]

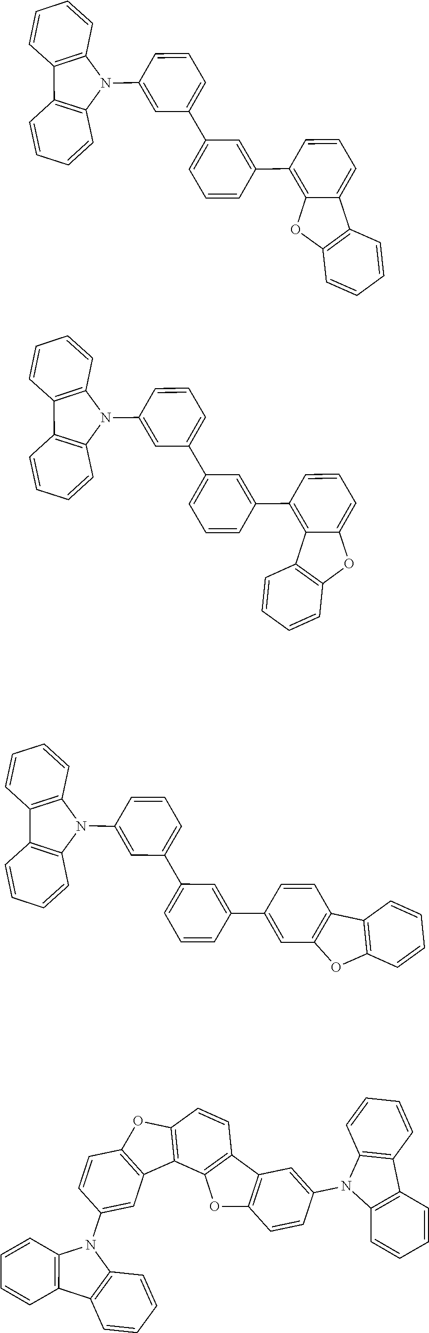 [SMILES: c1cc(-c2cccc(-n3c4ccccc4c4ccccc43)c2)cc(-c2cccc3c2oc2ccccc23)c1 ; c1cc(-c2cccc(-n3c4ccccc4c4ccccc43)c2)cc(-c2cccc3oc4ccccc4c23)c1 ; c1cc(-c2cccc(-n3c4ccccc4c4ccccc43)c2)cc(-c2ccc3c(c2)oc2ccccc23)c1 ; c1ccc2c(c1)c1ccccc1n2-c1ccc2oc3c(ccc4oc5ccc(-n6c7ccccc7c7ccccc76)cc5c43)c2c1]

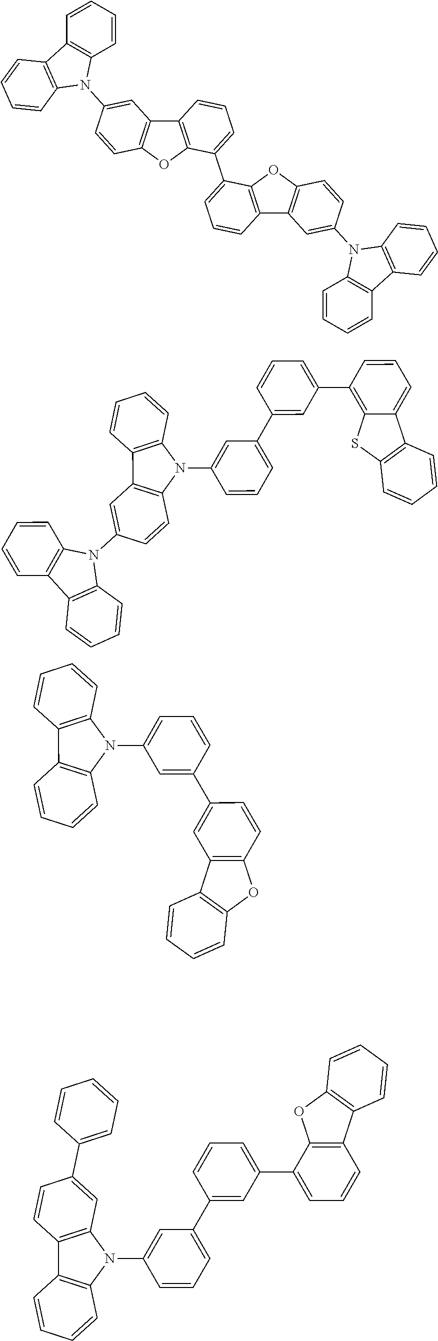

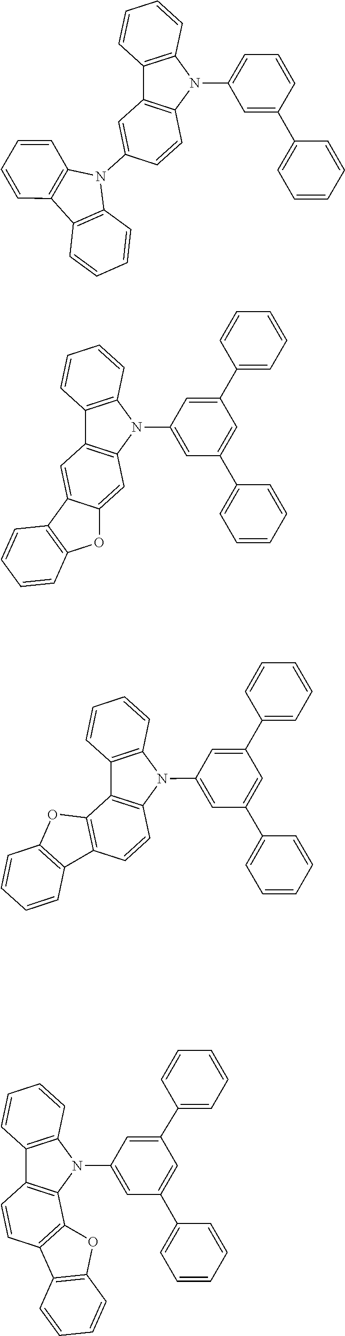 [SMILES: c1ccc(-c2cccc(-n3c4ccccc4c4cc(-n5c6ccccc6c6ccccc65)ccc43)c2)cc1 ; c1ccc(-c2cc(-c3ccccc3)cc(-n3c4ccccc4c4cc5c(cc43)oc3ccccc35)c2)cc1 ; c1ccc(-c2cc(-c3ccccc3)cc(-n3c4ccccc4c4c5oc6ccccc6c5ccc43)c2)cc1 ; c1ccc(-c2cc(-c3ccccc3)cc(-n3c4ccccc4c4ccc5c6ccccc6oc5c43)c2)cc1]

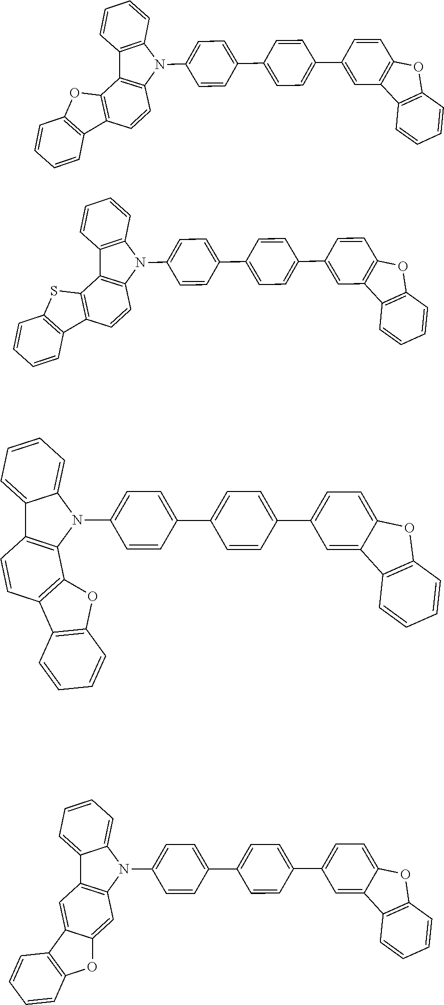 [SMILES: c1ccc2c(c1)oc1ccc(-c3ccc(-c4ccc(-n5c6ccccc6c6c7oc8ccccc8c7ccc65)cc4)cc3)cc12 ; c1ccc2c(c1)oc1ccc(-c3ccc(-c4ccc(-n5c6ccccc6c6c7sc8ccccc8c7ccc65)cc4)cc3)cc12 ; c1ccc2c(c1)oc1ccc(-c3ccc(-c4ccc(-n5c6ccccc6c6ccc7c8ccccc8oc7c65)cc4)cc3)cc12 ; c1ccc2c(c1)oc1ccc(-c3ccc(-c4ccc(-n5c6ccccc6c6cc7c(cc65)oc5ccccc57)cc4)cc3)cc12]

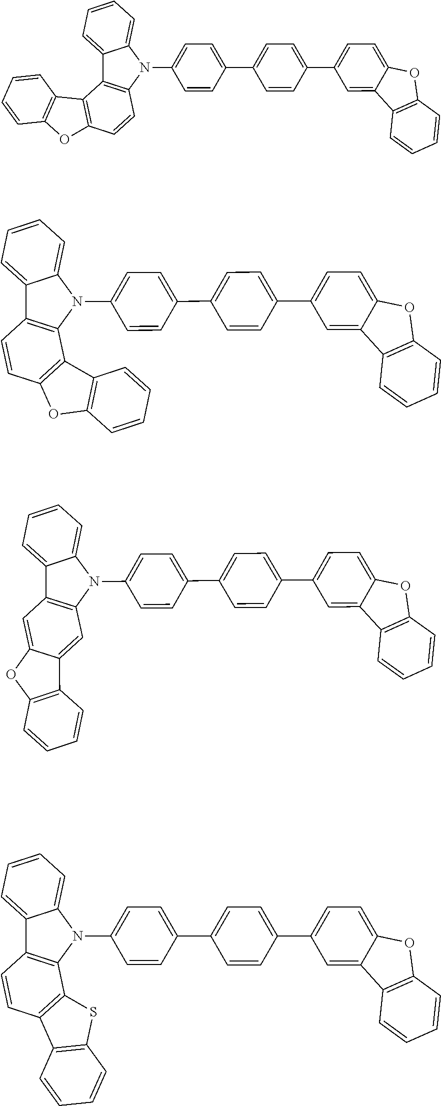 [SMILES: c1ccc2c(c1)oc1ccc(-c3ccc(-c4ccc(-n5c6ccccc6c6c7c(ccc65)oc5ccccc57)cc4)cc3)cc12 ; c1ccc2c(c1)oc1ccc(-c3ccc(-c4ccc(-n5c6ccccc6c6ccc7oc8ccccc8c7c65)cc4)cc3)cc12 ; c1ccc2c(c1)oc1ccc(-c3ccc(-c4ccc(-n5c6ccccc6c6cc7oc8ccccc8c7cc65)cc4)cc3)cc12 ; c1ccc2c(c1)oc1ccc(-c3ccc(-c4ccc(-n5c6ccccc6c6ccc7c8ccccc8sc7c65)cc4)cc3)cc12]

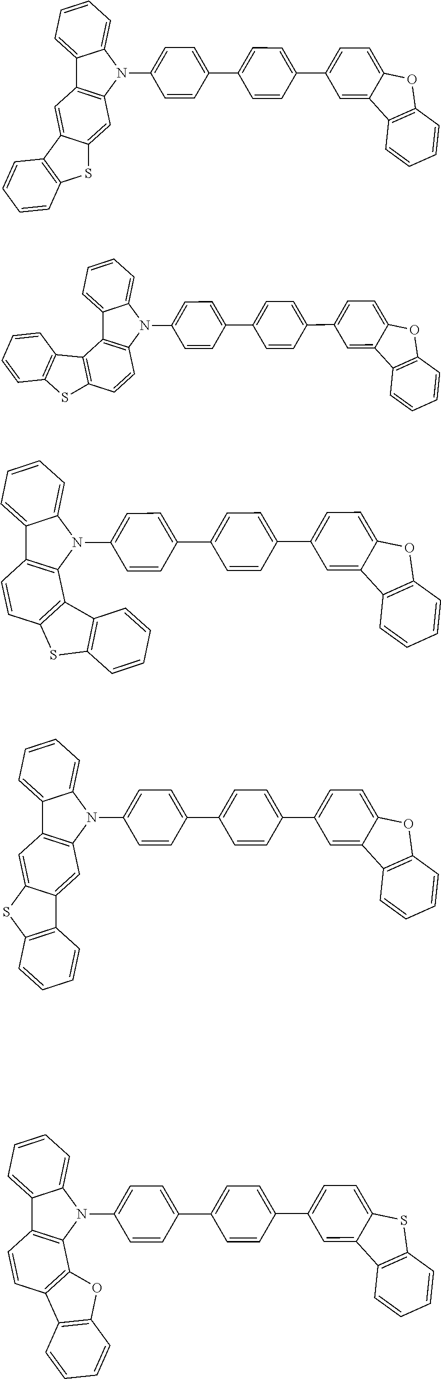 [SMILES: c1ccc2c(c1)oc1ccc(-c3ccc(-c4ccc(-n5c6ccccc6c6cc7c(cc65)sc5ccccc57)cc4)cc3)cc12 ; c1ccc2c(c1)oc1ccc(-c3ccc(-c4ccc(-n5c6ccccc6c6c7c(ccc65)sc5ccccc57)cc4)cc3)cc12 ; c1ccc2c(c1)oc1ccc(-c3ccc(-c4ccc(-n5c6ccccc6c6ccc7sc8ccccc8c7c65)cc4)cc3)cc12 ; c1ccc2c(c1)oc1ccc(-c3ccc(-c4ccc(-n5c6ccccc6c6cc7sc8ccccc8c7cc65)cc4)cc3)cc12 ; c1ccc2c(c1)oc1c2ccc2c3ccccc3n(-c3ccc(-c4ccc(-c5ccc6sc7ccccc7c6c5)cc4)cc3)c21]

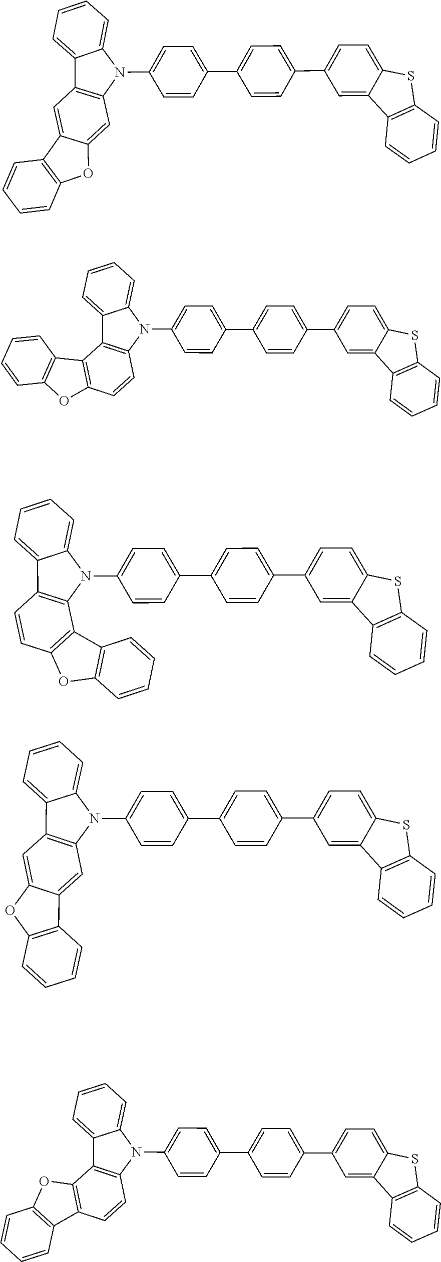 [SMILES: c1ccc2c(c1)oc1cc3c(cc12)c1ccccc1n3-c1ccc(-c2ccc(-c3ccc4sc5ccccc5c4c3)cc2)cc1 ; c1ccc2c(c1)oc1ccc3c(c4ccccc4n3-c3ccc(-c4ccc(-c5ccc6sc7ccccc7c6c5)cc4)cc3)c12 ; c1ccc2c(c1)oc1ccc3c4ccccc4n(-c4ccc(-c5ccc(-c6ccc7sc8ccccc8c7c6)cc5)cc4)c3c12 ; c1ccc2c(c1)oc1cc3c4ccccc4n(-c4ccc(-c5ccc(-c6ccc7sc8ccccc8c7c6)cc5)cc4)c3cc12 ; c1ccc2c(c1)oc1c2ccc2c1c1ccccc1n2-c1ccc(-c2ccc(-c3ccc4sc5ccccc5c4c3)cc2)cc1]

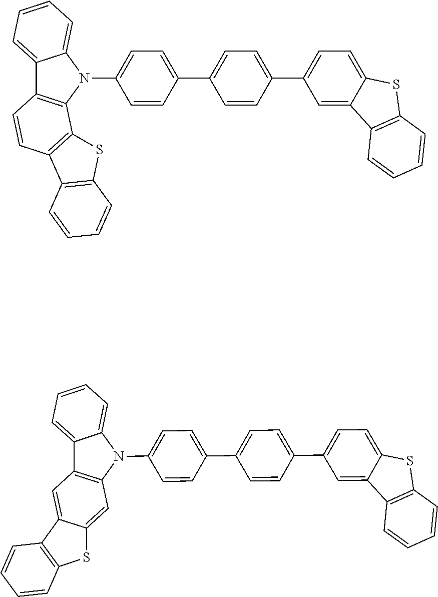 [SMILES: c1ccc2c(c1)sc1ccc(-c3ccc(-c4ccc(-n5c6ccccc6c6ccc7c8ccccc8sc7c65)cc4)cc3)cc12 ; c1ccc2c(c1)sc1ccc(-c3ccc(-c4ccc(-n5c6ccccc6c6cc7c(cc65)sc5ccccc57)cc4)cc3)cc12]

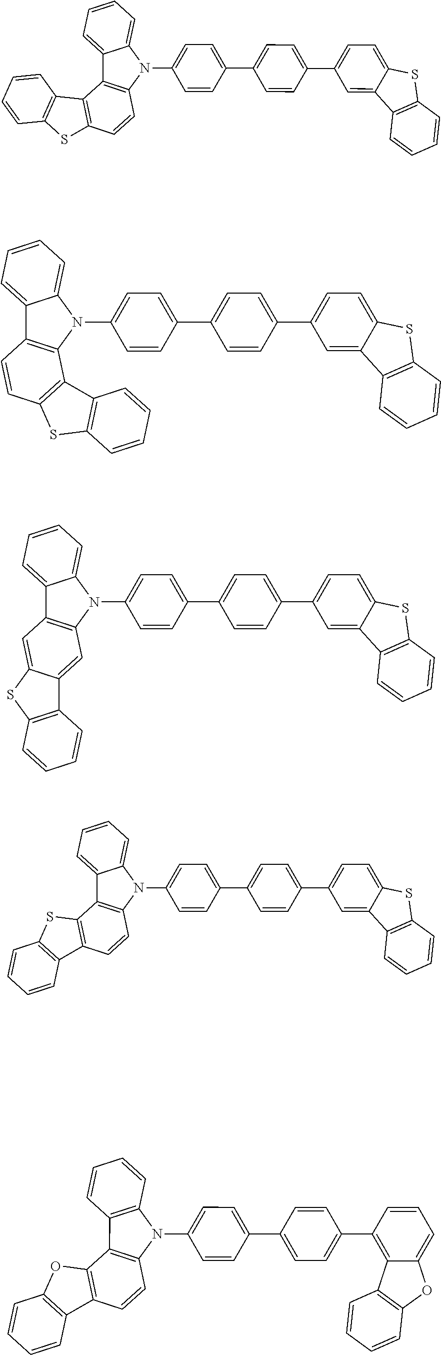 [SMILES: c1ccc2c(c1)sc1ccc(-c3ccc(-c4ccc(-n5c6ccccc6c6c7c(ccc65)sc5ccccc57)cc4)cc3)cc12 ; c1ccc2c(c1)sc1ccc(-c3ccc(-c4ccc(-n5c6ccccc6c6ccc7sc8ccccc8c7c65)cc4)cc3)cc12 ; c1ccc2c(c1)sc1ccc(-c3ccc(-c4ccc(-n5c6ccccc6c6cc7sc8ccccc8c7cc65)cc4)cc3)cc12 ; c1ccc2c(c1)sc1ccc(-c3ccc(-c4ccc(-n5c6ccccc6c6c7sc8ccccc8c7ccc65)cc4)cc3)cc12 ; c1ccc2c(c1)oc1c2ccc2c1c1ccccc1n2-c1ccc(-c2ccc(-c3cccc4oc5ccccc5c34)cc2)cc1]

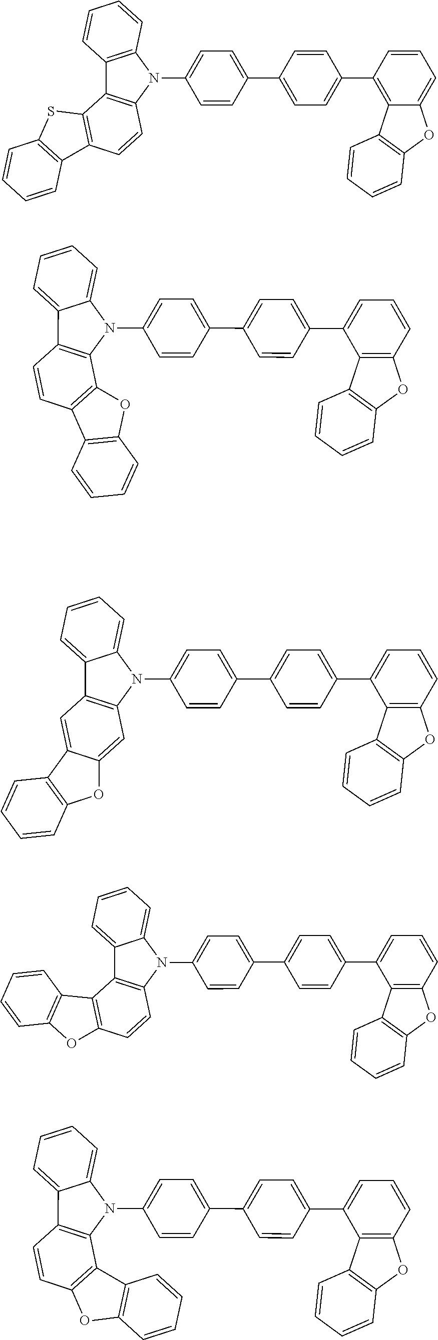 [SMILES: c1ccc2c(c1)oc1cccc(-c3ccc(-c4ccc(-n5c6ccccc6c6c7sc8ccccc8c7ccc65)cc4)cc3)c12 ; c1ccc2c(c1)oc1c2ccc2c3ccccc3n(-c3ccc(-c4ccc(-c5cccc6oc7ccccc7c56)cc4)cc3)c21 ; c1ccc2c(c1)oc1cc3c(cc12)c1ccccc1n3-c1ccc(-c2ccc(-c3cccc4oc5ccccc5c34)cc2)cc1 ; c1ccc2c(c1)oc1cccc(-c3ccc(-c4ccc(-n5c6ccccc6c6c7c(ccc65)oc5ccccc57)cc4)cc3)c12 ; c1ccc2c(c1)oc1cccc(-c3ccc(-c4ccc(-n5c6ccccc6c6ccc7oc8ccccc8c7c65)cc4)cc3)c12]

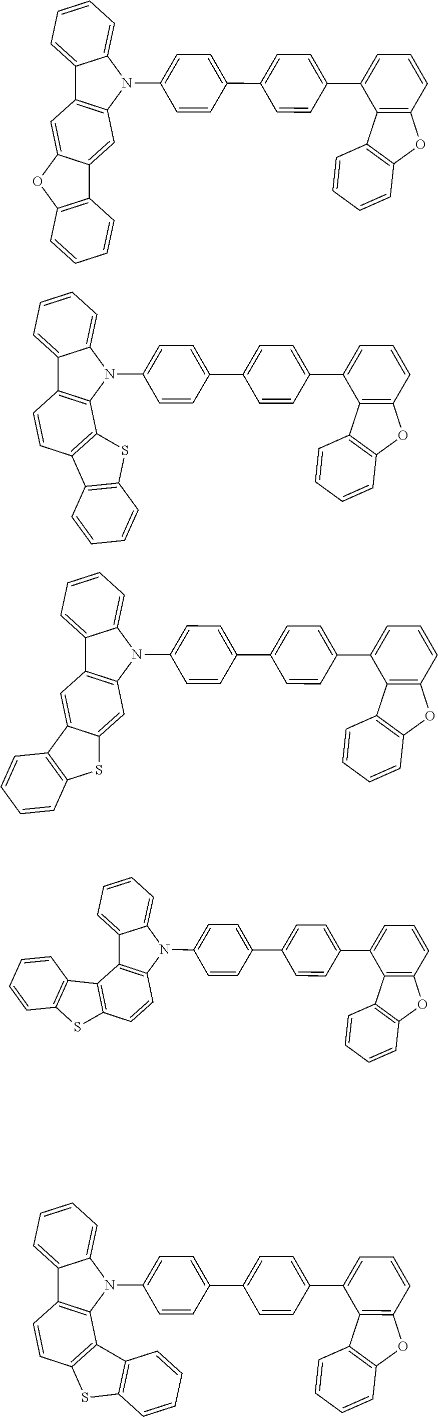

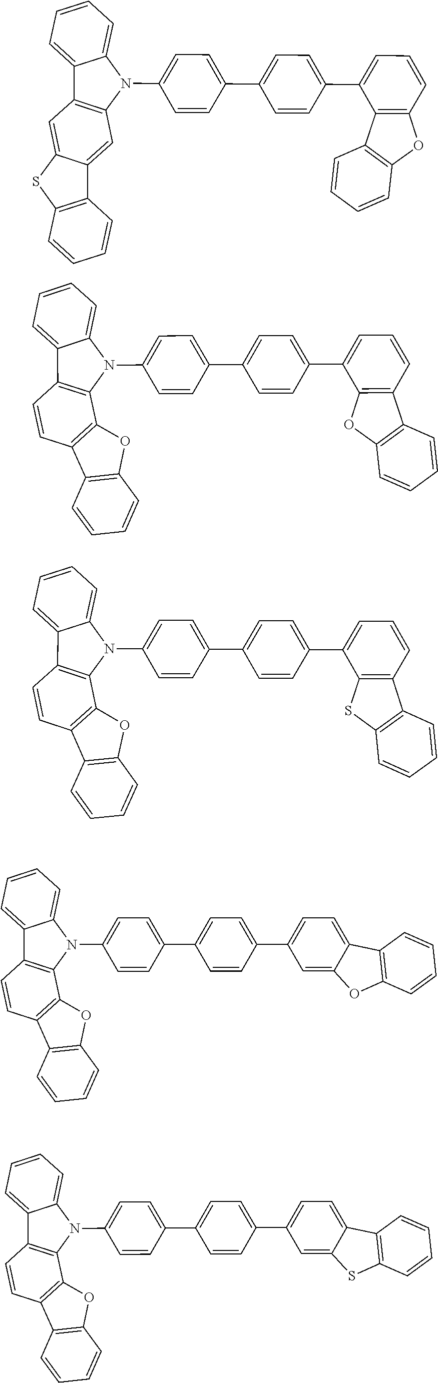

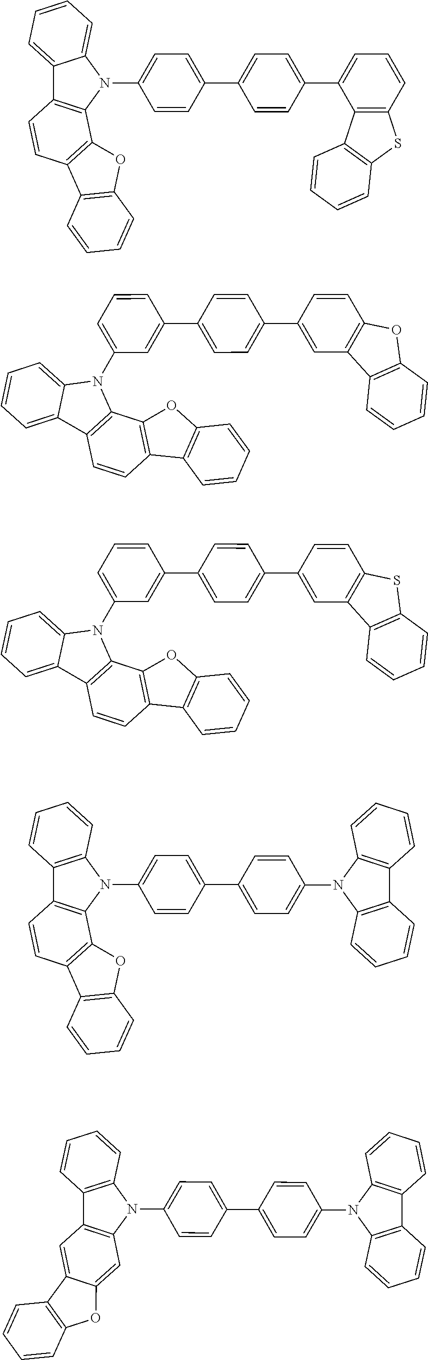

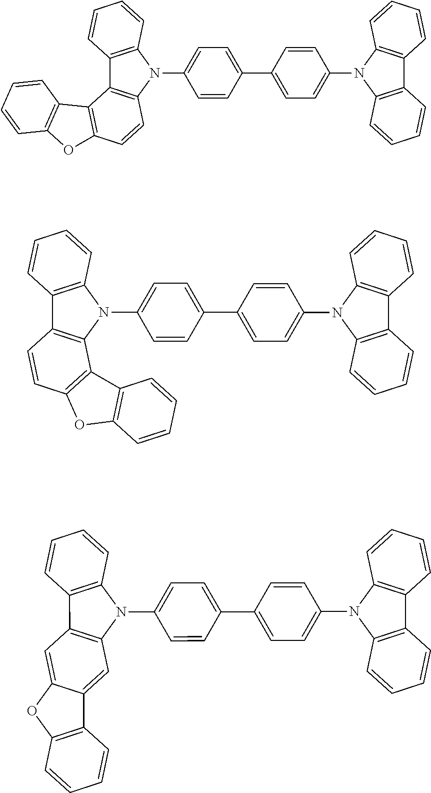 [SMILES: c1ccc2c(c1)oc1ccc3c(c4ccccc4n3-c3ccc(-c4ccc(-n5c6ccccc6c6ccccc65)cc4)cc3)c12 ; c1ccc2c(c1)oc1ccc3c4ccccc4n(-c4ccc(-c5ccc(-n6c7ccccc7c7ccccc76)cc5)cc4)c3c12 ; c1ccc2c(c1)oc1cc3c4ccccc4n(-c4ccc(-c5ccc(-n6c7ccccc7c7ccccc76)cc5)cc4)c3cc12]

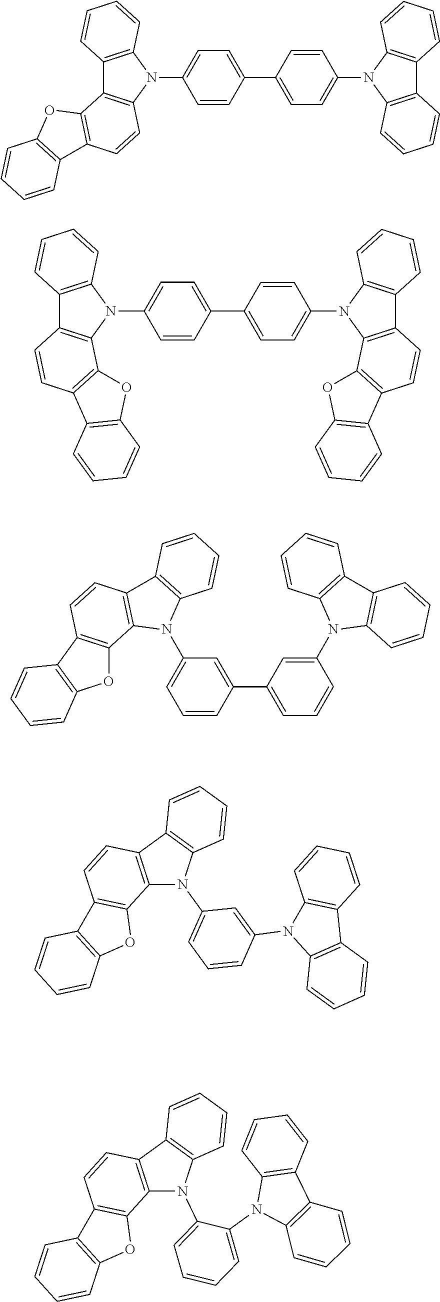

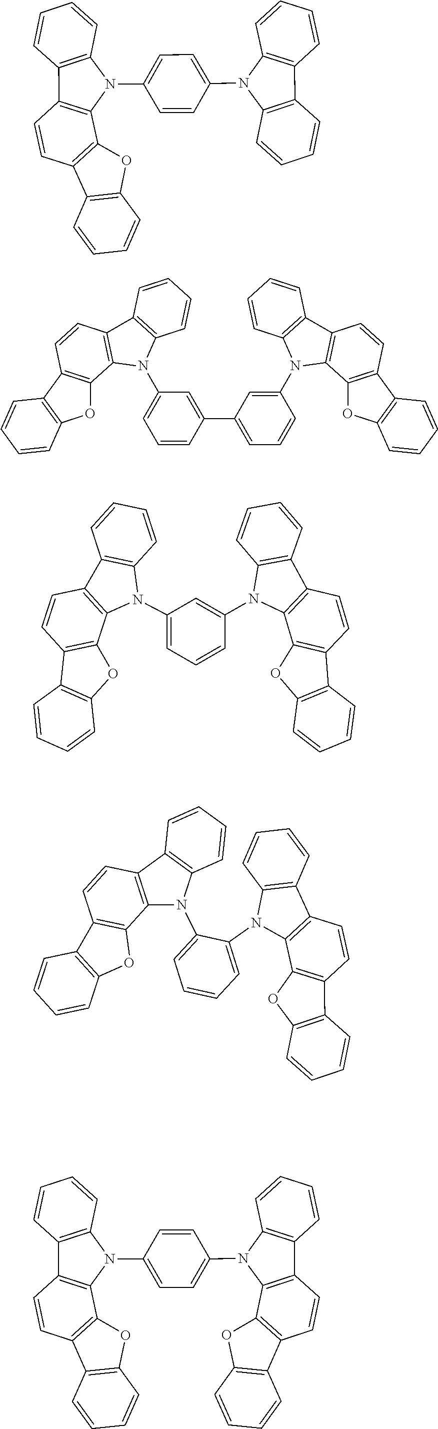

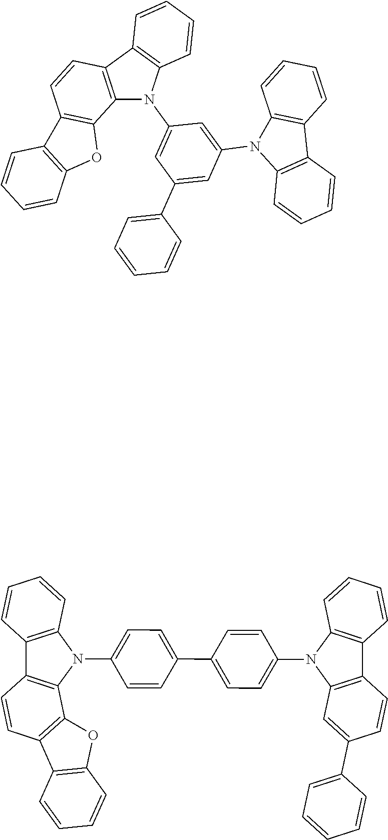 [SMILES: c1ccc(-c2cc(-n3c4ccccc4c4ccccc43)cc(-n3c4ccccc4c4ccc5c6ccccc6oc5c43)c2)cc1 ; c1ccc(-c2ccc3c4ccccc4n(-c4ccc(-c5ccc(-n6c7ccccc7c7ccc8c9ccccc9oc8c76)cc5)cc4)c3c2)cc1]

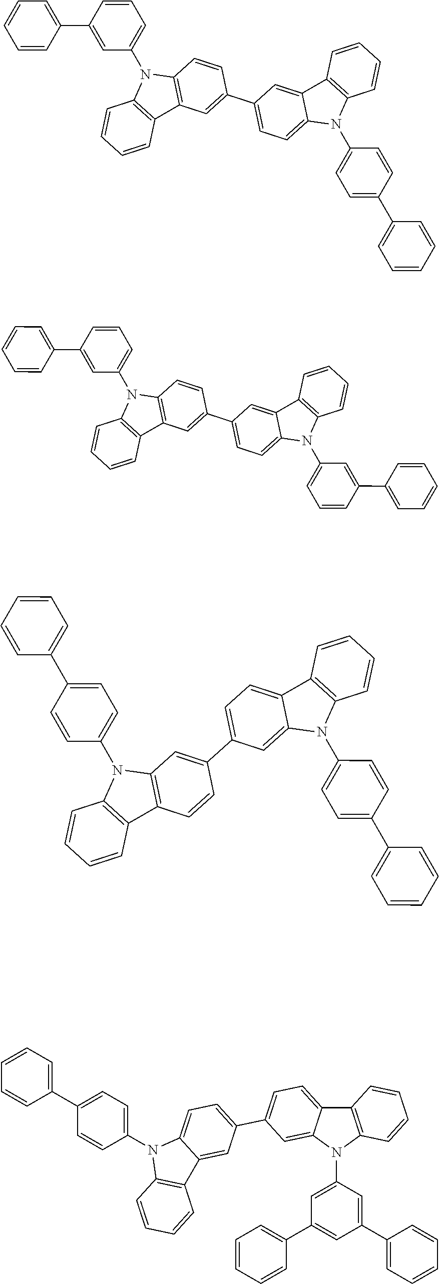 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2ccc(-n3c4ccccc4c4ccc(-c5ccc6c7ccccc7n(-c7ccc(-c8ccccc8)cc7)c6c5)cc43)cc2)cc1 ; c1ccc(-c2ccc(-n3c4ccccc4c4cc(-c5ccc6c7ccccc7n(-c7cc(-c8ccccc8)cc(-c8ccccc8)c7)c6c5)ccc43)cc2)cc1]

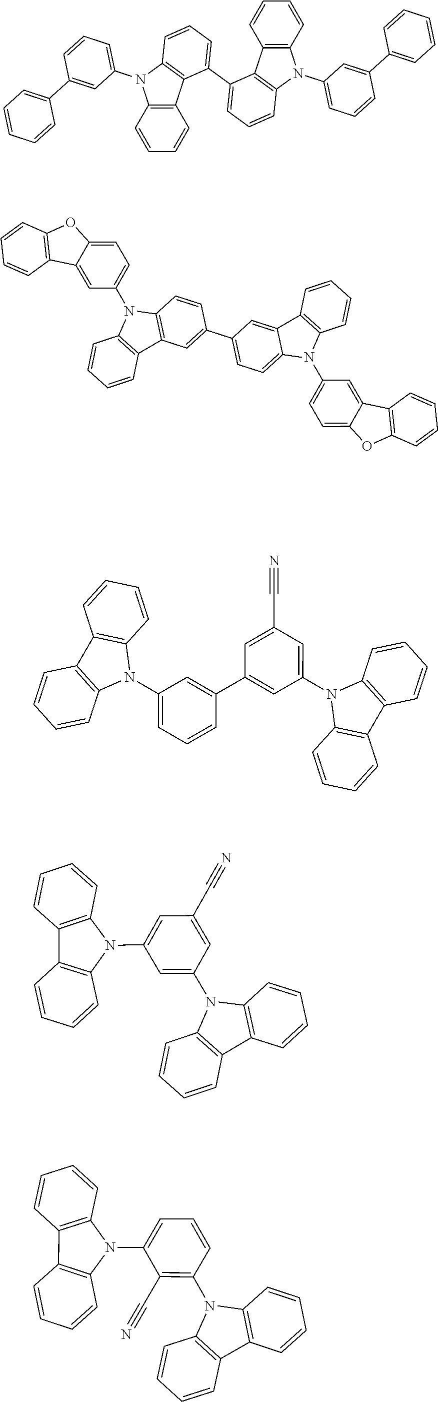 [SMILES: c1ccc(-c2cccc(-n3c4ccccc4c4c(-c5cccc6c5c5ccccc5n6-c5cccc(-c6ccccc6)c5)cccc43)c2)cc1 ; c1ccc2c(c1)oc1ccc(-n3c4ccccc4c4cc(-c5ccc6c(c5)c5ccccc5n6-c5ccc6oc7ccccc7c6c5)ccc43)cc12 ; N#Cc1cc(-c2cccc(-n3c4ccccc4c4ccccc43)c2)cc(-n2c3ccccc3c3ccccc32)c1 ; N#Cc1cc(-n2c3ccccc3c3ccccc32)cc(-n2c3ccccc3c3ccccc32)c1 ; N#Cc1c(-n2c3ccccc3c3ccccc32)cccc1-n1c2ccccc2c2ccccc21]

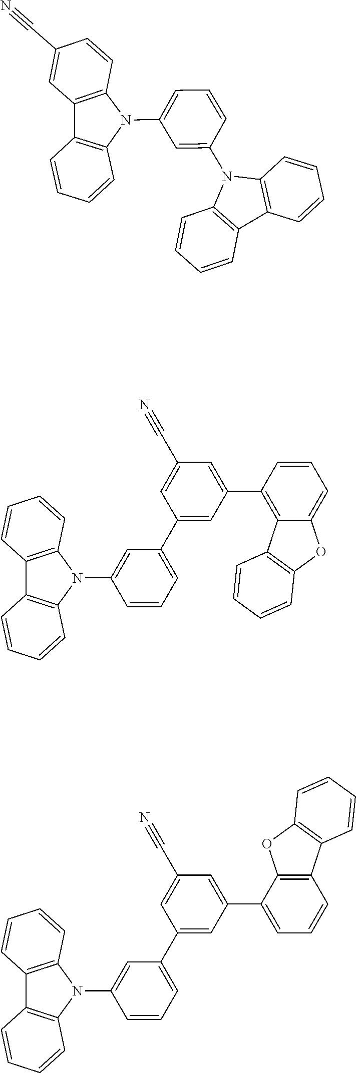 [SMILES: N#Cc1ccc2c(c1)c1ccccc1n2-c1cccc(-n2c3ccccc3c3ccccc32)c1 ; N#Cc1cc(-c2cccc(-n3c4ccccc4c4ccccc43)c2)cc(-c2cccc3oc4ccccc4c23)c1 ; N#Cc1cc(-c2cccc(-n3c4ccccc4c4ccccc43)c2)cc(-c2cccc3c2oc2ccccc23)c1]

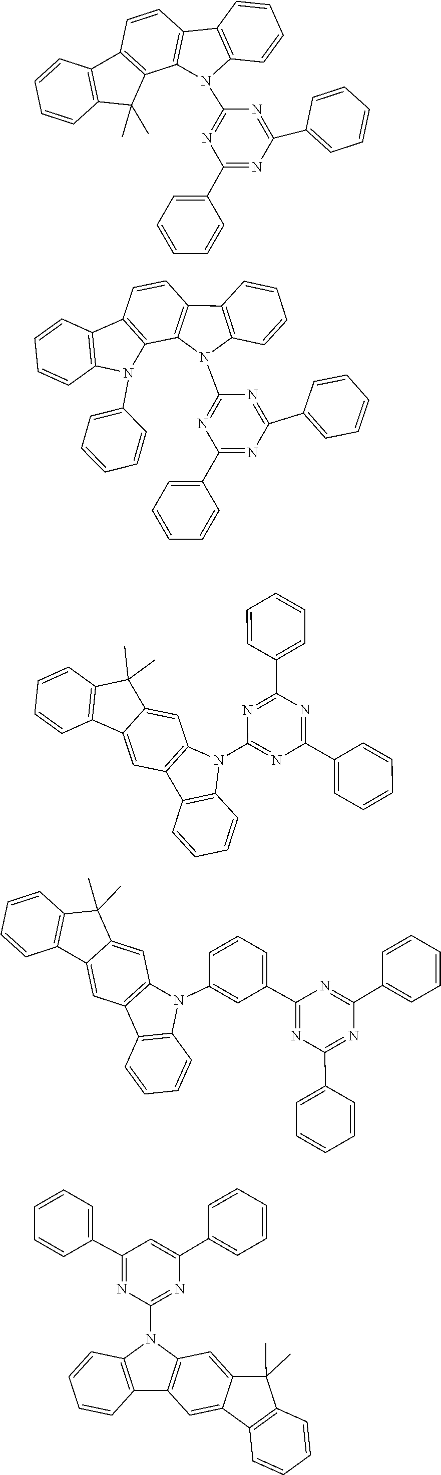

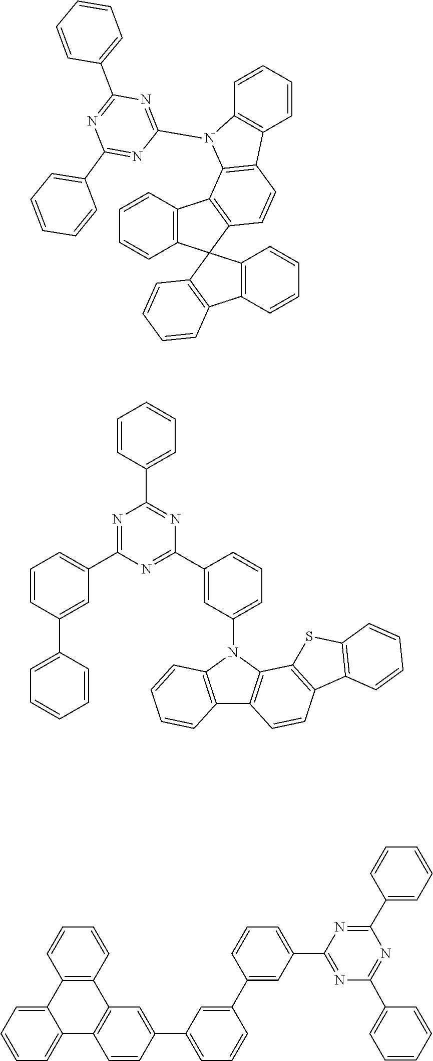 [SMILES: c1ccc(-c2nc(-c3ccccc3)nc(-n3c4ccccc4c4ccc5c(c43)-c3ccccc3C53c4ccccc4-c4ccccc43)n2)cc1 ; c1ccc(-c2cccc(-c3nc(-c4ccccc4)nc(-c4cccc(-n5c6ccccc6c6ccc7c8ccccc8sc7c65)c4)n3)c2)cc1 ; c1ccc(-c2nc(-c3ccccc3)nc(-c3cccc(-c4cccc(-c5ccc6c7ccccc7c7ccccc7c6c5)c4)c3)n2)cc1]

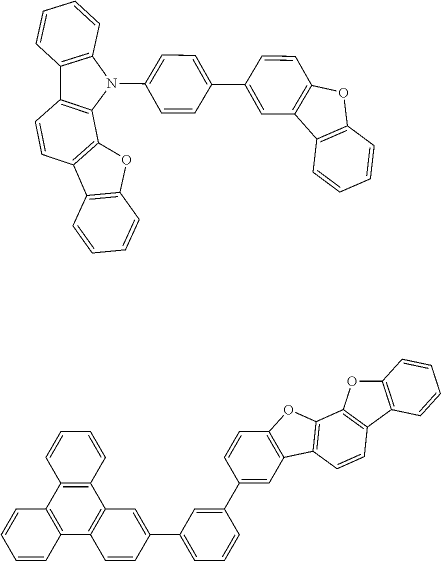 [SMILES: c1ccc2c(c1)oc1ccc(-c3ccc(-n4c5ccccc5c5ccc6c7ccccc7oc6c54)cc3)cc12 ; c1cc(-c2ccc3oc4c(ccc5c6ccccc6oc54)c3c2)cc(-c2ccc3c4ccccc4c4ccccc4c3c2)c1]

### Relationship Between Compound M1 Compound M2 and Compound M3 in Emitting Layer

In the organic EL device according to the exemplary embodiment, it is preferable that the emitting layer contains the compound M1 and the compound M3, and the lowest singlet energy S₁(M1) of the compound M1 and the lowest singlet energy S₁(M3) of the compound M3 satisfy a relationship of a numerical formula (Numerical Formula 2) below.

S₁(M3)>S₁(M1) (Numerical Formula 2)

In the organic EL device according to the exemplary embodiment, it is preferable that the emitting layer contains the compound M1, the compound M2, and the compound M3, the compound M2 is a fluorescent compound, and the lowest singlet energy S1(M1) of the compound M1, the lowest singlet energy S₁(M2) of the compound M2, and the lowest singlet energy S₁(M3) of the compound M3 satisfy a relationship of a numerical formula (Numerical Formula 3) below.

S₁(M3)>S₁(M1)>S₁(M2) (Numerical Formula 3)

An energy gap T_{77K}(M3) at 77K of the compound M3 is preferably larger than an energy gap T_{77K}(M1) at 77K of the compound M1.

An energy gap T_{77K}(M3) at 77K of the compound M3 is preferably larger than an energy gap 1-77K(M2) at 77K of the compound M2.

An energy gap T_{77K}(M1) at 77K of the compound M1, an energy gap T_{77K}(M2) at 77K of the compound M2, and an energy gap T_{77K}(M3) at 77K of the compound M3 preferably satisfy a relationship of a numerical formula (Numerical Formula 2B) below.

T_{77K}(M3)>T_{77K}(M1)>T_{77K}(M2) (Numerical Formula 2B)

It is preferable that mainly the fluorescent compound emits light in the emitting layer when the organic EL device of the exemplary embodiment emits light.

The organic EL device according to the exemplary embodiment preferably emits red light or green light in the same manner as the organic EL device of the first exemplary embodiment.

The maximum peak wavelength of light emitted from the organic EL device can be measured according to the same method as in the organic EL device of the first exemplary embodiment.

### Content Ratios of Compounds in Emitting Layer

Content ratios of the compound M1, the compound M2, and the compound M3 in the emitting layer preferably fall, for instance, within ranges below.

The content ratio of the compound M1 is preferably in a range from 10 mass % to 80 mass %, more preferably in a range from 10 mass % to 60 mass %, and still more preferably in a range from 20 mass % to 60 mass %.

The content ratio of the compound M2 is preferably in a range from 0.01 mass % to 10 mass %, more preferably in a range from 0.01 mass % to 5 mass %, and still more preferably in a range from 0.01 mass % to 1 mass %.

The content ratio of the compound M3 is preferably in a range from 10 mass % to 80 mass %.

The upper limit of a total of the content ratios of the compound M1, the compound M2, and the compound M3 in the emitting layer is 100 mass %. It should be noted that the emitting layer of the exemplary embodiment may further contain material(s) other than the compounds M1, M2 and M3.

The emitting layer may contain a single type of the compound M1 or may contain two or more types of the compound M1. The emitting layer may contain a single type of the compound M2 or may contain two or more types of the compound M2. The emitting layer may contain a single type of the compound M3 or may contain two or more types of the compound M3.

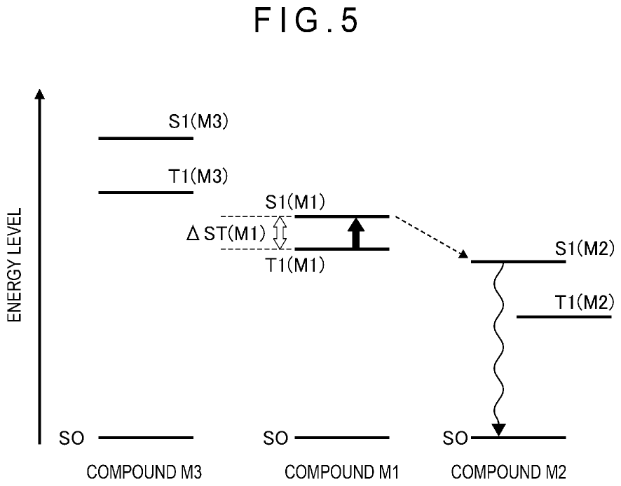

FIG. 5 illustrates an example of a relationship between energy levels of the compound M1, the compound M2, and the compound M3 in the emitting layer. In FIG. 5, S0 represents a ground state. S1 (M1) represents a lowest singlet state of the compound M1. T1(M1) represents a lowest triplet state of the compound M1. S1(M2) represents a lowest singlet state of the compound M2. T1(M2) represents a lowest triplet state of the compound M2. S1 (M3) represents a lowest singlet state of the compound M3. T₁(M3) represents a lowest triplet state of the compound M3. A dashed arrow directed from S1(M1) to S1(M2) in FIG. 5 represents Förster energy transfer from the lowest singlet state of the compound M1 to the lowest singlet state of the compound M2.

As illustrated in FIG. 5, when a compound having a small ΔST(M1) is used as the compound M1, inverse intersystem crossing from the lowest triplet state T1(M1) to the lowest singlet state S1(M1) can be caused by a heat energy. Subsequently, Förster energy transfer from the lowest singlet state S1(M1) of the compound M1 to the compound M2 occurs to generate the lowest singlet state S1(M2). Consequently, fluorescence from the lowest singlet state S1(M2) of the compound M2 can be observed. It is inferred that the internal quantum efficiency can be theoretically raised up to 100% also by using delayed fluorescence by the TADF mechanism.

The organic EL device according to the second exemplary embodiment contains: the compound M4 of the first exemplary embodiment in the first layer; and in the emitting layer, the compound M1 of the first exemplary embodiment, the compound M2 having the lowest singlet energy smaller than that of the compound M1, and the compound M3 having the lowest singlet energy larger than that of the compound M1.

According to the second exemplary embodiment, a luminous efficiency of the organic EL device is improvable. The organic EL device according to the second exemplary embodiment is usable in an electronic device such as a display device and a light-emitting unit.

### Third Exemplary Embodiment

An arrangement of an organic EL device according to a third exemplary embodiment will be described below. In the description of the third exemplary embodiment, the same components as those in the first or second exemplary embodiment are denoted by the same reference signs and names to simplify or omit an explanation of the components. In the third exemplary embodiment, the same materials and compounds as described in the first or second exemplary embodiment are usable, unless otherwise specified.

The organic EL device according to the third exemplary embodiment is different from the organic EL device according to the first or second exemplary embodiment in that the emitting layer contains the compounds M1 and M3 but does not contain the compound M2. The third exemplary embodiment is the same as the first or second exemplary embodiment in other respects.

Specifically, in the third exemplary embodiment, the emitting layer as a first organic layer contains the compound M1 and the compound M3.

In this arrangement, it is preferable that the compound M3 is a host material and the compound M1 is a dopant material.

In the exemplary embodiment, in a case where the emitting layer contains the compound M1 of the first exemplary embodiment, the emitting layer preferably does not contain a phosphorescent metal complex and also preferably does not contain a metal complex other than the phosphorescent metal complex.

### Compound M1

The compound M1 is the compound M1 of the first exemplary embodiment.

The compound M1 is a thermally activated delayed fluorescent compound.

### Compound M3

The compound M3 is the same as the compound M3 described in the second exemplary embodiment.

### Relationship Between Compound M1 and Compound M3 in Emitting Layer

In the organic EL device according to the exemplary embodiment, the lowest singlet energy S₁(M1) of the compound M1 and the lowest singlet energy S₁(M3) of the compound M3 preferably satisfy a relationship of a numerical formula (Numerical Formula 2) below.

S₁(M3)>S₁(M1) (Numerical Formula 2)

An energy gap T_{77K}(M3) at 77K of the compound M3 is preferably larger than an energy gap T_{77K}(M1) at 77K of the compound M1.

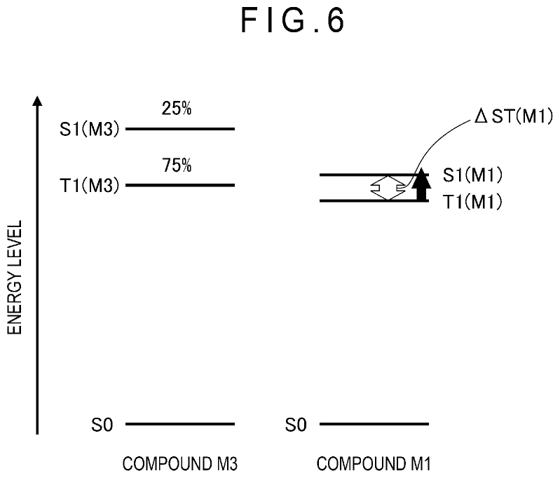

FIG. 6 is an illustration for explaining the principle of light emission according to an exemplary embodiment of the invention.

In FIG. 6, S0 represents a ground state. S1(M1) represents the lowest singlet state of the compound M1. T1(M1) represents a lowest triplet state of the compound M1. S1(M3) represents the lowest singlet state of the compound M3. T1(M3) represents a lowest triplet state of the compound M3.

As illustrated in FIG. 6, when a compound having a small ΔST(M1) is used as the compound M1, inverse intersystem crossing from the lowest triplet state T1(M1) to the lowest singlet state S1(M1) can be caused by a heat energy.

With use of inverse intersystem crossing occurring in the compound M1, for instance, light emission as described in (i-1) or (ii-1) below can be observed.
(i-1) Light emission from the lowest singlet state S1(M1) of the compound M1 can be observed when the emitting layer does not contain a fluorescent dopant with the lowest singlet state S1 smaller than the lowest singlet state S1(M1) of the compound M1.
(ii-1) Light emission from a fluorescent dopant can be observed when the emitting layer contains the fluorescent dopant with the lowest singlet state S₁ smaller than the lowest singlet state S1(M1) of the compound M1 (i.e., the fluorescent compound M2 in the first or second exemplary embodiment).

In the organic EL device of the third exemplary embodiment, light emission described in the above (i-1) can be observed. In the organic EL device of the first or second exemplary embodiment, light emission described in the above (ii-1) can be observed.

### Content Ratios of Compounds in Emitting Layer

In the organic EL device of the third exemplary embodiment, the content ratios of the compound M1 and the compound M3 in the emitting layer preferably fall within the ranges exemplified below.

The content ratio of the compound M1 is preferably in a range from 10 mass % to 90 mass %, more preferably in a range from 10 mass % to 80 mass %, still more preferably in a range from 10 mass % to 60 mass %, and still further more preferably in a range from 20 mass % to 60 mass %.

The content ratio of the compound M3 is preferably in a range from 10 mass % to 90 mass %.

The upper limit of a total of the content ratios of the compound M1 and the compound M3 in the emitting layer is 100 mass %.

In the organic EL device according to the third exemplary embodiment, the emitting layer may contain a single type of the compound M1 or may contain two or more types of the compound M1. The emitting layer may contain a single type of the compound M3 or may contain two or more types of the compound M3.

The organic EL device according to the third exemplary embodiment contains: the compound M4 of the first exemplary embodiment in the first layer; and in the emitting layer, the compound M1 of the first exemplary embodiment and the compound M3 having the lowest singlet energy larger than that of the compound M1.

According to the third exemplary embodiment, a luminous efficiency of the organic EL device is improvable. The organic EL device according to the third exemplary embodiment is usable in an electronic device such as a display device and a light-emitting unit.

### Fourth Exemplary Embodiment

### Electronic Device

An electronic device according to a fourth exemplary embodiment is installed with any one of the organic EL devices according to the above exemplary embodiments. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light.

### Modification of Embodiment(s)

The scope of the invention is not limited by the above-described exemplary embodiments but includes any modification and improvement as long as such modification and improvement are compatible with the invention.

For instance, the emitting layer is not limited to a single layer, but may be provided by laminating a plurality of emitting layers. When the organic EL device has the plurality of emitting layers, it is only required that at least one of the emitting layers satisfies the conditions described in the above exemplary embodiments. For instance, the rest of the emitting layers may be a fluorescent emitting layer or a phosphorescent emitting layer with use of emission caused by electron transfer from the triplet excited state directly to the ground state.

When the organic EL device includes a plurality of emitting layers, these emitting layers may be mutually adjacently provided, or may form a so-called tandem organic EL device, in which a plurality of emitting units are layered via an intermediate layer.

For instance, a blocking layer may be provided adjacent to at least one of a side of the emitting layer close to the anode or a side of the emitting layer close to the cathode. The blocking layer is preferably provided in contact with the emitting layer to block at least any of holes, electrons, or excitons.

For instance, when the blocking layer is provided in contact with the side of the emitting layer close to the cathode, the blocking layer permits transport of electrons, and blocks holes from reaching a layer provided closer to the cathode (e.g., the electron transporting layer) beyond the blocking layer. When the organic EL device includes the electron transporting layer, the blocking layer is preferably interposed between the emitting layer and the electron transporting layer.

When the blocking layer is provided in contact with the side of the emitting layer close to the anode, the blocking layer permits transport of holes and blocks electrons from reaching a layer provided closer to the anode (e.g., the hole transporting layer) beyond the blocking layer. When the organic EL device includes the hole transporting layer, the blocking layer is preferably interposed between the emitting layer and the hole transporting layer.

Alternatively, the blocking layer may be provided adjacent to the emitting layer so that the excitation energy does not leak out from the emitting layer toward neighboring layer(s). The blocking layer blocks excitons generated in the emitting layer from being transferred to a layer(s) (e.g., the electron transporting layer and the hole transporting layer) closer to the electrode(s) beyond the blocking layer.

The emitting layer is preferably bonded with the blocking layer.

Specific structure, shape and the like of the components in the invention may be designed in any manner as long as an object of the invention can be achieved.

### EXAMPLES

Examples of the invention will be described below. However, the invention is by no means limited to Examples.

### Compounds

Structures of a compound represented by the formula (4) and used for producing organic EL devices in Examples 1 to 4 are shown below.

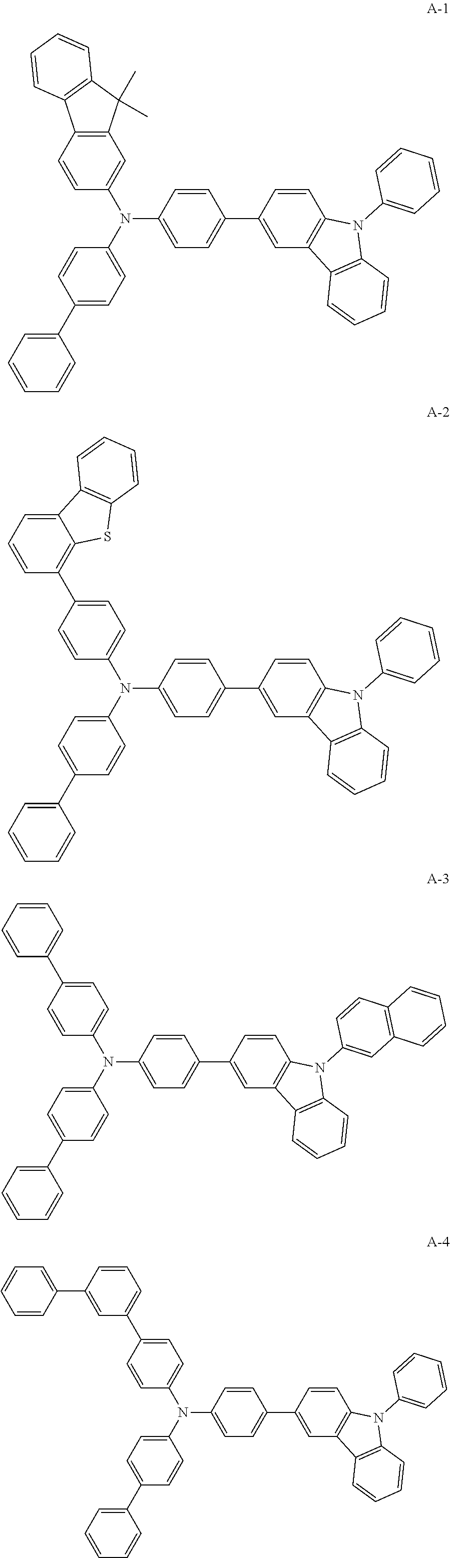

Structures of comparative compounds used for producing organic EL devices in Comparatives 1 to 6 are shown below.

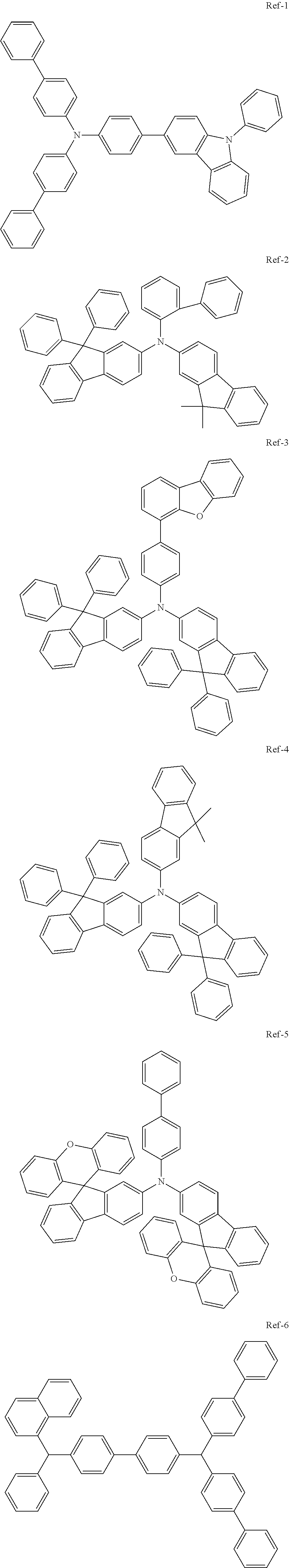

Structures of a compound represented by the formula (1) and used for producing organic EL devices in Examples 1 to 4 are shown below.

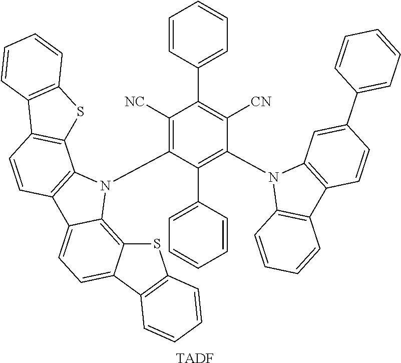

Structures of other compounds used for producing organic EL devices in Examples 1 to 4 and Comparatives 1 to 6 are shown below.

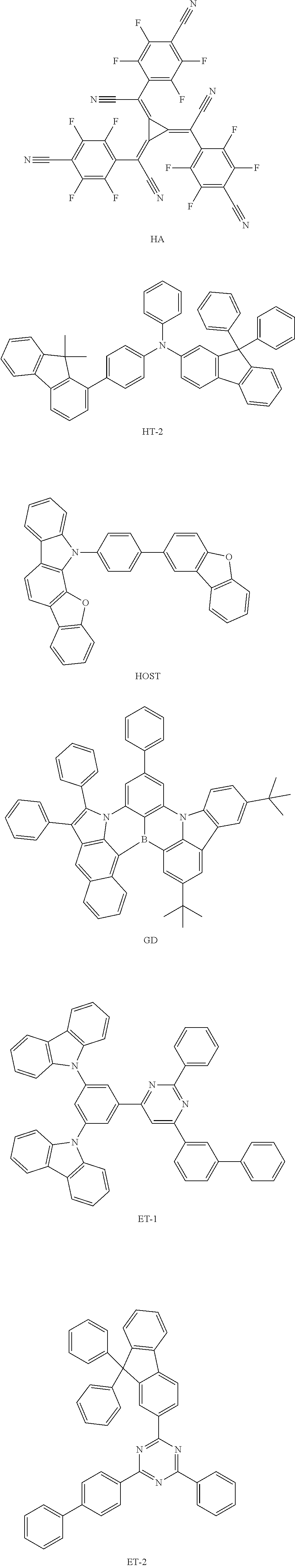

### Production of Organic EL Devices

The organic EL devices were produced and evaluated as follows.

### Example 1

A glass substrate (size: 25 mm×75 mm×1.1 mm thick, produced by Geomatec Co., Ltd.) having an ITO transparent electrode (anode) was ultrasonics cleaned in isopropyl alcohol for five minutes, and then UV-ozone-cleaned for one minute. The film thickness of ITO was 130 nm.

After the glass substrate having the transparent electrode line was cleaned, the glass substrate was mounted on a substrate holder of a vacuum deposition apparatus. Firstly, a compound A-1 as the compound M5 and a compound HA as the compound M6 were co-deposited on a surface of the glass substrate where the transparent electrode line was provided in a manner to cover the transparent electrode, thereby forming a 10-nm-thick hole injecting layer (second layer), Ratios of the compound A-1 and the compound HA in the hole injecting layer were 97 mass % and 3 mass %, respectively.

Next, the compound A-1 as the compound M4 was vapor-deposited on the hole injecting layer to form a 90-nm-thick first hole transporting layer (first layer),

Next, a compound HT-2 as the compound M7 was vapor-deposited on the first hole transporting layer to form a 30-nm-thick second hole transporting layer (third layer).

Next, a compound HOST as the compound M3, a compound TADF as the compound M1, and a compound GD as the compound M2 were co-deposited on the second hole transporting layer to form a 25-nm-thick emitting layer. Ratios of the compound HOST, the compound TADF, and the compound GD in the emitting layer were 74.4 mass %, 25 mass %, and 0.6 mass %, respectively.

Next, a compound ET-1 was vapor-deposited on the emitting layer to form a hole blocking layer.

Next, a compound ET-2 and Liq were co-deposited on the hole blocking layer to form a 50-nm-thick electron transporting layer. The ratios of the compound ET-2 and Liq in the electron transporting layer were both 50 mass %. Liq is an abbreviation of (8-quinolinolato)lithium ((8-Quinolinolato)lithium).

Next, ytterbium (Yb) was vapor-deposited on the electron transporting layer to form a 1-nm-thick electron injecting layer.

Subsequently, metal aluminum (Al) was vapor-deposited on the electron injecting layer to form an 80-nm-thick metal A1 cathode.

A device arrangement of the organic EL device in Example 1 is roughly shown as follows,

ITO(130) A-1:HA(10,97%:3%)/A-1(90)/HT-2(30)/HOST:TADF:GD(25,74.4°/0:25%:0.6%)/ET-1(5)/ET-2:Lig(50,50%:50%) Yb(1)/Al(80)

In the above-described device arrangements, numerals in parentheses represent a film thickness (unit: nm).

The numerals (97%:3%) represented by percentage in the same parentheses indicate a ratio (mass %) between the compound A-1 and the compound HA in the hole injecting layer. The numerals (74.4%: 25%:0.6%) represented by percentage in the same parentheses indicate a ratio (mass %) between the compound HOST, the compound TADF, and the compound GD in the emitting layer. The numerals (50%:50%) represented by percentage in the same parentheses indicate a ratio (mass %) between the compound ET-2 and Liq in the electron transporting layer. Similar notations apply to the description below.

### Examples 2 to 4

The organic EL devices in Examples 2 to 4 were produced in the same manner as in Example 1 except that the compound A-1 used in the hole injecting layer and the first hole transporting layer in Example 1 was replaced by compounds shown in Table 1.

### Comparatives 1 to 6

The organic EL devices in Comparatives 1 to 6 were produced in the same manner as in Example 1 except that the compound A-1 used in the hole injecting layer and the first hole transporting layer in Example 1 were replaced by compounds shown in Table 1.

### Evaluation of Organic EL Devices

The organic EL devices produced were evaluated as follows. Table 1 shows the evaluation results. Table 1 also shows the evaluation results of the compounds used in the first hole transporting layer in Examples. Although comparative compounds Ref-1 to Ref-6 do not correspond to the compound M4 represented by the formula (4), the comparative compounds Ref-1 to Ref-6 are shown in the same column as the compound M4 in Table 1 for convenience.

### External Quantum Efficiency EQE

Voltage was applied on the produced organic EL device such that a current density was 10.00 mA/cm², where spectral radiance spectrum was measured by a spectroradiometer CS-2000 (manufactured by Konica Minolta, Inc.). The external quantum efficiency EQE (unit: %) was calculated based on the obtained spectral radiance spectra, assuming that the spectra was provided under a Lambertian radiation.

TABLE 1

| | Hole Injecting Layer | | First Hole | | | |
|---|---|---|---|---|---|---|
| | (Second Layer) | | Transporting Layer (First Layer) | | | |
| | Compound | Compound | Compound M4 | | | Device |
| | M5 | M6 | | μ_{H}(M4) | S₁(M4) | Evaluation |
| | Name | Name | Name | [cm²/Vs] | [eV] | EQE [%] |
| Example 1 | A-1 | HA | A-1 | 5.50 × 10⁻⁴ | 3.18 | 17.89 |
| Example 2 | A-2 | HA | A-2 | 6.38 × 10⁻⁵ | 3.21 | 18.20 |
| Example 3 | A-3 | HA | A-3 | 6.27 × 10⁻⁴ | 3.22 | 17.81 |
| Example 4 | A-4 | HA | A-4 | 4.52 × 10⁻⁴ | 3.22 | 17.78 |
| Comparative 1 | Ref-1 | HA | Ref-1 | 7.33 × 10⁻⁴ | 3.23 | 17.48 |
| Comparative 2 | Ref-2 | HA | Ref-2 | 1.06 × 10⁻² | 3.13 | 16.45 |
| Comparative 3 | Ref-3 | HA | Ref-3 | 3.60 × 10⁻⁴ | 3.11 | 17.10 |
| Comparative 4 | Ref-4 | HA | Ref-4 | 3.57 × 10⁻³ | 3.08 | 16.80 |
| Comparative 5 | Ref-5 | HA | Ref-5 | 2.69 × 10⁻⁴ | 3.12 | 16.71 |
| Comparative 6 | Ref-6 | HA | Ref-6 | 4.90 × 10⁻⁴ | 3.10 | 16.40 |

The organic EL devices in Examples 1 to 4 were improved in terms of luminous efficiency as compared with the organic EL devices in Comparatives 1 to 6, the organic EL devices in Examples 1 to 4 including: the emitting layer containing the delayed fluorescent compound M1: and the first layer containing the compound M4 represented by the formula (4) and satisfying the formulae (a) and (b).

### Evaluation of Compounds

The above-described compounds were evaluated as follows. Table 1 or 2 shows the evaluation results.

### Hole Mobility

Hole mobility μ_{H} was measured using a device for mobility evaluation produced according to the following steps.

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV-ozone-cleaned for 30 minutes. The film thickness of ITO was 130 nm.

After the glass substrate having the transparent electrode line was cleaned, the glass substrate was mounted on a substrate holder of a vacuum deposition apparatus. Firstly, the compound HA-2 was vapor-deposited on a surface of the glass substrate where the transparent electrode line was provided in a manner to cover the transparent electrode, thereby forming a 5-nm-thick hole injecting layer.

Next, the compound HT-A was vapor-deposited on the hole injecting layer to form a 10-nm-thick hole transporting layer.

Subsequently, a compound Target, which was to be measured for the hole mobility μ_{H}, was vapor-deposited to form a measurement target layer having a thickness of 200 nm.

Subsequently, metal aluminum (Al) was vapor-deposited on the measurement target layer to form an 80-nm-thick metal cathode.

An arrangement of the above device for mobility evaluation is roughly shown as follows.

ITO(130)/HA-2(5)/HT-A(10)/Target(200)/Al(80)

Numerals in parentheses represent a film thickness (nm).

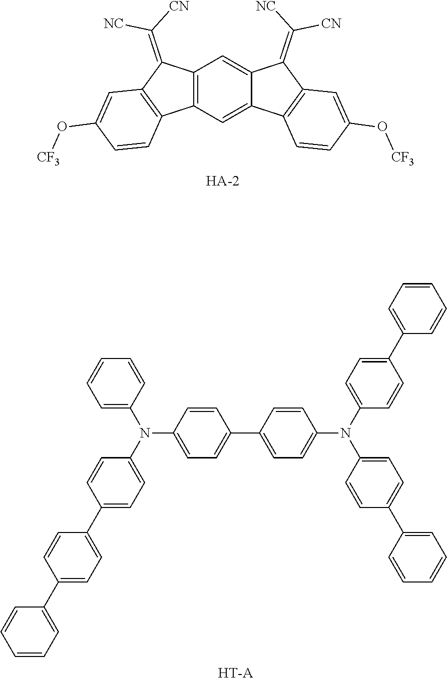 [SMILES: N#CC(C#N)=C1c2cc(OC(F)(F)F)ccc2-c2cc3c(cc21)C(=C(C#N)C#N)c1cc(OC(F)(F)F)ccc1-3 ; "HA-2" ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; "HT-A"]

Subsequently, the hole mobility was measured using a device for mobility evaluation produced as described above according to the following steps.

The device for evaluating the hole mobility was set in an impedance measurement apparatus and an impedance measurement was performed.

In the impedance measurement, a measurement frequency was swept from 1 Hz to 1 MHz. At this time, an alternating current amplitude of 0.1 V and a direct current voltage V were applied to the device.

A modulus M was calculated from the measured impedance Z using a relationship of a calculation formula (C1) below.

M=jωZ Calculation Formula (C1):

In the calculation formula (C1), j is an imaginary unit whose square is −1 and ω is an angular frequency [rad/s].

In a bode plot in which an imaginary part of the modulus M was represented by an ordinate axis and the frequency [Hz] was represented by an abscissa axis, an electrical time constant τ of the device for mobility evaluation was obtained from a frequency fmax showing a peak using a calculation formula (C2) below.

τ=1/(2−πfmax) Calculation Formula (C2):

π in the calculation formula (C2) is a symbol representing a circumference ratio.

A hole mobility μ_{H} was calculated from a relationship of a calculation formula (C3) below using τ obtained above.

μ_{H}=d²/(Vτ) Calculation Formula (C3):

d in the calculation formula (C3) is a total film thickness of organic thin film(s) forming the device. As in the above-described device arrangement for the mobility evaluation, d=215 [nm] is satisfied.

The hole mobility herein is a value obtained in a case where a square root of an electric field intensity meets E^{1/2}=500 [V^{1/2}/cm^{1/2}]. The square root of the electric field intensity, E^{1/2}, can be calculated from a relationship of a calculation formula (C4) below.

E^{1/2}=V^{1/2}/d^{1/2} Calculation Formula (C4):

In Examples, for the impedance measurement, a 1260 type by Solartron Analytical was used as the impedance measurement apparatus, and for a higher accuracy, a 1296 type dielectric constant measurement interface by Solartron Analytical was used together therewith.

### Lowest Singlet Energy S₁

The lowest singlet energy S₁ of a measurement target compound was measured according to the above-described solution method.

### Fluorescence Quantum Yield (PLQY)

Each measurement target compound was dissolved in toluene at a concentration of 5 μmol/L to prepare a toluene solution. Subsequently, the prepared solution was bubbled with nitrogen for five minutes and sealed so as not to be mixed with outside air.

A photoluminescence quantum yield (PLQY) of the prepared toluene solution of the measurement target compound was measured using an absolute PL (photoluminescence) quantum yield measurement machine Quantaurus-QY (manufactured by Hamamatsu Photonics K.K.).

### Maximum Peak Wavelength of Compounds

A maximum peak wavelength λ of each of the compounds was measured according to the following method.

A toluene solution of each measurement target compound at a concentration of 5 μmol/L was prepared and put in a quartz cell. An emission spectrum (ordinate axis: luminous intensity, abscissa axis: wavelength) of the thus-obtained sample was measured at a normal temperature (300K). In Examples, the emission spectrum was measured with a spectrophotometer (device name: F-7000) manufactured by Hitachi High-Tech Corporation. It should be noted that the machine for measuring the emission spectrum is not limited to the machine used herein. A peak wavelength of the emission spectrum exhibiting the maximum luminous intensity was defined as the maximum peak wavelength λ.

### Delayed Fluorescence of Compounds

Delayed fluorescence was checked by measuring transient PL using an apparatus illustrated in FIG. 2. The compound TADF was dissolved in toluene to prepare a dilute solution with an absorbance of 0.05 or less at the excitation wavelength to eliminate contribution of self-absorption. In order to prevent quenching due to oxygen, the sample solution was frozen and degassed and then sealed in a cell with a lid under an argon atmosphere to obtain an oxygen-free sample solution saturated with argon.

The fluorescence spectrum of the sample solution was measured with a spectrofluorometer FP-8600 (produced by JASCO Corporation), and the fluorescence spectrum of a 9,10-diphenylanthracene ethanol solution was measured under the same conditions. Using the fluorescence area intensities of both spectra, the total fluorescence quantum yield was calculated by an equation (1) in Morris et al, J. Phys. Chem. 80 (1976) 969.

Prompt emission was observed immediately when the excited state was achieved by exciting the compound TADF with a pulse beam (i.e., a beam emitted from a pulse laser) having a wavelength to be absorbed by the compound TADF, and Delay emission was observed not immediately when the excited state was achieved but after the excited state was achieved. The delayed fluorescence in Examples means that an amount of Delay emission is 5% or more with respect to an amount of Prompt emission. Specifically, provided that the amount of Prompt emission is denoted by X_{P} and the amount of Delay emission is denoted by X_{D}, the delayed fluorescence means that a value of X_{D}/X_{P} is 0.05 or more.

An amount of Prompt emission, an amount of Delay emission and a ratio between the amounts thereof can be obtained according to the method as described in “Nature 492, 234-238, 2012” (Reference Document 1). The amount of Prompt emission and the amount of Delay emission may be calculated using an apparatus different from one described in Reference Document 1 or the apparatus illustrated in FIG. 2.

It was confirmed that the amount of Delay emission was 5% or more with respect to the amount of Prompt emission in the compound TADF. Specifically, the value of X_{D}/X_{P} was 0.05 or more in the compound TADF.

### Energy Gap T77K at 77K and ΔST

An energy gap T77K of each of the measurement target compounds was measured according to the measurement method of the energy gap T77K described in the above “Relationship between Triplet Energy and Energy Gap at 77K.”

ΔST of the compound TADF was determined from the measurement results of T77K and the above values of the lowest singlet energy S₁. In the table, “<0.01” represents that ΔST is less than 0.01 eV,

TABLE 2

| Compound | λ | | S₁ | AST |
|---|---|---|---|---|
| Name | [nm] | PLQY | [eV] | [eV] |
| TADF | 495 | 0.83 | 2.66 | <0.01 |
| GD | 511 | 0.94 | 2.41 | 0.41 |
| HOST | 361 | 0.66 | 3.43 | 0.59 |

What is claimed is:

1. An organic electroluminescence device comprising:
an anode;
a cathode;
an emitting layer provided between the anode and the cathode; and
a first layer provided between the anode and the emitting layer, wherein the emitting layer comprises a compound M1 represented by a formula (1) below,
the compound M1 is a delayed fluorescent compound,
the first layer comprises a compound M4 represented by a formula (4) below, and
the compound M4 satisfies a formula (a) and a formula (b) below,
μ_{H}(M4)≤1.0×10⁻³ cm²/Vs Formula (a):
S₁(M4)≥3.15 eV Formula (b):
μ_{H}(M4) represents hole mobility of the compound M4, and S₁(M4) represents a lowest singlet energy of the compound M4, 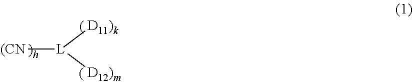
where, in the formula (1):
CN is a cyano group;
L is a substituted or unsubstituted aromatic hydrocarbon ring having 6 to 30 ring carbon atoms;
D₁₁ and D₁₂ are each independently a group represented by a formula (11), (12) or (13) below;
h is an integer of 2 or more;
k is an integer of 1 or more;
m is an integer of 0 or more;
D₁₁ and D₁₂ are mutually the same or different;
a plurality of D₁₁ are mutually the same or different; and
a plurality of D₁₂ are mutually the same or different, 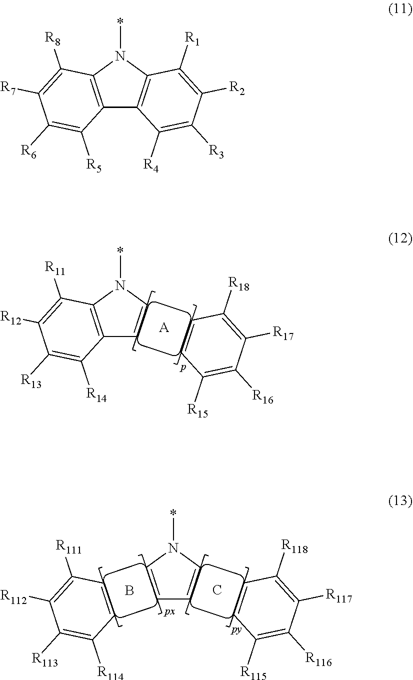
where, in the formula (11): at least one combination of adjacent two or more of R₁ to R₈ are mutually bonded to form a substituted or unsubstituted monocyclic ring, mutually bonded to form a substituted or unsubstituted fused ring, or not mutually bonded;
in the formula (12): at least one combination of adjacent two or more of R₁₁ to R₁₈ are mutually bonded to form a substituted or unsubstituted monocyclic ring, mutually bonded to form a substituted or unsubstituted fused ring, or not mutually bonded;
in the formula (13): at least one combination of adjacent two or more of R₁₁ to R₁₁₈ are mutually bonded to form a substituted or unsubstituted monocyclic ring, mutually bonded to form a substituted or unsubstituted fused ring, or not mutually bonded;
at least one D₁₁ is: a group represented by the formula (11) in which at least one combination of adjacent two or more of R₁ to R₈ are mutually bonded to form the substituted or unsubstituted monocyclic ring or the substituted or unsubstituted fused ring; a group represented by the formula (12); or a group represented by the formula (13);
R₁ to R₈ forming neither the substituted or unsubstituted monocyclic ring nor the substituted or unsubstituted fused ring in the formula (11), R₁₁ to R₁₈ forming neither the substituted or unsubstituted monocyclic ring nor the substituted or unsubstituted fused ring in the formula (12), and R₁₁₁ to R₁₁₈ forming neither the substituted or unsubstituted monocyclic ring nor the substituted or unsubstituted fused ring in the formula (13) are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having to 50 ring atoms;
in the formulae (12) and (13):
a ring A, a ring B, and a ring C are each independently any cyclic structure selected from the group consisting of cyclic structures represented by formulae (14) and (15) below;
the ring A, the ring B, and the ring C are fused with adjacent rings at any positions;
p, px and py are each independently 1, 2, 3, or 4;
when p is 2, 3, or 4, a plurality of rings A are mutually the same or different;
when px is 2, 3, or 4, a plurality of rings B are mutually the same or different;
when py is 2, 3, or 4, a plurality of rings C are mutually the same or different; and
* in the formulae (11) to (13) represents a bonding position to L in the formula (1), 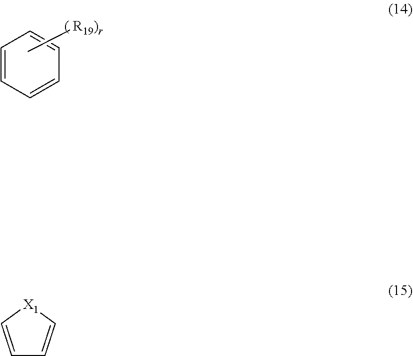
in the formula (14):
r is 0, 2, or 4;
a combination of a plurality of R₁₉ are mutually bonded to form a substituted or unsubstituted monocyclic ring, mutually bonded to form a substituted or unsubstituted fused ring, or not mutually bonded;
in the formula (15):
X₁ is a sulfur atom, an oxygen atom, C(R₁₅₁)(R₁₅₂), or N(R₁₅₃);
a combination of R₁₅₁ and R₁₅₂ are mutually bonded to form a substituted or unsubstituted monocyclic ring, mutually bonded to form a substituted or unsubstituted fused ring, or not mutually bonded;
R₁₅₃, R₁₅₁ and R₁₅₂ forming neither the substituted or unsubstituted monocyclic ring nor the substituted or unsubstituted fused ring, and R₁₉ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₉₂)(R₉₉₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a halogen atom, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms;
a plurality of R₁₉ are mutually the same or different; and
a plurality of X₁ are mutually the same or different, 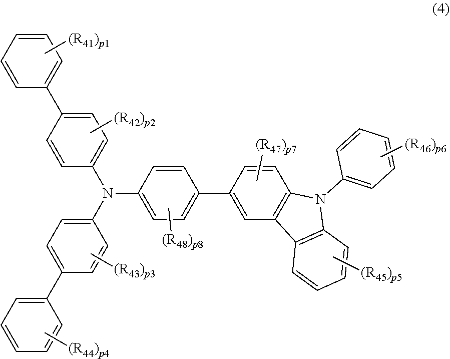
where, in the formula (4):
p1 is 5, p2 is 4, p3 is 4, p4 is 5, p5 is 4, p6 is 5, p7 is 3, and p8 is 4;
a plurality of R₄₁ are mutually the same or different;
at least one combination of adjacent two or more of the plurality of R₄₁ are mutually bonded to form a substituted or unsubstituted monocyclic ring, mutually bonded to form a substituted or unsubstituted fused ring, or not mutually bonded;
a plurality of R₄₂ are mutually the same or different;
at least one combination of adjacent two or more of the plurality of R₄₂ are mutually bonded to form a substituted or unsubstituted monocyclic ring, mutually bonded to form a substituted or unsubstituted fused ring, or not mutually bonded;
a plurality of R₄₃ are mutually the same or different;
at least one combination of adjacent two or more of the plurality of R₄₃ are mutually bonded to form a substituted or unsubstituted monocyclic ring, mutually bonded to form a substituted or unsubstituted fused ring, or not mutually bonded;
a plurality of R₄₄ are mutually the same or different;
at least one combination of adjacent two or more of the plurality of R₄₄ are mutually bonded to form a substituted or unsubstituted monocyclic ring, mutually bonded to form a substituted or unsubstituted fused ring, or not mutually bonded;
a plurality of R₄₅ are mutually the same or different;
at least one combination of adjacent two or more of the plurality of R₄₅ are mutually bonded to form a substituted or unsubstituted monocyclic ring, mutually bonded to form a substituted or unsubstituted fused ring, or not mutually bonded;
a plurality of R₄₆ are mutually the same or different;
at least one combination of adjacent two or more of the plurality of R₄₆ are mutually bonded to form a substituted or unsubstituted monocyclic ring, mutually bonded to form a substituted or unsubstituted fused ring, or not mutually bonded;
a combination of R₄₁ and R₄₂ are mutually bonded to form a substituted or unsubstituted monocyclic ring, mutually bonded to form a substituted or unsubstituted fused ring, or not mutually bonded;
a combination of R₄₃ and R₄₄ are mutually bonded to form a substituted or unsubstituted monocyclic ring, mutually bonded to form a substituted or unsubstituted fused ring, or not mutually bonded;
a plurality of R₄₇ are mutually the same or different;
a plurality of R₄₈ are mutually the same or different;
R₄₁ to R₄₆ forming neither the substituted or unsubstituted monocyclic ring nor the substituted or unsubstituted fused ring and R₄₇ to R₄₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms;
the compound M4 satisfies at least one of conditions (i), (ii), (iii), (iv), and (v) below:
the condition (i): at least one R₄₁ is not a hydrogen atom;
the condition (ii): a combination of R₄₁ and R₄₂ are mutually bonded to form a substituted or unsubstituted monocyclic ring or a substituted or unsubstituted fused ring;
the condition (iii): at least one combination of adjacent two or more of a plurality of R₄₁ are mutually bonded to form a substituted or unsubstituted monocyclic ring or a substituted or unsubstituted fused ring;
the condition (iv): at least one combination of adjacent two or more of a plurality of R₄₆ are mutually bonded to form a substituted or unsubstituted monocyclic ring or a substituted or unsubstituted fused ring; and
the condition (v): at least one R₄₆ is not a hydrogen atom,
in the formulae, R₉₀₁, R₉₀₂, R₉₀₃, R₉₀₄, R₉₀₅, R₉₀₆, R₉₀₇, R₉₀₈, R₉₀₉, R₉₃₁, R₉₃₂, R₉₃₃, R₉₃₄, R₉₃₅, R₉₃₆, and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₀₈ are present, the plurality of R₉₀₈ are mutually the same or different;
when a plurality of R₉₀₉ are present, the plurality of R₉₀₉ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

2. The organic electroluminescence device according to claim 1; wherein the compound M4 is a compound represented by a formula (41) below, 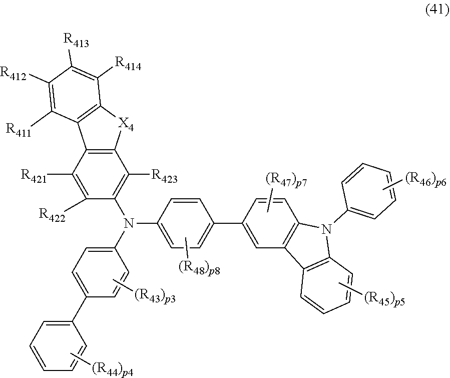
where, in the formula (41):
X₄ is C(Ra₄)(Rb₄), an oxygen atom, or a sulfur atom;
a combination of Ra₄ and Rb₄ are mutually bonded to form a substituted or unsubstituted monocyclic ring, mutually bonded to form a substituted or unsubstituted fused ring, or not mutually bonded;
Ra₄ and Rb₄ forming neither the substituted or unsubstituted monocyclic ring nor the substituted or unsubstituted fused ring each independently represent the same as R₄₁ to R₄₆ forming neither the substituted or unsubstituted monocyclic ring nor the substituted or unsubstituted fused ring;
p3 to p8 respectively represent the same as p3 to p8 in the formula (4);
R₄₁₁ to R₄₁₄ each independently represent the same as R₄₁ in the formula (4);
R₄₂₁ to R₄₂₃ each independently represent the same as R₄₂ in the formula (4); and
R₄₃ to R₄₅ respectively represent the same as R₄₃ to R₄₈ in the formula (4).

3. The organic electroluminescence device according to claim 1, wherein the compound M4 is a compound represented by a formula (42) below, 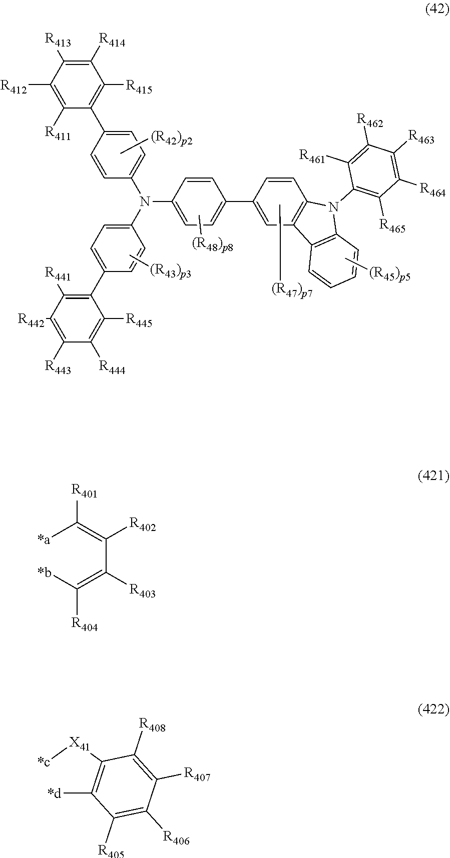
where, in the formula (42):
p2, p3, p5, p7, and p8 respectively represent the same as p2, p3, p5, p7, and p8 in the formula (4);
R₄₂, R₄₃, R₄₅, R₄₇, and R₄₈ respectively represent the same as R₄₂, R₄₃, R₄₅, R₄₇, and R₄₈ in the formula (4);
at least one combination selected from the group consisting of combinations of adjacent two or more of R₄₁₁ to R₄₁₅, combinations of adjacent two or more of R₄₄₁ to R₄₄₅, and combinations of adjacent two or more of R₄₆₁ to R₄₆₅ are mutually bonded to form a ring represented by the formula (421) or (422);
R₄₁₁ to R₄₁₅ not forming a ring represented by the formula (421) or (422) each independently represent the same as R₄₁ forming neither the substituted or unsubstituted monocyclic ring nor the substituted or unsubstituted fused ring;
R₄₄₁ to R₄₄₅ not forming a ring represented by the formula (421) or (422) each independently represent the same as R₄₄ forming neither the substituted or unsubstituted monocyclic ring nor the substituted or unsubstituted fused ring; and
R₄₆₁ to R₄₆₅ not forming a ring represented by the formula (421) or (422) each independently represent the same as R₄₆ forming neither the substituted or unsubstituted monocyclic ring nor the substituted or unsubstituted fused ring, in the formula (421):
at least one combination of adjacent two or more of R₄₀₁ to R₄₀₄ are mutually bonded to form a substituted or unsubstituted monocyclic ring, mutually bonded to form a substituted or unsubstituted fused ring, or not mutually bonded;
R₄₀₁ to R₄₀₄ forming neither the substituted or unsubstituted monocyclic ring nor the substituted or unsubstituted fused ring each independently represent the same as R₄₁ forming neither the substituted or unsubstituted monocyclic ring nor the substituted or unsubstituted fused ring; and
*a and *b each represent a bonding position,
in the formula (422):
X₄₁ is C(Rc₄)(Rd₄), an oxygen atom, a sulfur atom, or N(Rf₄);
a combination of Rc₄ and Rd₄ are mutually bonded to form a substituted or unsubstituted monocyclic ring, mutually bonded to form a substituted or unsubstituted fused ring, or not mutually bonded;
at least one combination of adjacent two or more of R₄₀₅ to R₄₀₈ are mutually bonded to form a substituted or unsubstituted monocyclic ring, mutually bonded to form a substituted or unsubstituted fused ring, or not mutually bonded;
Rf₄, R₄₀₅ to R₄₀₈ forming neither the substituted or unsubstituted monocyclic ring nor the substituted or unsubstituted fused ring, and Rc₄ and Rd₄ forming neither the substituted or unsubstituted monocyclic ring nor the substituted or unsubstituted fused ring each independently represent the same as R₄₆ forming neither the substituted or unsubstituted monocyclic ring nor the substituted or unsubstituted fused ring; and
*c and *d each represent a bonding position.

4. The organic electroluminescence device according to claim 1, wherein the first layer has a film thickness of 70 nm or more.

5. The organic electroluminescence device according to claim 1, wherein, of at least one layer provided between the anode and emitting layer, the first layer has a largest film thickness.

6. The organic electroluminescence device according to claim 1, further comprising: a second layer provided between the first layer and the anode, wherein
the second layer is smaller in film thickness than the first layer,
the second layer comprises a compound M5 and a compound M6,
the compound M5 and the compound M4 are mutually the same or different, and
the compound M6 is an accepting compound.

7. The organic electroluminescence device according to claim 1, further comprising: a third layer provided between the first layer and the emitting layer, wherein
the third layer is smaller in film thickness than the first layer,
the third layer comprises a compound M7, and
the compound M7 and the compound M4 are mutually different.

8. The organic electroluminescence device according to claim 1, wherein, in a compound represented by the formula (1), L is a substituted or unsubstituted aromatic hydrocarbon ring having 6 to 14 ring carbon atoms.

9. The organic electroluminescence device according to claim 1, wherein a compound represented by the formula (1) is represented by a formula (101) below, 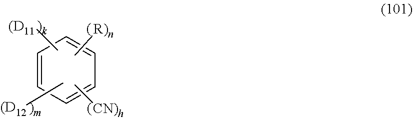
where, in the formula (101):
D₁₁ and D₁₂ respectively represent the same as D₁₁ and D₁₂ in the formula (1);
h is 2, 3, 4, or 5;
k is 1, 2, 3, or 4;
m is 0, 1, 2, or 3;
n is 0, 1, 2, or 3;
h+k+m+n=6 is satisfied;
R is each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₀₈, a group represented by —COOR₉₀₉, a cyano group, a nitro group, a group represented by —(═O)(R₉₃₁)(R₉₃₂), a group represented by —Ge(R₉₃₃)(R₉₃₄)(R₉₃₅), a group represented by —B(R₉₃₆)(R₉₃₇), a substituted or unsubstituted aryl group having 6 to 50 ring carbon atoms, or a substituted or unsubstituted heterocyclic group having 5 to 50 ring atoms; and
a plurality of R are mutually the same or different.

10. The organic electroluminescence device according to claim 9, wherein
h is 2, 3, or 4,
k is 1, 2, or 3,
m is 0, 1, or 2,
n is 1, 2, or 3, and
at least one R is a substituent, among which R as at least one substituent is bonded to a benzene ring in the formula (101) via carbon-carbon bonding.

11. The organic electroluminescence device according to claim 1, wherein at least one D₁₁ is a group represented by the formula (12) or (13).

12. The organic electroluminescence device according to claim 1, wherein at least one D₁₁ is a group represented by a formula (121), (122), or (131), 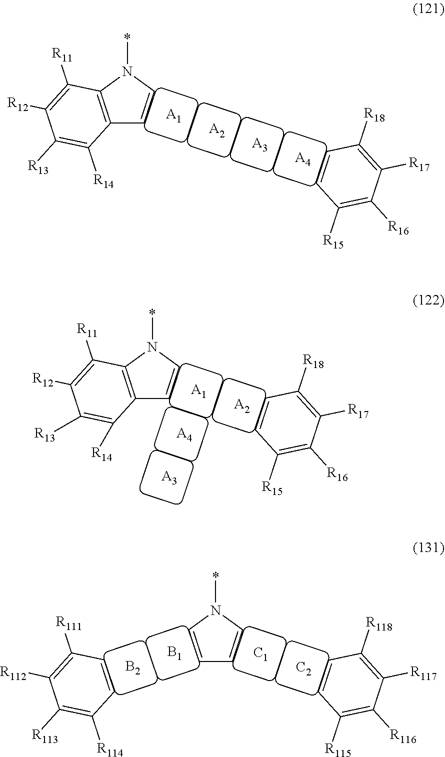
where, in the formulae (121) and (122):
R₁₁ to R₁₈ respectively represent the same as R₁₁ to R₁₈ in the formula (12); and
of a ring A₁, a ring A₂, a ring A₃, and a ring A₄, two of the rings A₁, A₂, A₃, and A₄ are each a cyclic structure represented by the formula (14) and the remaining two of the rings A₁, A₂, A₃, and A₄ are each a cyclic structure represented by the formula (15),
in the formula (131):
R₁₁₁ to R₁₁₈ respectively represent the same as R₁₁₁ to R₁₁₈ in the formula (13);
one of a ring B₁ and a ring B₂ is a cyclic structure represented by the formula (14) and the other of the ring B₁ and the ring B₂ is a cyclic structure represented by the formula (15); and
one of a ring C1 and a ring C2 is a cyclic structure represented by the formula (14) and the other of the ring C1 and the ring C2 is a cyclic structure represented by the formula (15), and
* in the formulae (121), (122), and (131) represents a bonding position to L in the formula (1).

13. The organic electroluminescence device according to claim 12, wherein the ring A₁ and the ring A₃ are each a cyclic structure represented by the formula (14) and the ring A₂ and the ring A₄ are each a cyclic structure represented by the formula (15),
the ring B₁ is a cyclic structure represented by the formula (14) and the ring B₂ is a cyclic structure represented by the formula (15), and
the ring C₁ is a cyclic structure represented by the formula (14) and the ring C₂ is a cyclic structure represented by the formula (15).

14. The organic electroluminescence device according to claim 12, wherein at least one D₁₁ is a group represented by the formula (131).

15. The organic electroluminescence device according to claim 12, wherein at least one D₁₁ is a group represented by a formula (123), (124), (125), or (132), 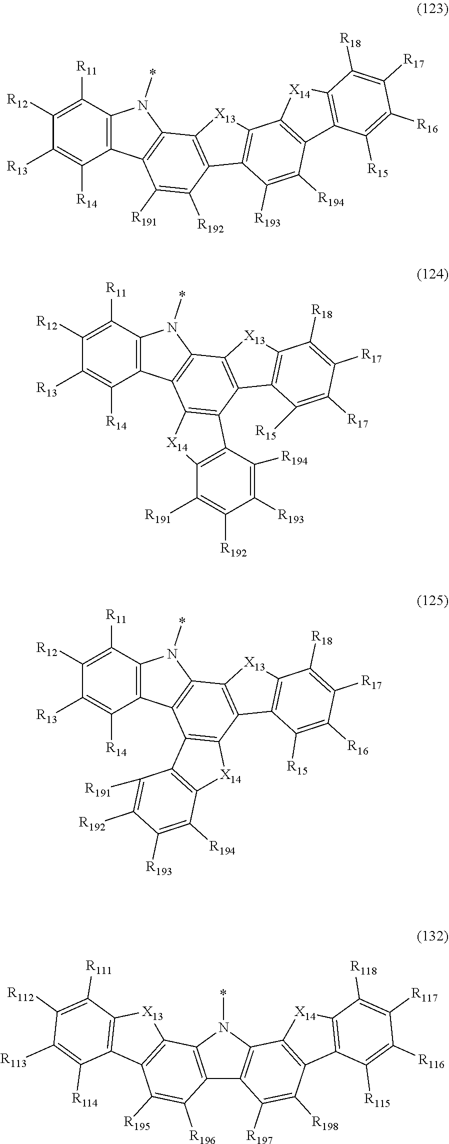
where, in the formulae (123), (124), and (125): R₁₁ to R₁₈ respectively represent the same as R₁₁ to R₁₈ in the formula (12); and R₁₉₁ to R₁₉₄ each independently represent the same as R₁₉ in the formula (14),
in the formula (132); R₁₁₁ to R₁₁₈ respectively represent the same as R₁₁₁ to R₁₁₈ in the formula (13); and R₁₉₅ to R₁₉₈ each independently represent the same as R₁₉ in the formula (14), and
in the formulae (123), (124), (125), and (132), X₁₃ and X₁₄ each independently represent the same as X₁ in the formula (15), and * represents a bonding position to L in the formula (1).

16. The organic electroluminescence device according to claim 15, wherein X₁₃ is a sulfur atom.

17. The organic electroluminescence device according to claim 15, wherein at least one D₁ is a group represented by the formula (132).

18. The organic electroluminescence device according to claim 1, wherein
D₁₂ is a group represented by the formula (11) or (12), and
m is an integer of 1 or more.

19. The organic electroluminescence device according to claim 18, wherein D₁₂ is a group represented by the formula (12).

20. The organic electroluminescence device according to claim 1, wherein a group represented by the formula (12) is a group selected from the group consisting of groups represented by formulae (12A), (12B), (12C), (12D), (12E), and (12F) below, 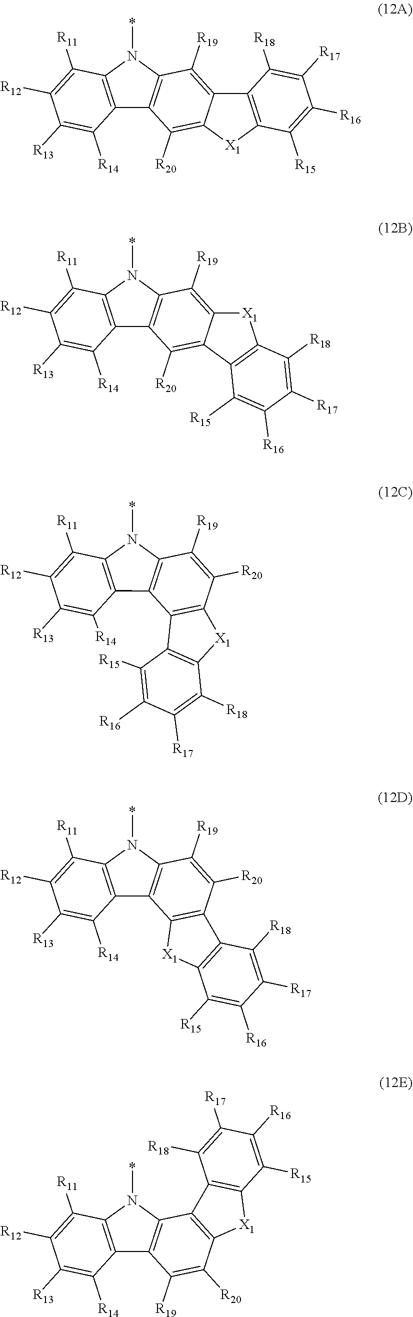 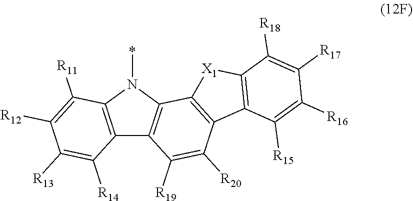
where, in the formulae (12A), (12B), (12C), (12D), (12E), and (12F):
R₁₁ to R₁₈ each independently represent the same as R₁₁ to R₁₈ in the formula (12);
R₁₉ and R₂₀ each independently represent the same as R₁₉ in the formula (14);
X₁ represents the same as X₁ in the formula (15); and
* in the formulae (12A), (12B), (12C), (12D), (12E), and (12F) represents a bonding position to L in the formula (1).

21. The organic electroluminescence device according to claim 1, wherein the emitting layer further comprises a compound M2 in addition to the compound M1,
the compound M2 is a fluorescent compound, and
a lowest singlet energy S1(M1) of the compound M1 and a lowest singlet energy S₁(M2) of the compound M2 satisfy a relationship of a numerical formula (Numerical Formula 1) below,
S₁(M1)>S₁(M2) (Numerical Formula 1).

22. The organic electroluminescence device according to claim 1, wherein
the emitting layer further comprises a compound M3 in addition to the compound M1, and
a lowest singlet energy S₁(M1) of the compound M1 and a lowest singlet energy S₁(M3) of the compound M3 satisfy a relationship of a numerical formula (Numerical Formula 2) below;
S₁(M3)>S₁(M1) (Numerical Formula 2).

23. The organic electroluminescence device according to claim 1, wherein
the emitting layer further comprises a compound M2 and a compound M3 in addition to the compound M1,
the compound M2 is a fluorescent compound, and
a lowest singlet energy S₁(M1) of the compound M1, a lowest singlet energy S₁(M2) of the compound M2, and a lowest singlet energy S₁(M3) of the compound M3 satisfy a relationship of a numerical formula (Numerical Formula 3) below,
S₁(M3)>S₁(M1)>S₁(M2) (Numerical Formula 3).

24. An electronic device comprising the organic electroluminescence device according to claim 1.
